(19) United States
(12) Patent Application Publication
(10) Pub. No.: US 2016/0048082 A1
(43) Pub. Date: Feb. 18, 2016

(54) PATTERN-FORMING METHOD, ELECTRONIC DEVICE AND METHOD FOR PRODUCING SAME, AND DEVELOPING FLUID

(71) Applicant: FUJIFILM Corporation, Tokyo (JP)

(72) Inventors: Masafumi KOJIMA, Haibara-gun (JP); Akiyoshi GOTO, Haibara-gun (JP); Michihiro SHIRAKAWA, Haibara-gun (JP); Hajime FURUTANI, Haibara-gun (JP); Akinori SHIBUYA, Haibara-gun (JP)

(73) Assignee: FUJIFILM CORPORATION, Tokyo (JP)

(21) Appl. No.: 14/919,329

(22) Filed: Oct. 21, 2015

Related U.S. Application Data
(63) Continuation of application No. PCT/JP2014/060860, filed on Apr. 16, 2014.

(30) Foreign Application Priority Data
May 2, 2013 (JP) 2013-097185

(51) Int. Cl. G03F 7/32; G03F 7/20

(52) U.S. Cl. CPC G03F 7/325; G03F 7/20; G03F 7/2053; G03F 7/2041

(57) ABSTRACT

A pattern-forming method includes forming a film on a substrate by using an actinic ray-sensitive or radiation-sensitive resin composition containing at least a resin that exhibits, due to an action of an acid, increase in polarity and decrease in solubility with respect to a developer including an organic solvent, and a compound that generates an acid by being irradiated with actinic rays or radiation; exposing the film; and forming a negative tone pattern by developing the exposed film with a developer including an organic solvent, in which the developer includes at least one compound A selected from the group consisting of an onium salt, a polymer having an onium salt, a nitrogen-containing compound including three or more nitrogen atoms, a basic polymer, and a phosphorus-based compound.

### CROSS-REFERENCE TO RELATED APPLICATIONS

This application is a Continuation of PCT International Application No. PCT/JP2014/060860 filed on Apr. 16, 2014, which claims priority under 35 U.S.C §119(a) to Japanese Patent Application No. 2013-097185 filed on May 2, 2013. Each of the above application(s) is hereby expressly incorporated by reference, in its entirety, into the present application.

### BACKGROUND OF THE INVENTION

1. Field of the Invention

The present invention relates to a pattern-forming method used in a production step of a semiconductor such as an IC, production of a circuit substrate such as liquid crystal or a thermal head, and further other photofabrication lithography steps. Specifically, the invention relates to a pattern-forming method which is preferable in the exposure in an ArF exposure apparatus and an ArF immersion-type projection exposure apparatus using a far ultraviolet ray having a wavelength of 300 nm or lower as a light source, a developer used in the pattern-forming method, an electronic device producing method, and an electronic device.

2. Description of the Related Art

A pattern-forming method using chemical amplification, so as to compensate for the desensitization by light absorption after a resist for a KrF excimer laser (248 nm) is used.

For example, in JP5056974B, in order to form a resist pattern that exhibits excellent lithography characteristics together with suppressing film thickness reduction of a resist film, a pattern-forming method in which a developer includes a nitrogen-containing compound is disclosed. Particularly, in a section of examples of JP5056974B, as the nitrogen-containing compound, tri-n-octylamine and the like are specifically used.

### SUMMARY OF THE INVENTION

Meanwhile, recently, in order to improve the performance of electronic apparatuses, it has been required to manufacture fine wire, and accordingly it is required to form a pattern of which an aspect ratio is higher. However, there was a problem in that, if a fine pattern has a high aspect ratio, the pattern after the development may collapse.

The inventors of the invention have found that if a pattern is formed by the method disclosed in JP5056974B, a pattern of a level required in the related art is able to be formed, but if a fine pattern of a level with a high aspect ratio, which has been recently required, is formed, collapse of the pattern occurs.

In view of this circumstances, the invention is to provide a pattern-forming method in which collapse of a pattern is suppressed even when a fine pattern with a high aspect ratio has been formed.

In addition, the invention is to provide an electronic device producing method including the pattern-forming method, an electronic device produced by the producing method, and a developer used in the pattern-forming method.

The inventors of the invention have diligently studied the problems in the related art, and have thereby found that the problems can be solved by including a certain compound in the developer.

That is, the objects below can be achieved by configurations described below.

(1) A pattern-forming method including forming a film on a substrate by using an actinic light-sensitive or radiation-sensitive resin composition containing at least a resin that exhibits increase in polarity and decrease in solubility with respect to a developer including an organic solvent, due to an action of an acid; exposing the film; and forming a negative tone pattern by developing the exposed film with a developer including an organic solvent, in which the developer includes at least one compound A selected from the group consisting of an onium salt, a polymer having an onium salt, a nitrogen-containing compound including three or more nitrogen atoms, a basic polymer, and a phosphorus-based compound.

(2) The pattern-forming method according to (1), in which the onium salt is at least one selected from the group consisting of an onium salt represented by Formula (1-1) described below and an onium salt represented by Formula (1-2) described below,

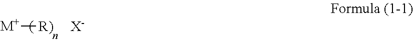

in Formula (1-1) and Formula (1-2), M represents, a nitrogen atom, a phosphorus atom, a sulfur atom, or an iodine atom, R's each are independently a hydrogen atom, an aliphatic hydrocarbon group that may include a heteroatom, an aromatic hydrocarbon group that may include a heteroatom, or a group obtained by combining two or more types thereof, and X⁻ represents a monovalent anion;

in Formula (1-2), L represents a divalent linking group;

in Formula (1-1), n represents an integer of 2 to 4, and n represents 4 if M is a nitrogen atom or a phosphorus atom, n represents 3 if M is a sulfur atom, and n represents 2 if M is an iodine atom;

in Formula (1-2), m's each independently represent an integer of 1 to 3; m represents 3 if M is a nitrogen atom or a phosphorus atom, m represents 2 if M is a sulfur atom, and m represents 1 if M represents an iodine atom; and

plural R's may be bonded to each other to form a ring.

(3) The pattern-forming method according to (1) or (2), in which the basic polymer is a polymer having an amino group.

(4) The pattern-forming method according to any one of (1) to (3), in which the basic polymer is a polymer having a repeating unit represented by Formula (2) described below,

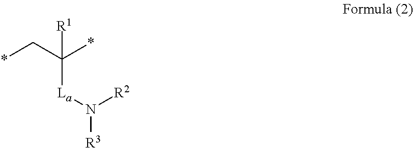

in Formula (2), R¹ represents a hydrogen atom or an alkyl group, R² and R³ each independently represent a hydrogen atom, an alkyl group that may include a heteroatom, a cycloalkyl group that may include a heteroatom, or an aromatic group that may include a heteroatom, Lₐ represents a divalent linking group, and R² and R³ may be bonded to each other to form a ring.

(5) The pattern-forming method according to any one of (1) or (4), in which a ratio of a molecular weight occupied by carbon atoms in cations of the onium salt to a total molecular weight of cations in the onium salt is 0.75 or less.

(6) The pattern-forming method according to any one of (2) to (5), in which pKa of a conjugate acid of an anion is greater than 4.0.

(7) The pattern-forming method according to any one of (1) to (6), in which a total content of the compound A in the developer is 10% by mass or less with respect to a total amount of the developer.

(8) The pattern-forming method according to any one of (1) to (7), in which the exposure is exposure by an ArF excimer laser.

(9) The pattern-forming method according to any one of (1) to (8), in which the exposure is liquid immersion exposure.

(10) The pattern-forming method according to any one of (1) to (9), in which a content of the organic solvent in the developer including the organic solvent is 90% by mass or greater and less than 100% by mass with respect to a total amount of the developer.

(11) An electronic device producing method including the pattern-forming method according to any one of (1) to (10).

(12) An electronic device produced by the electronic device producing method according to (11).

(13) A developer used in the pattern-forming method according to any one of (1) to (10), including at least one compound A selected from the group consisting of an onium salt, a polymer having an onium salt, a nitrogen-containing compound including three or more nitrogen atoms, a basic polymer, and a phosphorus-based compound.

(14) The developer according to (13), further including an organic solvent, in which a content of the organic solvent is 90% by mass or greater and less than 100% by mass.

According to the invention, it is possible to provide a pattern-forming method in which even when a fine pattern having a high aspect is formed, collapse of the pattern is suppressed.

In addition, according to the invention, the electronic device producing method including the pattern-forming method, an electronic device produced by the producing method, and a developer used in the pattern-forming method can be provided.

### DESCRIPTION OF THE PREFERRED EMBODIMENTS

Hereinafter, the embodiments of the invention are described in detail.

With respect to an expression of a group (atomic group) in this specification, expressions without “substituted” or “unsubstituted” include a group (atomic group) not having a substituent or a group (atomic group) having a substituent. For example, an expression “alkyl group” includes an alkyl group not having a substituent (unsubstituted alkyl group) and also an alkyl group having a substituent (substituted alkyl group).

An “actinic ray” or “radiation” in the specification means, for example, a far ultraviolet ray represented by a bright line spectrum of a mercury lamp, or an excimer laser, an extreme ultraviolet ray (EUV ray), an X ray, or an electron beam (EB). In addition, according to the invention, “light” refers to an actinic ray or radiation.

In addition, with respect to the term “exposure” in this specification includes, unless described otherwise, an exposure by a far ultraviolet ray or an extreme ultraviolet ray represented by a bright line spectrum of a mercury lamp or an excimer laser; an exposure by an X ray; a drawing by a particle ray such as an electron beam. an ion beam; or the like.

In this specification, the numerical range indicated by using “to” means a range including numerical values before and after “to” as minimum and maximum values.

In addition, in the specification, “(meth)acrylate” represents acrylate and methacrylate, “(meth)acryl” represents acryl and methacryl, and “(meth)acryloyl” represents acryloyl and methacryloyl.

One of the characteristics of the invention is to use a developer including a certain compound.

The certain compound is at least one compound selected from the group consisting of an onium salt, a polymer having an onium salt, a nitrogen-containing compound including three or more nitrogen atoms, a basic polymer, and a phosphorus-based compound. As a reason for exhibiting a certain effect obtained by using these compounds, a resin of which the polarity increases and solubility with respect to the developer including an organic solvent decreases due to the action of an acid acts with an acid so as to generate a group (particularly, polar group), the group and the compound strongly interact with each other, a mechanical strength of the formed pattern increases, and resultantly, collapse of the pattern is suppressed.

The pattern-forming method according to the invention includes at least three steps described below:

(1) a step of forming a film on a substrate by using an actinic ray-sensitive or radiation-sensitive resin composition containing at least a resin that exhibits increase in polarity and decrease in solubility with respect to a developer including an organic solvent, due to an action of an acid;

(2) a step of exposing the film; and

(3) a step of forming a negative tone pattern by developing the exposed film with a developer including an organic solvent.

Hereinafter, respective steps are described.

[Step (1): Film Forming Step]

Step (1) is a step of forming a film (hereinafter, referred to as “resist film”) on a substrate by using an actinic ray-sensitive or radiation-sensitive resin composition.

First, materials used in this step are described, and then a sequence of Step (1) is described.

<Actinic Ray-Sensitive or Radiation-Sensitive Resin Composition>

Hereinafter, the actinic ray-sensitive or radiation-sensitive resin composition (hereinafter, referred to as “composition” or “composition for forming resist film”) used in the invention is described.

The composition includes at least a resin (A) that exhibits increase in polarity and decrease in solubility with respect to a developer including an organic solvent, due to an action of an acid. In other words, the composition includes at least the resin (A) in which polarity increases due to an action of an acid that exhibits decrease solubility with respect to a developer including an organic solvent.

First, the resin (A) and other optional compounds are described.

[1] Resin (A) that Exhibits Increase in Polarity and Decrease in Solubility with Respect to Developer Including Organic Solvent, Due to an Action of an Acid (Hereinafter, Simply Referred to as “Resin (A)”)

As the resin (A) that is contained in the composition used in the invention and exhibits increase in polarity and decrease in solubility with respect to developer including an organic solvent, due to an action of an acid, for example, a resin (hereinafter, referred to as “acid-decomposable resin” or “resin (A)”) having a group (hereinafter, referred to as “acid-decomposable group”) in a main chain or a side chain of the resin or in both of the main chain and the side chain which is decomposed due to an action of an acid and that generates a polar group can be included.

The acid-decomposable group preferably has a structure in which a polar group is protected by a group which decomposes and leaves (is eliminated) due to an action of an acid.

The polar group is not particularly limited as long as the polar group is a group which is sparingly soluble or not soluble in the developer including the organic solvent, but an acidic group (a group decomposed by 2.38% by mass tetramethylammonium hydroxide aqueous solution used as a developer of a resist in the related art) such as a phenolic hydroxyl group, a carboxyl group, a fluorinated alcohol group (preferably a hexafluoroisopropanol group), a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, or a tris(alkylsulfonyl)methylene group, an alcoholic hydroxyl group, or the like are included.

In addition, the alcoholic hydroxyl group may be hydroxyl groups which are bonded to hydrocarbon groups except for hydroxyl groups (phenolic hydroxyl groups) which are directly bonded to aromatic rings, and an aliphatic alcohol (for example, fluorinated alcohol group (such as hexafluoroisopropanol group)) in which a hydroxyl group at an a position is substituted with an electron-withdrawing group such as a fluorine atom is excluded. As the alcoholic hydroxyl group, hydroxyl groups of which pKa is 12 or more and 20 or less is preferable.

As a preferable polar group, a carboxyl group, a fluorinated alcohol group (preferably, hexafluoroisopropanol group) and a sulfonic acid group are included.

A group which is preferable as the acid-decomposable group is a group in which hydrogen atoms of these groups are substituted with groups leaving due to an acid.

As the groups that are left (is eliminated) due to an acid, for example, —C(R₃₆)(R₃₇)(R₃₈), —C(R₃₆)(R₃₇)(OR₃₉), and —C(R₀₁)(R₀₂)(OR₃₉) can be included.

In the formula, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

The alkyl groups as R₃₆ to R₃₉, R₀₁, and R₀₂ are preferably alkyl groups having 1 to 8 carbon atoms, and, for example, a methyl group, an ethyl group, a propyl group, an n-butyl group, a sec-butyl group, a hexyl group, and an octyl group can be included.

Cycloalkyl groups as R₃₆ to R₃₉, R₀₁, and R₀₂ may be monocyclic types or polycyclic types. As the monocyclic type, cycloalkyl groups having 3 to 8 carbon atoms are preferable, and as the polycyclic type, cycloalkyl groups having 6 to 20 carbon atoms are preferable. In addition, at least one carbon atom in the cycloalkyl group may be substituted with a heteroatom such as an oxygen atom.

Aryl groups as R₃₆ to R₃₉, R₀₁, and R₀₂ are preferably aryl groups having 6 to 10 carbon atoms, and for example, a phenyl group, a naphthyl group, and an anthryl group can be included.

Aralkyl groups as R₃₆ to R₃₉, R₀₁, and R₀₂ are preferably aralkyl groups having 7 to 12 carbon atoms.

Alkenyl groups as R₃₆ to R₃₉, R₀₁, and R₀₂ are preferably alkenyl groups having 2 to 8 carbon atoms.

As the ring formed by bonding R₃₆ and R₃₇ to each other, (single ring or polycyclic ring) cycloalkyl groups are preferable. As a cycloalkyl group, a monocyclic cycloalkyl group such as a cyclopentyl group or a cyclohexyl group, or a polycyclic cycloalkyl group such as a norbornyl group, a tetracyclodecanyl group, a tetracyclododecanyl group, and an adamantyl group are preferable. A monocyclic cycloalkyl group having 5 to 6 carbon atoms is more preferable, and a monocyclic cycloalkyl group having 5 carbon atoms is particularly preferable.

The acid-decomposable group is preferably a cumyl ester group, an enol ester group, an acetal ester group, or a tertiary alkyl ester group. A tertiary alkyl ester group is more preferable.

The resin (A) preferably has a repeating unit having an acid-decomposable group.

In addition, the resin (A) preferably has a repeating unit represented by General Formula (AI) below, as the repeating unit having the acid-decomposable group. The repeating unit represented by General Formula (AI) is a repeating unit that generates a carboxyl group as the polar group due to an action of an acid.

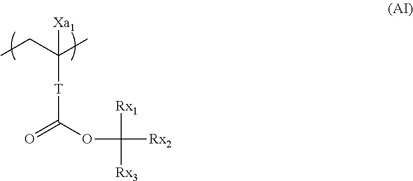

In General Formula (AI),
Xa₁ represents a hydrogen atom, an alkyl group, cyano group, or a halogen atom.

T represents a single bond or a divalent linking group.

Rx₁ to Rx₃ each independently represent an alkyl group or a cycloalkyl group.

Two of Rx₁ to Rx₃ may be bonded to form a ring structure.

As the divalent linking group as T, an alkylene group, a —COO—Rt-group, a —O—Rt-group, a phenylene group, and the like are included. In the formula, Rt represents an alkylene group or a cycloalkylene group.

T is preferably a single bond or a —COO—Rt-group. Rt is preferably an alkylene group having 1 to 5 carbon atoms, and a —CH₂— group, a —(CH₂)₂— group, and a —(CH₂)₃— group are more preferable. T is more preferably a single bond.

An alkyl group as Xa₁ may have a substituent, and as the substituent, for example, a hydroxyl group, a halogen atom (preferably, fluorine atom) are included.

The alkyl group as Xa₁ is preferably a group having 1 to 4 carbon atoms, a methyl group, an ethyl group, a propyl group, a hydroxymethyl group, and a trifluoromethyl group are included, and a methyl group is preferable.

Xa₁ is preferably a hydrogen atom or a methyl group.

The alkyl groups as Rx₁, Rx₂, and Rx₃ may have a straight chain shape or a branched shape, and are preferably groups having 1 to 4 carbon atoms such as a methyl group, an ethyl group, an n-propyl group, an isopropyl group, an n-butyl group, an isobutyl group, and a t-butyl group.

As the cycloalkyl groups as Rx₁, Rx₂, and Rx₃, a monocyclic cycloalkyl group such as a cyclopentyl group, and a cyclohexyl group, and a polycyclic cycloalkyl group such as a norbornyl group, a tetracyclodecanyl group, a tetracyclododecanyl group, and an adamantyl group are preferable.

As the ring structure formed by bonding two of Rx₁, Rx₂, and Rx₃, a monocyclic cycloalkane ring such as a cyclopentyl ring, and a cyclohexyl ring, and a polycyclic cycloalkyl group such as a norbornane ring, a tetracyclodecane ring, a tetracyclododecane ring, and an adamantane ring are preferable. A monocyclic cycloalkane ring having 5 or 6 carbon atoms is particularly preferable.

It is preferable that Rx₁, Rx₂, and Rx₃ each independently represent an alkyl group, and a straight chain or branched alkyl group having 1 or 4 carbon atoms is more preferable.

The respective groups described above may have a substituent, and as the substituent, for example, an alkyl group (having 1 to 4 carbon atoms), a cycloalkyl group (having 3 to 8 carbon atoms), a halogen atom, an alkoxy group (having 1 to 4 carbon atoms), a carboxyl group, and an alkoxycarbonyl group (having 2 to 6 carbon atoms) are included, and a group having 8 or less carbon atoms is preferable. Among them, in view of further enhancing dissolution contrast with respect to the developer including the organic solvent before and after acid decomposition, it is more preferable that the substituent is a group not having a heteroatom such as an oxygen atom, a nitrogen atom, and a sulfur atom (for example, it is preferable that the group is not an alkyl group or the like that is substituted with a hydroxyl group), it is still more preferable that the substituent is a group formed of a hydrogen atom and a carbon atom only, and it is particularly preferable that the substituent is a straight chain or branched alkyl group or a cycloalkyl group.

Hereinafter, specific examples of the repeating unit represented by General Formula (AI) are described below, but the invention is not limited to the specific examples.

In the specific examples, Rx represents a hydrogen atom, CH₃, CF₃, or CH₂OH. Rxa and Rxb respectively represent an alkyl group having 1 to 4 carbon atoms. Xa₁ represents a hydrogen atom, CH₃, CF₃, or CH₂OH. Z represents a substituent, and if there are plural Z's, the plural Z's may be identical to or different from each other. p represents 0 or a positive integer. Specific examples and preferred examples of Z are identical to specific examples and preferred examples of the substituents that may be included in respective groups such as Rx₁ to Rx₃.

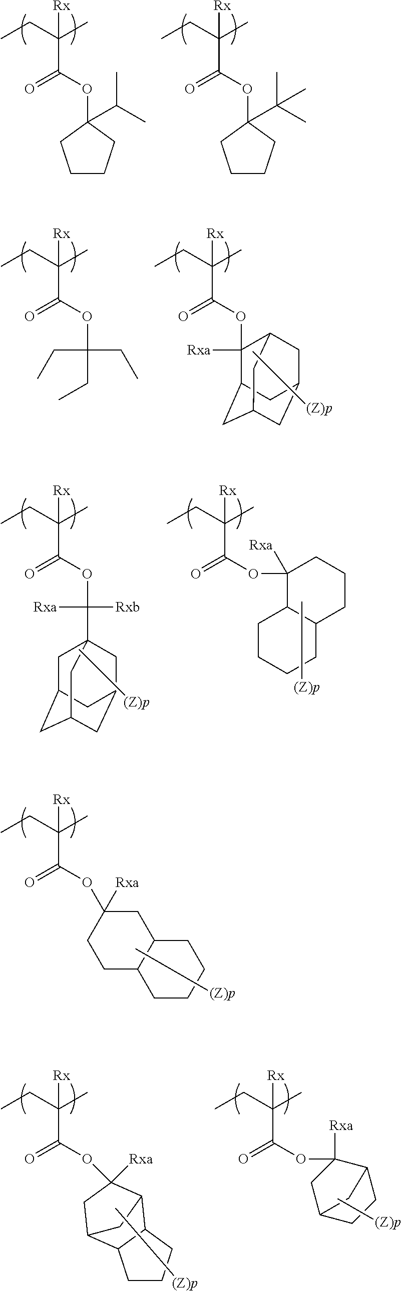

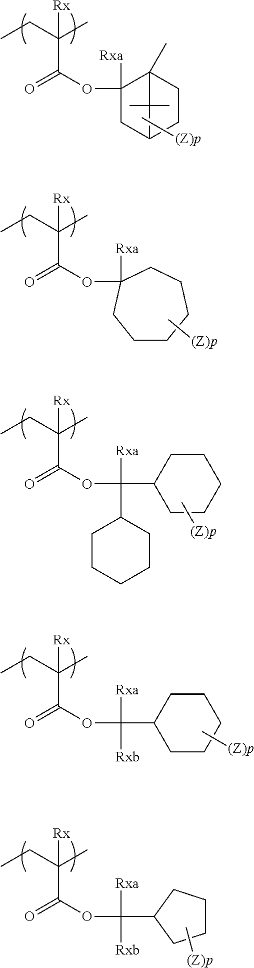

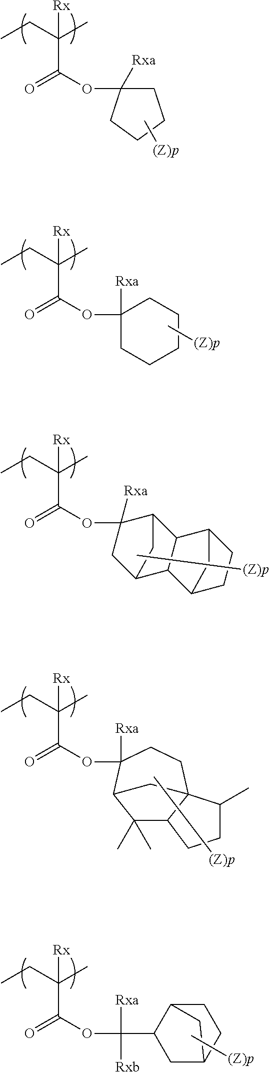

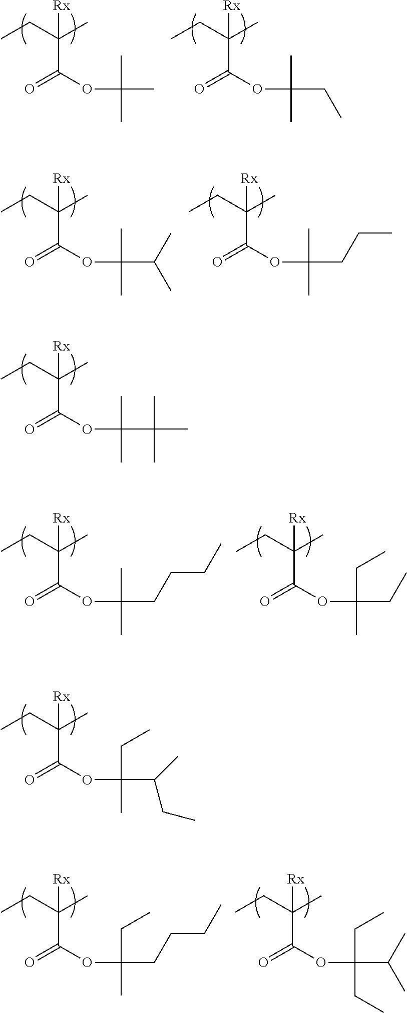

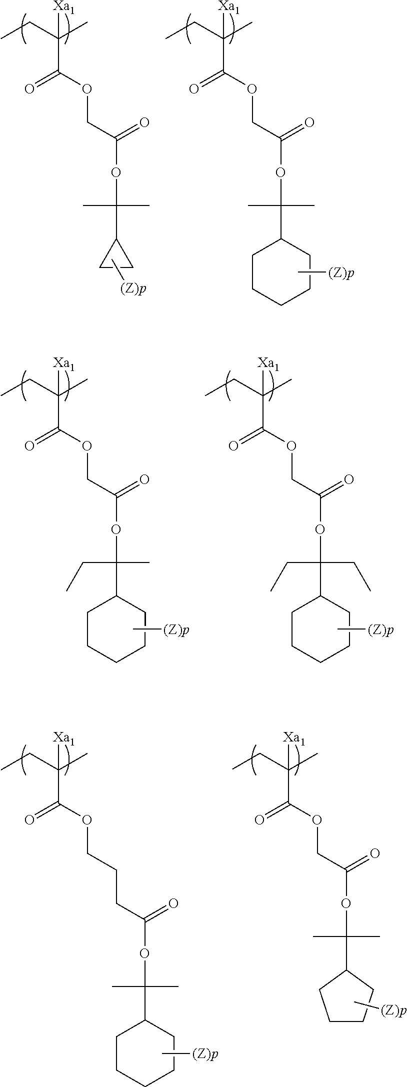

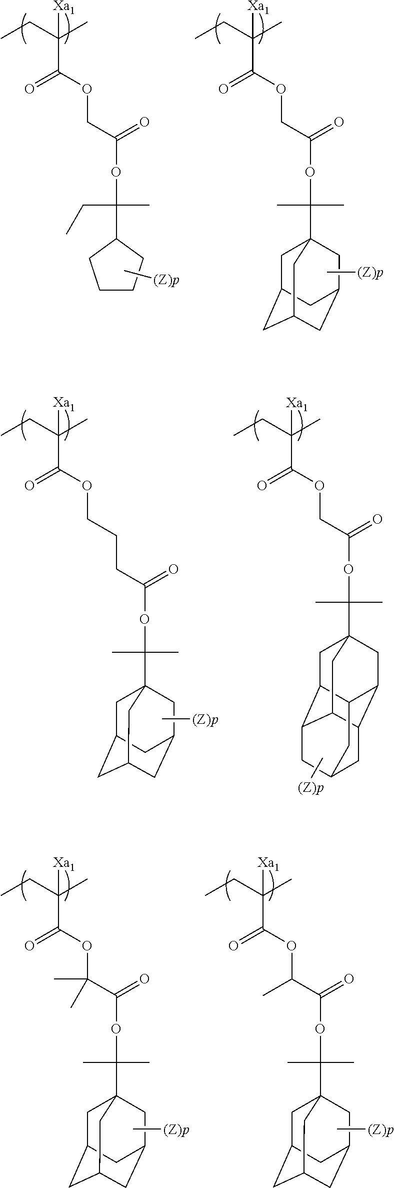

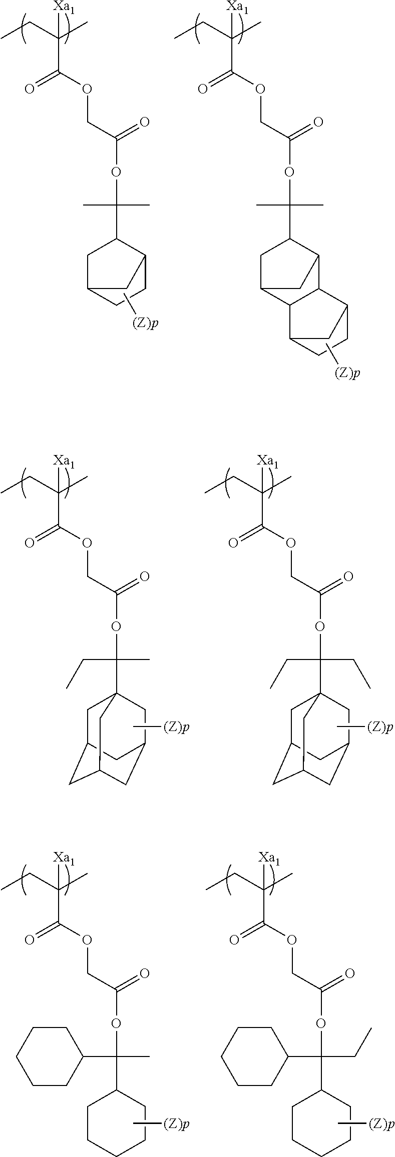

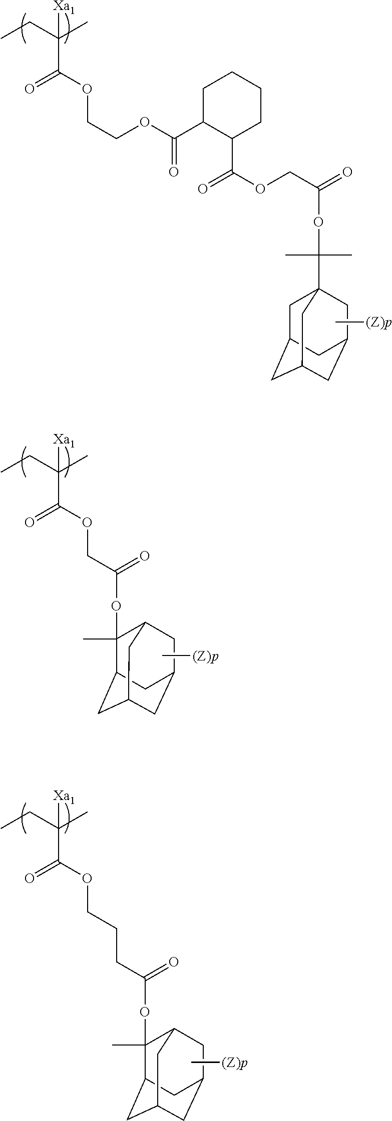

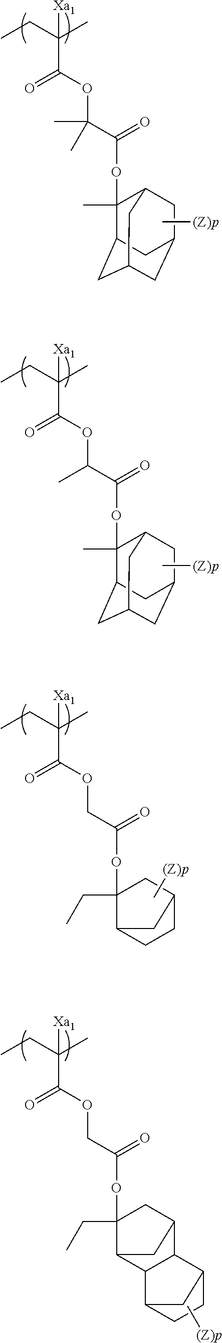

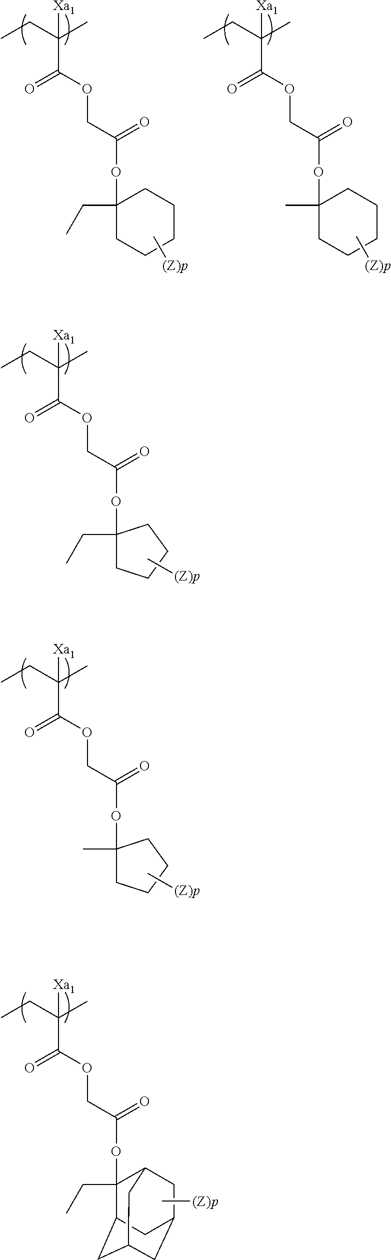

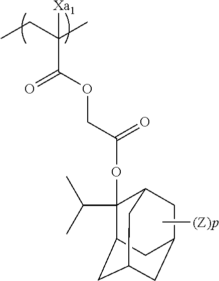

In the specific examples below, Xa represents a hydrogen atom, an alkyl group, a cyano group, or a halogen atom.

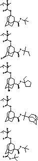

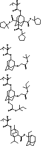

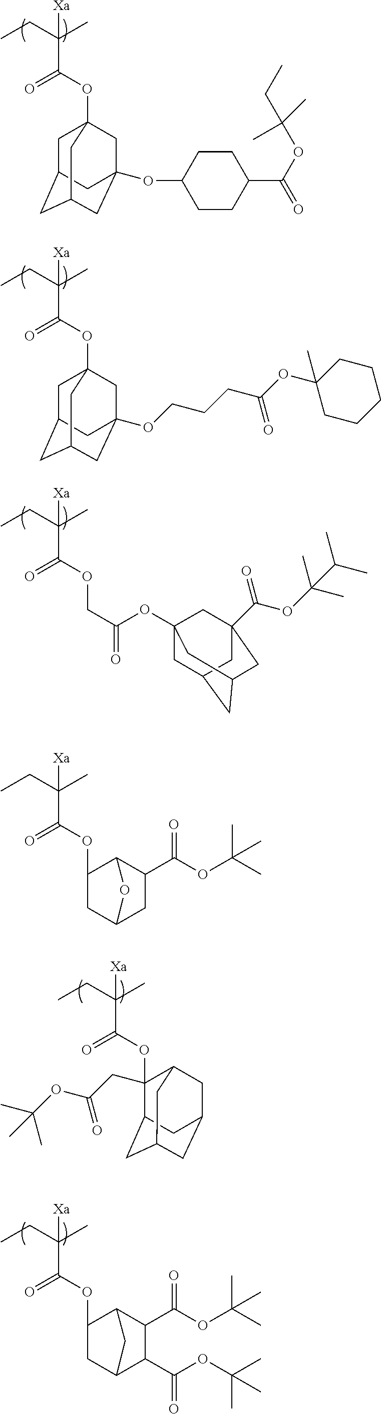

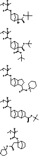

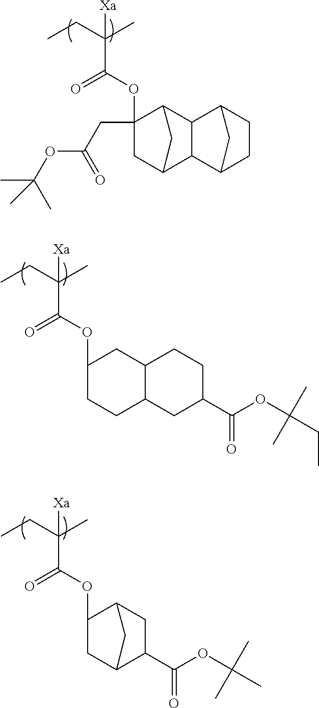

In addition, the resin (A) may have a repeating unit described below that is decomposed due to an action of an acid and generates an alcoholic hydroxyl group, as the repeating unit having the acid-decomposable group. In addition, the alcoholic hydroxyl group has an meaning contrasting with that of a phenolic hydroxyl group, and specifically represents a hydroxyl group that does not exhibit acidity peculiar to the phenolic hydroxyl group in water.

In the specific examples described below, Xa₁ represents a hydrogen atom, CH₃, CF₃, or CH₂OH.

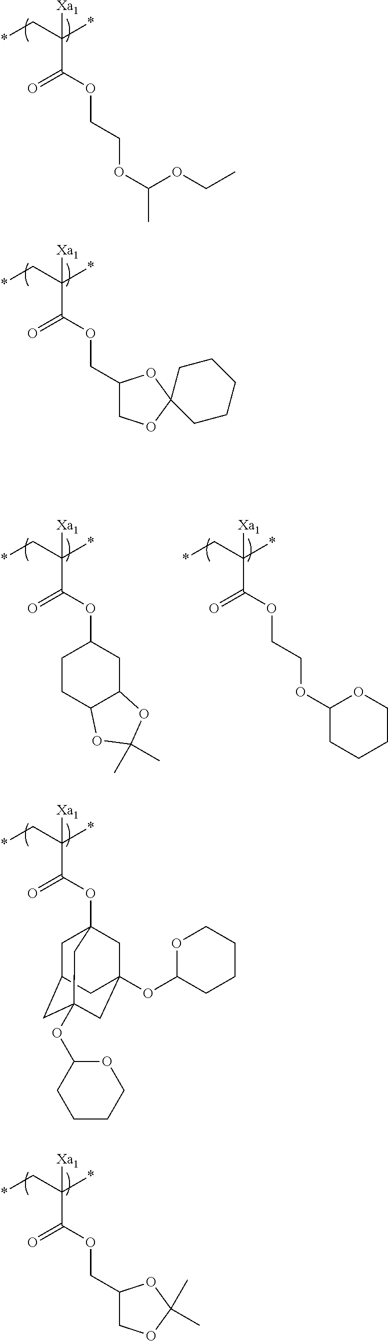

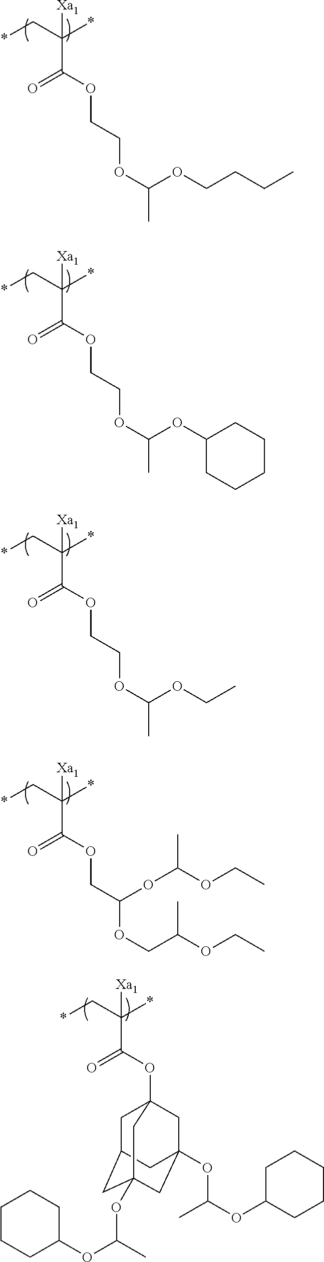

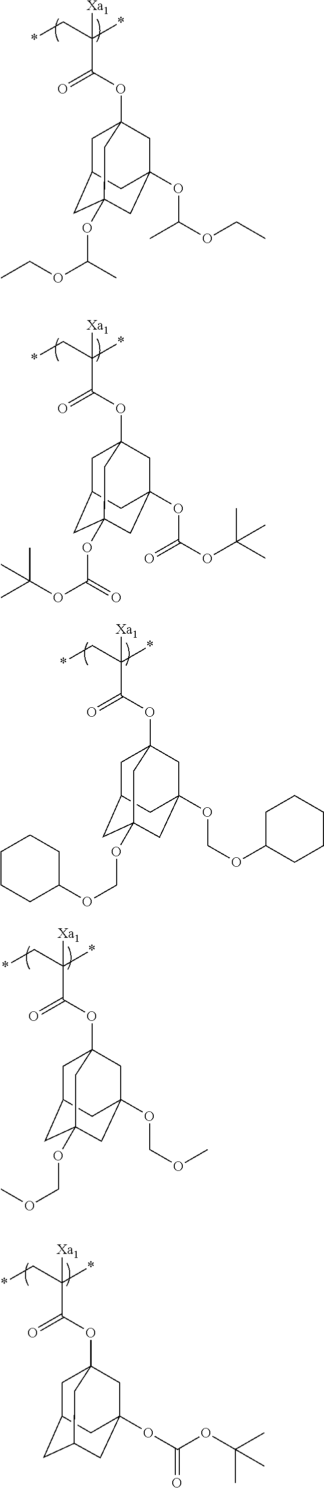

One type of the repeating unit having the acid-decomposable group may be used singly, or two or more types thereof may be used in combination. If two types are used in combination, as a preferred combination, a combination of which the structure is exemplified in Paragraph “0121” and following paragraphs in the specification of US2012/0009522A is included (in addition, the specification of US2012/0009522A is incorporated into this specification).

The content (if plural repeating units having acid-decomposable groups exist, a total content thereof) of the repeating unit having the acid-decomposable group included in the resin (A) is preferably 15% by mol or greater, more preferably 20% by mol or greater, still more preferably 25% by mol or greater, and particularly preferably 40% by mol or greater with respect to the entire repeating units of the resin (A). Among them, it is preferable that the resin (A) has the repeating unit represented by General Formula (AI) described above, and also the content thereof is 40% by mol or greater with respect to the entire repeating units in the resin (A) of the repeating unit represented by General Formula (AI).

In addition, the content of the repeating unit having the acid-decomposable group is preferably 80% by mol or less, more preferably 70% by mol or less, and still more preferably 65% by mol or less with respect to the entire repeating units of the resin (A).

The resin (A) may contain a repeating unit having a lactone structure or a sultone structure.

As the lactone structure or the sultone structure, any repeating unit can be used, as long as the repeating unit has a lactone structure or a sultone structure. A 5-membered to 7-membered ring lactone structure or a 5-membered to 7-membered ring sultone structure is preferable, and a structure in which a bicyclo structure or a spiro structure is formed in the 5-membered to 7-membered ring lactone structure and another ring structure is condensed or a structure in which a bicyclo structure or a spiro structure is formed in the 5-membered to 7-membered ring sultone structure and another ring structure is condensed is more preferable. It is preferable to have a repeating unit having a lactone structure represented by any one of General Formulae (LC1-1) to (LC1-21) or a sultone structure represented by any one of General Formulae (SL1-1) to (SL1-3). In addition, the lactone structure or the sultone structure may be directly bonded to a main chain. Preferable lactone structures are represented by General Formulae (LC1-1), (LC1-4), (LC1-5), (LC1-6), (LC1-13), (LC1-14), and (LC1-17), and a particularly preferable lactone structure is represented by General Formula (LC1-4). If these specific lactone structures are used, LER and development defects become satisfactory.

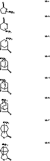

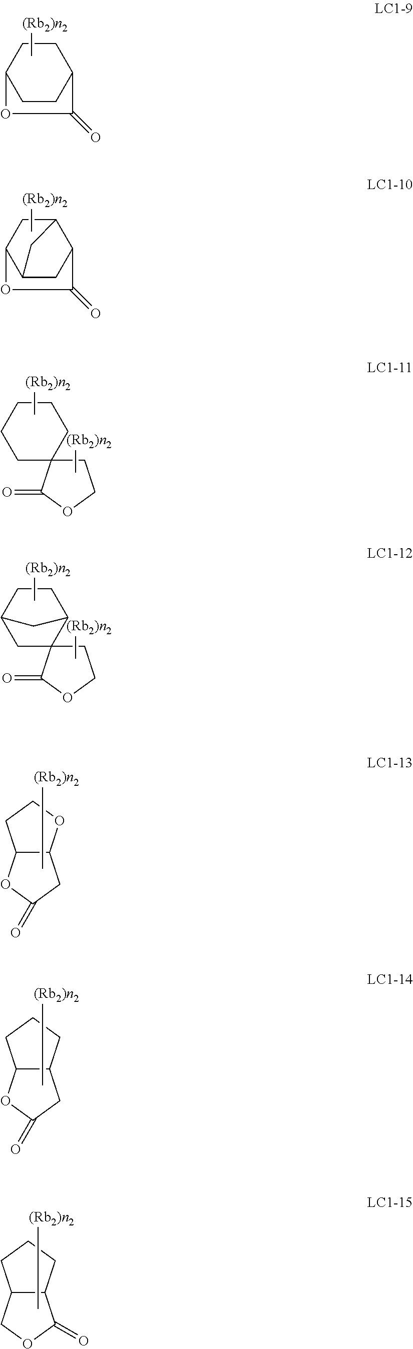

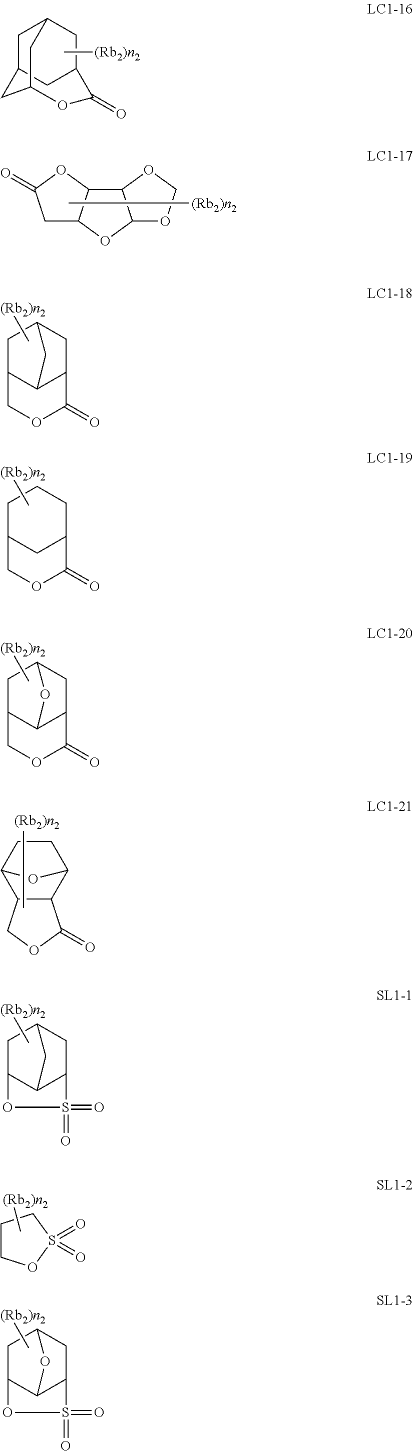

The lactone structure portion or the sultone structure portion may have or may not have a substituent (Rb₂). As a preferable substituent (Rb₂), an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group are included. An alkyl group having 1 to 4 carbon atoms, a cyano group, or an acid-decomposable group is more preferable. n₂ represents 0 to 4 integers. When n₂ is 2 or greater, plural existing substituents (Rb₂) may be identical to or different from each other. In addition, the plural existing substituents (Rb₂) may be bonded together so form a ring.

In the repeating unit having a lactone structure or a sultone structure, optical isomers generally exist, but any of optical isomers may be used. In addition, if one type of optical isomer may be used singly, or plural types of optical isomer may be used in a mixture. If one type of optical isomer is mainly used, an optical purity (ee) thereof is preferably 90% or higher and more preferably 95% or higher.

The repeating unit having the lactone structure or the sultone structure is preferably a repeating unit represented by General Formula (III) below.

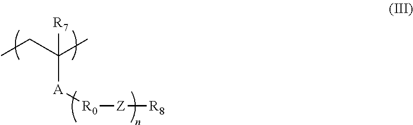

In General Formula (III) described above,
A represents an ester bond (group represented by —COO—) or an amide bond (group represented by —CONH—).

If there are plural R₀'s, the R₀'s each independently represent an alkylene group, a cycloalkylene group, or a combination of two or more kinds thereof.

If there are plural Z's, the Z's each independently represents a single bond, an ether bond, an ester bond, an amide bond, and a urethane bond

(a group represented by

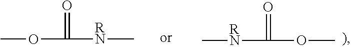

or a urea bond

(group represented by

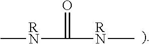

Here, R's each independently represent a hydrogen atom, an alkyl group, a cycloalkyl group, or an aryl group.

R₈ represents a monovalent organic group having a lactone structure or a sultone structure.

n is a number of cycles of a structure represented by —R₀—Z—, and represents an integer of 0 to 5. n is preferably 0 or 1 and is more preferably 0. If n is 0, —R₀—Z— does not exist, and the repeating unit becomes a single bond.

R₇ represents a hydrogen atom, a halogen atom, or an alkyl group.

An alkylene group and a cycloalkylene group as R₀ may have substituents.

Z is preferably an ether bond or an ester bond, and is particularly preferably an ester bond.

An alkyl group as R₇ is preferably an alkyl group having 1 to 4 carbon atoms, and a methyl group and an ethyl group are more preferable, and a methyl group is particularly preferable.

The alkylene group and the cycloalkylene group as R₀ and the alkyl group as R₇ may be substituted, respectively. As the substituent, for example, a fluorine atom, a halogen atom such as a chlorine atom or a bromine atom, a mercapto group, a hydroxyl group, an alkoxy group, and an acyloxy group are included.

R₇ is preferably a hydrogen atom, a methyl group, a trifluoromethyl group, and a hydroxymethyl group.

As a preferable alkylene group as R₀, a chain-shaped alkylene group having 1 to 10 carbon atoms is preferable and a chain-shaped alkylene group having 1 to 5 carbon atoms is more preferable. For example, a methylene group, an ethylene group, and a propylene group are included. A preferable cycloalkylene group is a cycloalkylene group having 3 to 20 carbon atoms, and for example, a cyclohexylene group, a cyclopentylene group, a norbornylene group, and an adamantylene group are preferable. In order to exhibit the effects of the invention, a chain-shaped alkylene group is more preferable and a methylene group is particularly preferable.

A monovalent organic group having a lactone structure or a sultone structure represented by R₈ is not particularly limited, as long as the monovalent organic group has the lactone structure or the sultone structure. As specific examples, a lactone structure or a sultone structure represented by any one of General Formulae (LC1-1) to (LC1-21) and (SL1-1) to (SL1-3) is preferable, and among these, a structure represented by General Formula (LC1-4) is particularly preferable. In addition, n₂ in General Formulae (LC1-1) to (LC1-21) is more preferably an integer of 2 or smaller.

In addition, R₈ is preferably a monovalent organic group having an unsubstituted lactone structure or sultone structure or a monovalent organic group having a lactone structure or a sultone structure having a methyl group, a cyano group, or an alkoxycarbonyl group as a substituent, and more preferably a monovalent organic group having a lactone structure (cyanolactone) having a cyano group as a substituent.

Specific examples of the repeating unit having the group having the lactone structure and the sultone structure are described below, but the invention is not limited thereto.

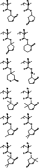

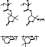

(In this formula, Rx represents H, CH₃, CH₂OH, or CF₃.)

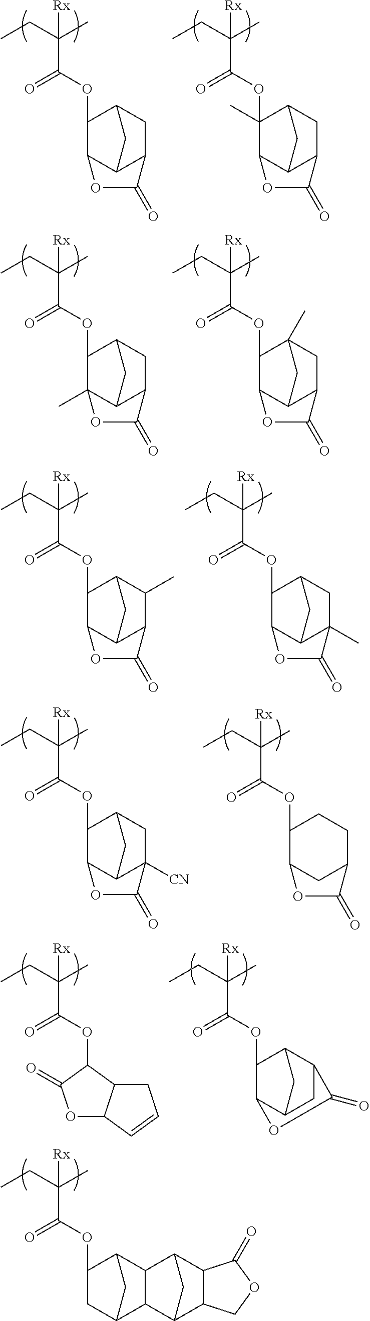

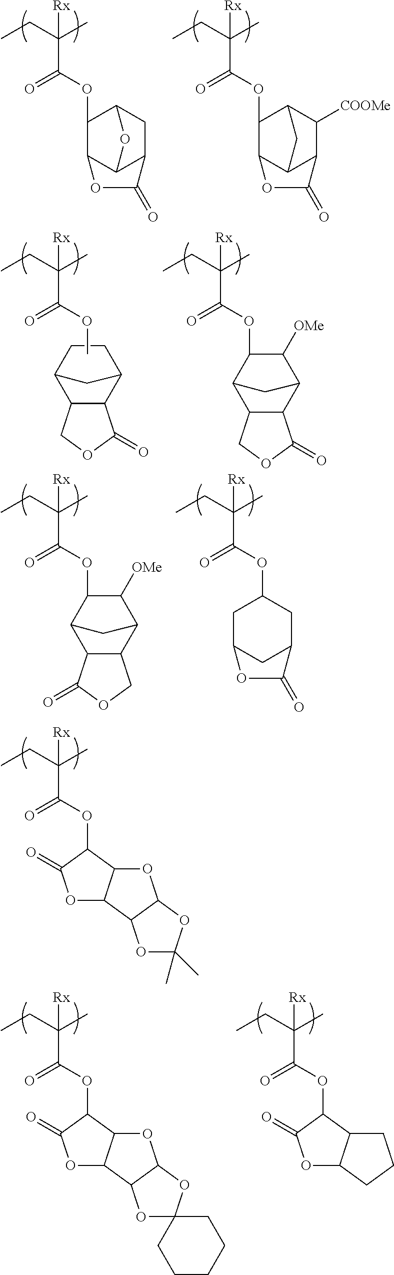

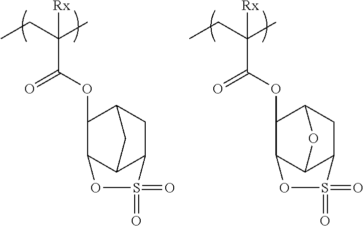

(In this formula, Rx represents H, CH₃, CH₂OH, or CF₃.)

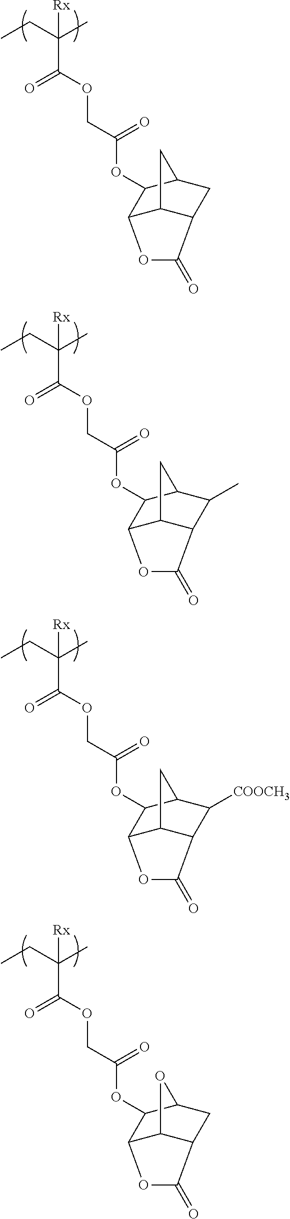

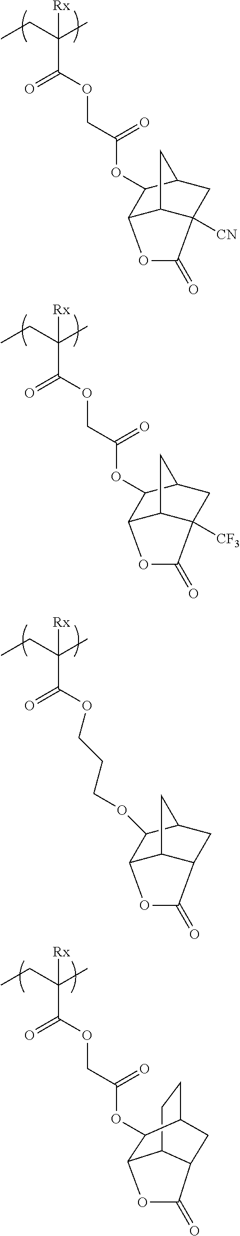

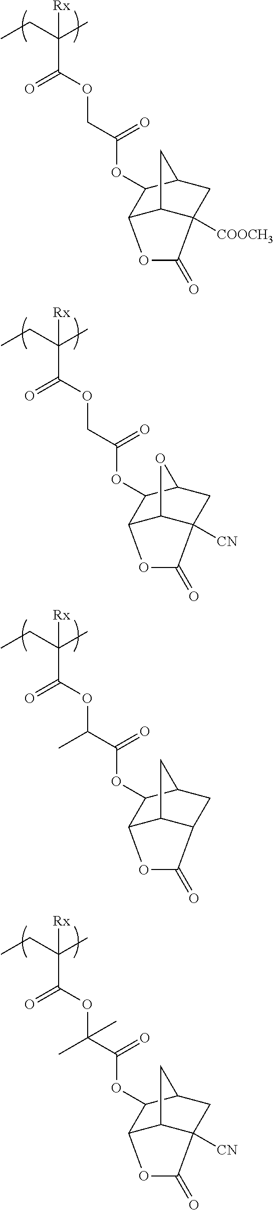

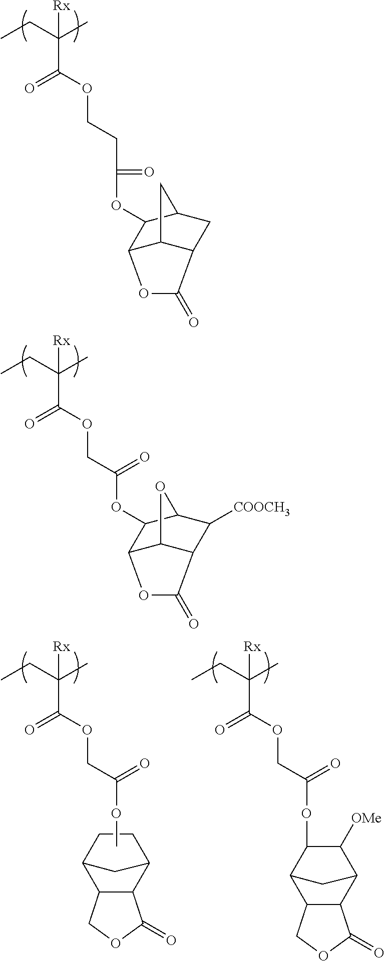

(In this formula, Rx represents H, CH₃, CH₂OH, or CF₃.)

In order to enhance the effect of the invention, repeating units having two or more types of lactone structure or sultone structure can be used in combination.

If the resin (A) contains the repeating unit having the lactone structure or the sultone structure, the content of the repeating unit having the lactone structure or the sultone structure is preferably in the range of 5% by mol to 60% by mol, more preferably in the range of 5% by mol to 55% by mol, and still more preferably in the range of 10% by mol to 50% by mol with respect to the entire repeating units in the resin (A).

In addition, the resin (A) may have a repeating unit having a cyclic carbonate ester structure.

The repeating unit having the cyclic carbonate ester structure preferably has a repeating unit represented by General Formula (A-1) below.

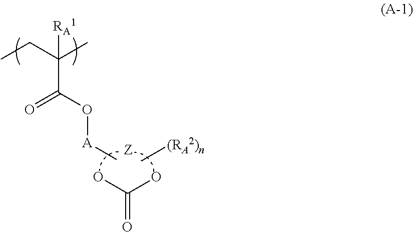

In General Formula (A-1), R_{A}¹ represents a hydrogen atom or an alkyl group.

If n is 2 or greater, R_{A}²'s each independently represent a substituent.

A represents a single bond or a divalent linking group.

Z represents a group represented by —O—C(═O)—O— in a formula and an atomic group that forms a monocyclic or polycyclic structure.

n represents an integer of 0 or greater.

General Formula (A-1) is described in detail.

The alkyl group represented by R_{A}¹ may have a substituent such as a fluorine atom. R_{A}¹ preferably represents a hydrogen atom, a methyl group, or a trifluoromethyl group, and more preferably represents a methyl group.

The substituent represented by R_{A}² is, for example, an alkyl group, a cycloalkyl group, a hydroxyl group, an alkoxy group, an amino group, and an alkoxycarbonylamino group. The substituent is preferably an alkyl group having 1 to 5 carbon atoms. The alkyl group may have a substituent such as a hydroxyl group.

n is an integer of 0 or greater that represents the number of substituents. For example, n is preferably in the range of 0 to 4 and more preferably 0.

As the divalent linking group represented by A, for example, an alkylene group, a cycloalkylene group, an ester bond, an amide bond, an ether bond, a urethane bond, or a urea bond, or a combination of two or more types thereof is included. As the alkylene group, an alkylene group having 1 to 10 carbon atoms is preferable, an alkylene group having 1 to 5 carbon atoms is more preferable, and for example, a methylene group, an ethylene group, and a propylene group are included.

According to the embodiment, A is preferably a single bond or an alkylene group.

As a single ring including —O—C(═O)—O— represented by Z, for example, with respect to cyclic carbonic acid esters represented by General Formula (a), a 5-membered to 7-membered ring in which n_{A}=2 to 4 is included, a 5-membered ring or 6-membered ring (n_{A}=2 or 3) is preferable, and a 5-membered ring (n_{A}=2) is more preferable.

As a polycyclic ring including —O—C(═O)—O—, represented by Z, for example, a structure in which a cyclic carbonic acid ester represented by General Formula (a) described below and another ring structure or other two more ring structures form a condensed ring or a structure in which a cyclic carbonic acid ester represented by General Formula (a) and another ring structure or other two more ring structures form a spiro ring is included. The “other ring structures” that can form a condensed ring or a spiro ring may be an alicyclic hydrocarbon group, may be an aromatic hydrocarbon group, or may be a heterocyclic ring.

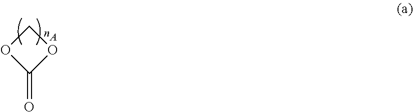

A monomer corresponding to the repeating unit represented by General Formula (A-1) can be synthesized by well-known methods in the related art disclosed in, for example, Tetrahedron Letters, Vol. 27, No. 32 p. 3741 (1986), Organic Letters, Vol. 4, No. 15 p. 2561 (2002), and the like.

In the resin (A), one type of the repeating units represented by General Formula (A-1) may be included singly, or two or more types thereof may be included.

In the resin (A), the content ratio of the repeating unit having a cyclic carbonate ester structure (preferably, repeating unit represented by General Formula (A-1)) is preferably in the range of 3% by mol to 80% by mol, more preferably in the range of 3% by mol to 60% by mol, particularly preferably in the range of 3% by mol to 30% by mol, and most preferably in the range of 10% by mol to 15% by mol with respect to the entire repeating units constituting the resin (A). If the content ratio thereof is as described above, developability, lower number of defectiveness, low LWR, low PEB temperature dependency, a profile, and the like, as a resist can be enhanced.

Specific examples of the repeating unit represented by General Formula (A-1) are described below, but the invention is not limited thereto.

In addition, R_{A}¹ in the specific examples below has the same meaning as R_{A}¹ in General Formula (A-1).

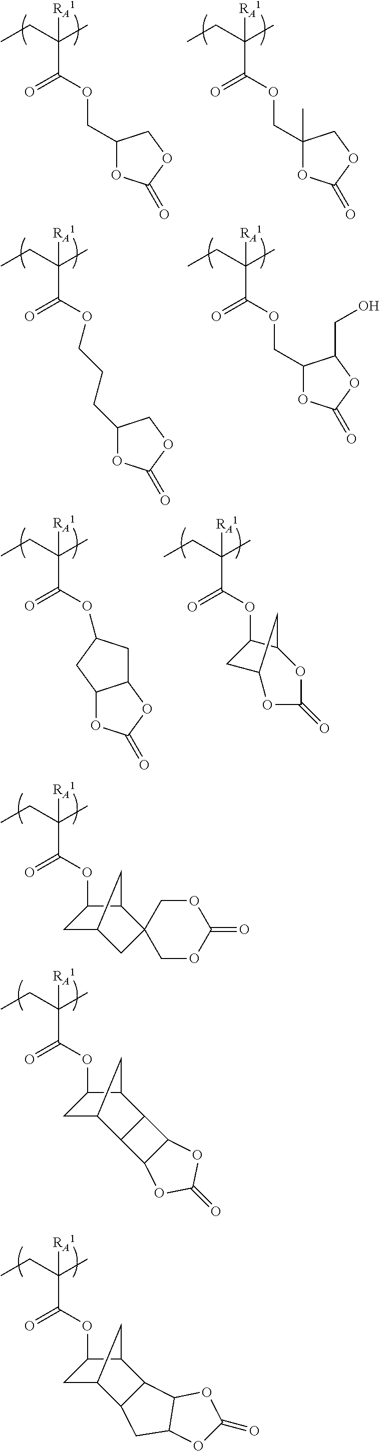

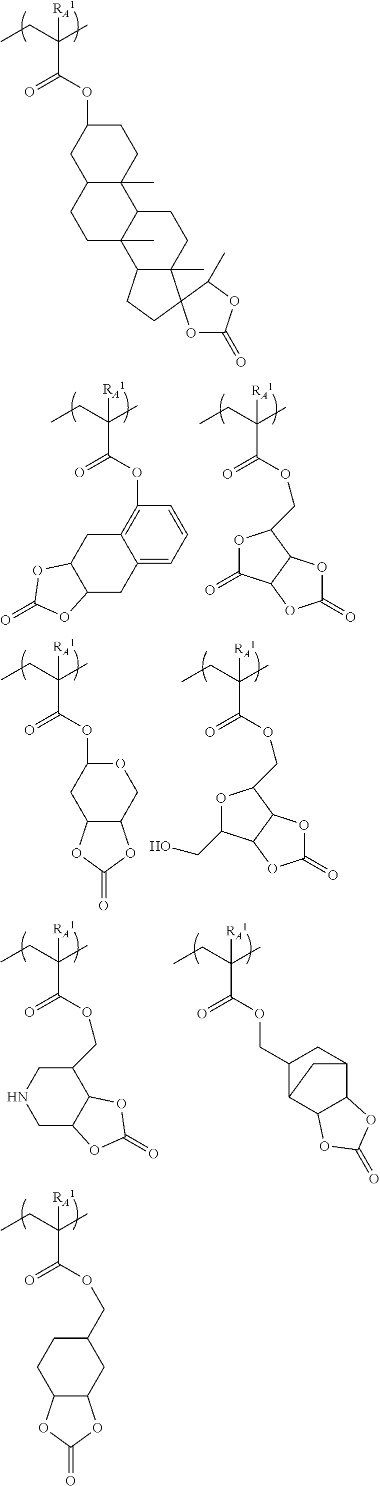

The resin (A) may have a repeating unit having a hydroxyl group or a cyano group. Accordingly, substrate adhesiveness and affinity for developer are enhanced. The repeating unit having the hydroxyl group or the cyano group is preferably a repeating unit having an alicyclic hydrocarbon structure substituted with a hydroxyl group or a cyano group, and it is preferable not to have an acid-decomposable group.

In addition, the repeating unit having an alicyclic hydrocarbon structure substituted with a hydroxyl group or a cyano group is preferably different from the repeating unit having the acid-decomposable group (that is, it is preferably a repeating unit which is stable with respect to an acid).

In the alicyclic hydrocarbon structure substituted with the hydroxyl group or the cyano group, as the alicyclic hydrocarbon structure, an adamantyl group, a diadamantyl group, and a norbornane group are preferable.

More preferably, a repeating unit represented by any one of General Formulae (AIIa) to (AIIc) is included.

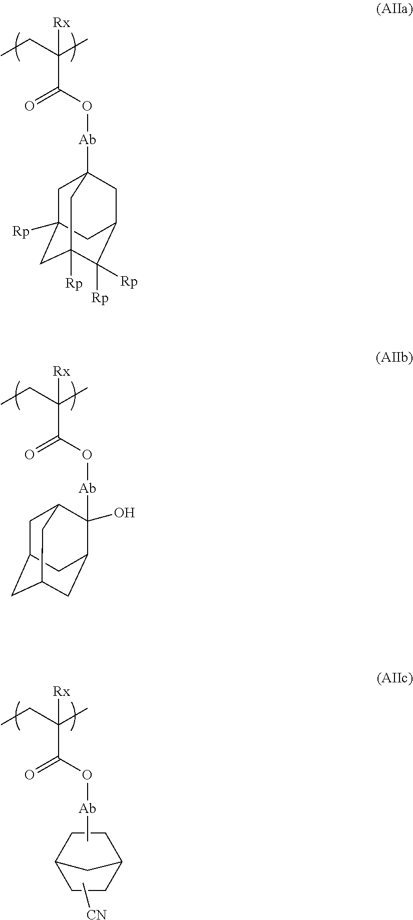

In the formulae, x represents a hydrogen atom, a methyl group, a hydroxymethyl group, or a trifluoromethyl group.

Ab represents a single bond or a divalent linking group.

As the divalent linking group represented by Ab, for example, an alkylene group, a cycloalkylene group, an ester bond, an amide bond, an ether bond, a urethane bond, a urea bond, or a combination of two or more types thereof is included. As the alkylene group, an alkylene group having 1 to 10 carbon atoms is preferable, an alkylene group having 1 to 5 carbon atoms is more preferable, and, for example, a methylene group, an ethylene group, and a propylene group are included.

In one embodiment of the invention, Ab is preferably a single bond or an alkylene group.

Rp represents a hydrogen atom, a hydroxyl group, or a hydroxyalkyl group. Plural Rp's may be identical to or different from each other, but one of the plural Rp's represents a hydroxyl group or a hydroxyalkyl group.

The resin (A) may contain or may not contain a repeating unit having a hydroxyl group or a cyano group. However, if the resin (A) contains a repeating unit having a hydroxyl group or a cyano group, the content of the repeating unit having the hydroxyl group or the cyano group is preferably in the range of 1% by mol to 40% by mol, more preferably in the range of 3% by mol to 30% by mol, and still more preferably in the range of 5% by mol to 25% by mol with respect to the entire repeating units in the resin (A). In addition, the resin (A) may contain two or more types of repeating units having a hydroxyl group or a cyano group, which have different structures.

Specific examples of the repeating unit having the hydroxyl group or the cyano group are described below, but the invention is not limited thereto.

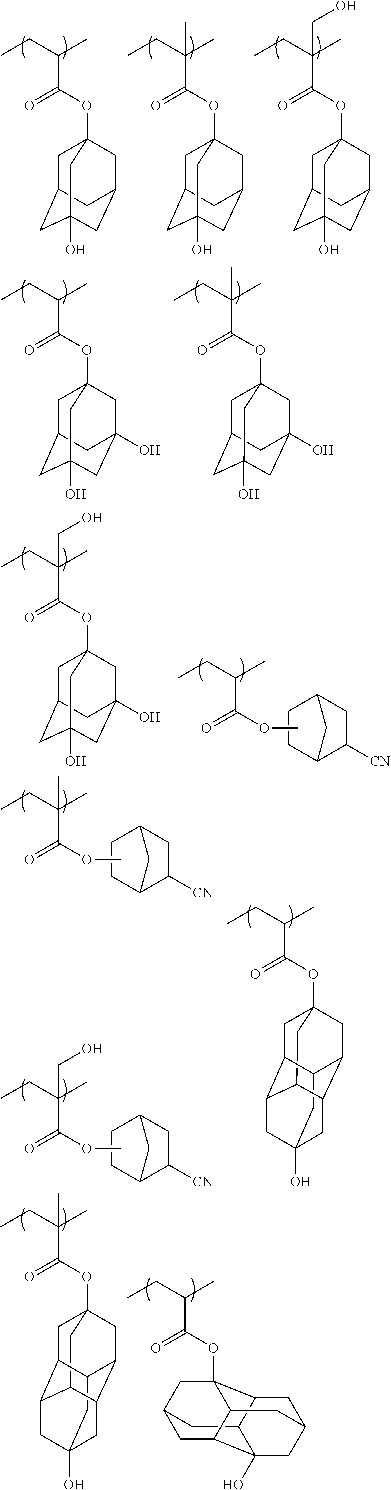

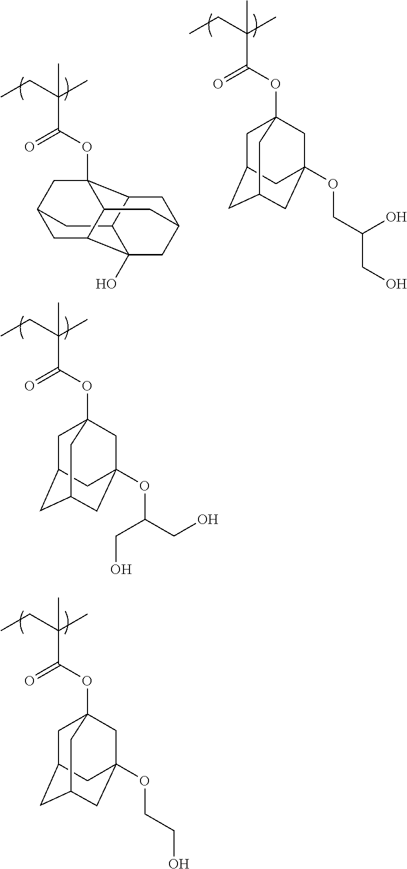

In addition, a monomer disclosed in “0011” and its subsequent paragraphs of WO2011/122336A, a repeating unit corresponding thereto, and the like can be appropriately used.

The resin (A) may have one type or two or more types of repeating unit structure having an acid group. As the acid group, a carboxyl group, a sulfonamide group, a sulfonylimide group, a bissulfonylimide group, a naphthol structure, and an aliphatic alcohol group in an electron-withdrawing group is substituted at an a position (for example, hexafluoroisopropanol group) are included, and it is more preferable to have a repeating unit having a carboxyl group. If the repeating unit having the acid group is contained, resolution properties for the use of a contact hole are increased. As the repeating unit having an acid group, all kinds of repeating unit in which an acid group is directly bonded to a main chain of a resin such as a repeating unit derived from an acrylic acid or a methacrylic acid, a repeating unit in which an acid group is bonded to a main chain of a resin through a linking group, or further a repeating unit in which a polymerization initiator or a chain transfer agent that has an acid group at the time of polymerization is used and introduced to a terminal of the polymer chain are preferable. The linking group may have a monocyclic or polycyclic cyclic hydrocarbon structure. A repeating unit derived from an acrylic acid and a methacrylic acid is particularly preferable.

The resin (A) may contain or may not contain the repeating unit having the acid group, but if the acid group is contained, the content of the repeating unit having the acid group is preferably 25% by mol or less and more preferably 20% by mol or less with respect to the entire repeating units in the resin (A). If the resin (A) contains the repeating unit having the acid group, the content of the repeating unit having the acid group in the resin (A) is generally 1% by mol or greater.

Specific examples of the repeating unit having the acid group are described below, but the invention is not limited thereto.

In the specific examples, Rx represents H, CH₃, CH₂OH, or CF₃.

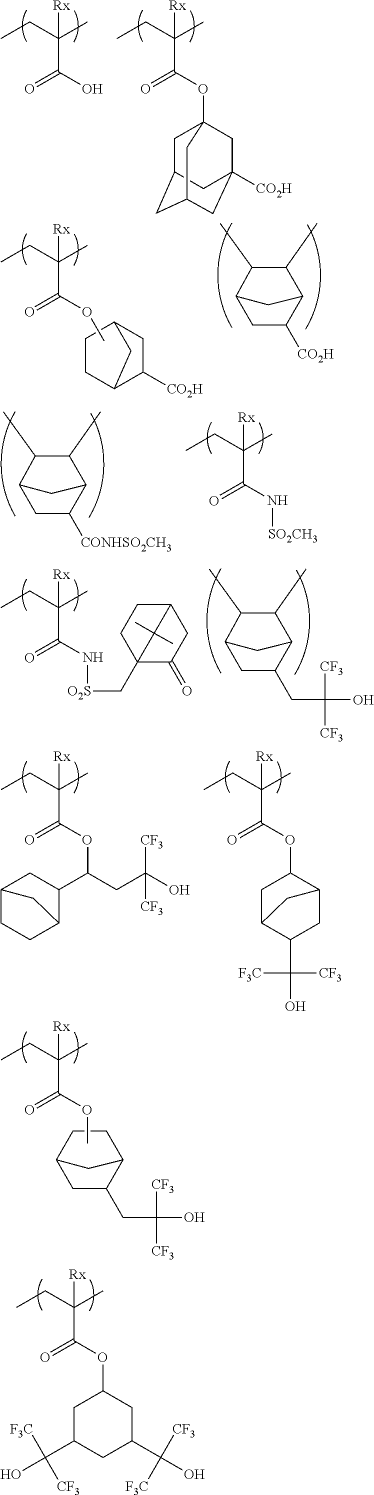

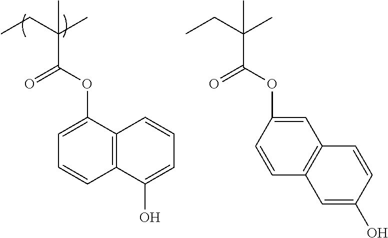

The resin (A) according to the invention further has an alicyclic hydrocarbon structure without a polar group (for example, the acid group described above, a hydroxyl group, and a cyano group), and may have a repeating unit that does not exhibit acid-decomposablility. Accordingly, it is possible to reduce elusion of a low-molecular-weight component from a resist film to an immersion liquid at the time of liquid immersion exposure and, at the same time, it is possible to appropriately adjust the solubility with respect of the resin at the time of development using a developer including the organic solvent. As a repeating unit like this, a repeating unit represented by General Formula (IV) is included.

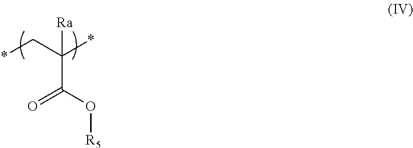

In General Formula (IV), R₅ represents a hydrocarbon group that has at least one cyclic structure and has a polar group.

Ra represents a hydrogen atom, an alkyl group, or a —CH₂—O—Ra₂ group. Ra₂ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

A ring structure of R₅ includes a monocyclic hydrocarbon group and a polycyclic hydrocarbon group. As the monocyclic hydrocarbon group, a cyclopentyl group, a cyclohexyl group, and the like are preferably included.

A ring-aggregated hydrocarbon group and a crosslinked cyclic hydrocarbon group are included in the polycyclic hydrocarbon group, and examples of the ring-aggregated hydrocarbon group include a bicyclohexyl group and a perhydronaphthalenyl group. As a crosslinked cyclic hydrocarbon ring, for example, bicyclic hydrocarbon rings such as pinane, bornane, norpinane, norbornane, bicyclooctane rings (such as bicyclo[2.2.2]octane rings, bicyclo[3.2.1]octane rings), tricyclic hydrocarbon rings such as homobledane, adamantane, tricyclo[5.2.1.0^{2,6}]decane, tricyclo[4.3.1.1^{2,5}]undecane rings, and tetracyclic hydrocarbon rings such as tetracyclo[4.4.0.1^{2,5}.1^{7,10}]dodecane and perhydro-1,4-methano-5,8-methanonaphthalene rings are included. In addition, as the condensed ring-type hydrocarbon rings, for example, condensed rings in which plural 5-membered to 8-membered cycloalkane rings such as perhydronaphthalene (decalin), perhydroanthracene, perhydrophenanthrene, perhydroacenaphthene, perhydrofluorene, perhydroindene, and perhydrophenalene rings are condensed are included in the crosslinked cyclic hydrocarbon ring.

As the preferable crosslinked cyclic hydrocarbon ring, a norbornyl group, an adamantyl group, a bicyclooctanyl group, a tricyclo[5,2,1,0^{2,6}]decanyl group, and the like are included. As a more preferable crosslinked cyclic hydrocarbon ring, a norbornyl group, an adamantyl group, and the like are included.

These alicyclic hydrocarbon structures may have substituents, and as preferable substituents, halogen atoms, alkyl groups, hydroxyl groups of which hydrogen atoms are substituted, and amino groups of which hydrogen atoms are substituted are included.

The resin (A) may contain or may not contain a repeating unit that has an alicyclic hydrocarbon structure without a polar group which does not exhibit acid-decomposablility, but if the repeating unit is contained, the content of the repeating unit is preferably in the range of 1% by mol to 50% by mol, more preferably in the range of 5% by mol to 50% by mol, still more preferably in the range of 5% by mol to 30% by mol, and particularly preferably in the range of 5% by mol to 20% by mol with respect to the entire repeating units in the resin (A). In addition, the resin (A) may have two or more types of alicyclic hydrocarbon structure without a polar group, of which structures are different from each other and may contain repeating units which do not exhibit acid-decomposablility.

Specific examples of the repeating unit that has an alicyclic hydrocarbon structure without a polar group and that does not exhibit acid-decomposablility are described below, but the invention is not limited thereto. In the formula, Ra represents H, CH₃, CH₂OH, or CF₃.

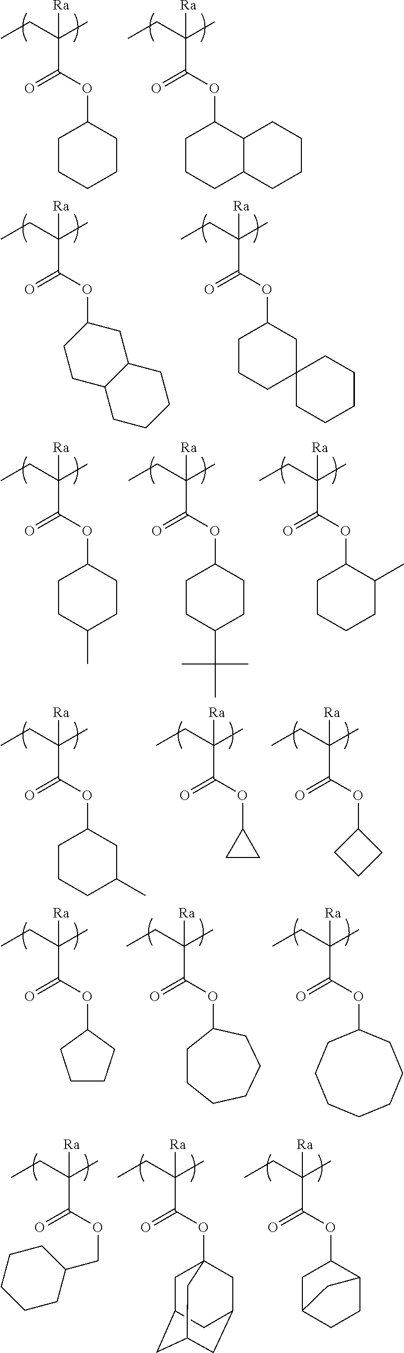

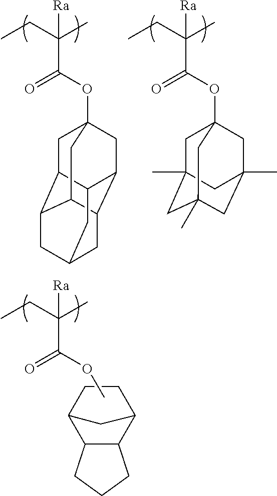

In addition to the repeating structure unit, the resin (A) used in the composition may have various repeating structure units for the purpose of adjusting dry etching resistance, adaptability of standard developer, substrate adhesiveness, and a resist profile, and further resolving power, heat resistance, sensitivity, and the like which are generally required characteristics of the actinic ray-sensitive or radiation-sensitive resin composition.

As the repeating structure unit like this, the repeating structure unit corresponding to the monomer described below can be included, but the invention is not limited thereto.

Accordingly, performance required for the resin used in the actinic ray-sensitive or radiation-sensitive resin composition, particularly,

(1) Solubility with respect to coating solvent,

(2) Film forming properties (glass transition point),

(3) Alkali-developability,

(4) Film thinning (hydrophilic and hydrophobic properties and alkali soluble group selection),

(5) Adhesiveness of an unexposed portion to a substrate,

(6) Dry etching resistance,

and the like can be finely adjusted.

Such a monomer, for example, a compound having one addition polymerizable unsaturated bond selected from acrylic acid esters, methacrylic acid esters, acrylamides, methacrylamides, allyl compounds, vinyl ethers, vinyl esters, and the like can be included.

In addition, if an addition polymerizable unsaturated compound is copolymerizable with monomers corresponding to the various repeating structure units, the addition polymerizable unsaturated compound may be copolymerized.

With respect to the resin (A) used in the actinic ray-sensitive or radiation-sensitive resin composition, molar ratios of the respective repeating structure units are appropriately set in order to adjust dry etching resistance, adaptability of standard developer, substrate adhesiveness, and a resist profile of the actinic ray-sensitive or radiation-sensitive resin composition, and further resolving power, heat resistance, sensitivity, and the like which are generally required characteristics of the actinic ray-sensitive or radiation-sensitive resin composition.

As the form of the resin (A), any form of a random shape, a block shape, a comb shape, and a star shape may be used. The resin (A) can be synthesized by, for example, radical, cationic, or anionic polymerization of the unsaturated monomers corresponding to the respective structures. In addition, a desired resin can be obtained by performing polymer reaction after polymerization by using the unsaturated monomers corresponding to precursors of the respective structures.

If the actinic ray-sensitive or radiation-sensitive resin composition is for ArF exposure, in view of the transparency to ArF light, it is preferable that the resin (A) does not have an aromatic ring substantially (specifically, in the resin, a proportion of a repeating unit having an aromatic group is preferably 5% by mol or less, more preferably 3% by mol or less, and ideally 0% by mol, that is, does not have an aromatic group) and it is preferable that the resin (A) has a monocyclic or polycyclic alicyclic hydrocarbon structure.

If the actinic ray-sensitive or radiation-sensitive resin composition includes a hydrophobic resin (D) described below, in view of compatibility with the hydrophobic resin (D), it is preferable that the resin (A) does not contain a fluorine atom and a silicon atom (specifically, a proportion of a repeating unit containing a fluorine atom or a silicon atom in the resin is preferably 5% by mol or less, more preferably 3% by mol or less, and ideally 0% by mol).

The resin (A) used in the actinic ray-sensitive or radiation-sensitive resin composition is preferably a resin in which all repeating units are (meth)acrylate-based repeating units. In this case, any one of a resin in which all repeating units are methacrylate-based repeating units, a resin in which all repeating units are acrylate-based repeating units, and a resin in which all repeating units are formed of methacrylate-based repeating units and acrylate-based repeating units may be used, but it is preferable that the acrylate-based repeating units occupy 50% by mol or less of the entire repeating units.

As preferable specific examples of the resin (A), resins used in examples described below may be used, and additionally following resins may be used.

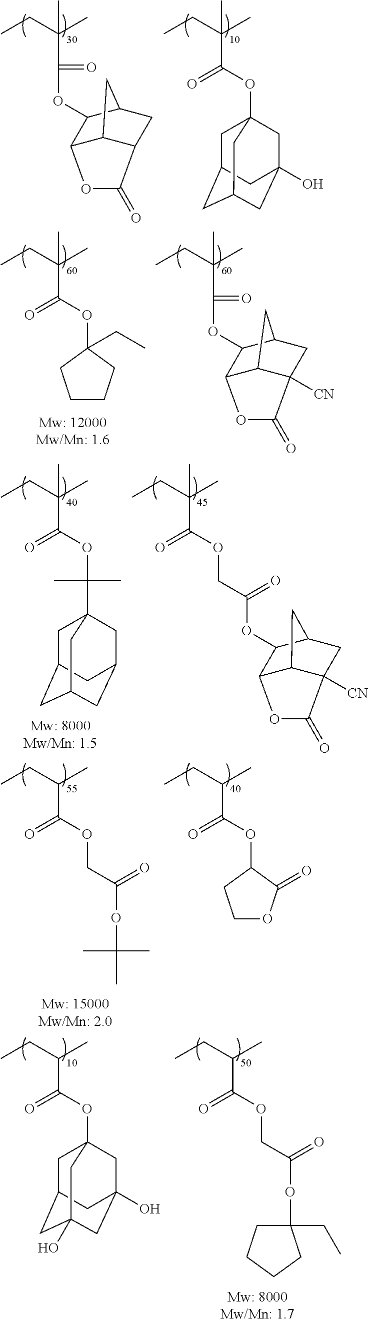

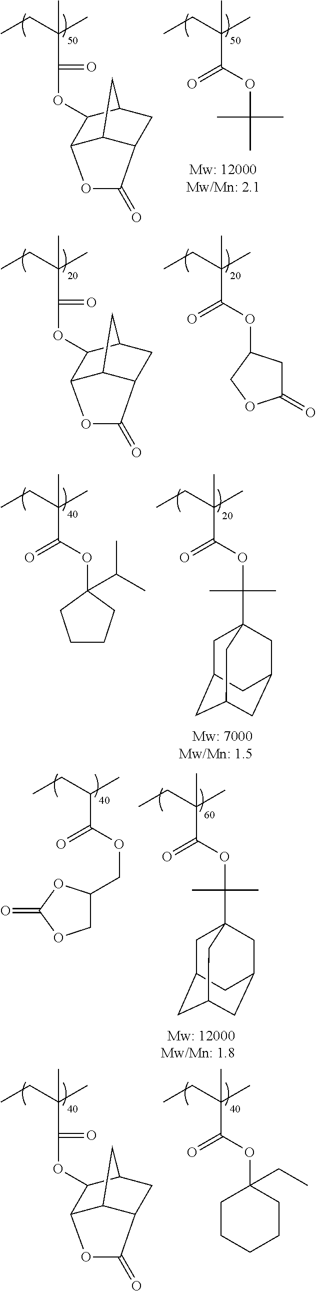

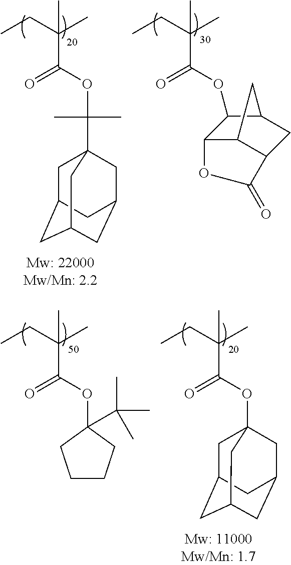

If the actinic ray-sensitive or radiation-sensitive resin composition is irradiated with KrF excimer laser light, an electron beam, an X ray, or a high energy ray (EUV or the like) having a wavelength of 50 nm or less, it is preferable that the resin (A) may further have a repeating unit containing an aromatic ring structure, for example, a hydroxystyrene-based repeating unit. More preferably, it is preferable that a hydroxystyrene-based repeating unit, a hydroxystyrene-based repeating unit protected by an acid-decomposable group, and an acid-decomposable repeating unit such as a (meth)acrylic acid tertiary alkyl ester are included.

As a repeating unit having a preferable hydroxystyrene-based acid-decomposable group, for example, a repeating unit having t-butoxycarbonyloxystyrene, 1-alkoxyethoxystyrene, and a (meth)acrylic acid tertiary alkyl ester are included, and a repeating unit having 2-alkyl-2-adamantyl (meth)acrylate and dialkyl(1-adamantyl)methyl (meth)acrylate is more preferable.

Specific examples of the resin having the repeating unit containing an aromatic ring structure are described below, but the invention is not limited thereto.

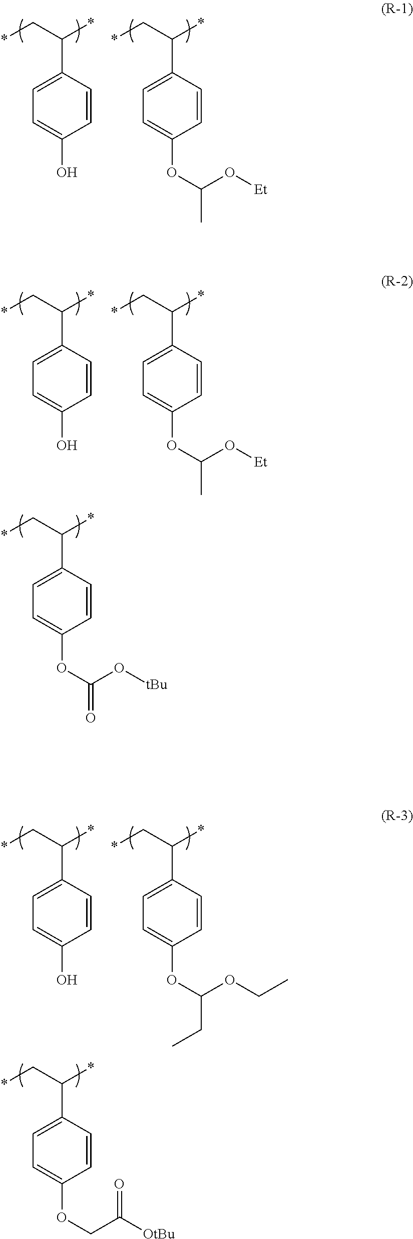

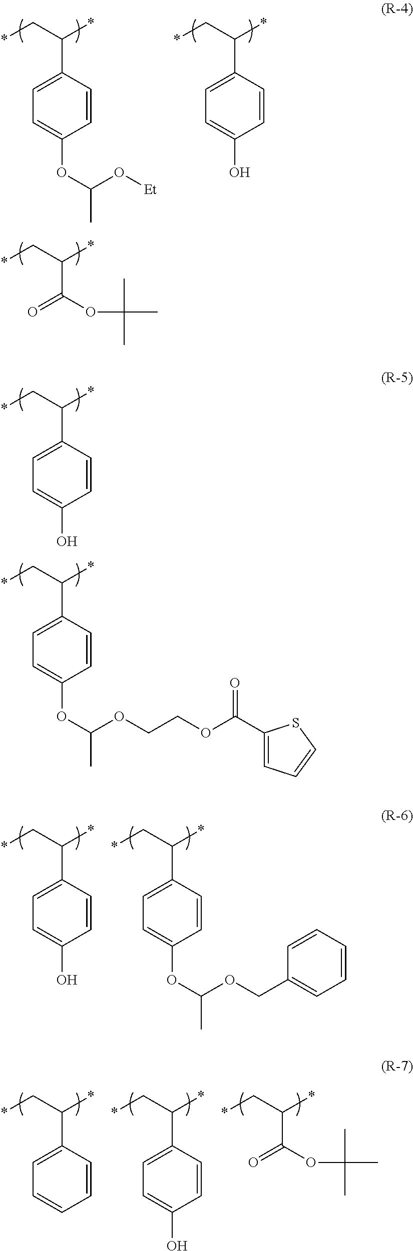

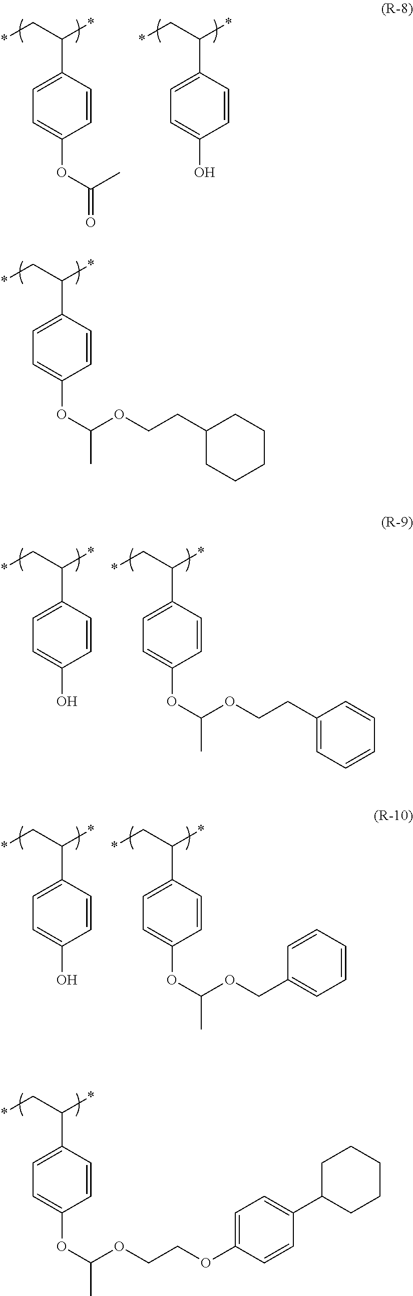

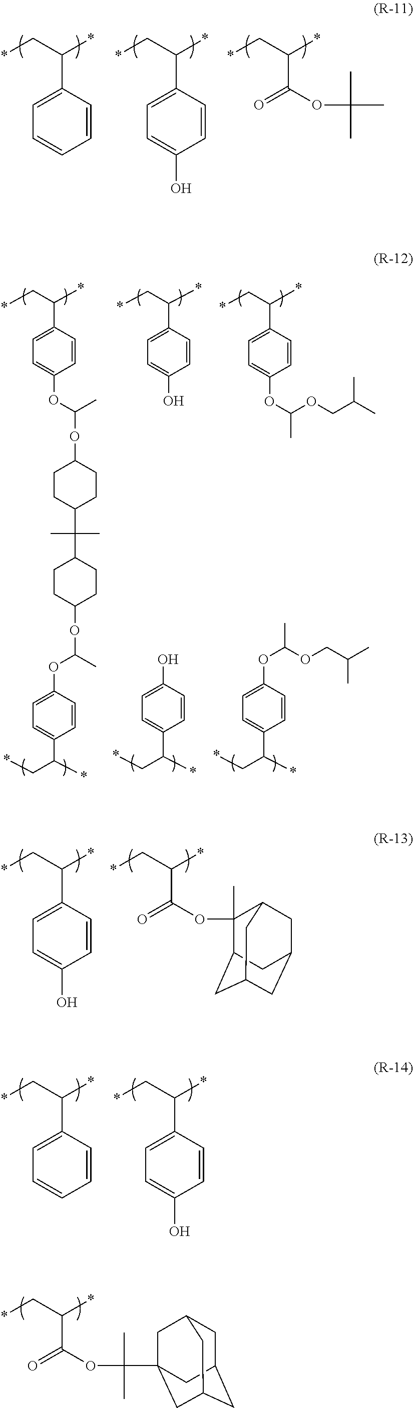

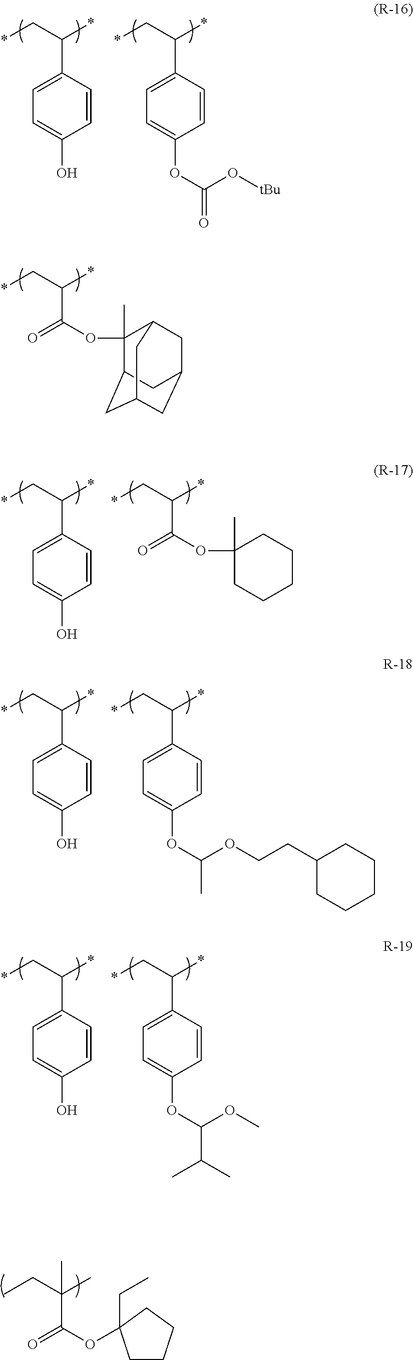

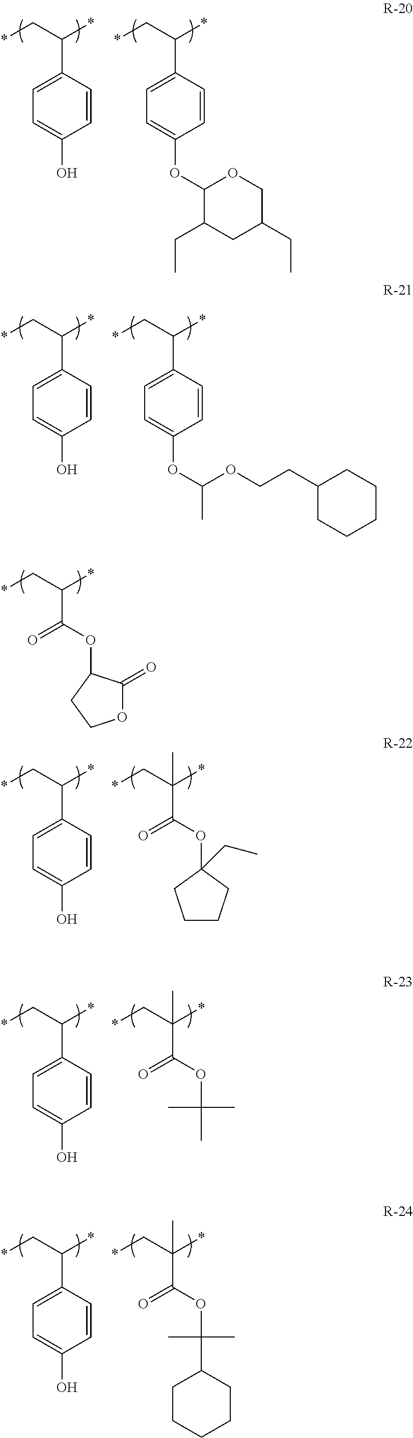

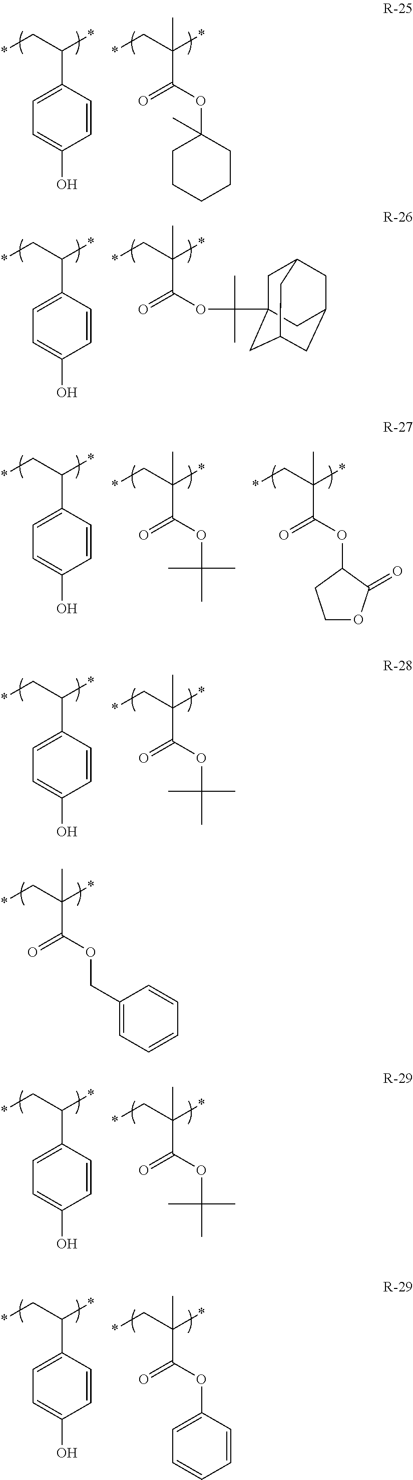

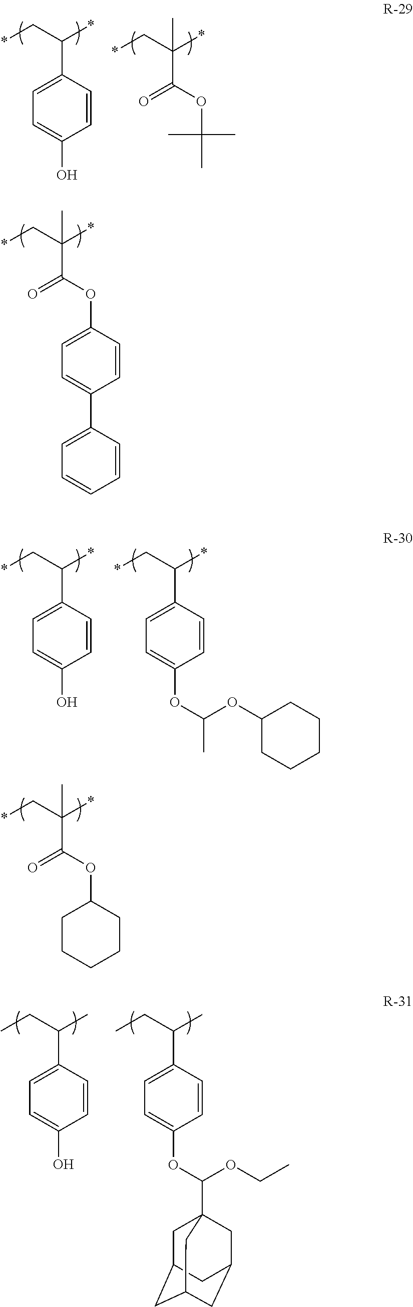

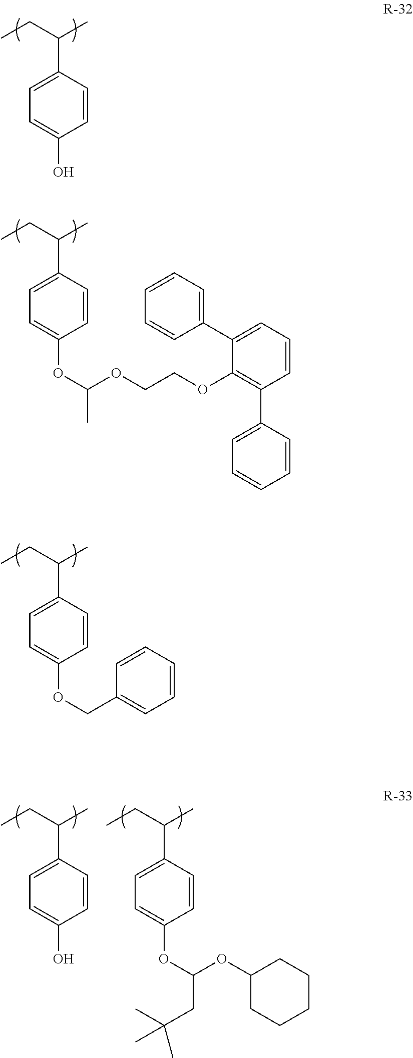

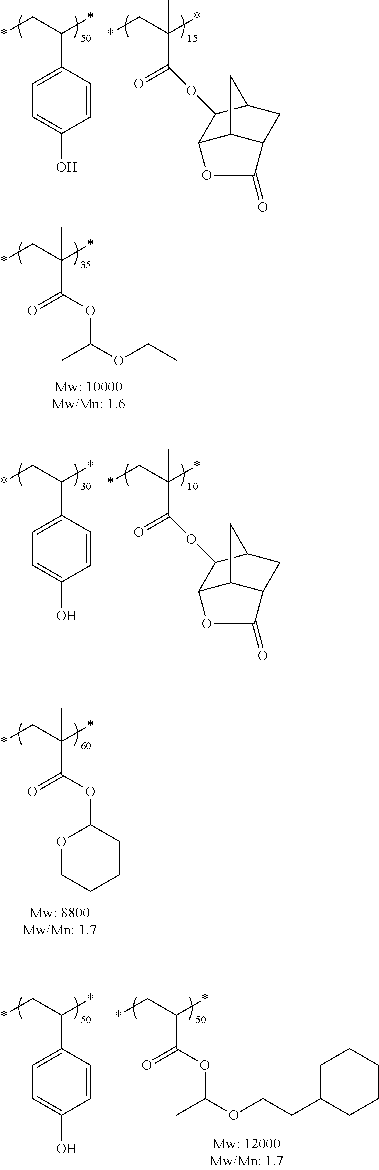

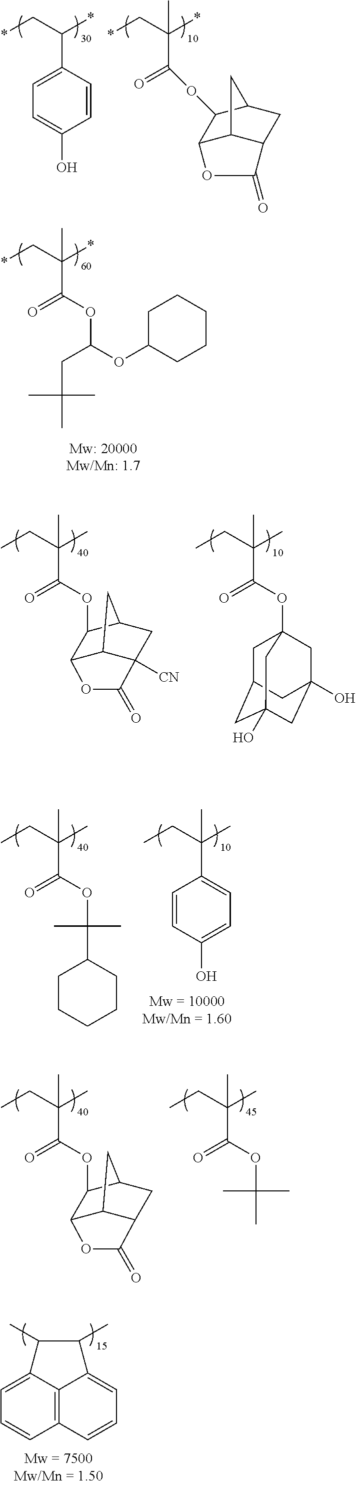

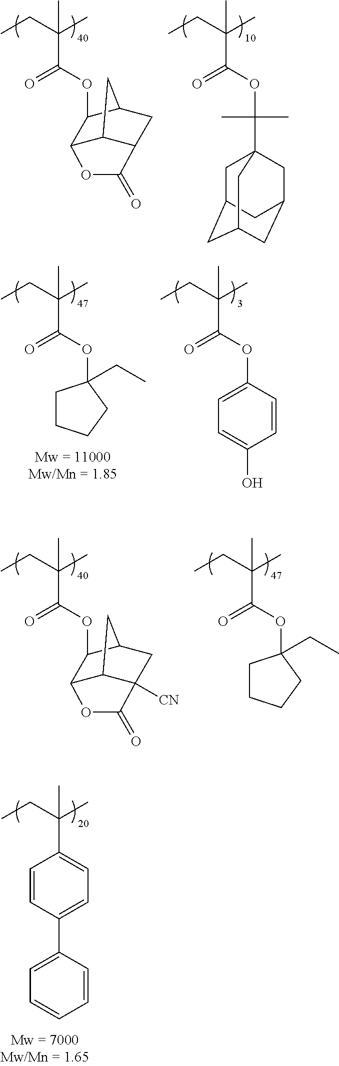

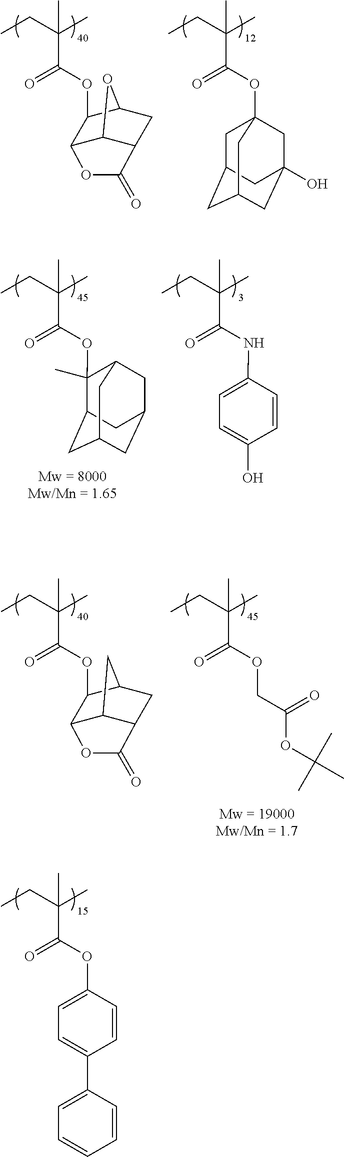

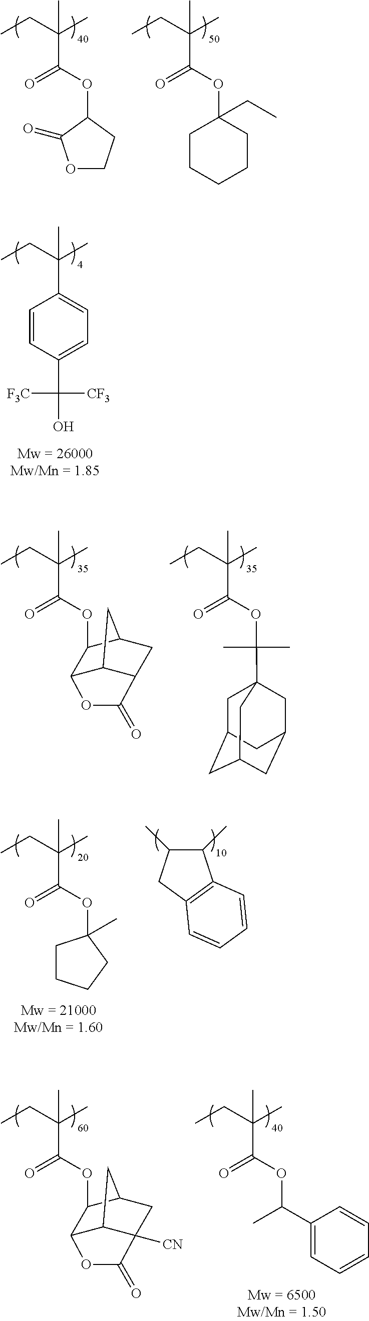

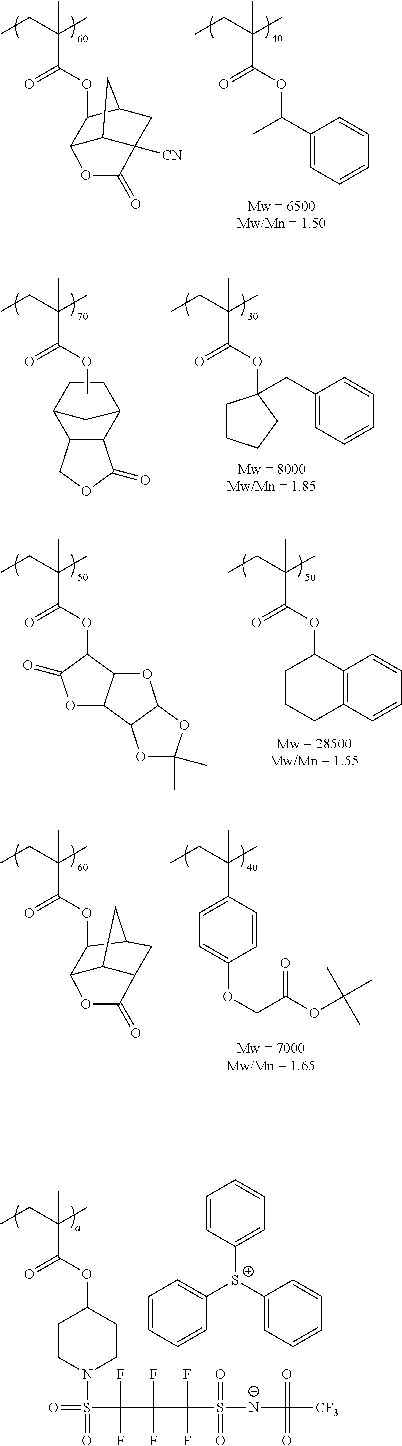

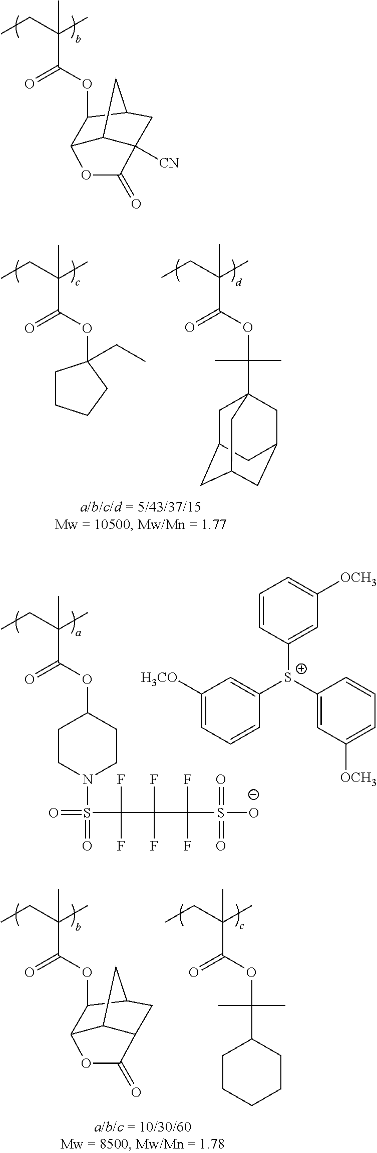

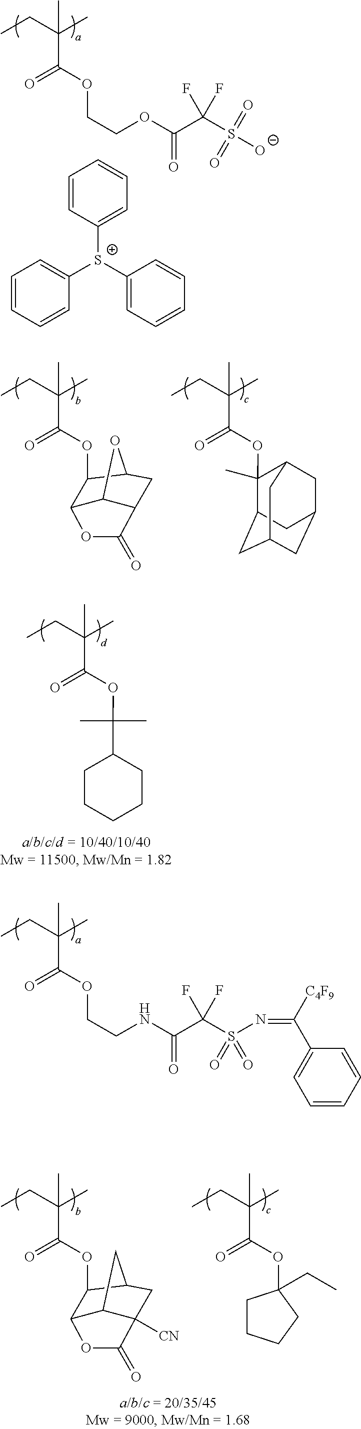

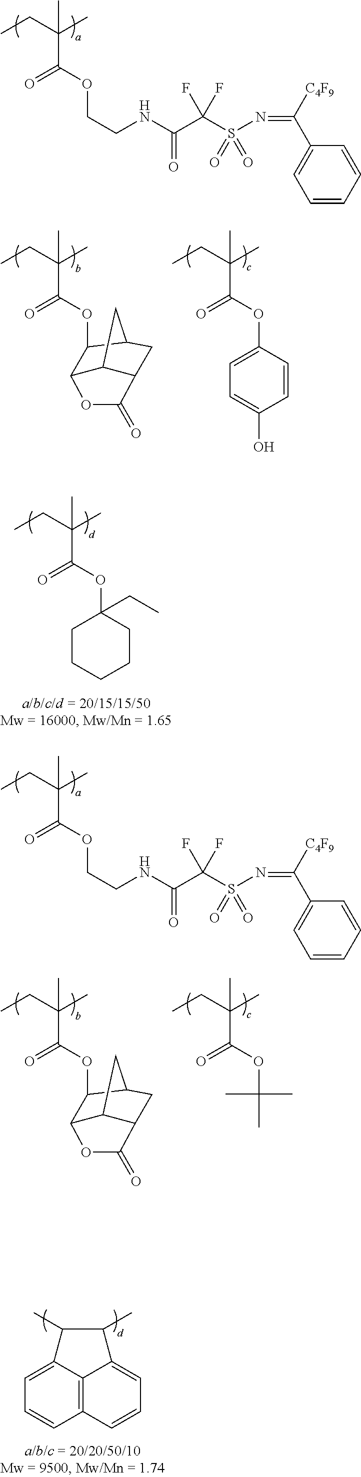

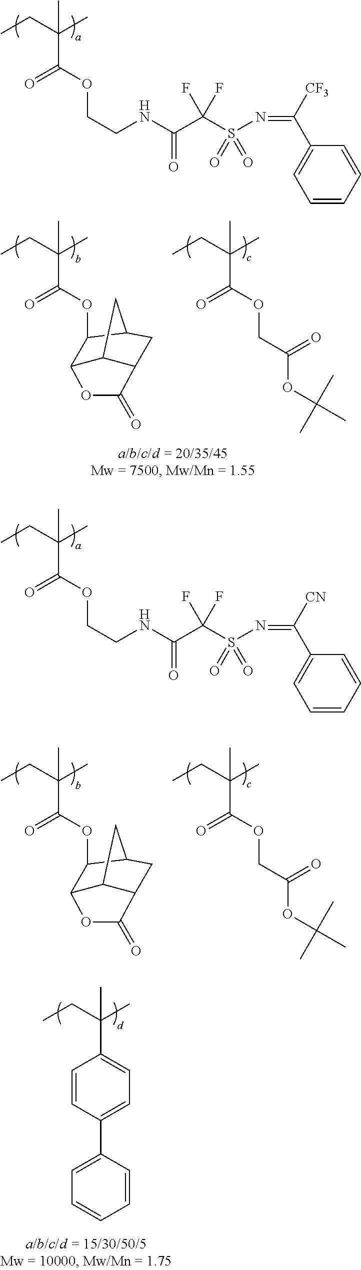

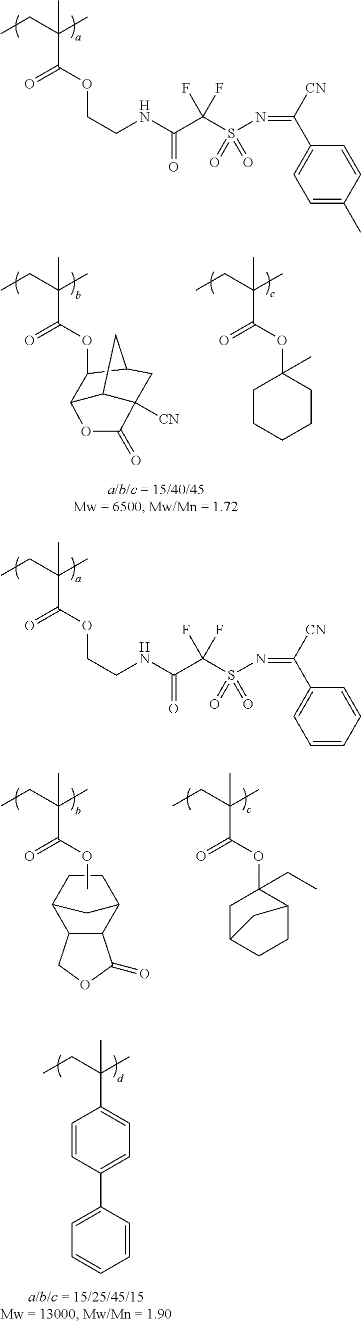

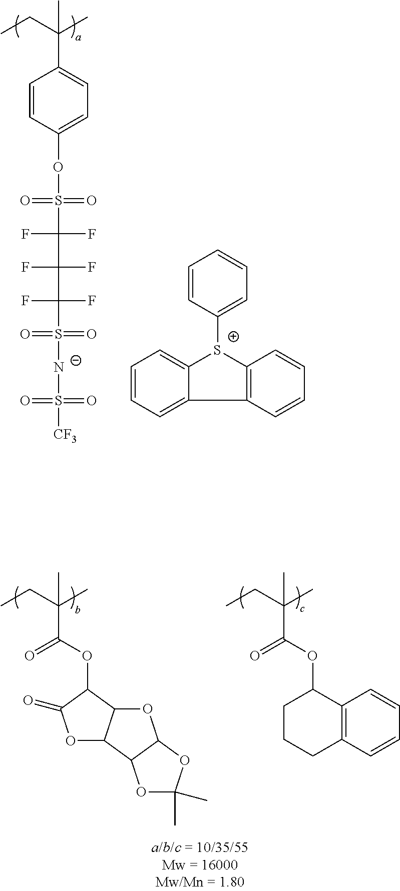

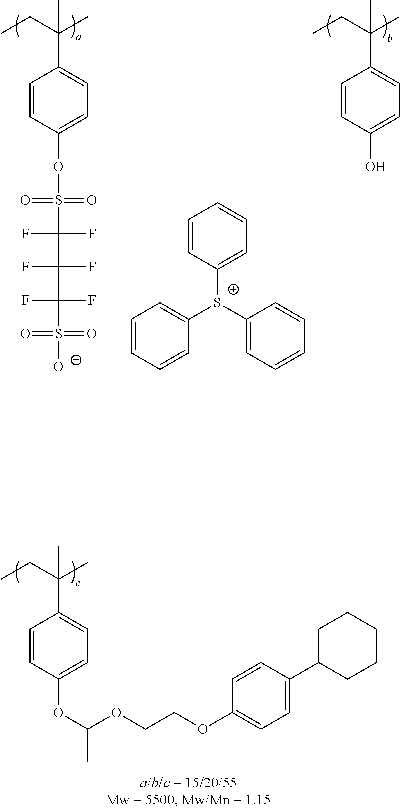

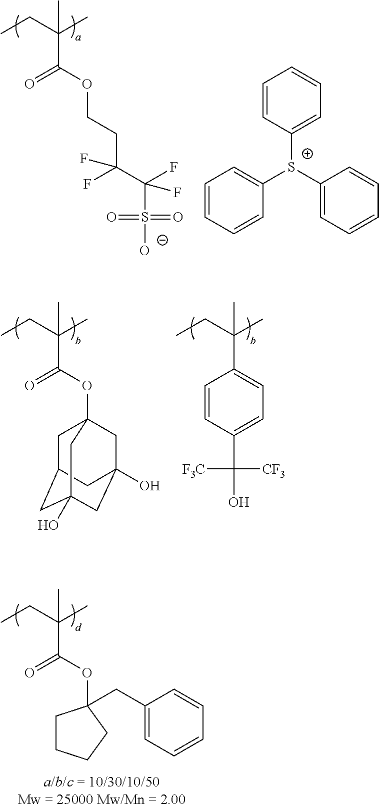

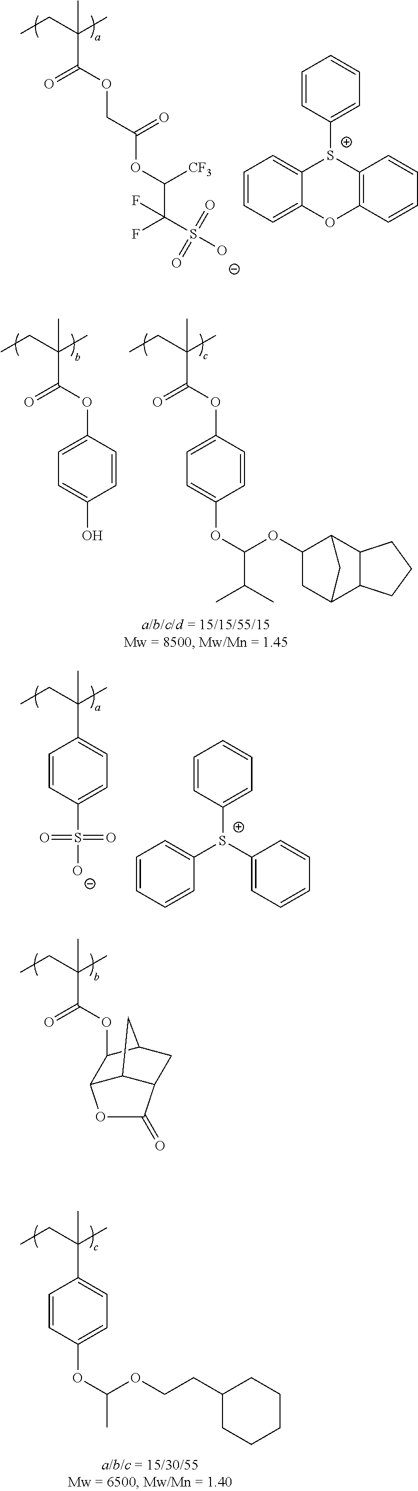

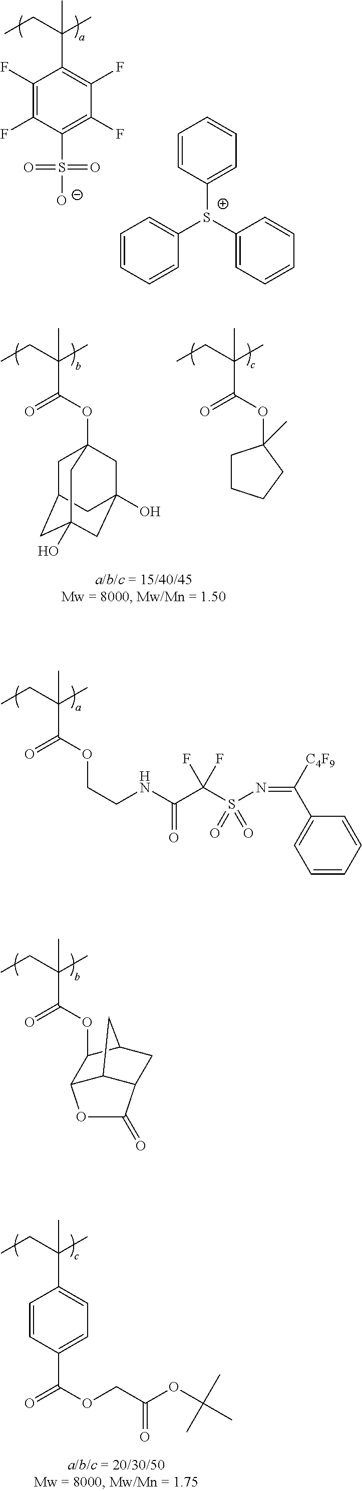

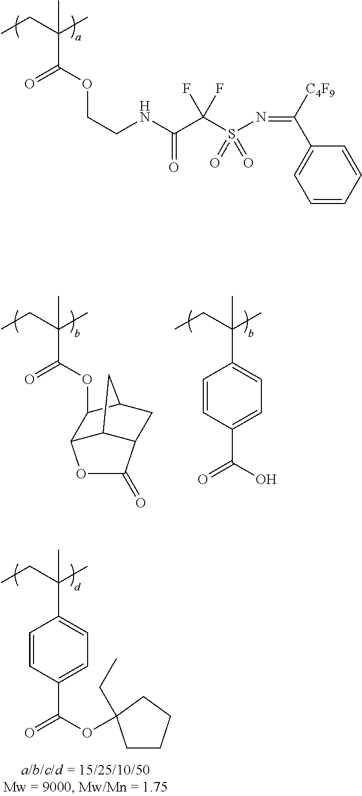

In the specific examples above, tBu represents a t-butyl group.

The resin (A) according to the invention can be synthesized according to well-known methods (for example, radical polymerization, living radical polymerization, and anionic polymerization). For example, the description in Paragraphs “0121” to “0128” of JP2012-073402A (Paragraphs “0203” to “0211” of corresponding US2012/077122A) can be referred to, and the contents thereof are incorporated in this specification.

A weight average molecular weight of the resin (A) according to the invention is 7,000 or greater as described above, preferably in the range of 7,000 to 200,000, more preferably in the range of 7,000 to 50,000, still more preferably in the range of 7,000 to 40,000, and particularly preferably in the range of 7,000 to 30,000, in terms of polystyrene in the GPC method. If the weight average molecular weight is smaller than 7,000, solubility with respect to the developer becomes too high, and there is a concern that an accurate pattern may not be formed.

Resins having a dispersity (molecular weight distribution) generally in the range of 1.0 to 3.0, preferably in the range of 1.0 to 2.6, more preferably in the range of 1.0 to 2.0, and particularly preferably in the range of 1.4 to 2.0 are used. As the resin of which a molecular weight distribution is smaller, resolutions and resist forms become more excellent, sidewalls of a resist pattern become smoother, and roughness properties become more excellent.

According to the invention, the weight average molecular weight (Mw) and the number average molecular weight (Mn) can be obtained, for example, by using an HLC-8120 (manufactured by Tosoh Corporation), 7.8 mm ID×30.0 cm TSK gel Multipore HXL-M (manufactured by Tosoh Corporation) as a column, and tetrahydrofuran (THF) as an eluent.

With respect to the actinic ray-sensitive or radiation-sensitive resin composition, a proportion incorporated into total compositions of the resin (A) is preferably in the range of 30% by mass to 99% by mass and more preferably in the range of 60% by mass to 95% by mass in the total solid content.

In addition, according to the invention, one kind of the resin (A) may be used singly, or plural types thereof may be used in combination.

[2] Compound (B) that Generates an Acid by being Irradiated with Actinic Rays or Radiation

Generally, the actinic ray-sensitive or radiation-sensitive resin composition used in the invention may further include a compound (B) (hereinafter, referred to as “acid generator” or “the compound (B)”) that generates an acid by being irradiated with actinic rays or radiation. As the compound (B) that generates an acid by being irradiated with actinic rays or radiation, a compound that generates an organic acid by being irradiated with actinic rays or radiation is preferable. In addition, the compound (B) may be included in the resin (A) described above. More preferably, the compound (B) may be linked to the resin (A) through a chemical bond.

The compound (B) that generates an acid by being irradiated with actinic rays or radiation may have the form of a low-molecular-weight compound or the form of being combined with a portion of a polymer. In addition, the form of a low-molecular-weight compound and the form of being combined with a portion of a polymer may be used in combination.

If the compound (B) that generates an acid by being irradiated with actinic rays or radiation has the form of a low-molecular-weight compound, the molecular weight is preferably 3,000 or less, more preferably 2,000 or less, and still more preferably 1,000 or less.

If the compound (B) that generates an acid by being irradiated with actinic rays or radiation has the form of being combined with a portion of a polymer, the compound (B) may be combined with a portion of the acid-decomposable resin described above or may be combined with a resin different from the acid-decomposable resin.

According to the invention, the compound (B) that generates an acid by being irradiated with actinic rays or radiation preferably has the form of a low-molecular-weight compound.

As the acid generator, a photoinitiator of photocationic polymerization, a photoinitiator of photoradical polymerization, a photo-decoloring agent of pigments, photo-discoloring agents, and well-known compounds that generate an acid by being irradiated with actinic rays or radiation used in a micro resist or the like, and mixtures thereof can be appropriately selected and be used.

For example, diazonium salts, phosphonium salts, sulfonium salts, iodonium salts, imide sulfonates, oxime sulfonates, diazodisulfones, disulfones, and o-nitrobenzylsulfonates can be included.

As a preferable compound among the acid generators, compounds represented by General Formulae (ZI), (ZII), and (ZIII) can be included.

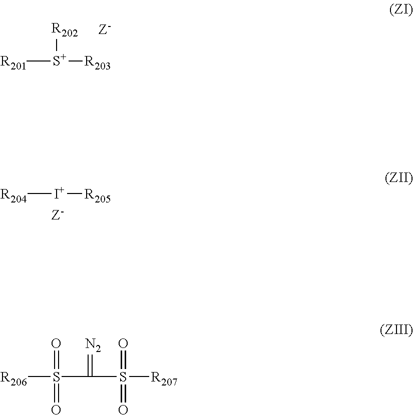

In General Formula (ZI) described above,
R₂₀₁, R₂₀₂, and R₂₀₃ each independently represent an organic group.

The numbers of carbon atoms in the organic groups as R₂₀₁, R₂₀₂, and R₂₀₃ are generally in the range of 1 to 30 and preferably in the range of 1 to 20.

In addition, two of R₂₀₁ to R₂₀₃ may be bonded to form a ring structure, or an oxygen atom, a sulfur atom, an ester bond, an amide bond, or a carbonyl group may be included in the ring. As the group formed by bonding two of R₂₀₁ to R₂₀₃ to each other, an alkylene group (for example, a butylene group or a pentylene group) can be included.

Z⁻ represents a non-nucleophilic anion.

As the non-nucleophilic anion as Z⁻, for example, a sulfonate anion, a carboxylate anion, a sulfonylimide anion, a bis(alkylsulfonyl)imide anion, and a tris(alkylsulfonyl)methyl anion can be included.

The non-nucleophilic anion is an anion having extremely low capability of occurrence of nucleophilic reaction and is an anion that can prevent decomposition with time by the nucleophilic reaction in a molecule. Accordingly, the temporal stability of the actinic ray-sensitive or radiation-sensitive resin composition is enhanced.

As the sulfonate anion, for example, an aliphatic sulfonate anion, an aromatic sulfonate anion, and a camphorsulfonate anion are included.

As the carboxylate anion, for example, an aliphatic carboxylate anion, an aromatic carboxylate anion, and an aralkylcarboxylate anion are included.

The aliphatic portion in the aliphatic sulfonate anion and the aliphatic carboxylate anion may be an alkyl group or a cycloalkyl group. The alkyl group having 1 to 30 carbon atoms and the cycloalkyl group having 3 to 30 carbon atoms are preferable, and, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, and a bornyl group can be included.

As the aromatic group in the aromatic sulfonate anion and the aromatic carboxylate anion, an aryl group having 6 to 14 carbon atoms is preferable and, for example, a phenyl group, a tolyl group, and a naphthyl group can be included.

The alkyl group, the cycloalkyl group, and the aryl group in the aliphatic sulfonate anion and the aromatic sulfonate anion may have substituents. As a substituent of the alkyl group, the cycloalkyl group, and the aryl group in the aliphatic sulfonate anion and the aromatic sulfonate anion, for example, a nitro group, a halogen atom (fluorine atom, chlorine atom, bromine atom, and iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms) can be included. With respect to the aryl group and the ring structure included in the respective groups, an alkyl group (preferably having 1 to 15 carbon atoms) and a cycloalkyl group (preferably having 3 to 15 carbon atoms) can be further included as the substituents.

As the aralkyl group in the aralkylcarboxylate anion, an aralkyl group having 7 to 12 carbon atoms, for example, a benzyl group, a phenethyl group, a naphthylmethyl group, a naphthylethyl group, and a naphthylbutyl group can be preferably included.

The alkyl group, the cycloalkyl group, the aryl group, and the aralkyl group in the aliphatic carboxylate anion, the aromatic carboxylate anion, and the aralkylcarboxylate anion may have substituents. As a substituent, for example, in the same manner as in the aromatic sulfonate anion, a halogen atom, an alkyl group, a cycloalkyl group, an alkoxy group, and an alkylthio group can be included.

As the sulfonylimide anion, for example, a saccharin anion can be included.

Alkyl groups in a bis(alkylsulfonyl)imide anion and a tris(alkylsulfonyl)methide anion are preferably alkyl groups having 1 to 5 carbon atoms. For example, a methyl group, an ethyl group, a propyl group, an isopropyl group, an n-butyl group, an isobutyl group, a sec-butyl group, a pentyl group, and a neopentyl group can be included.

Two alkyl groups in the bis(alkylsulfonyl)imide anion may be linked to each other and form an alkylene group (preferably having 2 to 4 carbon atoms) such that the two alkyl groups form a ring together with an imide group and two sulfonyl groups. As a substituent that an alkylene group formed by linking these alkyl groups and two alkyl groups in the bis(alkylsulfonyl)imide anion to each other may have, a halogen atom, an alkyl group substituted with a halogen atom, an alkoxy group, an alkylthio group, an alkyloxysulfonyl group, an aryloxysulfonyl group, and a cycloalkylaryloxysulfonyl group can be included. An alkyl group substituted with a fluorine atom is preferable.

As additional non-nucleophilic anions, for example, fluorinated phosphorus (for example, PF₆⁻), fluorinated boron (for example, BF₄⁻), and fluorinated antimony (for example, SbF₆⁻) can be included.

As the non-nucleophilic anion of Z⁻, an aliphatic sulfonate anion in which a fluorine atom is substituted on at least one a position of a sulfonic acid, an aromatic sulfonate anion substituted with a fluorine atom or a group having a fluorine atom, a bis(alkylsulfonyl)imide anion in which an alkyl group is substituted with a fluorine atom, and a tris(alkylsulfonyl)methide anion in which an alkyl group is substituted with a fluorine atom are preferable. The non-nucleophilic anion is preferably a perfluoro aliphatic sulfonate anion having 4 to 8 carbon atoms or a benzenesulfonate anion having a fluorine atom, and more preferably a nonafluorobutanesulfonate anion, a perfluorooctane sulfonate anion, a pentafluorobenzenesulfonic acid anion, and a 3,5-bis(trifluoromethyl)benzenesulfonate anion.

The acid generator is preferably a compound that generates an acid represented by General Formula (V) or (VI) below, by being irradiated with actinic rays or radiation. Since the acid generator is a compound that generates the acid represented by General Formula (V) or (VI) below, and the acid generator has a cyclic organic group, such that resolution properties, and roughness performance can become excellent.

The non-nucleophilic anion may be an anion that generates an organic acid represented by General Formula (V) or (VI) below.

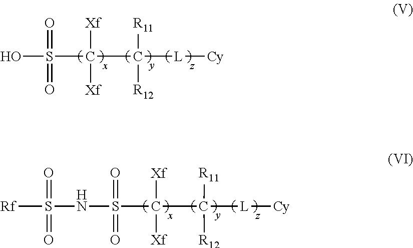

In the general formulae above,
Xf's each independently represent a fluorine atom or an alkyl group substituted with at least one fluorine atom.

R₁₁ and R₁₂ each independently represent a hydrogen atom, a fluorine atom, or an alkyl group.

L's each independently represent a divalent linking group.

Cy represents a cyclic organic group.

Rf is a group including a fluorine atom.

x represents an integer of 1 to 20.

y represents an integer of 0 to 10.

z represents an integer of 0 to 10.

Xf represents a fluorine atom or an alkyl group substituted with at least one fluorine atom. The number of carbon atoms of the alkyl group is preferably in the range of 1 to 10 and more preferably in the range of 1 to 4. In addition, the alkyl group substituted with at least one fluorine atom is preferably a perfluoroalkyl group.

Xf is preferably a fluorine atom or a perfluoroalkyl group having 1 to 4 carbon atoms. Xf is more preferably a fluorine atom or CF₃. Xf's on both sides are particularly preferably fluorine atoms.

R₁₁ and R₁₂ are each independently a hydrogen atom, a fluorine atom, or an alkyl group. The alkyl group may have a substituent (preferably a fluorine atom), and a substituent having 1 to 4 carbon atoms is preferable. A perfluoroalkyl group having 1 to 4 carbon atoms is more preferable. As an alkyl group having substituents of R₁₁ and R₁₂, CF₃ is preferable.

L represents a divalent linking group. As the divalent linking group, for example, —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), or a divalent linking group obtained by combining two or more types thereof is included. Among them, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- are more preferable.

Cy represents a cyclic organic group. As the cyclic organic group, for example, an alicyclic group, an aryl group, and a heterocyclic group are included.

The alicyclic group may be a monocyclic type or may be a polycyclic type. As the monocyclic-type alicyclic group, for example, a monocyclic cycloalkyl group such as a cyclopentyl group, a cyclohexyl group, and a cyclooctyl group is included. As a polycyclic-type alicyclic group, an alicyclic group having 7 or more carbon atoms in a bulky structure such as a norbornyl group, a tricyclodecanyl group, a tetracyclodecanyl group, a tetracyclododecanyl group, and an adamantyl group is preferable, in view of the suppression of diffusibility in a film in a post exposure baking (PEB) step and the enhancement of a mask error enhancement factor (MEEF).

The aryl group may be a monocyclic type or may be a polycyclic type. As the aryl group, for example, a phenyl group, a naphthyl group, a phenanthryl group, and an anthryl group are included. Among them, a naphthyl group of which light absorbance at 193 nm is relatively low is preferable.

The heterocyclic group may be a monocyclic type or a polycyclic type, but the polycyclic-type heterocyclic group can further suppress the diffusion of an acid further. In addition, the heterocyclic group may have aromaticity or may not have aromaticity. As a heterocyclic ring having aromaticity, for example, a furan ring, a thiophene ring, a benzofuran ring, a benzothiophene ring, a dibenzofuran ring, a dibenzothiophene ring, and a pyridine ring are included. As a heterocyclic ring not having aromaticity, for example, a tetrahydropyran ring, a lactone ring, a sultone ring, and a decahydroisoquinoline ring are included. As a heterocyclic ring in the heterocyclic group, a furan ring, a thiophene ring, a pyridine ring, or a decahydroisoquinoline ring is particularly preferable. In addition, as an example of the lactone ring or the sultone ring, a lactone structure exemplified in the resin (A) above or sultone is included.

The cyclic organic group described above may include a substituent. As the substituent, for example, an alkyl group (which may be a straight chain shape or a branched shape and preferably has 1 to 12 carbon atoms), a cycloalkyl group (which may be monocyclic, polycyclic, or a spiro-ring and preferably has 3 to 20 carbon atoms), an aryl group (preferably having 6 to 14 carbon atoms), a hydroxyl group, an alkoxy group, an ester group, an amide group, a urethane group, a ureido group, a thioether group, a sulfonamide group, and a sulfonic acid ester group are included. In addition, carbon constituting a cyclic organic group (carbon contributing to form of ring) may be carbonyl carbon.

x is preferably 1 to 8. Among them, 1 to 4 are preferable, and 1 is particularly preferable. y is preferably 0 to 4, and 0 is more preferable. z is preferably 0 to 8. Among them, 0 to 4 are preferable.

As a group including a fluorine atom represented by Rf, for example, an alkyl group having at least one fluorine atom, a cycloalkyl group having at least one fluorine atom, and an aryl group having at least one fluorine atom are included.

The alkyl group, the cycloalkyl group, and the aryl group may be substituted with fluorine atoms or may be substituted with other substituents including fluorine atoms. If Rf is a cycloalkyl group having at least one fluorine atom or an aryl group having at least one fluorine atom, as other substituents including the fluorine atom, for example, an alkyl group substituted with at least one fluorine atom is included.

In addition, the alkyl group, the cycloalkyl group, and the aryl group may be further substituted with substituents not having fluorine atoms. As the substituents, for example, among the substituents described above in Cy, substituents not having fluorine atoms can be included.

As the alkyl group having at least one fluorine atom represented by Rf, for example, alkyl groups which are the same as the alkyl groups described above as the alkyl groups substituted with at least one fluorine atom represented by Xf are included. As the cycloalkyl group having at least one fluorine atom represented by Rf, for example, a perfluorocyclopentyl group and a perfluorocyclohexyl group are included. As the aryl group having at least one fluorine atom represented by Rf, for example, a perfluorophenyl group is included.

In addition, the non-nucleophilic anion is preferably an anion represented by any one of General Formulae (B-1) to (B-3) below.

In addition, the anion represented by General Formula (B-1) below is described.

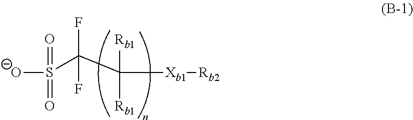

In General Formula (B-1) above,

R_{b1}'s each independently represent a hydrogen atom, a fluorine atom or a trifluoromethyl group (CF₃).

n represents an integer of 1 to 4.

n is preferably an integer of 1 to 3 and more preferably 1 or 2.

X_{b1} represents a single bond, an ether bond, an ester bond (—OCO— or —COO—) or a sulfonic acid ester bond (—OSO₂— or —SO₃—).

X_{b1} is preferably an ester bond (—OCO— or —COO—) or a sulfonic acid ester bond (—OSO₂— or —SO₃—).

R_{b2} represents a substituent having 6 or more carbon atoms.

As the substituent having 6 or more carbon atoms with respect to R_{b2}, a bulky group is preferable, and an alkyl group, an alicyclic group, an aryl group, a heterocyclic group, and the like, which have 6 or more carbon atoms, are included.

The alkyl group having 6 or more carbon atoms with respect to R_{b2} may have a straight chain shape or a branched shape and is preferably a straight chain or branched alkyl group having 6 to 20 carbon atoms, and for example, a straight chain or branched hexyl group, a straight chain or branched heptyl group, and a straight chain or branched octyl group are included. In view of bulkiness, a branched alkyl group is preferable.

The alicyclic group having 6 or more carbon atoms with respect to R_{b2} may be a monocyclic type or a polycyclic type. As the monocyclic-type alicyclic group, for example, a monocyclic cycloalkyl group such as a cyclohexyl group and a cyclooctyl group is included. As the polycyclic-type alicyclic group, for example, a polycyclic cycloalkyl group such as a norbornyl group, a tricyclodecanyl group, a tetracyclodecanyl group, a tetracyclododecanyl group, and an adamantyl group is included. Among them, an alicyclic group with a bulky structure having 7 or more carbon atoms such as a norbornyl group, a tricyclodecanyl group, a tetracyclodecanyl group, a tetracyclododecanyl group, and an adamantyl group is preferable in view of reduction of diffusibility in a film in a post exposure baking (PEB) step and the enhancement of a mask error enhancement factor (MEEF).

The aryl group having 6 or more carbon atoms with respect to R_{b2} may be a monocyclic type or may be a polycyclic type. As the aryl group, for example, a phenyl group, a naphthyl group, a phenanthryl group, and an anthryl group are included. Among them, a naphthyl group of which light absorbance at 193 nm is comparatively low is preferable.

The heterocyclic group having 6 or more carbon atoms with respect to R_{b2} may be a monocyclic type or a polycyclic type, but the polycyclic-type heterocyclic group can more reduces the diffusion of an acid. In addition, the heterocyclic group may have aromaticity or may not have aromaticity. As a heterocyclic ring having aromaticity, for example, a benzofuran ring, a benzothiophene ring, a dibenzofuran ring, and a dibenzothiophene ring are included. As a heterocyclic ring not having aromaticity, for example, a tetrahydropyran ring, a lactone ring, and a decahydroisoquinoline ring are included. As a heterocyclic ring in the heterocyclic group, a benzofuran ring or a decahydroisoquinoline ring is particularly preferable. In addition, as an example of the lactone ring, a lactone structure exemplified in the resin (A) above is included.

The substituent having 6 or more carbon atoms with respect to R_{b2} above may further include a substituent. As the further substituent, for example, an alkyl group (which may be a straight chain shape or a branched shape and preferably has 1 to 12 carbon atoms), a cycloalkyl group (which may be monocyclic, polycyclic, or a spiro-ring and preferably has 3 to 20 carbon atoms), an aryl group (preferably having 6 to 14 carbon atoms), a hydroxy group, an alkoxy group, an ester group, an amide group, a urethane group, a ureido group, a thioether group, a sulfonamide group, and a sulfonic acid ester group are included. In addition, carbon constituting an alicyclic group, an aryl group, or a heterocyclic group (carbon contributing to form of ring) may be carbonyl carbon.

Specific examples of anion represented by General Formula (B-1) are described below, but the invention is not limited thereto.

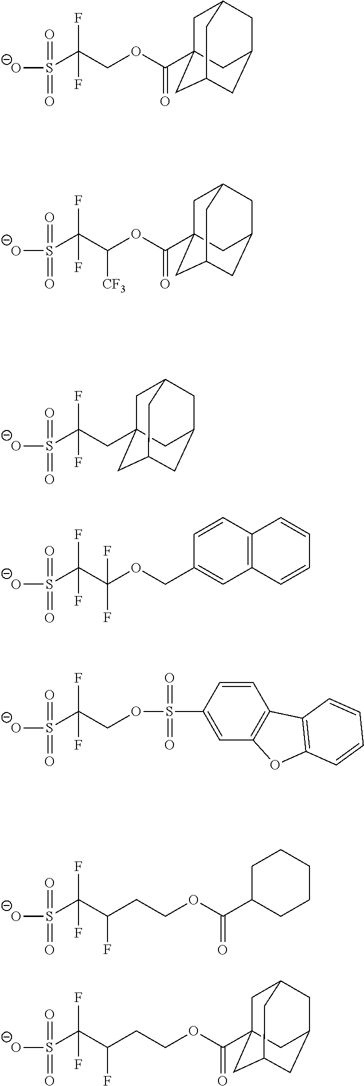

Subsequently, the anion represented by General Formula (B-2) is described.

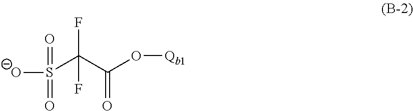

In General Formula (B-2),
Q_{b1} represents a group having a lactone structure, a group having a sultone structure, or a group having a cyclic carbonate structure.

As the lactone structure and the sultone structure with respect to Q_{b1}, for example, structures such as a lactone structure and a sultone structure in the repeating unit having the lactone structure and the sultone structure described in the section of the resin (A) above are included. Specifically, a lactone structure represented by any one of General Formulae (LC1-1) to (LC1-17) or a sultone structure represented by any one of General Formulae (SL1-1) to (SL1-3) are included.

The lactone structure or the sultone structure may be directly bonded to oxygen atoms of the ester groups in General Formula (B-2), but the lactone structure or the sultone structure may be bonded to the oxygen atom of the ester group through an alkylene group (for example, methylene group or ethylene group). In this case, the group having the lactone structure or the sultone structure can be an alkyl group having the lactone structure or the sultone structure as a substituent.

As a cyclic carbonate structure with respect to Q_{b1}, a cyclic carbonate structure of a 5-membered to 7-membered ring is preferable, and 1,3-dioxolan-2-one and 1,3-dioxan-2-one are included.

The cyclic carbonate structure may be directly bonded to an oxygen atom of an ester group in General Formula (B-2), but the cyclic carbonate structure may be bonded to the oxygen atom of the ester group through an alkylene group (for example, a methylene group and an ethylene group). In this case, a group having the cyclic carbonate structure may be an alkyl group having a cyclic carbonate structure as a substituent.

Specific examples of the anion represented by General Formula (B-2) are described below, but the invention is not limited thereto.

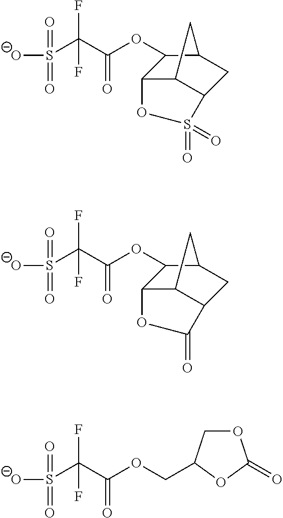

Subsequently, the anion represented by General Formula (B-3) below is described.

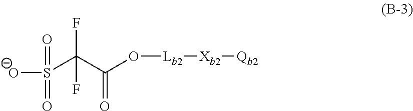

In General Formula (B-3),
L_{b2} represents an alkylene group having 1 to 6 carbon atoms, for example, a methylene group, an ethylene group, a propylene group, and a butylene group are included, and an alkylene group having 1 to 4 carbon atoms is preferable.

X_{b2} represents an ether bond or an ester bond (—OCO— or —COO—).

Q_{b2} represents an alicyclic group or a group containing an aromatic ring.

An alicyclic group with respect to Q_{b2} may be a monocyclic type or a polycyclic type. As the monocyclic-type alicyclic group, for example, a monocyclic cycloalkyl group such as a cyclopentyl group, a cyclohexyl group, and a cyclooctyl group are included. As the polycyclic-type alicyclic group, an alicyclic group having a bulky structure having 7 or more carbon atoms such as norbornyl group, a tricyclodecanyl group, a tetracyclodecanyl group, a tetracyclododecanyl group, and an adamantyl group is preferable.

As the aromatic ring in a group containing an aromatic ring with respect to Q_{b2}, an aromatic ring having 6 to 20 carbon atoms is preferable, a benzene ring, a naphthalene ring, a phenanthrene ring, an anthracene ring, and the like are included, and a benzene ring or a naphthalene ring are more preferable. The aromatic ring may be substituted with at least one fluorine atom, and as the aromatic ring substituted with at least one fluorine atom, a perfluorophenyl group and the like are included.

The aromatic ring may be directly bonded to X_{b2}, or the aromatic ring may be bonded to X_{b2} through an alkylene group (for example, methylene group or ethylene group). In this case, the group containing the aromatic ring may be an alkyl group having the aromatic ring as a substituent.

Specific examples of an anion structure represented by General Formula (B-3) are described below, but the invention is not limited thereto.

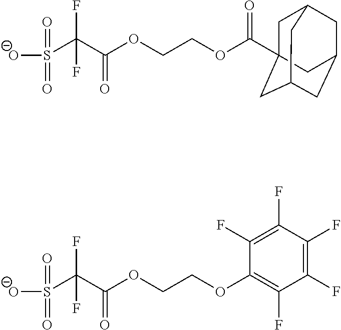

In General Formula (ZI), as the organic group represented by R₂₀₁, R₂₀₂, and R₂₀₃, for example, groups corresponding to the compounds (ZI-1), (ZI-2), (ZI-3), and (ZI-4) described below can be included.

In addition, a compound having plural structures represented by General Formula (ZI) may be used. For example, a compound in which at least one of R₂₀₁ to R₂₀₃ of a compound represented by General Formula (ZI) is bonded to at least one of R₂₀₁ to R₂₀₃ of another compound represented by General Formula (ZI) through a single bond or a linking group may be used.

As a more preferable (ZI) component, compounds (ZI-1), (ZI-2), (ZI-3), and (ZI-4) described below can be included.

The compound (ZI-1) is an arylsulfonium compound in which at least one of R₂₀₁ to R₂₀₃ of General Formula (ZI) is an aryl group, that is, a compound in which arylsulfonium is included as a cation.

In the arylsulfonium compound, all of R₂₀₁ to R₂₀₃ may be an aryl group, or a portion of R₂₀₁ to R₂₀₃ may be an aryl group, and the rest may be an alkyl group or a cycloalkyl group.

As the arylsulfonium compound, for example, a triarylsulfonium compound, a diarylalkylsulfonium compound, an aryldialkylsulfonium compound, a diarylcycloalkylsulfonium compound, and an aryldicycloalkylsulfonium compound can be included.

As the aryl group consisting of the arylsulfonium compound, a phenyl group and a naphthyl group are preferable, and a phenyl group is more preferable. The aryl group may be an aryl group having a heterocyclic structure having an oxygen atom, a nitrogen atom, and a sulfur atom. As the heterocyclic structure, a pyrrole residue, a furan residue, a thiophene residue, an indole residue, a benzofuran residue, a benzothiophene residue, and the like are included. If the arylsulfonium compound has 2 or more aryl groups, the 2 or more aryl groups may be identical to or different from each other.

The alkyl group or the cycloalkyl group included in the arylsulfonium compound, if necessary, is preferably a straight chain or branched alkyl group having 1 to 15 carbon atoms or a cycloalkyl group having 3 to 15 carbon atoms, and for example, a methyl group, an ethyl group, a propyl group, an n-butyl group, a sec-butyl group, a t-butyl group, a cyclopropyl group, a cyclobutyl group, and a cyclohexyl group can be included.

The aryl group, the alkyl group, or the cycloalkyl group as R₂₀₁ to R₂₀₃ may have an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, and a phenylthio group, as a substituent. As a preferable substituent, a straight chain or branched alkyl group having 1 to 12 carbon atoms, a cycloalkyl group having 3 to 12 carbon atoms, or a straight chain, branched, or cyclic alkoxy group having 1 to 12 carbon atoms is included, and an alkyl group having 1 to 4 carbon atoms and an alkoxy group having 1 to 4 carbon atoms are more preferable. A substituent may be substituted with any one of three of R₂₀₁ to R₂₀₃, or may be substituted with all of three of R₂₀₁ to R₂₀₃. In addition, if R₂₀₁ to R₂₀₃ are aryl groups, the substituents preferably are substituted at p-positions of the aryl groups.

Subsequently, the compound (ZI-2) is described.

The compound (ZI-2) is a compound in which R₂₀₁ to R₂₀₃ in Formula (ZI) each independently represent an organic group having an aromatic ring. Herein, the aromatic ring includes an aromatic ring containing a heteroatom.

The organic group that does not contain an aromatic ring as R₂₀₁ to R₂₀₃ generally has 1 to 30 carbon atoms and preferably has 1 to 20 carbon atoms.

R₂₀₁ to R₂₀₃ are each independently and preferably an alkyl group, a cycloalkyl group, an aryl group, or a vinyl group, more preferably a straight chain or branched 2-oxoalkyl group, 2-oxocycloalkyl group, or alkoxycarbonylmethyl group, and particularly preferably a straight chain or branched 2-oxoalkyl group.

As the alkyl group and the cycloalkyl group as R₂₀₁ to R₂₀₃, a straight chain or branched alkyl group having 1 to 10 carbon atoms (for example, methyl group, ethyl group, propyl group, butyl group, and pentyl group) is preferable, and a cycloalkyl group having 3 to 10 carbon atoms (cyclopentyl group, cyclohexyl group, and norbornyl group) can be included. As the alkyl group, a 2-oxoalkyl group, more preferably, an alkoxycarbonylmethyl group can be included. As the cycloalkyl group, more preferably, 2-oxocycloalkyl group can be included.

The 2-oxoalkyl group may be a straight chain group or a branched group, and a group having >C═O at the position 2 of the alkyl group can be preferably included.

The 2-oxocycloalkyl group can preferably include a group having >C═O at the position 2 of the cycloalkyl group.

As the alkoxy group in the alkoxycarbonylmethyl group, an alkoxy group having 1 to 5 carbon atoms (methoxy group, ethoxy group, propoxy group, butoxy group, and pentoxy group) can be preferably included.

R₂₀₁ to R₂₀₃ may be further substituted with a halogen atom, an alkoxy group (for example, having 1 to 5 carbon atoms), a hydroxyl group, a cyano group, and a nitro group.

Subsequently, the compound (ZI-3) is described.

The compound (ZI-3) is a compound represented by General Formula (ZI-3) below and a compound having a phenacylsulfonium salt structure.

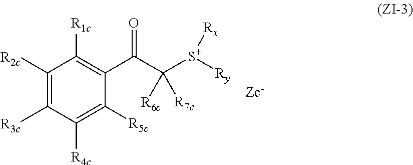

In General Formula (ZI-3),
R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

R_{6c} and R_{7c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Any two or more of R_{1c} to R_{5c}, R_{5c} and R_{6c}, R_{6c} and R_{7c}, R_{5c} and Rₓ, and Rₓ and R_{y} may be bonded to each other to form a ring structure, and the ring structure may include an oxygen atom, a sulfur atom, a ketone group, an ester bond, and an amide bond.

As the ring structure, an aromatic or non-aromatic hydrocarbon ring, an aromatic or non-aromatic heterocyclic ring, or a polycyclic condensed ring obtained by combining two or more rings thereof can be included. As the ring structure, 3-membered to 10-membered rings can be included, 4-membered to 8-membered rings are preferable, and 5-membered or 6-membered rings are more preferable.

As a group formed by bonding any 2 or more of R_{1c} to R_{5c} to each other, R_{6c} and R_{7c} to each other, or Rₓ and R_{y} to each other, a butylene group, a pentylene group, and the like can be included.

As a group formed by bonding R_{5c} to R_{6c}, and R_{5c} to Rₓ a single bond or an alkylene group is preferable, and as an alkylene group, a methylene group, an ethylene group, and the like can be included.

Zc⁻ represents a non-nucleophilic anion, and a non-nucleophilic anion in the same manner as Z⁻ in General Formula (ZI) can be included.

The alkyl groups as R_{1c} to R_{7c} may be straight chain groups or branched groups, and for example, an alkyl group having 1 to 20 carbon atoms, and preferably straight chain or branched alkyl groups having 1 to 12 carbon atoms (for example, methyl group, ethyl group, straight chain or branched propyl group, straight chain or branched butyl group, and straight chain or branched pentyl group) can be included, and as a cycloalkyl group, for example, a cycloalkyl group having 3 to 10 carbon atoms (for example, cyclopentyl group, and cyclohexyl group) can be included.

The aryl groups as R_{1c} to R_{5c} preferably have 5 to 15 carbon atoms, and for example, a phenyl group and a naphthyl group can be included.

The alkoxy groups as R_{1c} to R_{5c} may be a straight chain group, a branched group, or a cyclic group, and for example, an alkoxy group having 1 to 10 carbon atoms, and preferably, a straight chain and branched alkoxy group having 1 to 5 carbon atoms (for example, methoxy group, ethoxy group, straight chain or branched propoxy group, straight chain or branched butoxy group, straight chain or branched pentoxy group), and a cyclic alkoxy group having 3 to 10 carbon atoms (for example, cyclopentyloxy group, cyclohexyloxy group) can be included.

Specific examples of the alkoxy group in the alkoxycarbonyl group as R_{1c} to R_{5c} are the same as the specific examples of the alkoxy group as R_{1c} to R_{5c} described above.

Specific examples of the alkyl group in the alkylcarbonyloxy group and the alkylthio group as R_{1c} to R_{5c} are the same as the specific examples of the alkyl group as R_{1c} to R_{5c} described above.

Specific examples of the cycloalkyl group in the cycloalkylcarbonyloxy group as R_{1c} to R_{5c} are the same as the specific examples of the cycloalkyl group as R_{1c} to R_{5c} described above.

Specific examples of the aryl group in the aryloxy group and the arylthio group as R_{1c} to R_{5c} are the same as the specific examples of the aryl group as R_{1c} to R_{5c} described above.

Preferably, any one of R_{1c} to R_{5c} is a straight chain or branched alkyl group, a cycloalkyl group, or a straight chain, branched, or cyclic alkoxy group, and more preferably a sum of the numbers of the carbon atoms of R_{1c} to R_{5c} is 2 to 15. Accordingly, solvent solubility is more enhanced, and the generation of particles during the time of storage is suppressed.

As the ring structure that may be formed by bonding any 2 or more of R_{1c} to R_{5c} to each other, preferably a 5-membered or 6-membered ring, and particularly preferably a 6-membered ring (for example, phenyl ring) is included.

As the ring structure that may be formed by bonding R_{5c} and R_{6c} to each other, a 4 or more-membered ring (particularly preferably 5-membered to 6-membered ring) formed together with a carbonyl carbon atom and a carbon atom in General Formula (ZI-3) by constituting a single bond or an alkylene group (methylene group, ethylene group, and the like) by bonding R_{5c} and R_{6c} to each other is included.

The aryl groups as R_{6c} and R_{7c} preferably have 5 to 15 carbon atoms, and for example, a phenyl group and a naphthyl group can be included.

With respect to the forms of R_{6c} and R_{7c}, both are preferably alkyl groups. Particularly, it is preferable that R_{6c} and R_{7c} are respectively straight chain or branched alkyl groups having 1 to 4 carbon atoms, and particularly, it is preferable that both are methyl groups.

In addition, if a ring is formed by bonding R_{6c} and R_{7c}, as a group formed by bonding R_{6c} and R_{7c}, an alkylene group having 2 to 10 carbon atoms is preferable, and for example, an ethylene group, a propylene group, a butylene group, a pentylene group, and a hexylene group can be included. In addition, a ring formed by bonding R_{6c} and R_{7c} may include a heteroatom such as an oxygen atom in the ring.

As the alkyl group and the cycloalkyl group as Rₓ and R_{y}, the alkyl groups and the cycloalkyl groups which are the same as R_{1c} to R_{7c} can be included.

The 2-oxoalkyl group and the 2-oxocycloalkyl group as Rₓ and R_{y} can include groups having >C═O at the position 2 of the alkyl groups and the cycloalkyl groups as R_{1c} to R_{7c}.

With respect to the alkoxy groups in the alkoxycarbonylalkyl groups as Rₓ and R_{y}, the alkoxy groups which are the same as in R_{1c} to R_{5c} can be included. With respect to the alkyl group, for example, an alkyl group having 1 to 12 carbon atoms and, preferably, a straight chain alkyl group having 1 to 5 carbon atoms (for example, methyl group, ethyl group) can be included.

The aryl groups as Rₓ and R_{y} are not particularly limited, but aryl groups substituted with unsubstituted aryl groups or monocyclic or polycyclic cycloalkyl groups (preferably cycloalkyl groups having 3 to 10 carbon atoms) are preferable.

The vinyl groups as Rₓ and R_{y} are not particularly limited, but vinyl groups substituted with unsubstituted vinyl groups or monocyclic or polycyclic cycloalkyl groups (preferably cycloalkyl groups having 3 to 10 carbon atoms) are preferable.

As the ring structure that may be formed by bonding R_{5c} and Rₓ to each other, a 5 or more-membered ring (particularly preferably 5-membered ring) formed together with a sulfur atom and a carbonyl carbon atom in General Formula (ZI-3) by constituting a single bond or an alkylene group (methylene group, ethylene group, and the like) by bonding R_{5c} and Rₓ to each other is included.

As the ring structure that may be formed by bonding Rₓ and R_{y} to each other, a 5-membered or 6-membered ring, particularly preferably, a 5-membered ring (that is, tetrahydrothiophene ring) formed by divalent Rₓ and R_{y} (for example, methylene group, ethylene group, and propylene group), together with a sulfur atom in General Formula (ZI-3), is included.

Rₓ and R_{y} are preferably alkyl groups or cycloalkyl groups having 4 or more carbon atoms, more preferably alkyl groups or cycloalkyl groups having 6 or more carbon atoms, and still more preferably alkyl groups or cycloalkyl groups having 8 or more carbon atoms.

R_{1c} to R_{7c}, Rₓ and R_{y} may further have substituents, and as the substituents, a halogen atom (for example, fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, and an aryloxycarbonyloxy group can be included.

In General Formula (ZI-3) above, R_{1c}, R_{2c}, R_{4c}, and R_{5c} each independently represent a hydrogen atom, and R_{1c} is preferably a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

As the cation of the compound represented by General Formula (ZI-2) or (ZI-3) according to the invention, specific examples described below are included.

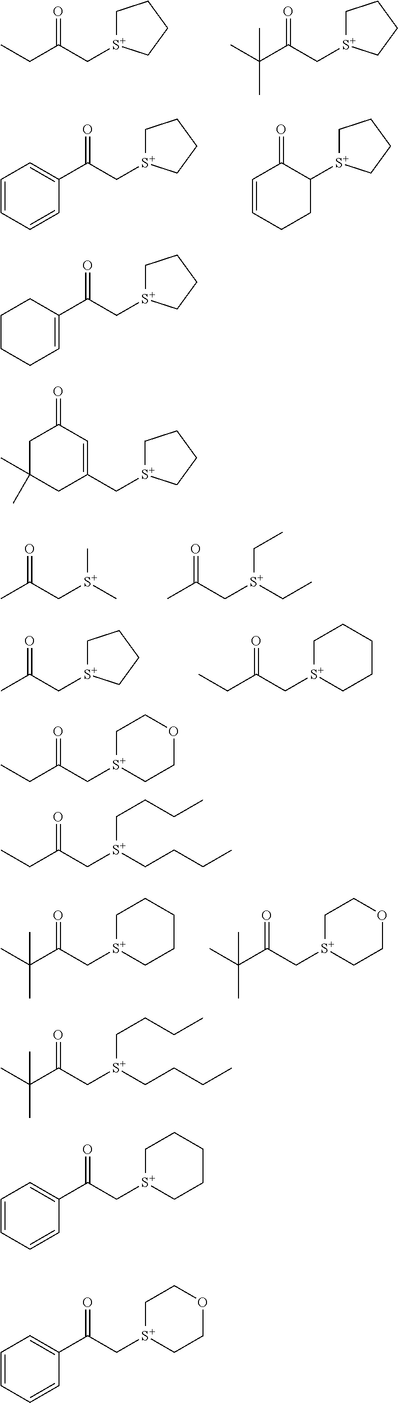

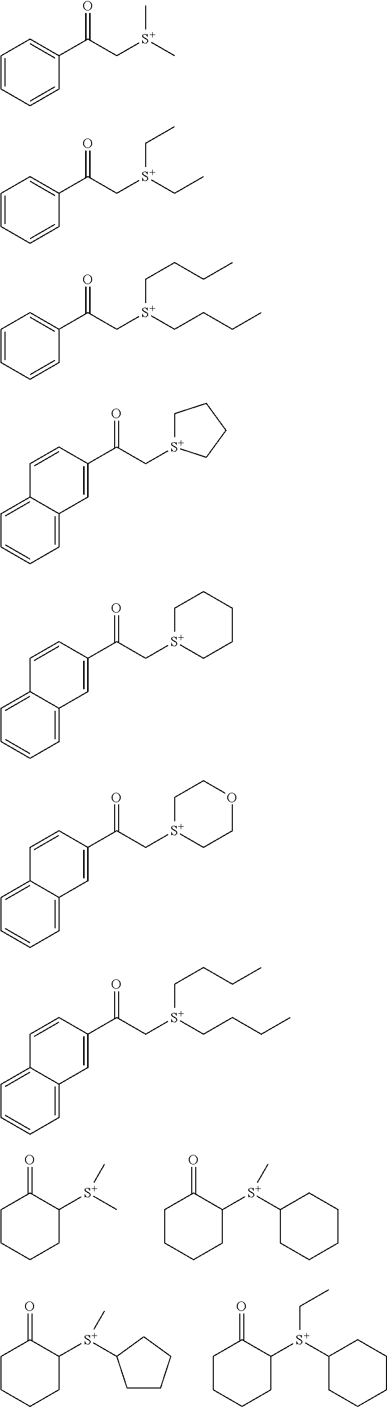

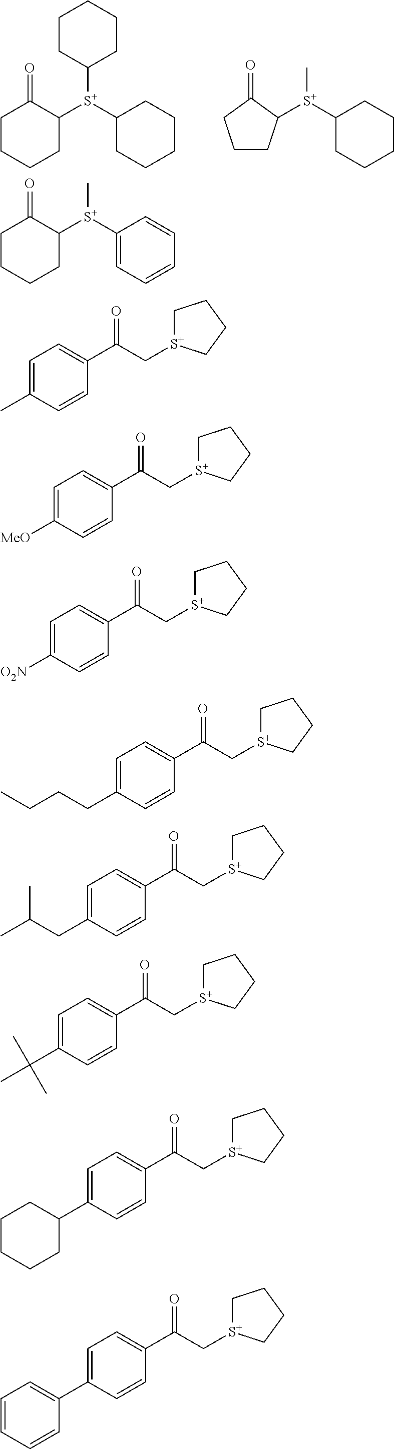

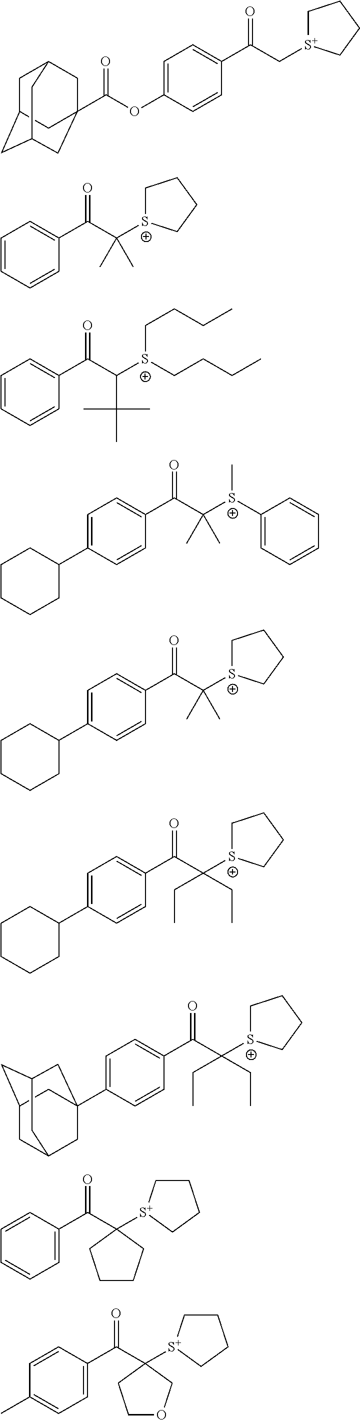

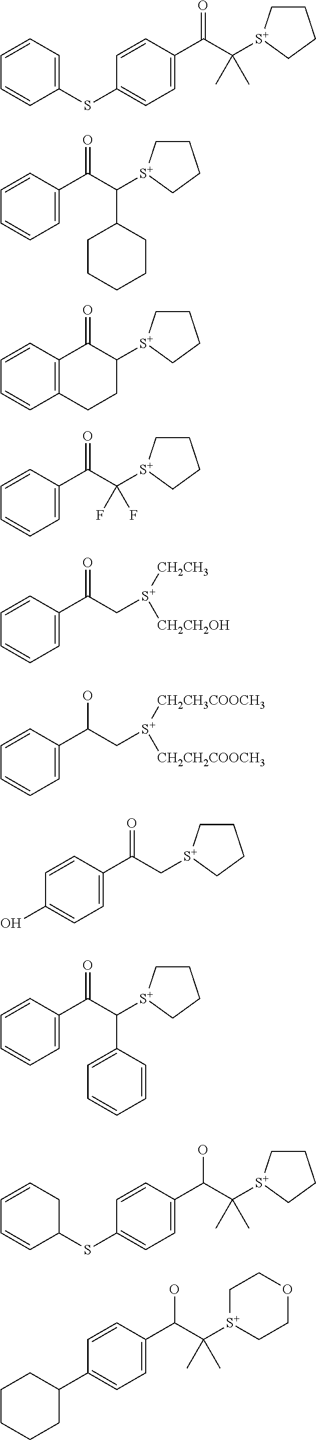

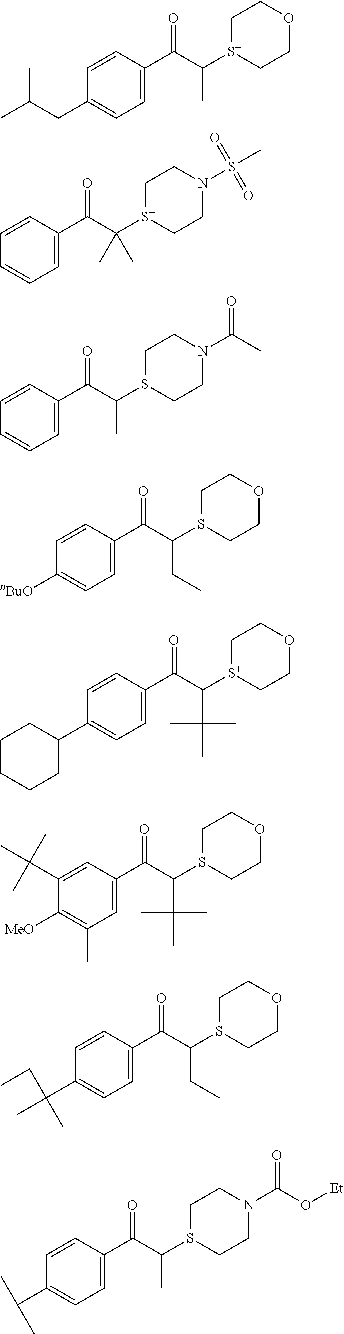

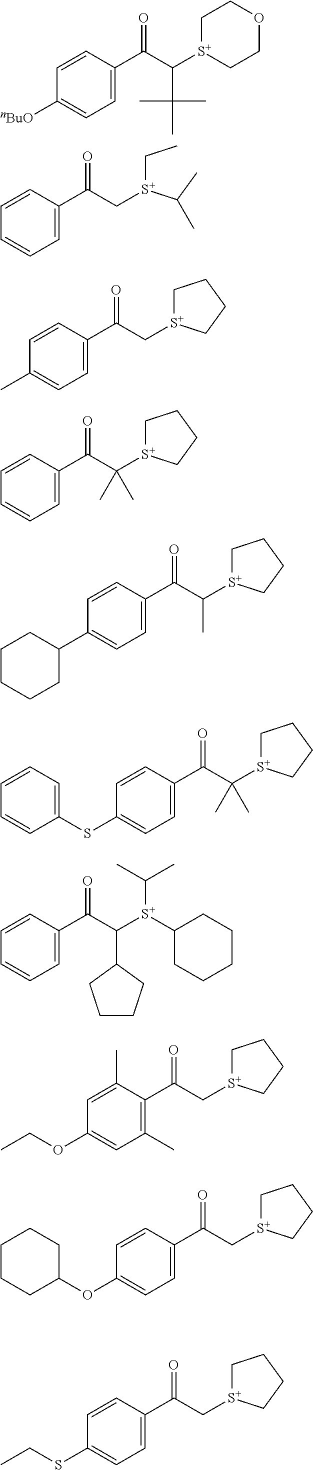

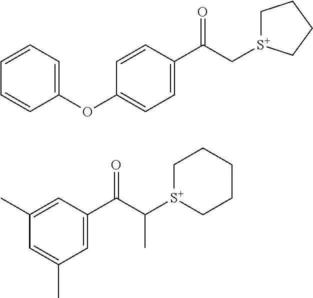

Subsequently, the compound (ZI-4) is described.

The compound (ZI-4) is represented by General Formula (ZI-4) below.

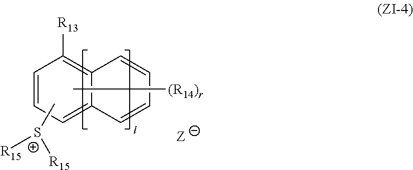

In General Formula (ZI-4),

R₁₃ represents a group having a hydrogen atom, a fluorine atom, a hydroxyl group, an alkyl group, a cycloalkyl group, an alkoxy group, an alkoxycarbonyl group, or a cycloalkyl group. These groups may have substituents.

If there are plural R₁₄'s, the plural R₁₄'s each independently represent a group having a hydroxyl group, an alkyl group, a cycloalkyl group, an alkoxy group, an alkoxycarbonyl group, an alkylcarbonyl group, an alkylsulfonyl group, a cycloalkylsulfonyl group, or a cycloalkyl group. These groups may have substituents.

R₁₅'s each independently represent an alkyl group, a cycloalkyl group, or a naphthyl group. Two R₁₅'s may be bonded to each other to form a ring. These groups may have substituents.

l represents an integer of 0 to 2.

r represents an integer of 0 to 8.

Z⁻ represents a non-nucleophilic anion, and a non-nucleophilic anion which is the same as in Z⁻ in General Formula (ZI) can be included.

In General Formula (ZI-4), as the alkyl groups as R₁₃, R₁₄, and R₁₅, groups that have straight chain shapes or branched shapes and have 1 to 10 carbon atoms are preferable, and a methyl group, an ethyl group, an n-butyl group, and a t-butyl group are preferable.

As the cycloalkyl groups as R₁₃, R₁₄, and R₁₅, monocyclic or polycyclic cycloalkyl groups (preferably, cycloalkyl group having 3 to 20 carbon atoms) are included, and cyclopropyl, cyclopentyl, cyclohexyl, cycloheptyl, and cyclooctyl groups are particularly preferable.

As the alkoxy groups as R₁₃ and R₁₄, groups which have straight chain shapes or branched shapes, and have 1 to 10 carbon atoms are preferable, and a methoxy group, an ethoxy group, an n-propoxy group, an n-butoxy group, and the like are preferable.

As the alkoxycarbonyl groups as R₁₃ and R₁₄, groups that have straight chain shapes or branched shapes and 2 to 11 carbon atoms are preferable, and a methoxycarbonyl group, an ethoxycarbonyl group, an n-butoxycarbonyl group, and the like are preferable.

As the groups having the cycloalkyl groups as R₁₃ and R₁₄, monocyclic or polycyclic cycloalkyl groups (preferably cycloalkyl groups having 3 to 20 carbon atoms) are included, and for example, monocyclic or polycyclic cycloalkyloxy groups and monocyclic or polycyclic cycloalkyl groups are included. These groups may further include substituents.

As the monocyclic or polycyclic cycloalkyloxy as R¹³ and R¹⁴, a group of which a total number of carbon atoms is 7 or more is preferable, a group of which a total number of carbon atoms is in the range of 7 to 15 is preferable, and a monocyclic cycloalkyl group is preferably included. The monocyclic cycloalkyloxy group of which a total number of carbon atoms is 7 or more represents a monocyclic cycloalkyloxy group arbitrarily having a substituent such as a carboxy group or an acyloxy group such as an alkyl group, a hydroxyl group, a halogen atom (fluorine, chlorine, bromine, and iodine), a nitro group, a cyano group, an amide group, a sulfonamide group, an alkoxy group, an alkoxycarbonyl group, an acyl group, an acetoxy group, a butyryloxy group, in a cycloalkyloxy group such as a cyclopropyloxy group, a cyclobutyloxy group, a cyclopentyloxy group, a cyclohexyloxy group, a cycloheptyloxy group, a cyclooctyloxy group, and a cyclododecanyloxy group and groups of which a total number of carbon atoms together with arbitrary substituents on the cycloalkyl groups is 7 or more.

In addition, as the polycyclic cycloalkyloxy group of which a total number of carbon atoms is 7 or more, a norbornyloxy group, a tricyclodecanyloxy group, a tetracyclodecanyloxy group, and an adamantyloxy group are included.

As the alkoxy group having monocyclic or polycyclic cycloalkyl groups as R₁₃ and R₁₄, groups of which a total number of carbon atoms is 7 or more are preferable, groups of which a total number of carbon atoms is in the range of 7 to 15 are more preferable, and an alkoxy group having a monocyclic cycloalkyl group is preferable. The alkoxy group having a monocyclic cycloalkyl group of which a total number of carbon atoms is 7 or more represents a group in which an monocyclic cycloalkyl group that may have the substituent described above in an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy, and iso-amyloxy and a total number of carbon atoms is 7 or more together with the substituent. For example, a cyclohexylmethoxy group, a cyclopentylethoxy group, and a cyclohexylethoxy group are included, and a cyclohexylmethoxy group is preferable.

In addition, as the alkoxy group having the polycyclic cycloalkyl group of which a total number of carbon atoms is 7 or more, a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, and an adamantylethoxy group are included, and a norbornylmethoxy group, a norbornylethoxy group, and the like are preferable.

As the alkyl group of the alkylcarbonyl group as R₁₄, specific examples which are the same as in the alkyl groups as R₁₃ to R₁₅ described above are included.

As the alkylsulfonyl group and the cycloalkylsulfonyl group as R₁₄, a group which has a straight chain shape, a branched shape, a cyclic shape, and of which the total number of carbon atoms is 1 to 10 is preferable, and for example, a methanesulfonyl group, an ethanesulfonyl group, a n-propanesulfonyl group, a n-butanesulfonyl group, a cyclopentanesulfonyl group, and a cyclohexanesulfonyl group are preferable.

As the substituent that may be included in the respective groups, a halogen atom (for example, fluorine atom), a hydroxyl group, a carboxyl group, a cyano group, a nitro group, an alkoxy group, an alkoxyalkyl group, an alkoxycarbonyl group, an alkoxycarbonyloxy group, and the like can be included.

As the ring structure that may be formed by bonding two R₁₅'s to each other, a 5-membered or 6-membered ring, particularly a 5-membered ring (that is, tetrahydrothiophene ring) formed by two R₁₅'s together with the sulfur atom in General Formula (ZI-4) is included, and may be condensed with the aryl group or the cycloalkyl group. The divalent R₁₅ may have a substituent, and, as the substituent, for example, a hydroxyl group, a carboxyl group, a cyano group, a nitro group, an alkyl group, a cycloalkyl group, an alkoxy group, an alkoxyalkyl group, an alkoxycarbonyl group, and an alkoxycarbonyloxy group can be included. Plural substituents may be present on the ring structure, and in addition, the substituents may be bonded to each other to form a ring (aromatic or non-aromatic hydrocarbon ring, aromatic or non-aromatic heterocyclic ring, or polycyclic condensed ring obtained by combining 2 or more of these rings).

As R₁₅ in General Formula (ZI-4), divalent groups in which a methyl group, an ethyl group, a naphthyl group, and a divalent group in which two R₁₅'s are bonded to each other and form a tetrahydrothiophene ring structure together with a sulfur atom are preferable.

As the substituent that may be included in R₁₃ and R₁₄, a hydroxyl group, an alkoxy group, an alkoxycarbonyl group, or a halogen atom (particularly, fluorine atom) is preferable.

As l, 0 or 1 is preferable, and 1 is more preferable.

As r, 0 to 2 are preferable.

As a cation of the compound represented by General Formula (ZI-4) according to the invention, specific examples described below are included.

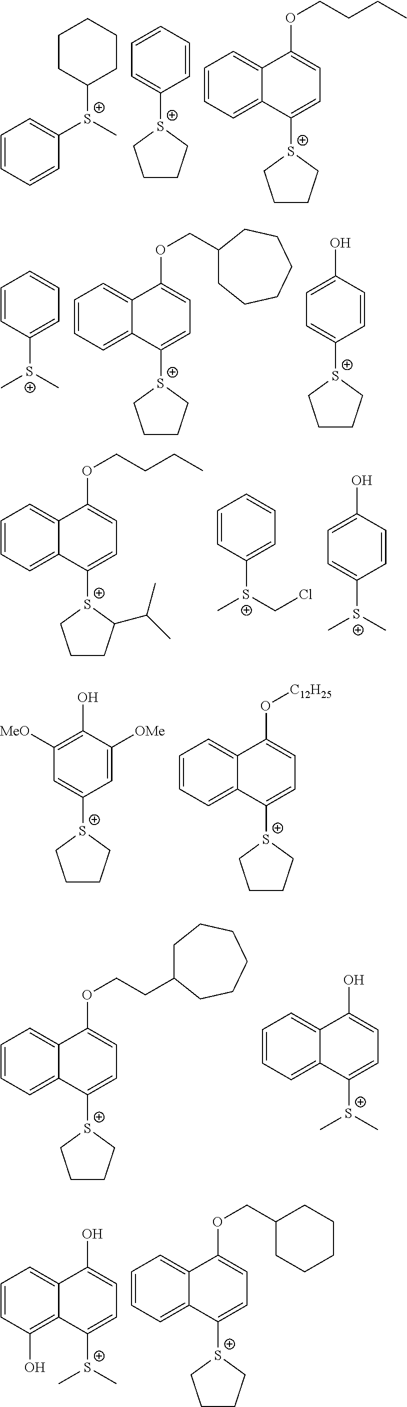

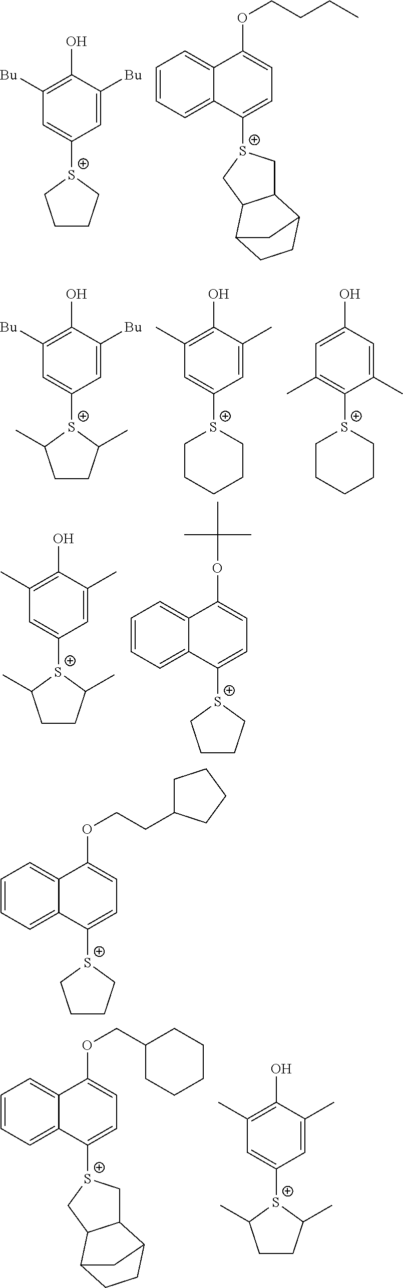

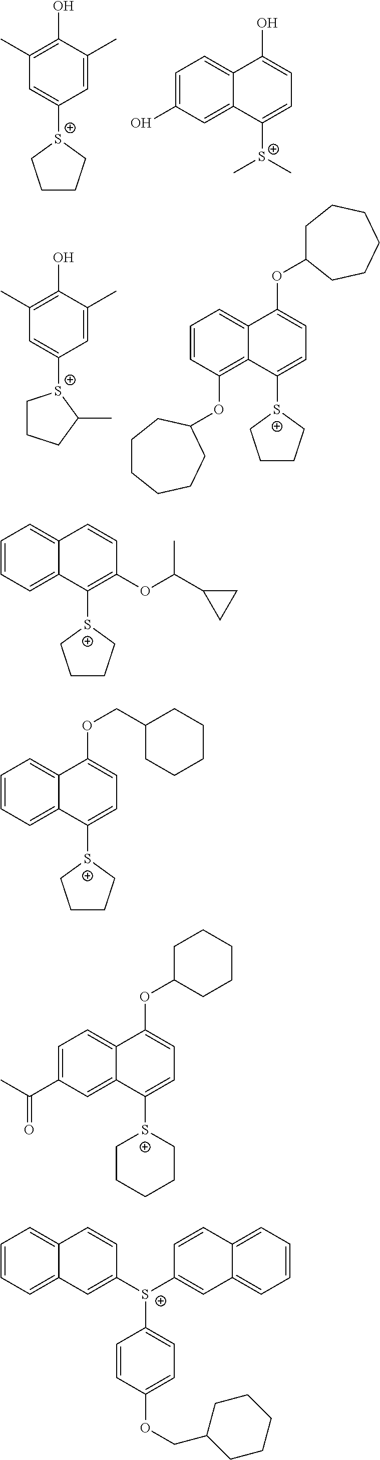

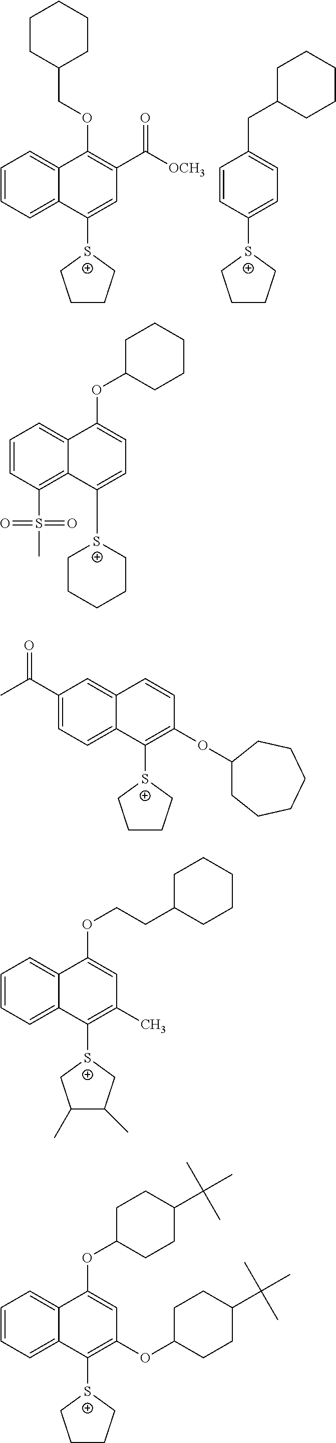

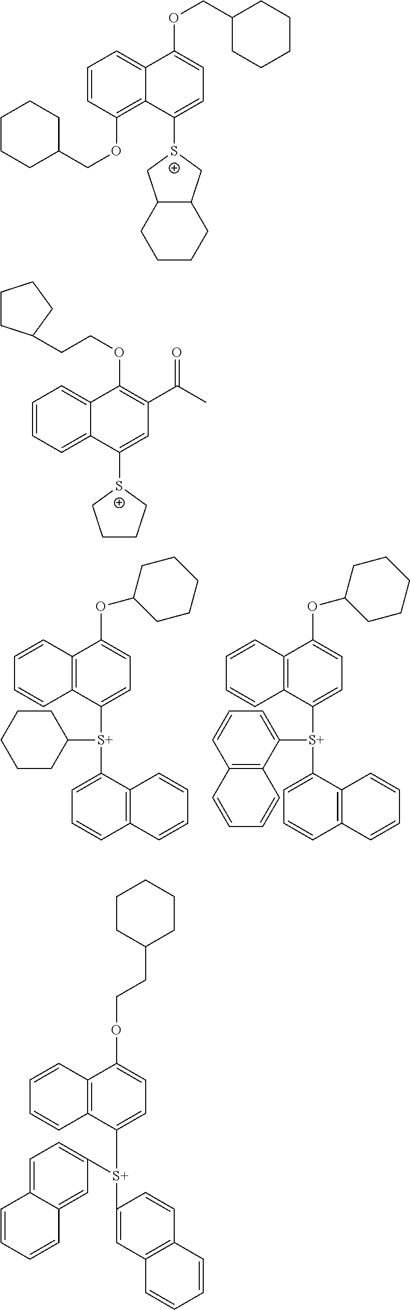

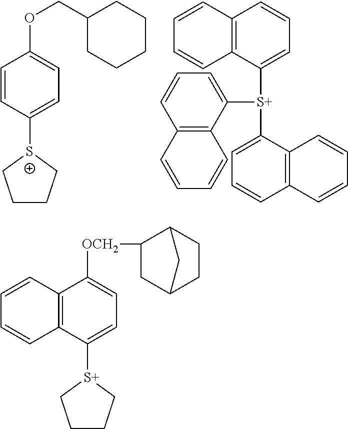

Subsequently, General Formulae (ZII) and (ZIII) are described.

In General Formulae (ZII) and (ZIII),

R₂₀₄ to R₂₀₇ each independently represent an aryl group, an alkyl group or a cycloalkyl group.

As the aryl groups as R₂₀₄ to R₂₀₇, phenyl groups and naphthyl groups are preferable, and phenyl groups are more preferable. The aryl groups as R₂₀₄ to R₂₀₇ may be aryl groups having heterocyclic structures having oxygen atoms, nitrogen atoms, sulfur atoms, and the like. As a skeleton of the aryl group having a heterocyclic structure, for example, pyrrole, furan, thiophene, indole, benzofuran, and benzothiophene can be included.

As the alkyl groups and the cycloalkyl groups in R₂₀₄ to R₂₀₇, preferably, straight chain or branched alkyl groups having 1 to 10 carbon atoms (for example, methyl groups, ethyl groups, propyl groups, butyl groups, and pentyl groups), and cycloalkyl groups having 3 to 10 carbon atoms (cyclopentyl groups, cyclohexyl groups, and norbornyl groups) can be included.

The aryl group, the alkyl group, and the cycloalkyl group as R₂₀₄ to R₂₀₇ may have substituents. As the substituents that may be included in the aryl group, the alkyl group, and the cycloalkyl group as R₂₀₄ to R₂₀₇, for example, an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group can be included.

Z⁻ represents a non-nucleophilic anion, and the non-nucleophilic anion which is the same as in Z⁻ in General Formula (ZI) can be included.

As the acid generator, further, compounds represented by General Formulae (ZIV), (ZV), and (ZVI) described below are included.

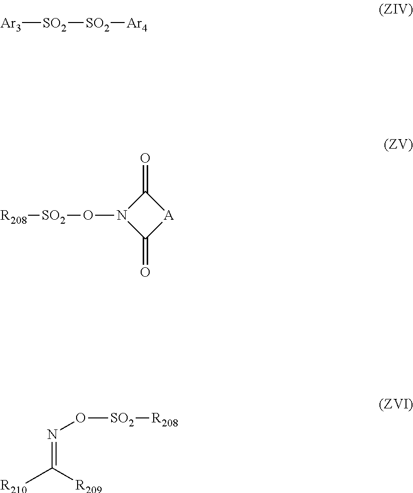

In General Formulae (ZIV) to (ZVI),

Ar₃ and Ar₄ each independently represent an aryl group.

R₂₀₈, R₂₀₉, and R₂₁₀ each independently represent an alkyl group, a cycloalkyl group, or an aryl group.

A represents an alkylene group, an alkenylene group, or an arylene group.

As specific examples of the aryl groups as Ar₃, Ar₄, R₂₀₈, R₂₀₉, and R₂₁₀, those which are the same as the specific examples of the aryl groups in R₂₀₁, R₂₀₂, and R₂₀₃ in General Formula (ZI-1) described above can be included.

As specific examples of the alkyl group and the cycloalkyl group as R₂₀₈, R₂₀₉, and R₂₁₀, respectively, those which are the same as the specific examples of the alkyl group and the cycloalkyl group in R₂₀₁, R₂₀₂, and R₂₀₃ in General Formula (ZI-2) described above can be included.

As the alkylene group as A, alkylene having 1 to 12 carbon atoms (for example, methylene group, ethylene group, propylene group, isopropylene group, butylene group, and isobutylene group) can be included. As an alkenylene group as A, an alkenylene group having 2 to 12 carbon atoms (for example, ethenylene group, propenylene group, and butenylene group) can be included. As an arylene group as A, an arylene group having 6 to 10 carbon atoms (for example, phenylene group, tolylene group, and naphthylene group) can be included.

Among the acid generators, compounds represented by General Formulae (ZI) to (ZIII) are more preferable.

In addition, as the acid generator, a compound that generates an acid having one sulfonic acid group or imide group is preferable, a compound that generates a monovalent perfluoroalkanesulfonic acid, a compound that generates an aromatic sulfonic acid substituted with a group containing a monovalent fluorine atom or a fluorine atom, or a compound that generates an imide acid substituted with a group containing a monovalent fluorine atom or a fluorine atom is more preferable, and a fluorine-substituted alkanesulfonic acid, a fluorine-substituted benzenesulfonic acid, a fluorine-substituted imide acid, or a sulfonium salt of a fluorine-substituted methide acid is still more preferable. The acid generators able to be used are particularly preferably a fluorine-substituted alkanesulfonic acid, a fluorine-substituted benzenesulfonic acid, and a fluorine-substituted imide acid, in which pKa of the generated acid is −1 or lower, and the sensitivity is enhanced.

Among the acid generators, particularly preferred examples are described below.

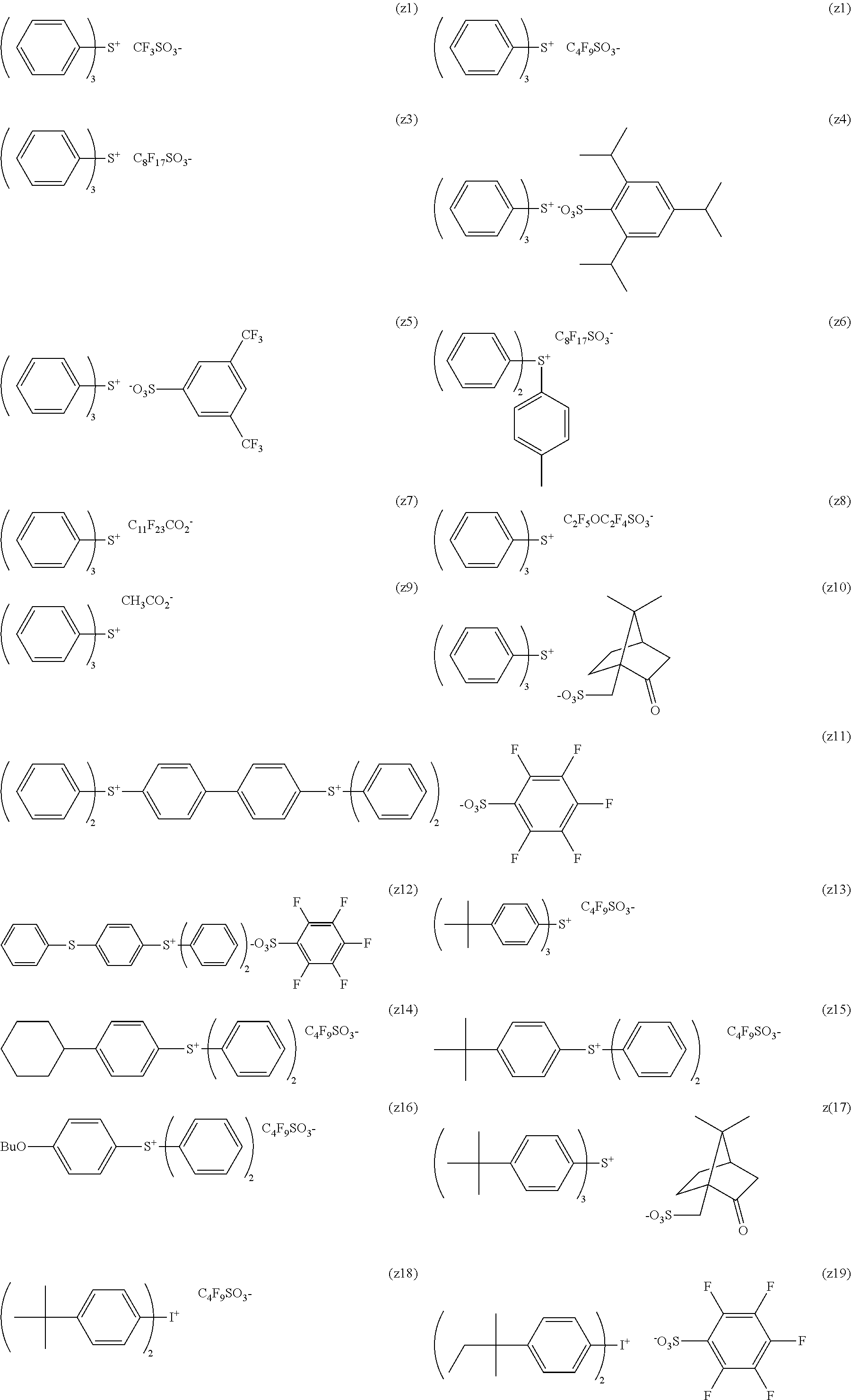

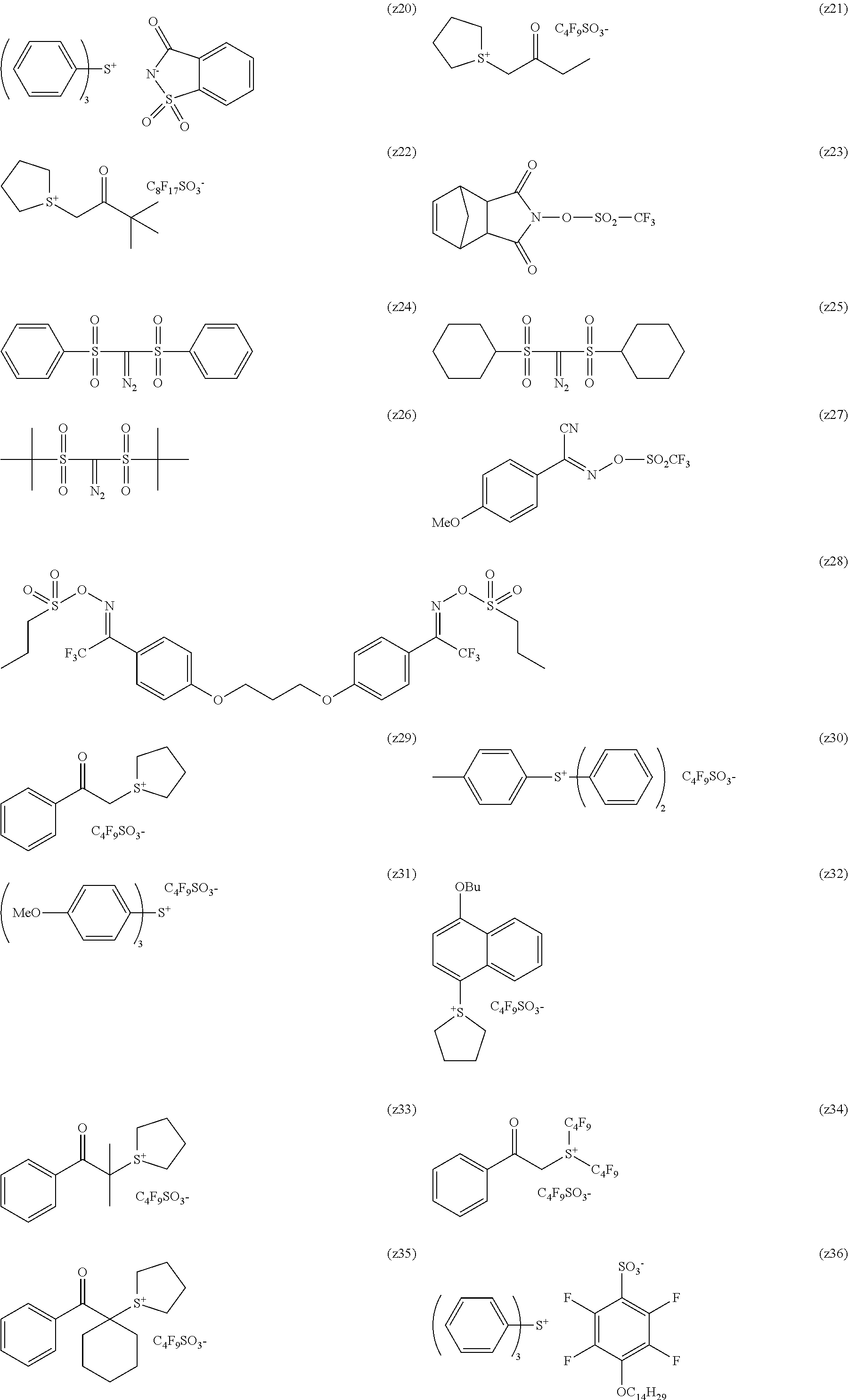

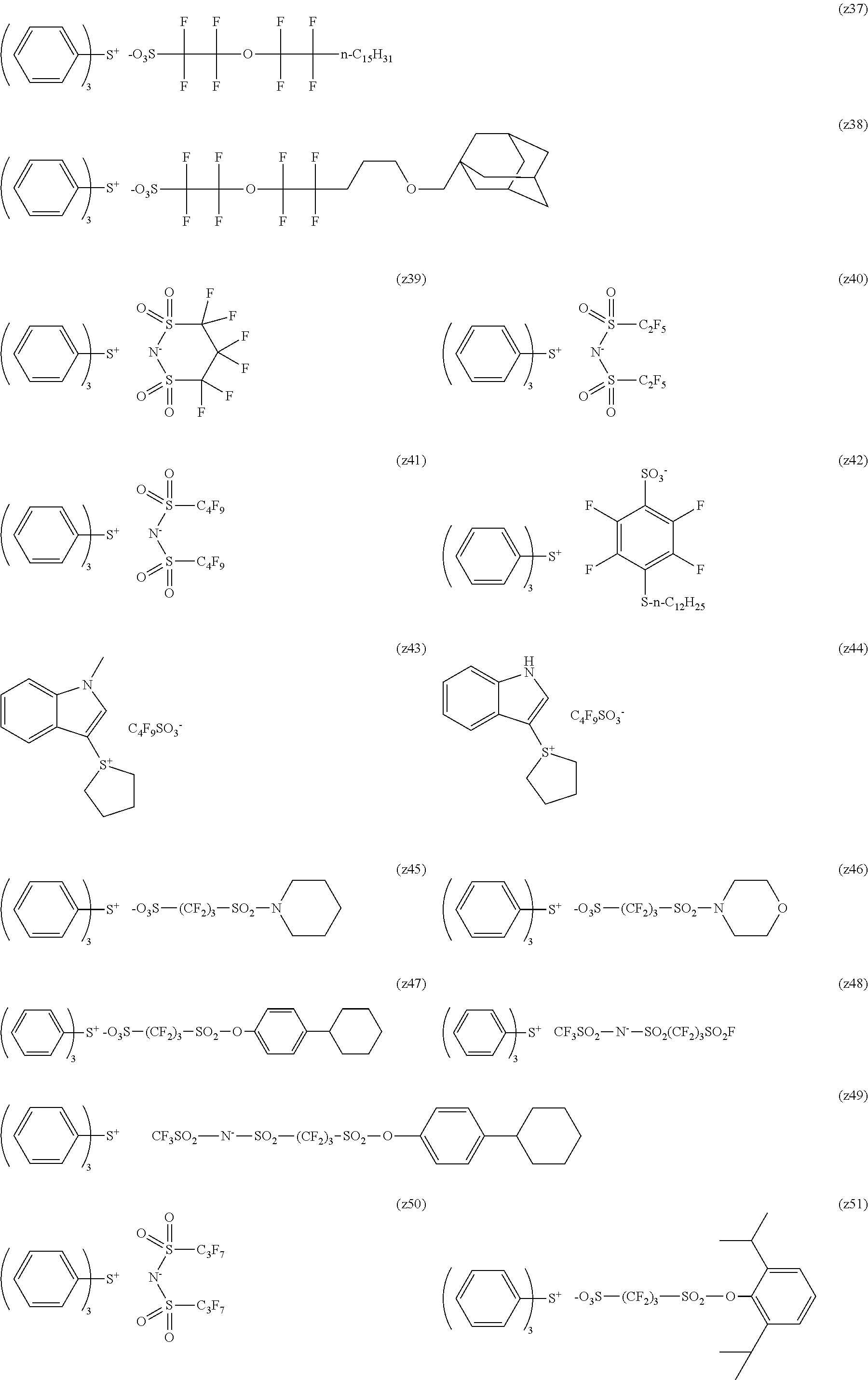

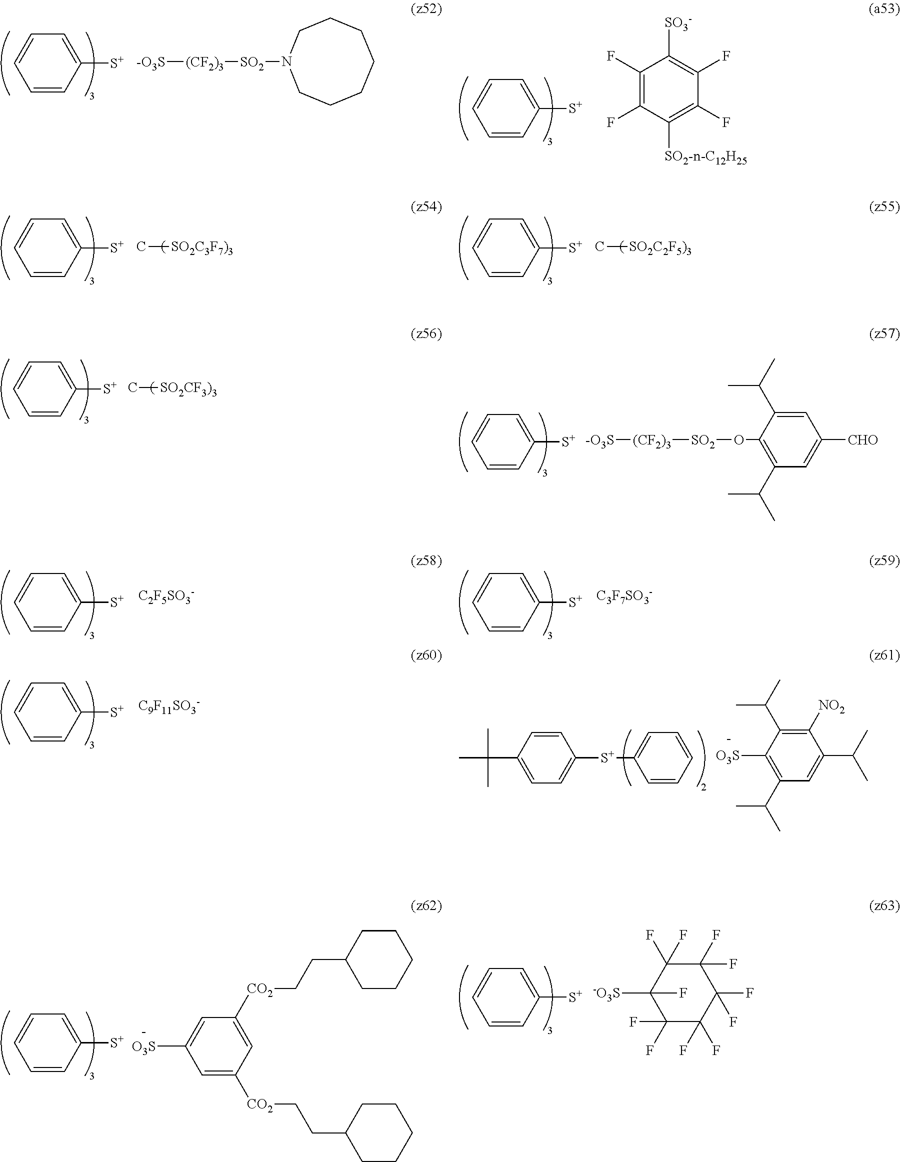

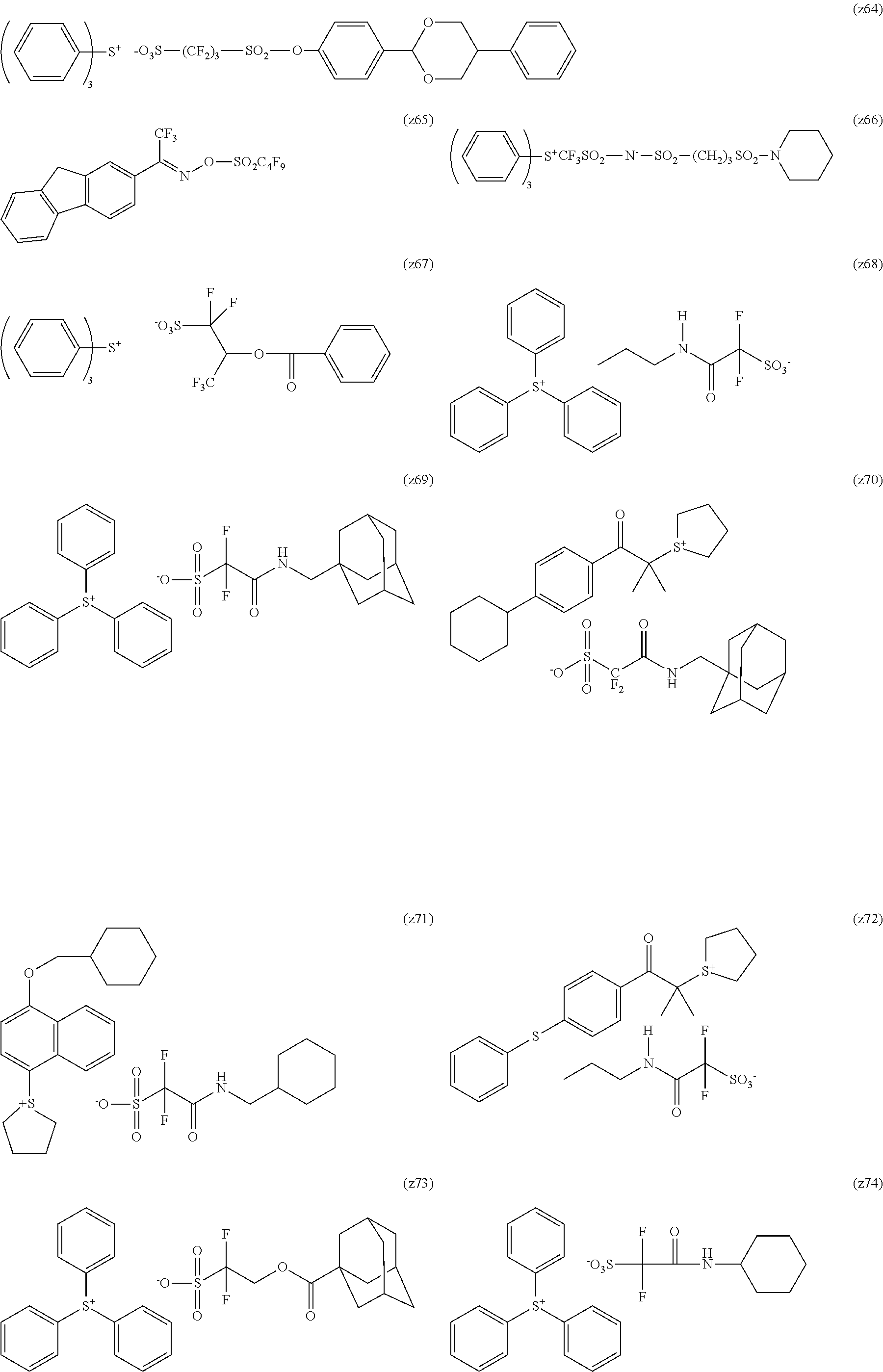

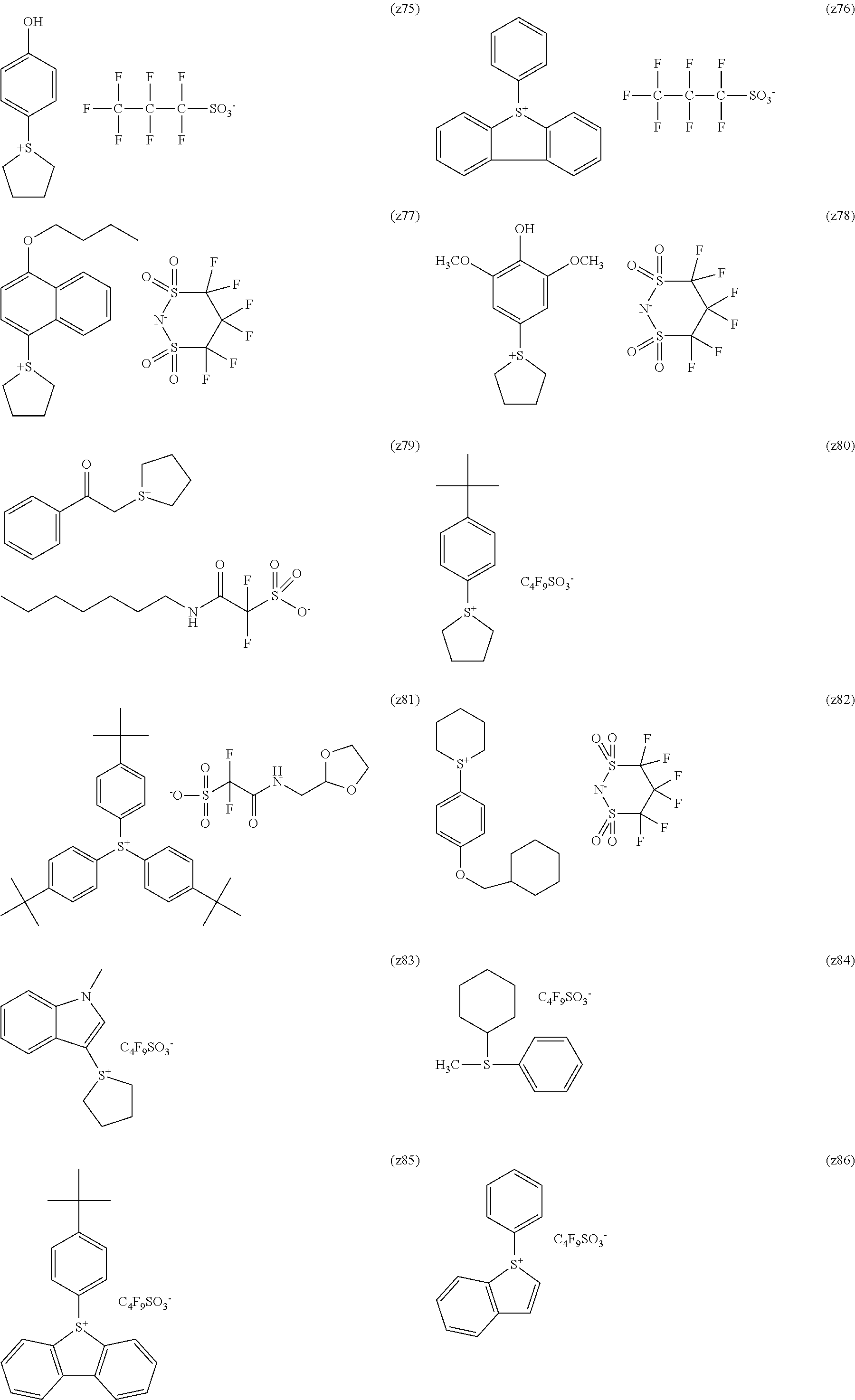

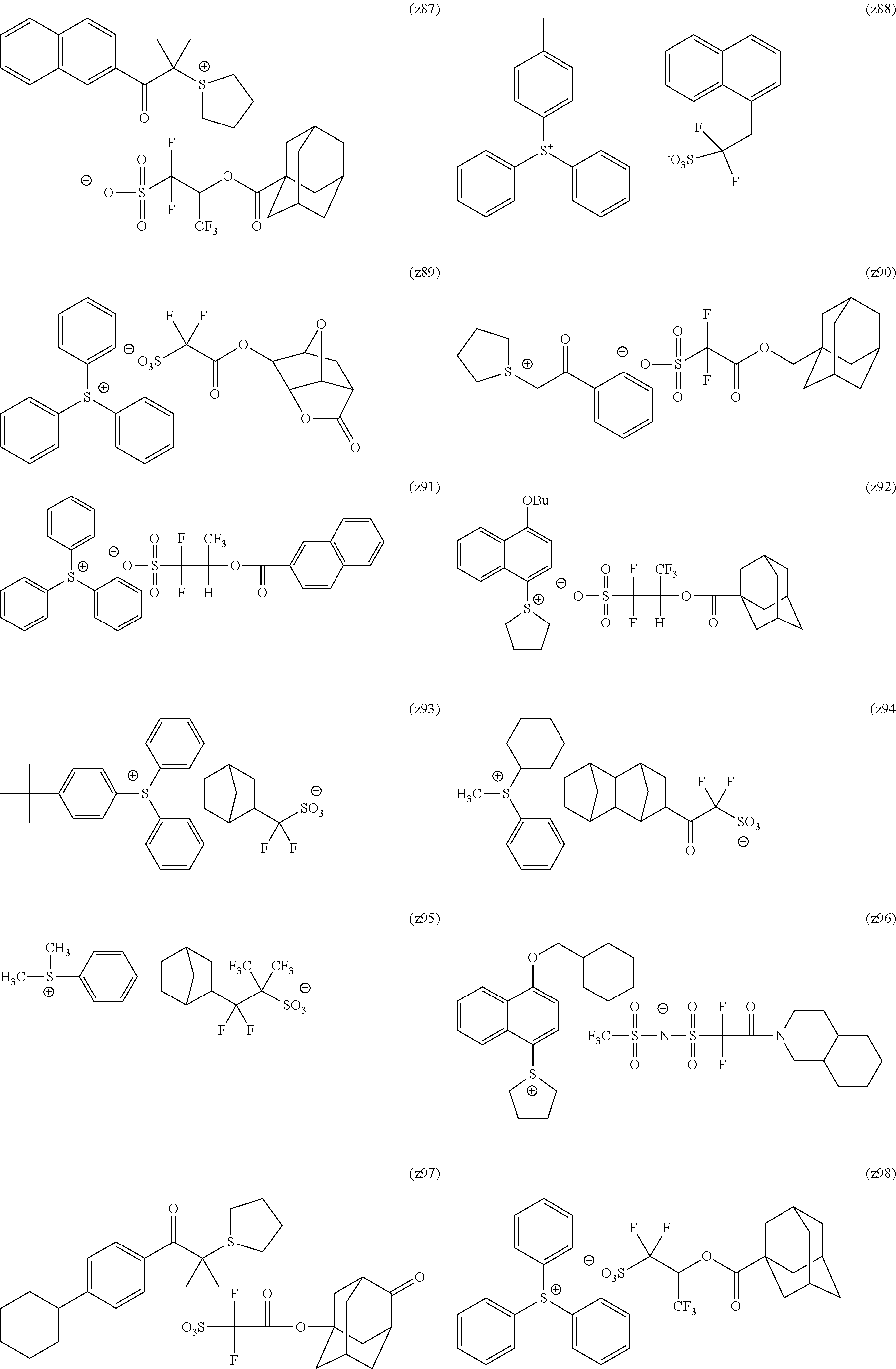

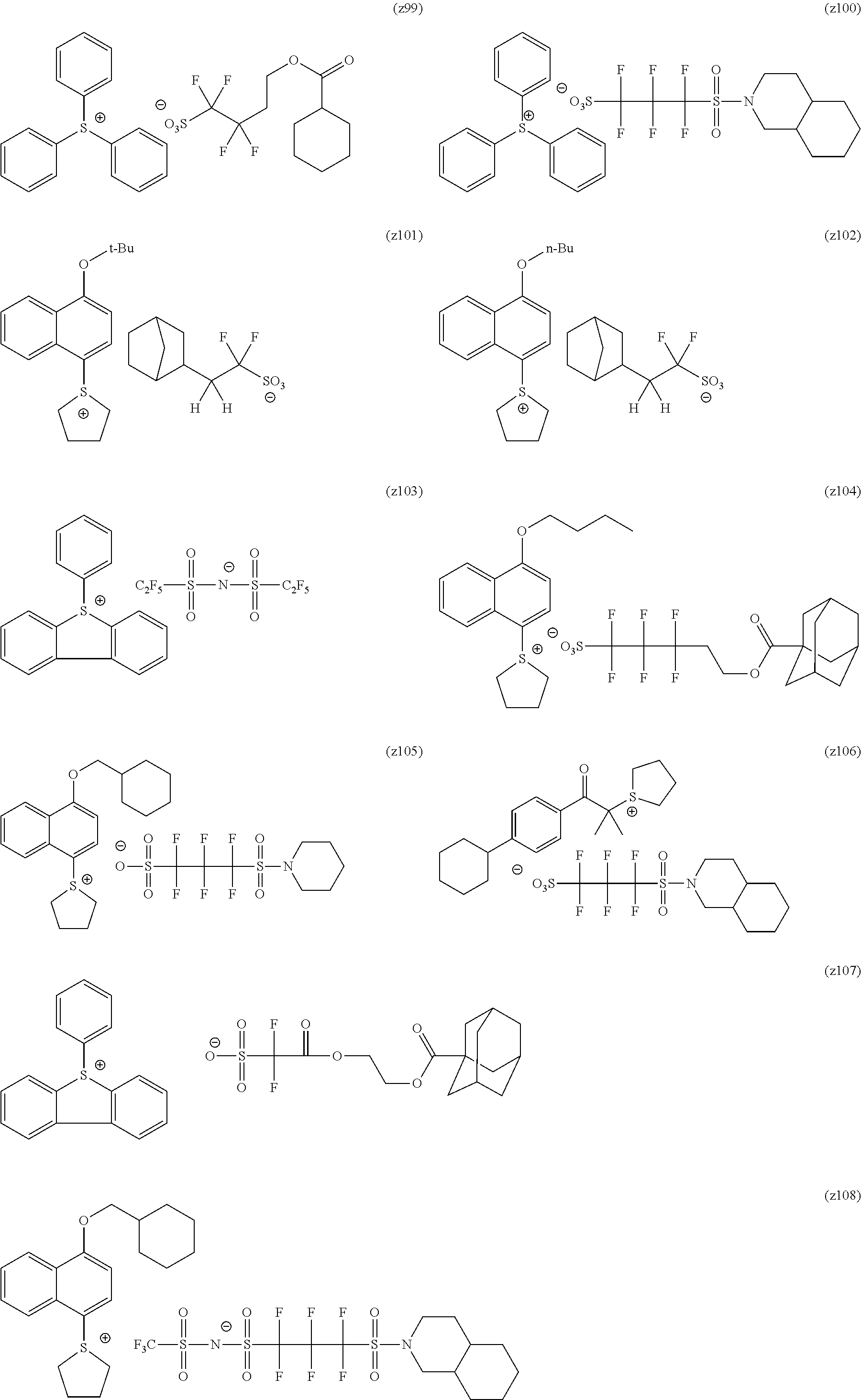

In addition, among the compounds (B), particularly preferred examples of compounds having anions represented by any one of General Formulae (B-1) to (B-3) are described below, but the invention is not limited thereto.

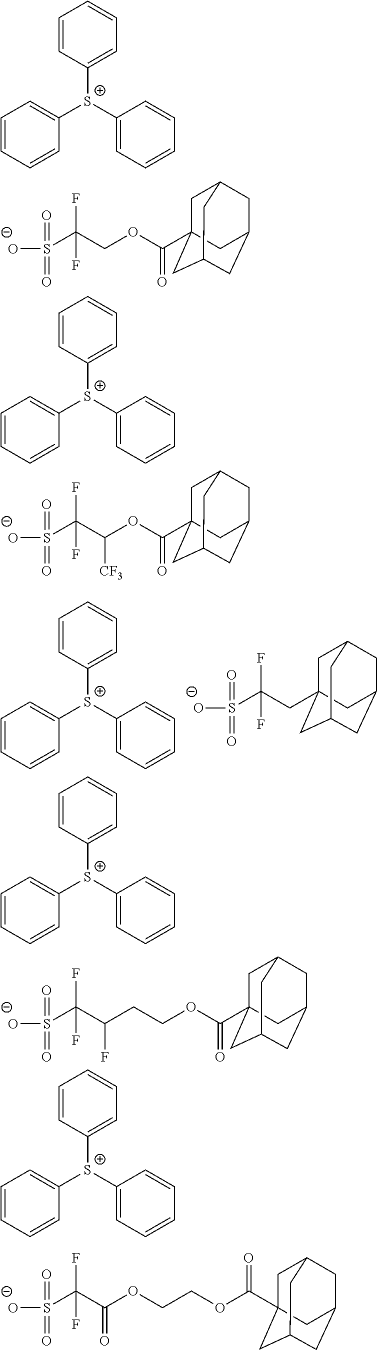

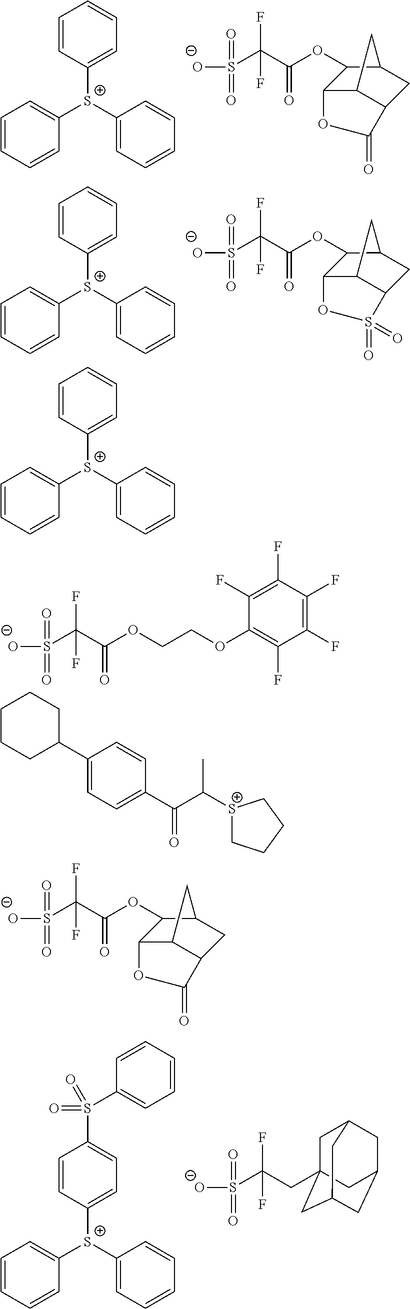

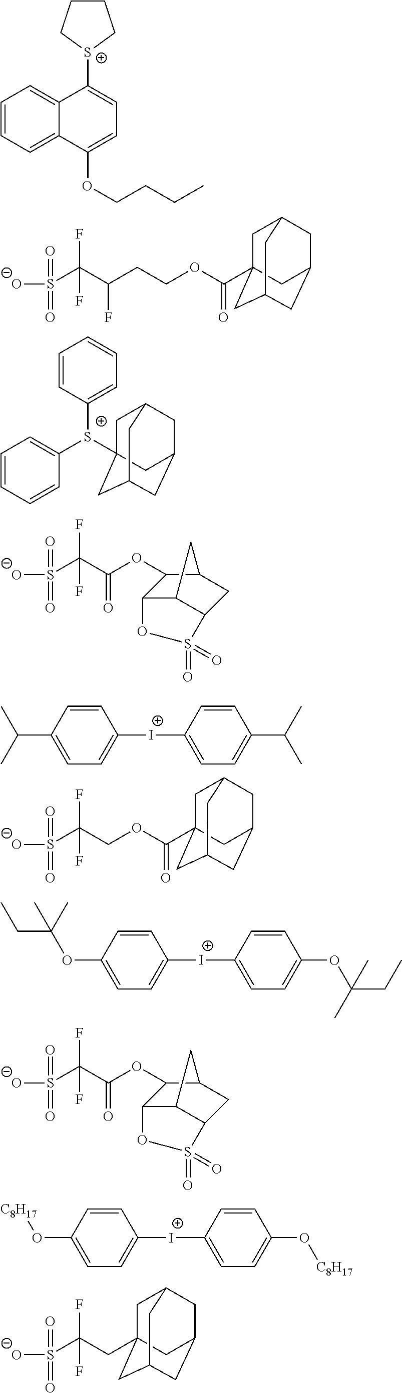

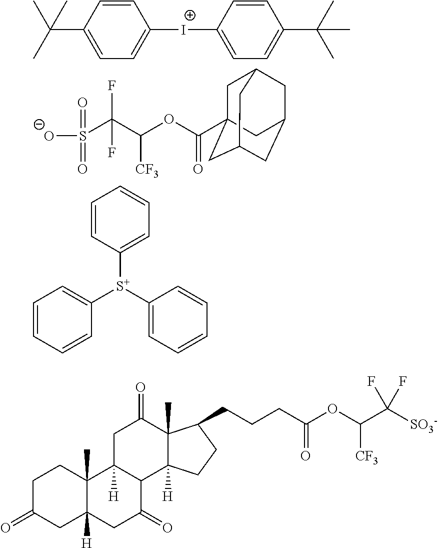

The acid generator can be synthesized by well-known methods, and can be synthesized by methods disclosed in, for example, JP2007-161707A, “0200” to “0210” of JP2010-100595A, “0051” to “0058” of WO2011/093280A, “0382” to “0385” of WO2008/153110A, and JP2007-161707A.

One type of the acid generator can be used singly or two or more types thereof may be used in combination.

The content in the composition of the compound (except for the case represented by General Formula (ZI-3) or (ZI-4)) that generates an acid by being irradiated with actinic rays or radiation is preferably in the range of 0.1% by mass to 30% by mass, more preferably in the range of 0.5% by mass to 25% by mass, still more preferably in the range of 3% by mass to 20% by mass, and particularly more preferably in the range of 3% by mass to 15% by mass with respect to a total solid content of the actinic ray-sensitive or radiation-sensitive resin composition.

In addition, in the case where the acid generator is represented by General Formula (ZI-3) or (ZI-4) above, the content thereof is preferably in the range of 5% by mass to 35% by mass, more preferably in the range of 6% by mass to 30% by mass, and still more preferably in the range of 6% by mass to 25% by mass with respect to the total solid content of the composition.

[3] Solvent (C)

The actinic ray-sensitive or radiation-sensitive resin composition used in the invention may include a solvent (C).

As the solvent (C) that can be used when the actinic ray-sensitive or radiation-sensitive resin composition is prepared, for example, organic solvents such as an alkylene glycol monoalkyl ether carboxylate, an alkylene glycol monoalkyl ether, an alkyl lactate, an alkyl alkoxypropionate, a cyclic lactone (preferably having 4 to 10 carbon atoms), a monoketone compound that may have a ring (preferably having 4 to 10 carbon atoms), an alkylene carbonate, an alkyl alkoxyacetate, and an alkyl pyruvate can be included.

As specific examples of these solvents, products disclosed in Paragraphs “0441” to “0455” of US2008/0187860A can be included.

According to the invention, as the solvent (C), a mixed solvent may be used.

For example, an alkylene glycol monoalkyl ether and an alkyl lactate are preferable, and mixed solvents selected from two or more types of propylene glycol monomethyl ether (PGME, also known as 1-methoxy-2-propanol), ethyl lactate, an alkylene glycol monoalkyl ether acetate, an alkyl alkoxypropionate, a monoketone compound that may have a ring, a cyclic lactone, and an alkyl acetate are preferable. Among them, a mixed solvent of propylene glycol monomethyl ether acetate (PGMEA, also known as 1-methoxy-2-acetoxypropane) (hereinafter, referred to as a “solvent A”) and one or more types of solvent (hereinafter, referred to as a “solvent B”) selected from propylene glycol monomethyl ether, ethyl ethoxypropionate, 2-heptanone, γ-butyrolactone, cyclohexanone, and butyl acetate, is preferable.

The mixing ratio of the mixed solvent (solvent A/solvent B) (mass ratio) is in the range of 1/99 to 99/1, preferably in the range of 10/90 to 90/10, and more preferably in the range of 20/80 to 60/40.

The solvent (C) preferably includes propylene glycol monomethyl ether acetate, and a single solvent of propylene glycol monomethyl ether acetate, or a mixed solvents containing two or more types including propylene glycol monomethyl ether acetate is preferable.

[4] Hydrophobic Resin (D)

When being applied to the liquid immersion exposure, the actinic ray-sensitive or radiation-sensitive resin composition used in the invention may include a hydrophobic resin (hereinafter, referred to as “hydrophobic resin (D)” or simply “resin (D)”). In addition, it is preferable that the hydrophobic resin (D) is different from the resin (A).

Accordingly, the hydrophobic resin (D) is unevenly distributed on the film surface. Therefore, if the immersion medium is water, a static or dynamic contact angle of the surface of the resist film to water increases, and thus immersion liquid conformity can be enhanced. In addition, the so-called outgas suppression effect can be expected for the hydrophobic resin (D). Accordingly, in the case of the EUV exposure, the hydrophobic resin (D) can be suitably used.

It is preferable that the hydrophobic resin (D) is designed to be unevenly distributed on the interface, but differently from a surfactant, the hydrophobic resin (D) does not have to have a hydrophilic group in a molecule necessarily and may not contribute to even mixing of a polar material or a non-polar material.

In order to cause the hydrophobic resin (D) to be unevenly distributed on the film surface, the hydrophobic resin (D) preferably has any one or more types of a “fluorine atom”, a “silicon atom”, and a “CH₃ partial structure contained in a side chain portion of resin” and more preferably has two or more types thereof.

If the hydrophobic resin (D) includes a fluorine atom and/or a silicon atom, the fluorine atom and/or the silicon atom in the hydrophobic resin (D) may be included in a main chain of the resin (D) and may be included in a side chain.

If the hydrophobic resin (D) includes a fluorine atom, as a partial structure having the fluorine atom, a resin having an alkyl group having a fluorine atom, a cycloalkyl group having a fluorine atom, or an aryl group having a fluorine atom is preferable.

The alkyl group having a fluorine atom (preferably, having 1 to 10 carbon atoms and more preferably having 1 to 4 carbon atoms) is a straight chain or branched alkyl group in which at least one hydrogen atom is substituted with a fluorine atom, and may further include a substituent in addition to the fluorine atom.

The cycloalkyl group having a fluorine atom is a monocyclic or polycyclic cycloalkyl group in which at least one hydrogen atom is substituted with a fluorine atom, and may further include a substituent in addition to the fluorine atom.

As the aryl group having the fluorine atom, an aryl group such as a phenyl group and a naphthyl group in which at least one hydrogen atom of the aryl group is substituted with a fluorine atom is included, and a substituent in addition to the fluorine atom may further be included.

As the alkyl group having a fluorine atom, the cycloalkyl group having a fluorine atom, and the aryl group having a fluorine atom, preferably, groups represented by General Formulae (F2) to (F4) described below can be included, but the invention is not limited thereto.

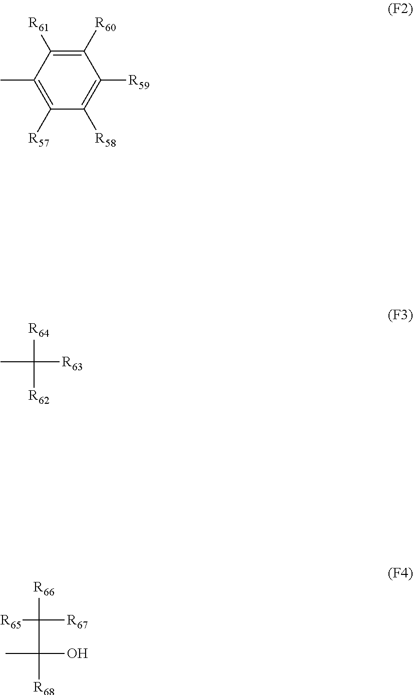

In General Formulae (F2) to (F4),
R₅₇ to R₆₈ each independently represent a hydrogen atom, a fluorine atom, or an alkyl group (having straight chain shape or branched shape). However, at least one of R₅₇ to R₆₁, at least one of R₆₂ to R₆₄, and at least one of R₆₅ to R₆₈ each independently represent a fluorine atom or an alkyl group (preferably having 1 to 4 carbon atoms) in which at least one hydrogen atom is substituted with a fluorine atom.

R₅₇ to R₆₁ and R₆₅ to R₆₇ all are preferably fluorine atoms. R₆₂, R₆₃, and R₆₈ are preferably alkyl groups (preferably having 1 to 4 carbon atoms) in which at least one hydrogen atom is substituted with a fluorine atom, and more preferably perfluoroalkyl groups having 1 to 4 carbon atoms. R₆₂ and R₆₃ may be linked to each other to form a ring.

As specific examples of the group represented by General Formula (F2), for example, a p-fluorophenyl group, a pentafluorophenyl group, and a 3,5-di(trifluoromethyl)phenyl group are included.

As specific examples of the group represented by General Formula (F3), a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group are included. A hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferable, and a hexafluoroisopropyl group and a heptafluoroisopropyl group are more preferable.

As specific examples of the group represented by Formula (F4), for example, —C(CF₃)₂OH, —C(C₂F₅)₂OH, —C(CF₃)(CH₃)OH, and —CH(CF₃)OH are included, and —C(CF₃)₂OH is preferable.

The partial structure including a fluorine atom may be directly bonded to the main chain, and further, may be bonded to the main chain through a group selected from the group consisting of an alkylene group, a phenylene group, an ether bond, a thioether bond, a carbonyl group, an ester bond, an amide bond, a urethane bond, and a ureylene bond, or a combination of two or more types thereof.

Hereinafter, as the specific examples of the repeating unit having a fluorine atom, repeating units disclosed in Paragraphs “0274” to “0276” of JP2012-073402A (Paragraphs “0398” to “0399” of corresponding US 2012/077122A) can be referred to, and the content thereof is incorporated in this specification.

The hydrophobic resin (D) may contain a silicon atom. As the partial structure having a silicon atom, partial structures disclosed in Paragraphs “0277” to “0281” of JP2012-073402A (Paragraphs “0400” to “0405” of corresponding US2012/077122A) can be referred to, and the content thereof is incorporated in this specification.

In addition, as described above, the hydrophobic resin (D) preferably includes a CH₃ partial structure in a side chain portion.

Here, in the CH₃ partial structure (hereinafter, also referred to as simply “side chain CH₃ partial structure”) included in the side chain portion in the hydrophobic resin (D), a CH₃ partial structure having an ethyl group, a propyl group, and the like is included.

Meanwhile, the methyl group (for example, α-methyl group of repeating unit having methacrylic acid structure) which is directly bonded to the main chain of the hydrophobic resin (D) less contributes to uneven distribution on the surface of the hydrophobic resin (D) due to the influence of the main chain, and thus the methyl group is not contained in the CH₃ partial structure according to the invention.

More specifically, if the hydrophobic resin (D) includes, for example, a repeating unit derived from a monomer having a polymerizable region having a carbon-carbon double bond such as a repeating unit represented by General Formula (M) and R₁₁ to R₁₄ are CH₃ “as it is”, the CH₃ is not included in the CH₃ partial structure included by the side chain portion according to the invention.

Meanwhile, the CH₃ partial structure existing away from the C—C main chain with any number of atoms therebetween corresponds to the CH₃ partial structure according to the invention. For example, if R₁₁ is an ethyl group (CH₂CH₃), one CH₃ partial structure according to the invention is included.

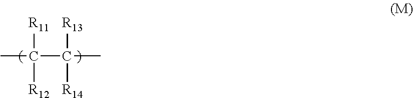

In General Formula (M),
R₁₁ to R₁₄ each independently represent a side chain portion.

As R₁₁ to R₁₄ of the side chain portion, a hydrogen atom, a monovalent organic group, and the like are included.

As the monovalent organic group with respect to R₁₁ to R₁₄, an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group, and the like are included, and these groups may further have substituents.

The hydrophobic resin (D) is preferably a resin having a repeating unit having the CH₃ partial structure in the side chain portion. Such a repeating unit preferably includes at least one type of repeating unit (x) of the repeating unit represented by General Formula (II) and the repeating unit represented by General Formula (III) described below.

Hereinafter, the repeating unit represented by General Formula (II) is described in detail.

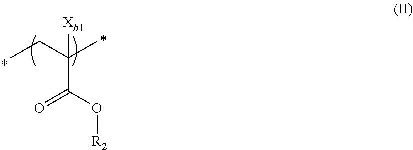

In General Formula (II) above, X_{b1} represents a hydrogen atom, an alkyl group, a cyano group, or a halogen atom, and R₂ represents an organic group that is stable with respect to an acid and that has one or more CH₃ partial structures. Here, more specifically, the organic group that is stable with respect to an acid is preferably an organic group that does not have a “group that is decomposed due to an action of an acid and generates a polar group” described in the resin (A) above.

The alkyl group as X_{b1} is preferably a group having 1 to 4 carbon atoms, and a methyl group, an ethyl group, a propyl group, a hydroxymethyl group, a trifluoromethyl group, and the like are included, but a methyl group is preferable.

X_{b1} is preferably a hydrogen atom or a methyl group.

As R₂, an alkyl group, a cycloalkyl group, an alkenyl group, a cycloalkenyl group, an aryl group, and an aralkyl group which have 1 or more CH₃ partial structures are included. The cycloalkyl group, the alkenyl group, the cycloalkenyl group, the aryl group, and the aralkyl group may further have alkyl groups as substituents.

R₂ is preferably an alkyl group or an alkyl-substituted cycloalkyl group that has 1 or more CH₃ partial structures.

The organic group that is stable with respect to an acid and that has 1 or more CH₃ partial structures as R₂ preferably has 2 to 10 CH₃ partial structures, and more preferably has 2 to 8 CH₃ partial structures.

With respect to R₂, as the alkyl group that has 1 or more CH₃ partial structures, a branched alkyl group having 3 to 20 carbon atoms is preferable.

With respect to R₂, the cycloalkyl group that has 1 or more CH₃ partial structures may be a monocyclic type or a polycyclic type. Specifically, groups having monocyclo, bicyclo, tricyclo, and tetracyclo structures that have 5 or more carbon atoms can be included. The number of carbon atoms is preferably 6 to 30, and particularly preferably 7 to 25.

With respect to R₂, as the alkenyl group having 1 or more CH₃ partial structures, a straight chain or branched alkenyl group having 1 to 20 carbon atoms is preferable, and a branched alkenyl group is more preferable.

With respect to R₂, as the aryl group having 1 or more CH₃ partial structures, an aryl group having 6 to 20 carbon atoms is preferable, and for example, a phenyl group and a naphthyl group are included, and a phenyl group is preferable.

With respect to R₂, as the aralkyl group having 1 or more CH₃ partial structures, an aralkyl group having 7 to 12 carbon atoms is preferable, and for example, a benzyl group, a phenethyl group, and a naphthylmethyl group can be included.

Preferable specific examples of the repeating unit represented by General Formula (II) are described below. However, the invention is not limited thereto.

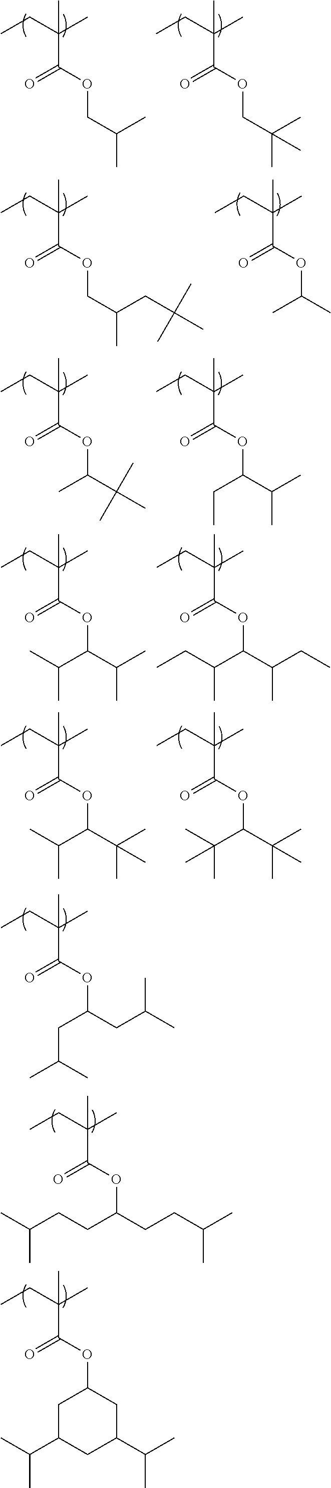

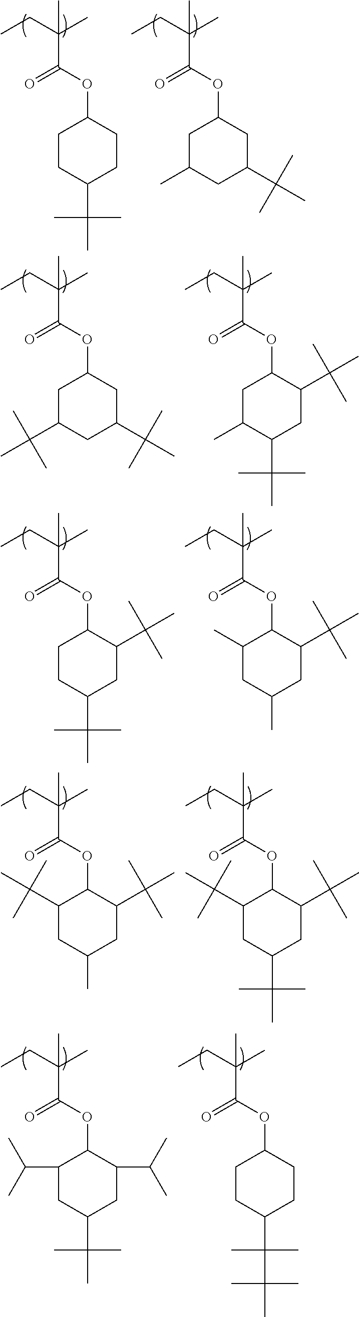

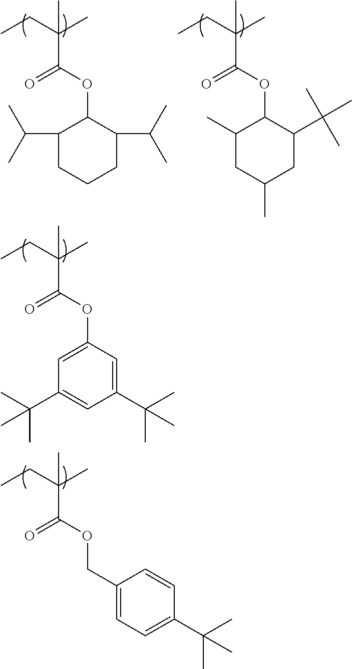

The repeating unit represented by General Formula (II) is preferably a repeating unit which is stable with respect to an acid (non-acid-decomposablility), and specifically, a repeating unit that does not have a group that is decomposed due to the action of an acid and generates a polar group is preferable.

Hereinafter, the repeating unit represented by General Formula (III) is described in detail

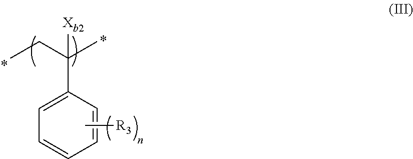

In General Formula (III) above, X_{b2} represents a hydrogen atom, an alkyl group, a cyano group, or a halogen atom, R₃ represents an organic group that is stable with respect to an acid and that has 1 or more CH₃ partial structures, and n represents an integer of 1 to 5.

The alkyl group as X_{b2} is preferably an alkyl group having 1 to 4 carbon atoms, a methyl group, an ethyl group, a propyl group, a hydroxymethyl group, a trifluoromethyl group, or the like is included, but a hydrogen atom is preferable.

X_{b2} is preferably a hydrogen atom.

R₃ is an organic group that is stable with respect to an acid, and thus, specifically, R₃ is preferably an organic group that does not have a “group that is decomposed due to the action of an acid and generates a polar group” described in the resin (A).

As R₃, an alkyl group having 1 or more CH₃ partial structures is included.

The organic group that is stable with respect to an acid and that has 1 or more CH₃ partial structures as R₃ preferably includes 1 to 10 CH₃ partial structures, more preferably 1 to 8 CH₃ partial structures, and still more preferably 1 to 4 CH₃ partial structures.

With respect to R₃, as the alkyl group having 1 or more CH₃ partial structures, a branched alkyl group having 3 to 20 carbon atoms is preferable.

n represents an integer of 1 to 5, preferably represents an integer of 1 to 3, and more preferably represents 1 or 2.

Preferable specific examples of the repeating unit represented by General Formula (III) are described below. However, the invention is not limited thereto.

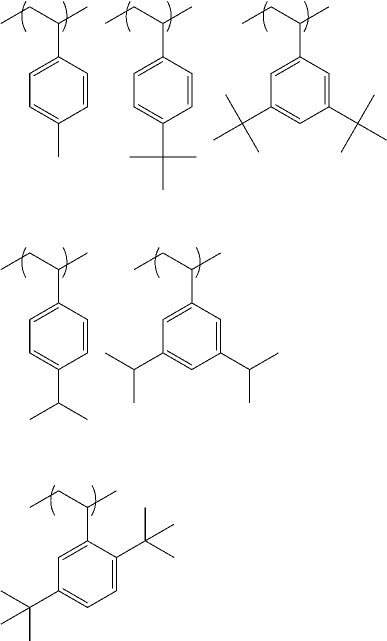

The repeating unit represented by General Formula (III) is preferably a repeating unit that is stable with respect to an acid (non-acid-decomposablility), and specifically, a repeating unit that does not have a group that is decomposed due to the action of an acid and generates a polar group is preferable.

In a case where the hydrophobic resin (D) includes the CH₃ partial structure in the side chain portion and further in a case where the hydrophobic resin (D) particularly does not include a fluorine atom and a silicon atom, the content of at least one type of the repeating unit (x) of the repeating unit represented by General Formula (II) and the repeating unit represented by General Formula (III) is preferably 90% by mol or greater and more preferably 95% by mol or greater with respect to the entire repeating units of the hydrophobic resin (D). The content is generally 100% by mol or less with respect to the entire repeating units of the hydrophobic resin (D).

If the hydrophobic resin (D) contains 90% by mol or greater of at least one type of repeating unit (x) of the repeating unit represented by General Formula (II) and the repeating unit represented by General Formula (III) with respect to the entire repeating units of the hydrophobic resin (D), the surface free energy of the hydrophobic resin (D) increases. As a result, it is difficult for the uneven distribution of the hydrophobic resin (D) on the surface of the resist film to occur, the static/dynamic contact angle of the resist film with respect to water is reliably increased, and thus immersion liquid conformity is increased.

In addition, the hydrophobic resin (D) may have at least one group selected from the group consisting of (x) to (z) described below, in a case (i) where the fluorine atom and/or the silicon atom is included, or in a case (ii) where the CH₃ partial structure is included in the side chain portion:
(x) an acid group,
(y) a group having a lactone structure, an acid anhydride group, or an acid imide group, and
(z) a group that is decomposed due to an action of an acid.

As the acid group (x), a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, and the like are included.

As a preferable acid group, a fluorinated alcohol group (preferably hexafluoroisopropanol), a sulfonimide group, and a bis(alkylcarbonyl)methylene group, and the like are included.

As a repeating unit having the acid group (x), a repeating unit in which the acid group is directly bonded to the main chain of the resin such as the repeating unit by an acrylic acid or a methacrylic acid, or a repeating unit in which an acid group is bonded to the main chain of the resin through a linking group, and the like are included, and further a polymerization initiator having an acid group or a chain transfer agent can be introduced to the terminal of the polymer chain used at the time of polymerization. Any of these cases are preferable. The repeating unit having the acid group (x) may have at least one of the fluorine atom and the silicon atom.

The content of the repeating unit having the acid group (x) is preferably in the range of 1% by mol to 50% by mol, more preferably in the range of 3% by mol to 35% by mol, and still more preferably in the range of 5% by mol to 20% by mol with respect to the entire repeating units in the hydrophobic resin (D).

As specific examples of the repeating unit having the acid group (x), repeating units disclosed in Paragraphs “0285” to “0287” of JP2012-073402A (Paragraph “0414” of corresponding US2012/077122A) may be referred to, and the content thereof is incorporated to this specification.

As a group having a lactone structure, an acid anhydride group, or an acid imide group (y), a group having a lactone structure is particularly preferable.

A repeating unit including these groups is, for example, a repeating unit in which these groups are directly bonded to a main chain of a resin, such as a repeating unit including an acrylic acid ester and a methacrylic acid ester. Otherwise, the repeating unit may be a repeating unit in which these groups are bonded to a main chain of a resin through a linking group. Otherwise, the repeating unit may use a polymerization initiator or a chain transfer agent at the time of polymerization, and may be introduced to a terminal of a resin.

As the repeating units having the group having the lactone structure, for example, repeating units which are the same as the repeating units having the lactone structures described in the section of the resin (A) above may be included.

The content of the repeating unit having the group having the lactone structure, the acid anhydride group, or the acid imide group is preferably in the range of 1% by mol to 100% by mol, more preferably in the range of 3% by mol to 98% by mol, and still more preferably in the range of 5% by mol to 95% by mol with respect to the entire repeating units in the hydrophobic resin (D).

With respect to the hydrophobic resin (D), the repeating unit having a group (z) that is decomposed due to an action of an acid may include repeating units which are the same as the repeating units having the acid-decomposable groups described in the resin (A). The repeating units having the groups (z) that are decomposed due to an action of an acid may have any one of a fluorine atom and a silicon atom. With respect to the hydrophobic resin (D), the content of the repeating unit having the group (z) that is decomposed due to an action of an acid is preferably in the range of 1% by mol to 80% by mol, more preferably in the range of 10% by mol to 80% by mol, and still more preferably in the range of 20% by mol to 60% by mol with respect to the entire repeating units in the resin (D).

The hydrophobic resin (D) may further have a repeating unit represented by General Formula (III) below.

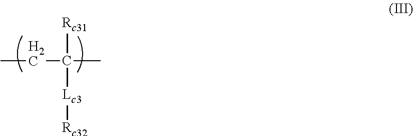

In General Formula (III),
R_{c31} represents a hydrogen atom, an alkyl group (that may be substituted with a fluorine atom or the like), a cyano group, or a —CH₂—O—Rac₂ group. In the formula, Rac₂ represents a hydrogen atom, an alkyl group, or an acyl group. R_{c31} is preferably a hydrogen atom, a methyl group, a hydroxymethyl group, or a trifluoromethyl group, and particularly preferably a hydrogen atom or a methyl group.

R_{c32} represents an alkyl group, a cycloalkyl group, an alkenyl group, a cycloalkenyl group, or a group having an aryl group. These groups may be substituted with a group including a fluorine atom or a silicon atom.

L_{c3} represents a single bond or a divalent linking group.

With respect to General Formula (III), the alkyl group as R_{c32} is preferably a straight chain or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, a phenyl group and a naphthyl group are more preferable, and these may have substituents.

R_{c32} is preferably an unsubstituted alkyl group or an alkyl group substituted with a fluorine atom.

The divalent linking group as L_{c3} is preferably an alkylene group (preferably having 1 to 5 carbon atoms), an ether bond, a phenylene group, or an ester bond (group represented by —COO—).

The content of the repeating unit represented by General Formula (III) is preferably in the range of 1% by mol to 100% by mol, more preferably in the range of 10% by mol to 90% by mol, and still more preferably in the range of 30% by mol to 70% by mol with respect to the entire repeating units in the hydrophobic resin.

It is preferable that the hydrophobic resin (D) further has a repeating unit represented by General Formula (CII-AB) below.

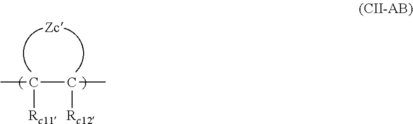

In Formula (CII-AB),
R_{c11}′ and R_{c12}′ each independently represent a hydrogen atom, a cyano group, a halogen atom, or an alkyl group.

Zc′ represents an atomic group that includes 2 carbon atoms (C—C) bonded to each other and that is for forming an alicyclic structure.

The content of the repeating unit represented by General Formula (CII-AB) is in the range of 1% by mol to 100% by mol, more preferably in the range of 10% by mol to 90% by mol, and still more preferably in the range of 30% by mol to 70% by mol with respect to the entire repeating units in the hydrophobic resin.

Hereinafter, specific examples of the repeating unit represented by General Formulae (III) and (CII-AB) are described below, but the invention is not limited thereto. In the formulae, Ra represents H, CH₃, CH₂OH, CF₃, or CN.

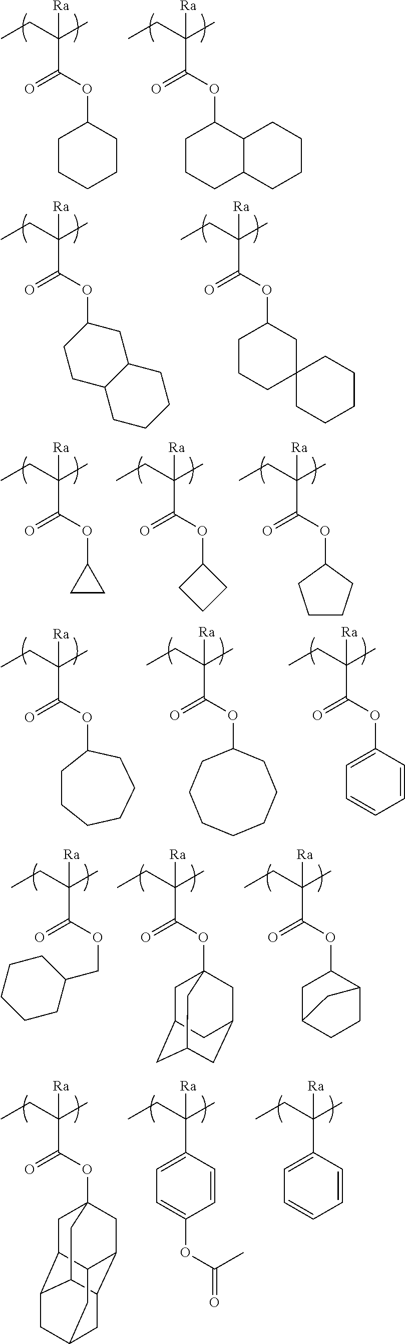

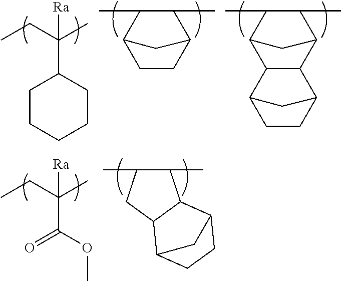

If the hydrophobic resin (D) has a fluorine atom, the content of fluorine atoms is preferably in the range of 5% by mol to 80% by mass and more preferably in the range of 10% by mol to 80% by mass with respect to the weight average molecular weight of the hydrophobic resin (D). In addition, the content of the repeating unit including fluorine atoms is preferably in the range of 10% by mol to 100% by mol and more preferably in the range of 30% by mol to 100% by mol with respect to the entire repeating units included in the hydrophobic resin (D).

If the hydrophobic resin (D) has a silicon atom, the content of silicon atoms is preferably in the range of 2% by mass to 50% by mass and more preferably in the range of 2% by mass to 30% by mass with respect to the weight average molecular weight of the hydrophobic resin (D). In addition, the content of the repeating unit including silicon atoms is preferably in the range of 10% by mol to 100% by mol and more preferably in the range of 20% by mol to 100% by mol with respect to the entire repeating units included in the hydrophobic resin (D).

Meanwhile, if the hydrophobic resin (D) includes the CH₃ partial structure in the side chain portion, the hydrophobic resin (D) preferably has a form in which a fluorine atom and a silicon atom are not substantially contained, and specifically, the content of the repeating unit having the fluorine atom and the silicon atom is preferably 5% by mol or less, more preferably 3% by mol or less, and still more preferably 1% by mol or less, and ideally 0% by mol, that is, does not contain a fluorine atom and a silicon atom, with respect to the entire repeating units in the hydrophobic resin (D). In addition, the hydrophobic resin (D) is formed of only a repeating unit that is formed of only atoms selected from a carbon atom, an oxygen atom, a hydrogen atom, a nitrogen atom, and a sulfur atom. More specifically, the content of the repeating unit that includes only the atoms selected from a carbon atom, an oxygen atom, a hydrogen atom, a nitrogen atom, and a sulfur atom is preferably 95% by mol or greater, more preferably 97% by mol or greater, and still more preferably 99% by mol or greater, and ideally 100% by mol with respect to the entire repeating units of the hydrophobic resin (D).

The weight average molecular weight of the hydrophobic resin (D) in terms of polystyrene standards is preferably in the range of 1,000 to 100,000, more preferably in the range of 1,000 to 50,000, and still more preferably in the range of 2,000 to 15,000.

In addition, one type of the hydrophobic resin (D) may be used, and plural types thereof may be used in combination.

The content of the hydrophobic resin (D) in the composition is preferably in the range of 0.01% by mass to 10% by mass, more preferably in the range of 0.05% by mass to 8% by mass, and still more preferably in the range of 0.1% by mass to 7% by mass with respect to the total solid content of the actinic ray-sensitive or radiation-sensitive resin composition.

It is natural that the hydrophobic resin (D) has some impurities such as metals in the same manner as the resin (A), and a residual monomer or an oligomer component is preferably in the range of 0.01% by mass to 5% by mass, more preferably in the range of 0.01% by mass to 3% by mass, and still more preferably in the range of 0.05% by mass to 1% by mass. Accordingly, it is possible to obtain an actinic ray-sensitive or radiation-sensitive resin composition that does not have foreign substances in the liquid and does not exhibit variation in sensitivity over time. In addition, in view of the resolution, the resist form, the sidewall of the resist pattern, and the roughness, the molecular weight distribution (Mw/Mn, also referred to as the dispersity) is preferably in the range of 1 to 5, more preferably in the range of 1 to 3, and still more preferably in the range of 1 to 2.

As the hydrophobic resin (D), various commercially available products can be used, or the hydrophobic resin (D) may be synthesized by well-known methods (for example, radical polymerization). For example, as the general synthesization method, a collective polymerization method in which polymerization is performed by dissolving monomer species or initiators in a solvent and performing baking, and a dripping polymerization method in which a solution of the monomer species and an initiator are added to a baking solvent by being dripped over 1 hour to 10 hours are included, and the dripping polymerization method is preferable.

The reaction solvent, the polymerization initiator, reaction conditions (temperature, concentration, and the like), and a refinement method after reaction are the same as those described for the resin (A), but in the synthesization of the hydrophobic resin (D), the concentration in the reaction is preferably in the range of 30% by mass to 50% by mass.

Hereinafter, specific examples of the hydrophobic resin (D) are described. In addition, the molar ratios (corresponding to respective repeating units in the sequence from the left), the weight average molecular weights, and the dispersity of the repeating units in the respective resins are presented in the table below.

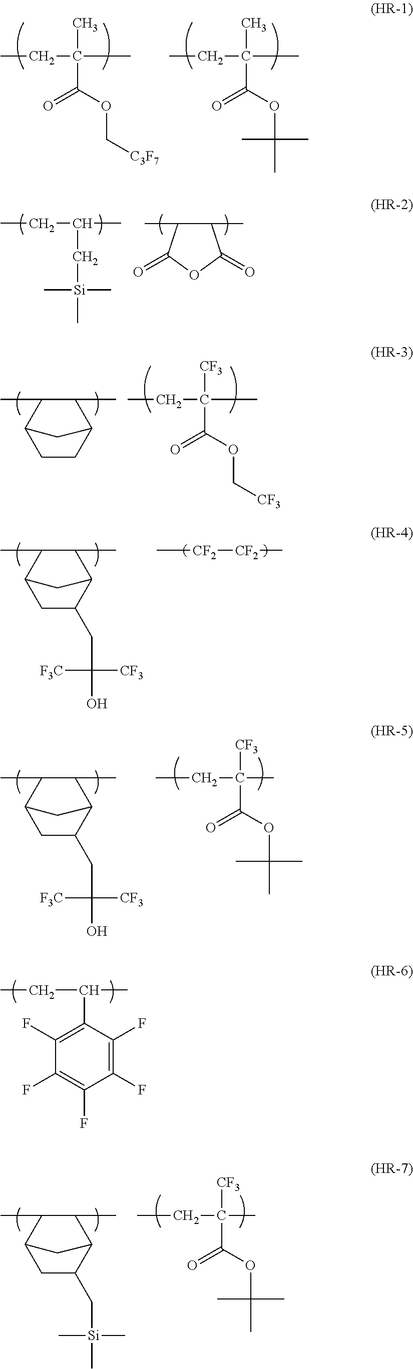

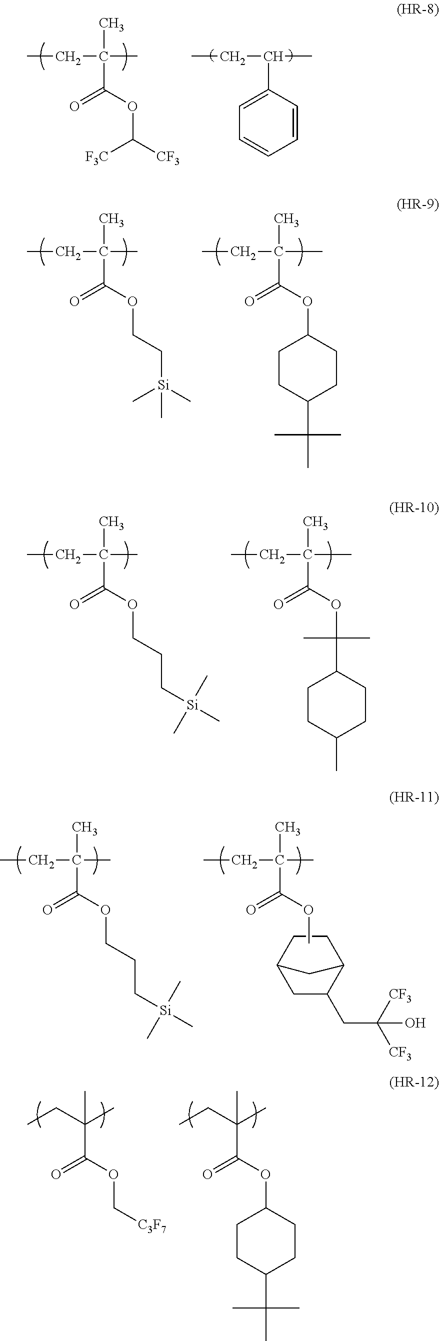

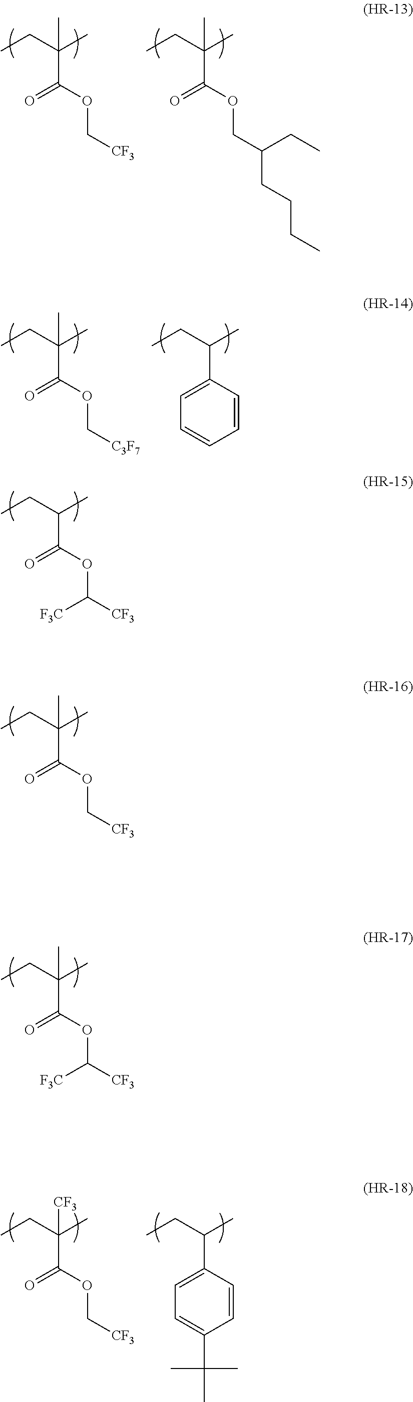

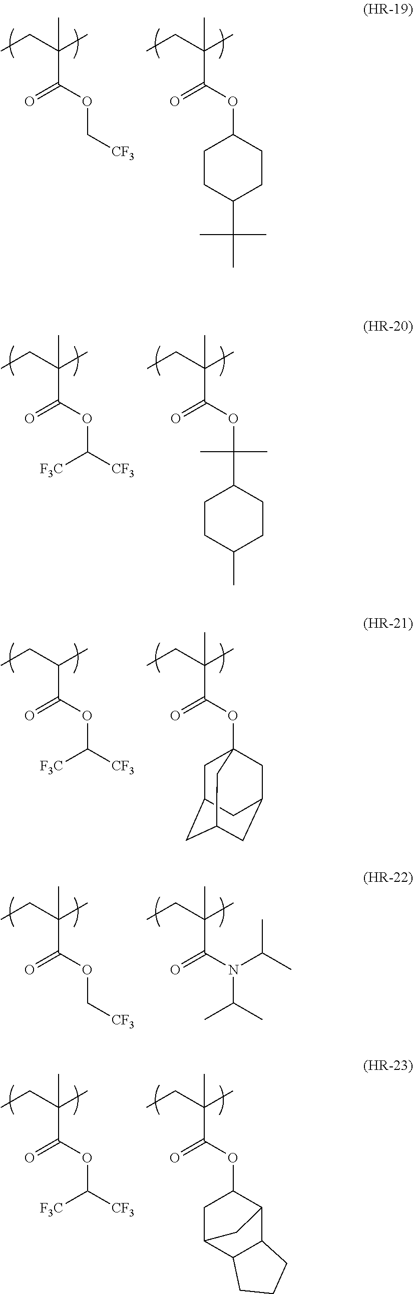

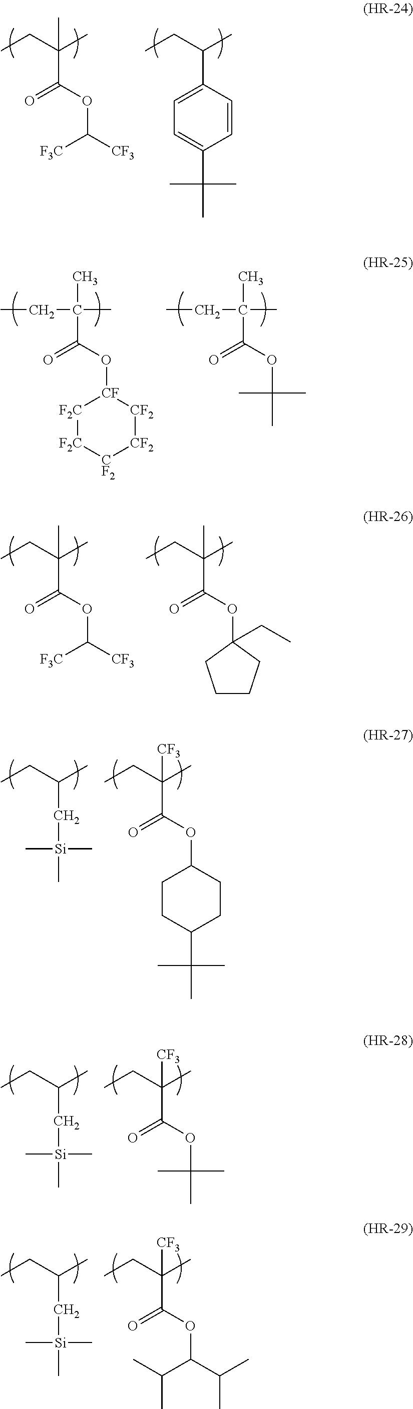

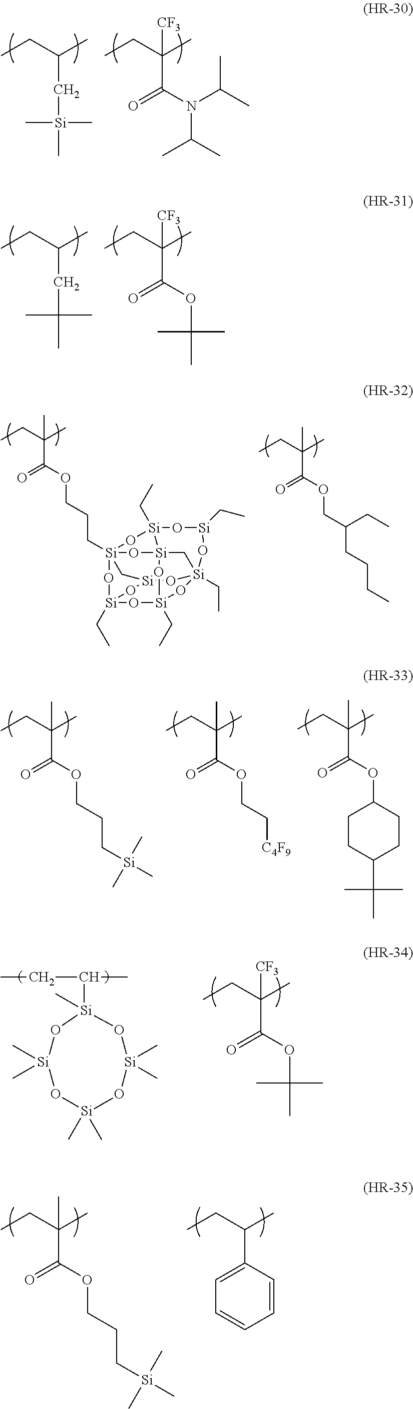

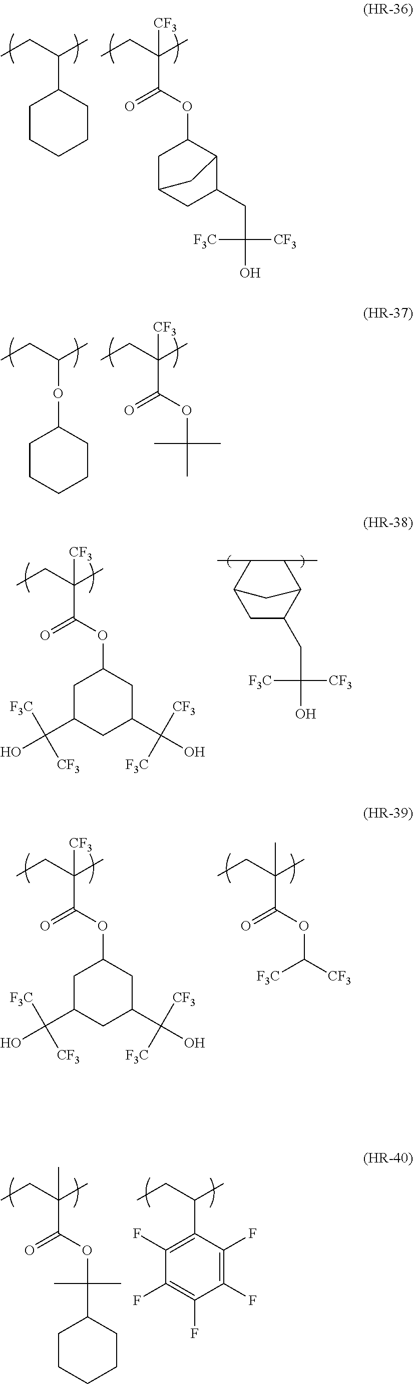

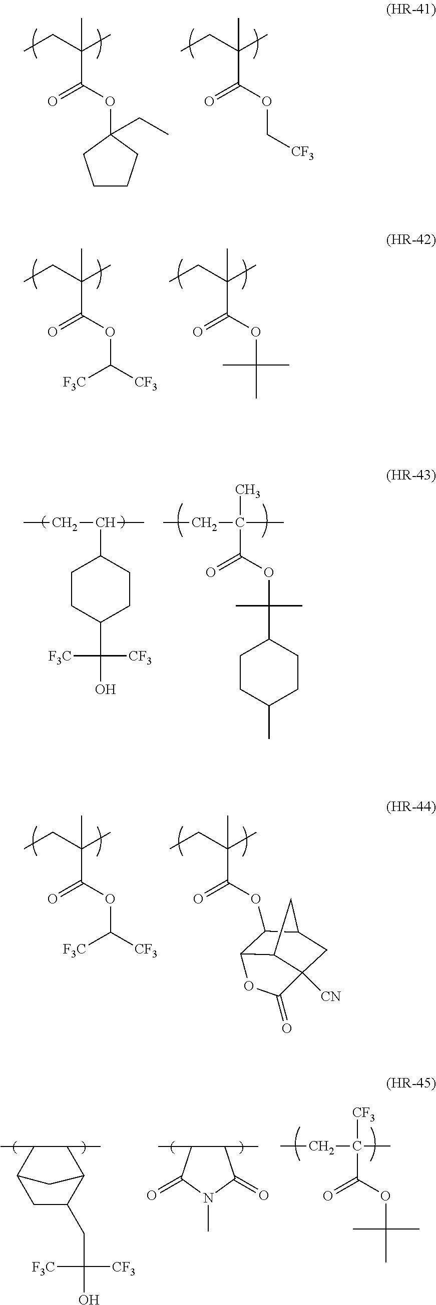

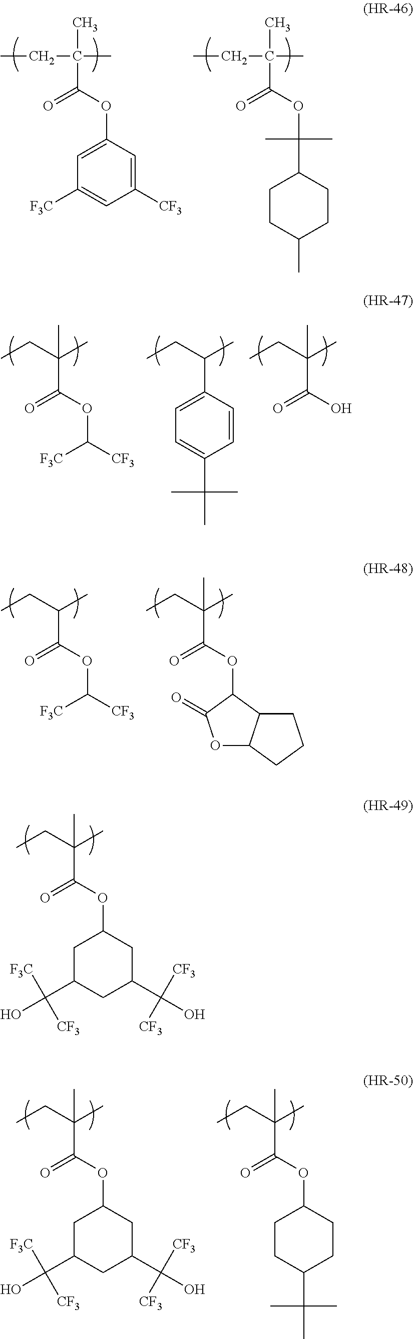

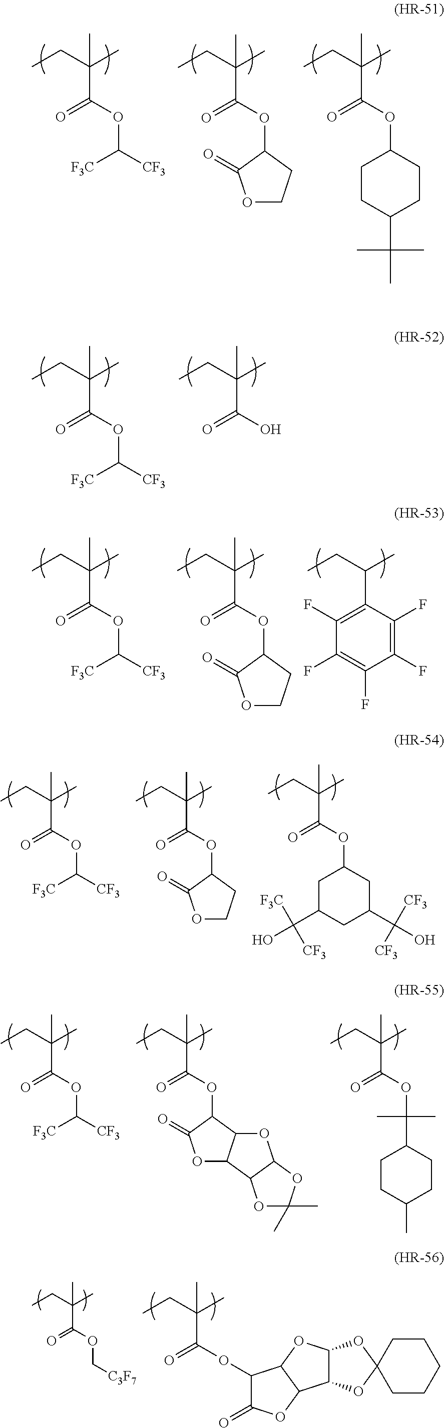

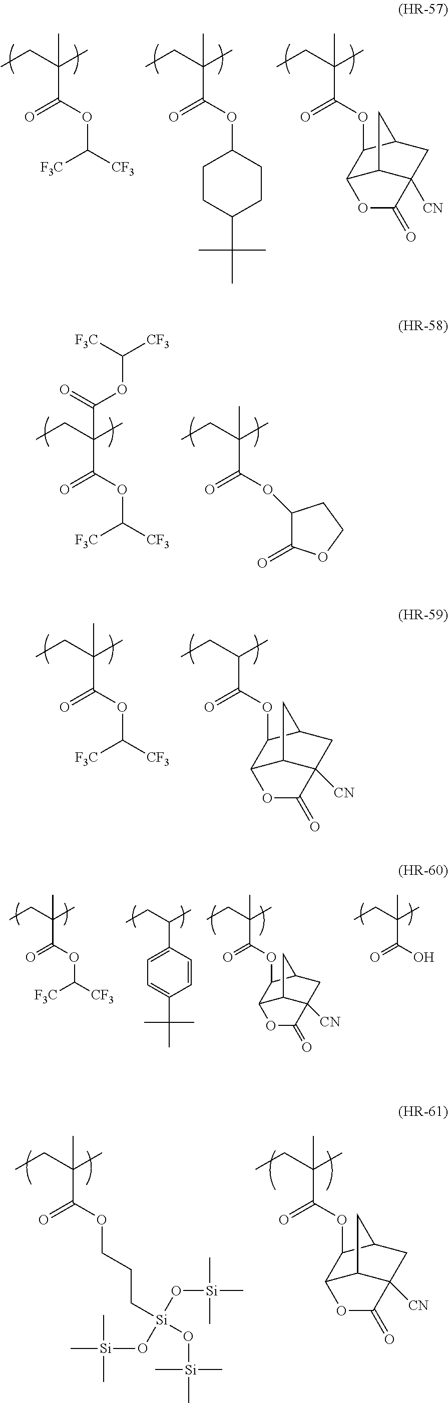

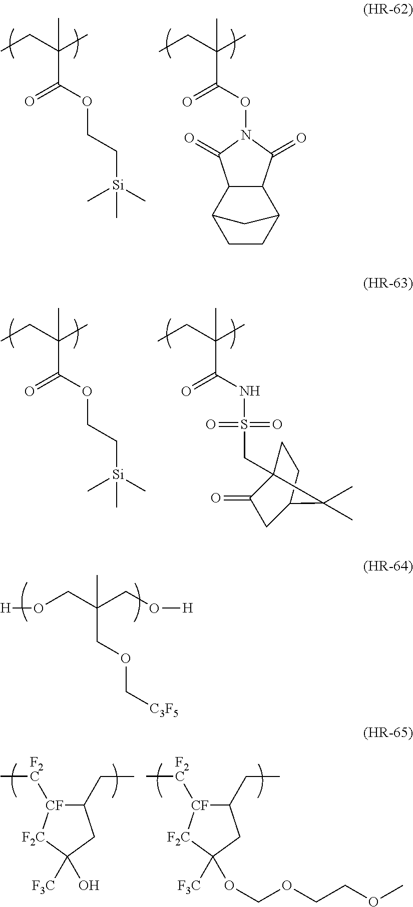

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

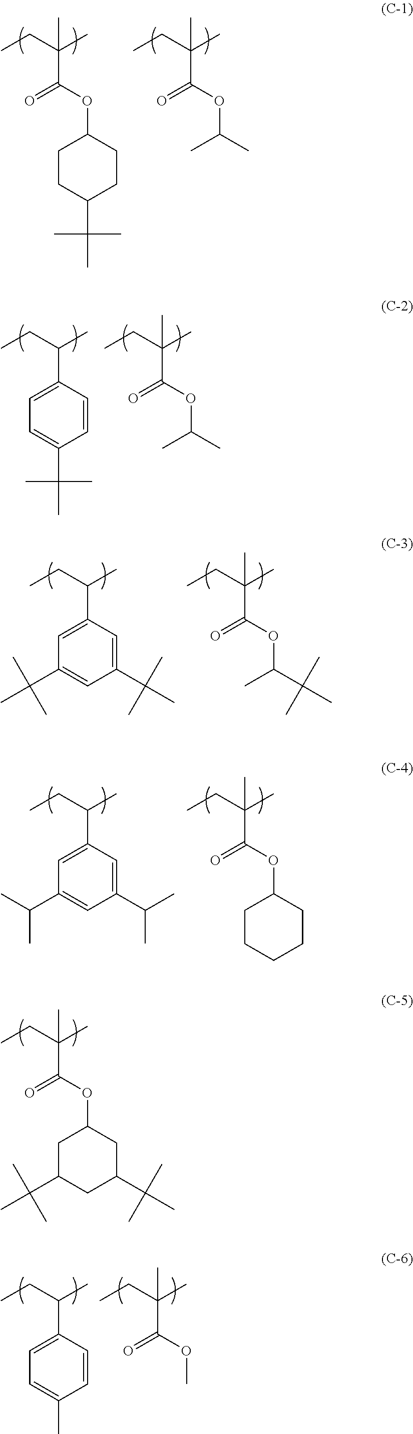

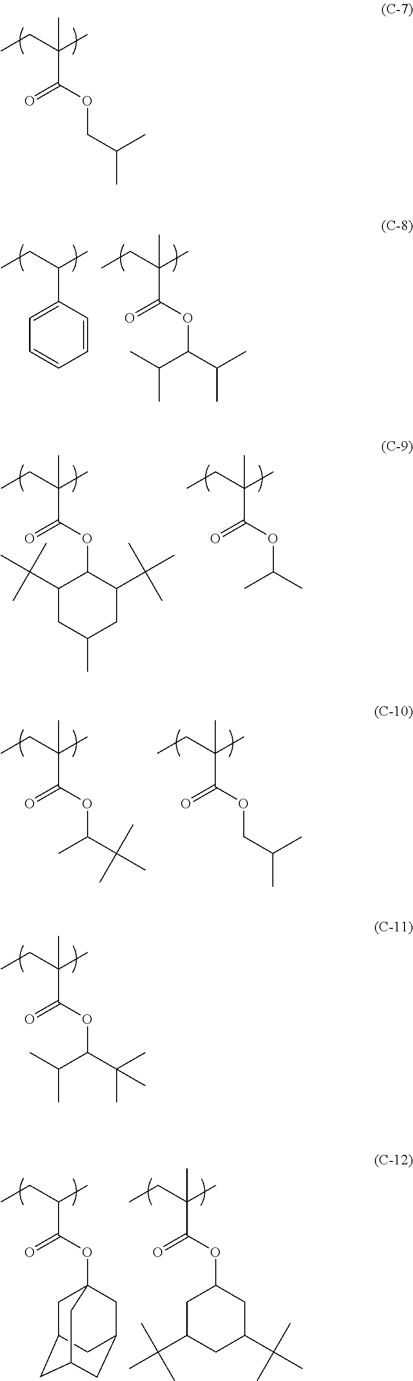

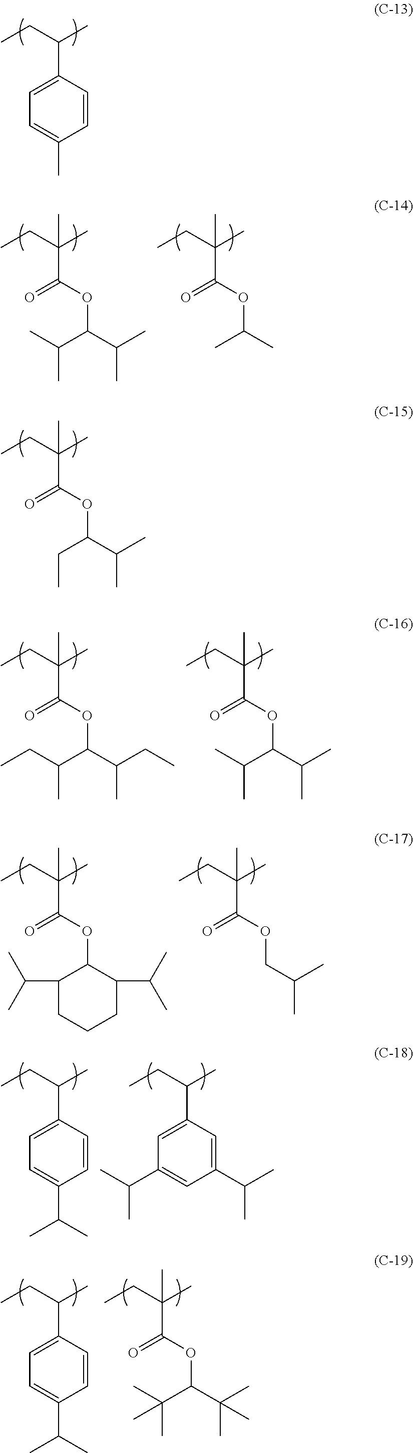

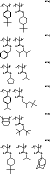

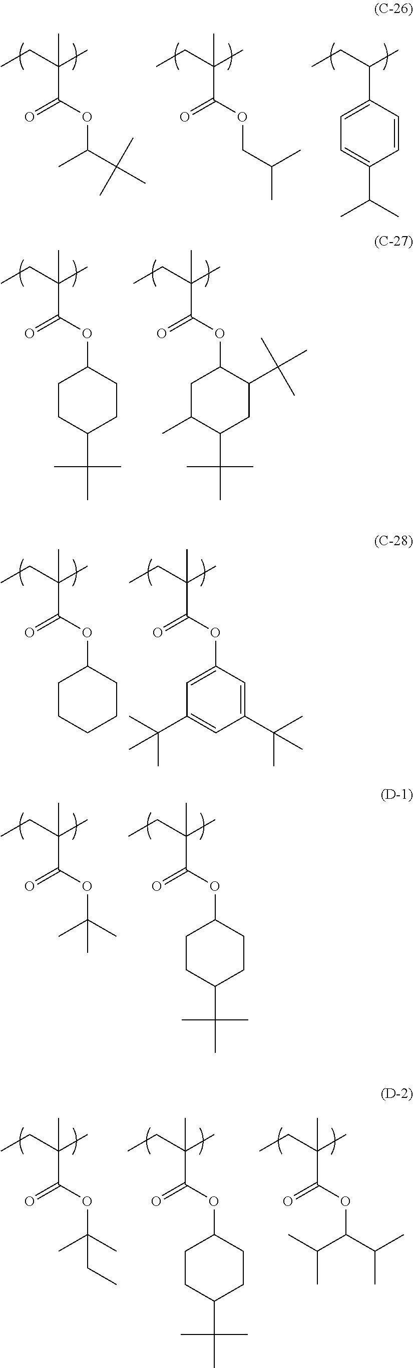

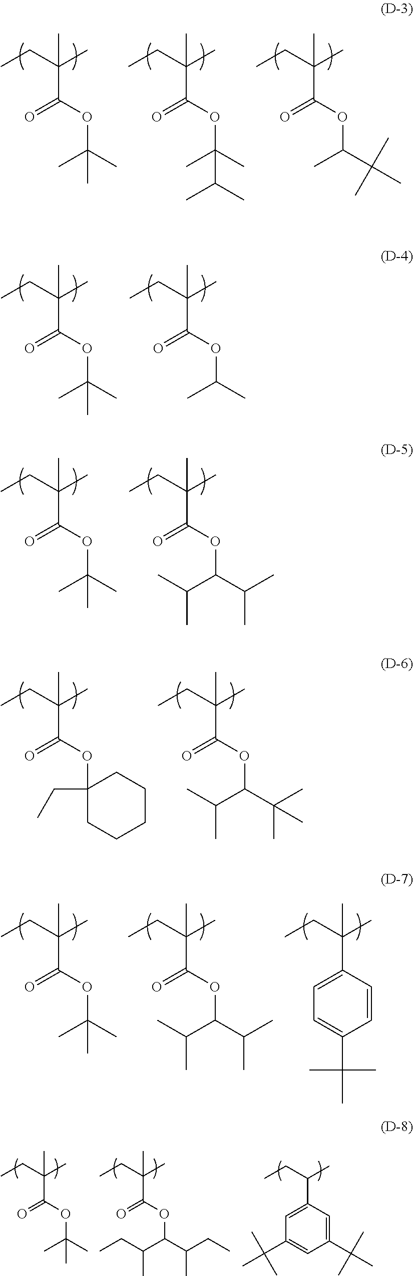

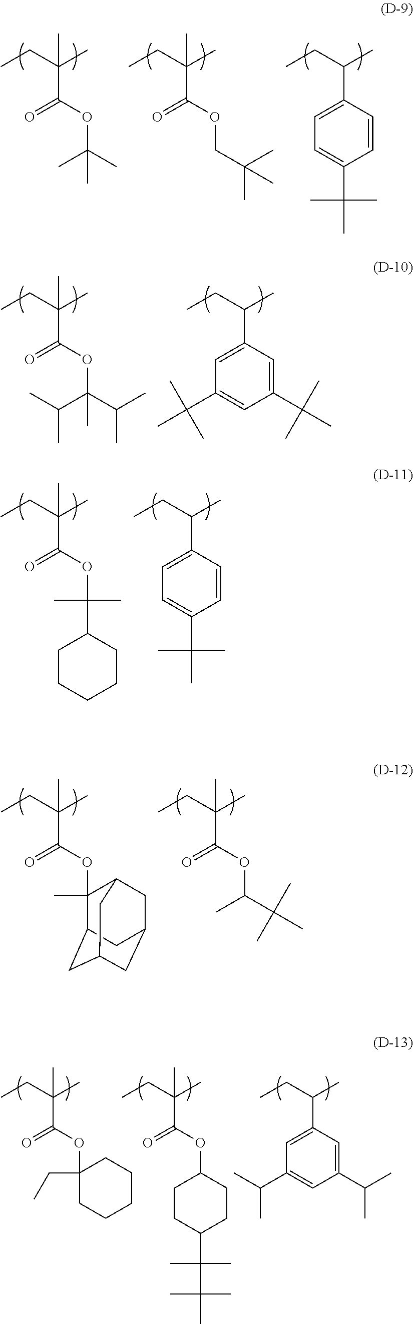

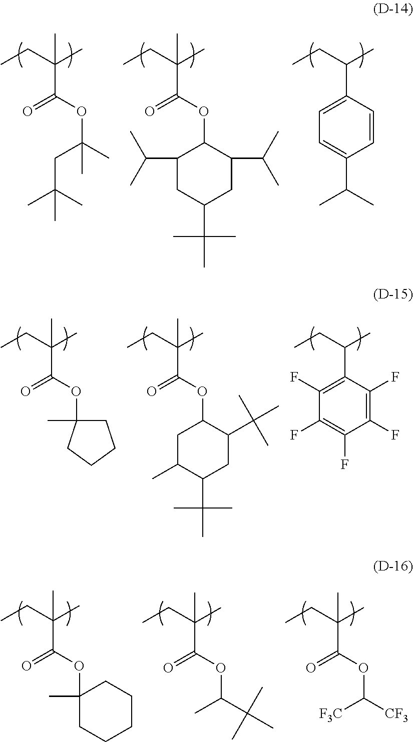

TABLE 2

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 3

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5] Basic Compound

In order to reduce the variation in performance over time from the exposure to the baking, the actinic ray-sensitive or radiation-sensitive resin composition used in the invention may include a basic compound. The useable basic compound is not particularly limited, but for example, compounds classified into (1) to (5) as described below can be used.

(1) Basic Compound (N)

As the basic compound, preferably, the compound (N) having the structures indicated by Formulae (A) to (E) below can be included.

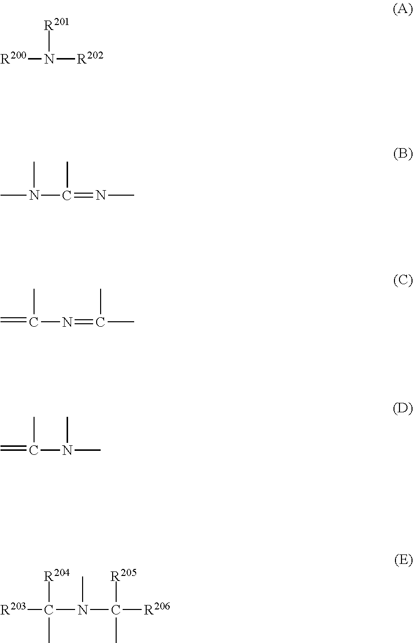

In General Formulae (A) and (E),

R²⁰⁰, R²⁰¹, and R²⁰² may be identical to or different from each other and represent a hydrogen atom, an alkyl group (preferably having 1 to 20 carbon atoms), a cycloalkyl group (preferably having 3 to 20 carbon atoms), or an aryl group (having 6 to 20 carbon atoms). Here, R²⁰¹ and R²⁰² may be bonded to each other to form a ring.

R²⁰³, R²⁰⁴, R²⁰⁵, and R²⁰⁶ may be identical to or different from each other, and represent an alkyl group having 1 to 20 carbon atoms.

With respect to the alkyl group, as the alkyl group having the substituent, an aminoalkyl group having 1 to 20 carbon atoms, a hydroxyalkyl group having 1 to 20 carbon atoms, and a cyanoalkyl group having 1 to 20 carbon atoms are preferable.

The alkyl group in these General Formulae (A) and (E) is preferably unsubstituted.

As the preferable compound (N), guanidine, aminopyrrolidine, pyrazole, pyrazoline, piperazine, aminomorpholine, aminoalkylmorpholine, piperidine, and the like can be included. As the more preferable compound (N), a compound (N) having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, an aniline derivative having a hydroxyl group and/or an ether bond, and the like can be included.

As the compound (N) having an imidazole structure, imidazole, 2,4,5-triphenylimidazole, benzimidazole, 2-phenylbenzimidazole, and the like are included. As the compound (N) having a diazabicyclo structure, 1,4-diazabicyclo[2,2,2]octane, 1,5-diazabicyclo[4,3,0]non-5-ene, 1,8-diazabicyclo[5,4,0]undec-7-ene, and the like are included. As the compound (N) having an onium hydroxide structure, tetrabutylammonium hydroxide, a triarylsulfonium hydroxide, phenacylsulfonium hydroxide, and sulfonium hydroxide having a 2-oxo-alkyl group are included, and specifically, triphenylsulfonium hydroxide, tris(t-butylphenyl)sulfonium hydroxide, bis(t-butylphenyl)iodonium hydroxide, phenacyl thiophenium hydroxide, 2-oxo-propyl thiophenium hydroxide, and the like are included. As the compound (N) having an onium carboxylate structure, a product in which an anion portion of the compound (N) having the onium hydroxide structure is a carboxylate is included, and for example, acetate, adamantane-1-carboxylate, and perfluoroalkylcarboxylate are included. As the compound (N) having a trialkylamine structure, tri(n-butyl)amine, tri(n-octyl)amine, and the like can be included. As the aniline compound (N), 2,6-diisopropylaniline, N,N-dimethylaniline, N,N-dibutylaniline, and N,N-dihexylaniline, and the like can be included. As the alkylamine derivative having a hydroxyl group and/or an ether bond, ethanolamine, diethanolamine, triethanolamine, N-phenyl-diethanolamine, tris(methoxyethoxyethyl)amine, and the like can be included. As the aniline derivative having a hydroxyl group and/or an ether bond, N,N-bis(hydroxyethyl)aniline and the like can be included.

As a preferable basic compound (N), further, an amine compound having a phenoxy group, an ammonium salt compound having a phenoxy group, an amine compound having a sulfonic acid ester group, and an ammonium salt compound having a sulfonic acid ester group can be included. As examples of these compounds, compounds (C1-1) to (C3-3) described in Paragraph “0066” of US2007/0224539A1 are included.

In addition, compounds described below are preferable as the basic compound (N).

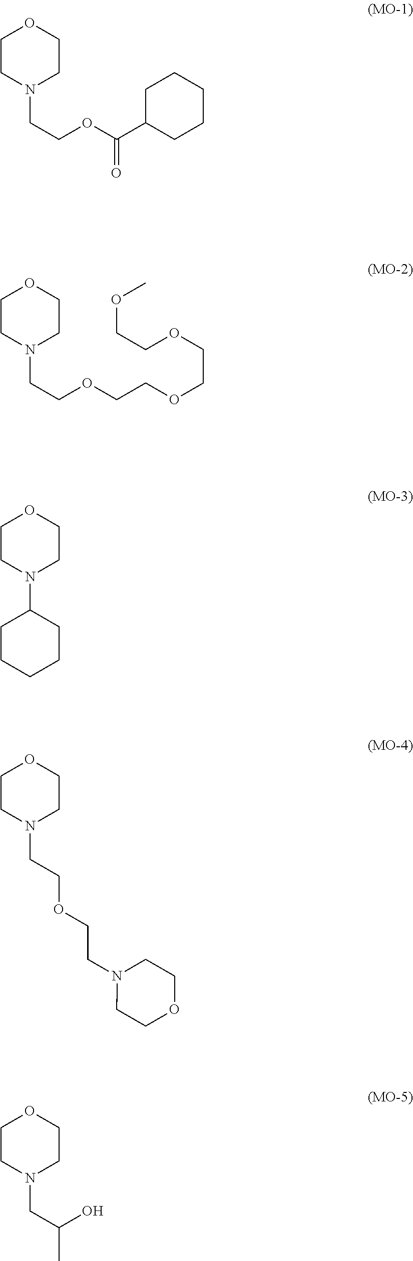

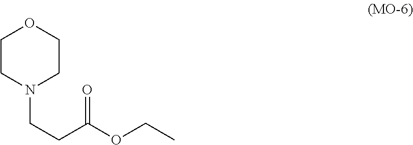

As the basic compound (N), in addition to the compounds described above, compounds described in Paragraphs “0180” to “0225” of JP2011-22560A, Paragraphs “0218” and “0219” of JP2012-137735A, and Paragraphs “0416” to “0438” of WO2011/158687A can be used. The basic compound (N) may be a basic compound or an ammonium salt compound, of which basicity decreases due to irradiation of actinic rays or radiation.

One type of these basic compounds (N) may be used singly, or two or more types thereof may be used in combination.

The actinic ray-sensitive or radiation-sensitive resin composition may contain or may not contain the basic compound (N). If the basic compound (N) is contained, the content ratio of the basic compound (N) is generally in the range of 0.001% by mass to 10% by mass and preferably in the range of 0.01% by mass to 5% by mass with respect to the solid content of the actinic ray-sensitive or radiation-sensitive resin composition.

A use ratio between the acid generator and the basic compound (N) in the composition is preferably such that acid generator/basic compound (molar ratio)=2.5 to 300. That is, in view of the sensitivity and the resolution, the molar ratio is preferably 2.5 or more, and in view of the suppression of the decrease of the resolution, caused by the thickening of the resist pattern with time until the post exposure baking treatment, the molar ratio is preferably 300 or less. The acid generator/basic compound (N) (molar ratio) is more preferably in the range of 5.0 to 200 and still more preferably in the range of 7.0 to 150.

(2) Basic Compound or Ammonium Salt Compound (E) of which Basicity Decreases by being Irradiated with Actinic Rays or Radiation

The actinic ray-sensitive or radiation-sensitive resin composition preferably contains a basic compound or an ammonium salt compound (hereinafter, also referred to as “compound (E)”) of which basicity decreases by being irradiated with actinic rays or radiation.

The compound (E) is preferably a compound (E-1) that has a basic functional group or an ammonium group, and a group that generates an acidic functional group by being irradiated with actinic rays or radiation. That is, the compound (E) is preferably a basic compound having a basic functional group and a group that generates an acidic functional group due to the irradiation of actinic rays or radiation or an ammonium salt compound having an ammonium group and a group that generates an acidic functional group due to the irradiation of actinic rays or radiation.

As a compound that is generated by the decomposition of the compound (E) or (E-1) by being irradiated with actinic rays or radiation and of which basicity decreases, compounds represented by General Formula (PA-I), (PA-II), or (PAIII) are included. In view of excellent effects relating to LWR, uniformity of the local pattern dimension, and DOF that can coexist with each other at a high level, particularly, compounds represented by General Formula (PA-II) or (PA-III) are preferable.

In addition, the compound represented by General Formula (PA-I) is described.

Q-A₁-(X)ₙ—B—R (PA-I)

In General Formula (PA-I),
A₁ represents a single bond or a divalent linking group.

Q represents —SO₃H or —CO₂H. Q corresponds to an acidic functional group that is generated by being irradiated with actinic rays or radiation.

X represents —SO₂— or —CO—.

n represents 0 or 1.

B represents a single bond, an oxygen atom, or —N(Rx)-.

Rx represents a hydrogen atom or a monovalent organic group.

R represents a monovalent organic group having a basic functional group or a monovalent organic group having an ammonium group.

Subsequently, the compound represented by General Formula (PA-II) is described.

Q₁-X₁—NH—X₂-Q₂ (PA-II)

In General Formula (PA-II),
Q₁ and Q₂ each independently represent a monovalent organic group. However, any one of Q₁ and Q₂ has a basic functional group. Q₁ and Q₂ may be bonded to each other to form a ring, and the formed ring may have a basic functional group.

X₁ and X₂ each independently represent —CO— or —SO₂—.

In addition, —NH— corresponds to an acidic functional group that is generated by being irradiated with actinic rays or radiation.

Subsequently, the compound represented by General Formula (PA-III) is described.

Q₁-X₁—NH—X₂-A₂-(X₃)ₘ—B-Q₃ (PA-III)

In General Formula (PA-III),
Q₁ and Q₃ each independently represent a monovalent organic group. However, any one of Q₁ and Q₃ has a basic functional group. Q₁ and Q₃ may be bonded to each other to form a ring, and the formed ring may have a basic functional group.

X₁, X₂, and X₃ each independently represent —CO— or —SO₂—.

A₂ represents a divalent linking group.

B represents a single bond, an oxygen atom, or —N(Qx)-.

Qx represents a hydrogen atom or a monovalent organic group.

When B is —N(Qx)-, Q₃ and Qx may be bonded to each other to form a ring.

m represents 0 or 1.

In addition, —NH— corresponds to an acidic functional group that is generated by being irradiated with actinic rays or radiation.

Hereinafter, specific examples of the compound (E) are described, but the invention is not limited thereto. Further, in addition to the exemplified compounds, as preferable specific examples of the compound (E), compounds of (A-1) to (A-44) of US2010/0233629A, (A-1) to (A-23) of US2012/0156617A, or the like are included.

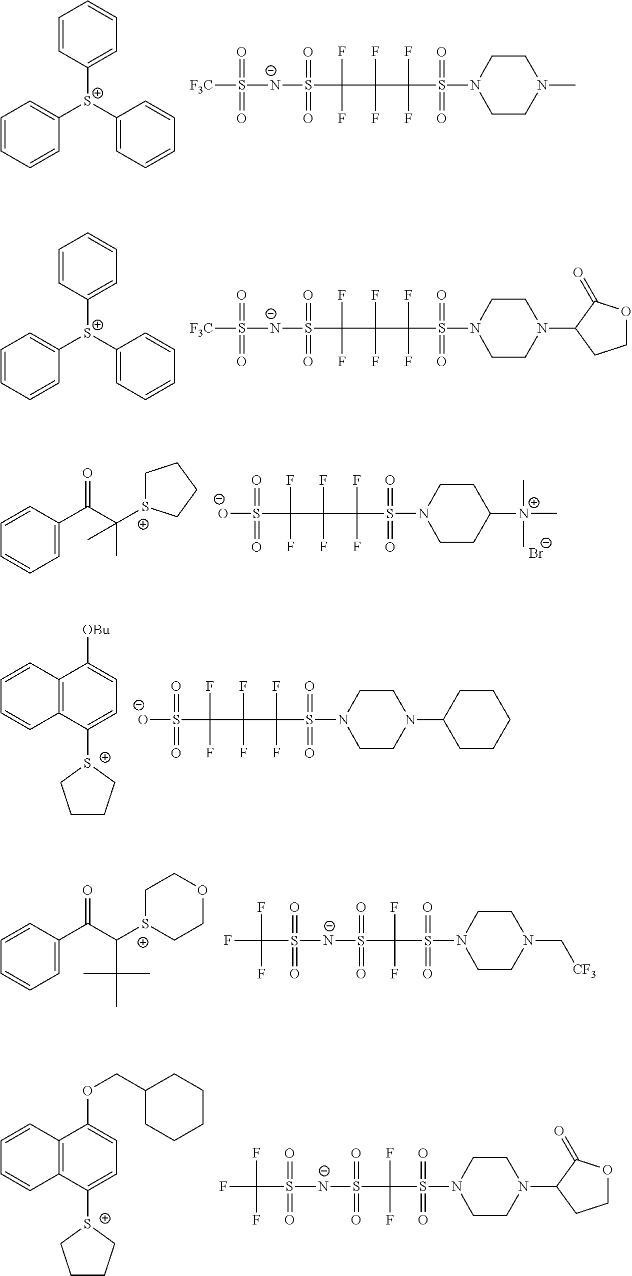

The molecular weight of the compound (E) is preferably in the range of 500 to 1,000.

The actinic ray-sensitive or radiation-sensitive resin composition may or may not contain the compound (E), but if the compound (E) is contained, the content of the compound (E) is preferably in the range of 0.1% by mass to 20% by mass and more preferably in the range of 0.1% by mass to 10% by mass with respect to the solid content of the actinic ray-sensitive or radiation-sensitive resin composition.

In addition, as one form of the compound (E), a compound (E-2) that is decomposed by being irradiated with actinic rays or radiation and that generates an acid (weak acid) of the strength at a level in which an acid decomposition group of the resin (A) is not acid-decomposed can be also included.

As the compound, for example, an onium salt (preferably a sulfonium salt) of a carboxylic acid that does not have a fluorine atom, an onium salt (preferably a sulfonium salt) of a sulfonic acid that does not have a fluorine atom, and the like can be included. More preferably, for example, among onium salts represented by General Formula (6A) described below, an onium salt in which a carboxylate anion does not have a fluorine atom, and among onium salts represented by General Formula (6B) described below, an onium salt in which a sulfonate anion does not have a fluorine atom, and the like are included. As the cation structure of a sulfonium salt, a sulfonium cation structure included in the acid generator (B) can be preferably included.

As the compound (E-2), more specifically, a compound included in Paragraph “0170” of WO2012/053527A, a compound included in Paragraphs “0268” and “0269” of JP2012-173419A, and the like are included.

(3) Low-Molecular-Weight Compound (F) that has Nitrogen Atom and has Group that is Left Due to an Action of an Acid

The actinic ray-sensitive or radiation-sensitive resin composition may contain a compound (hereinafter, referred to as a “compound (F)”) that has a nitrogen atom and has a group that is left due to an action of an acid.

The group that is left due to an action of an acid is not particularly limited, but an acetal group, a carbonate group, a carbamate group, a tertiary ester group, a tertiary hydroxyl group, and a hemiaminal ether group are preferable, and a carbamate group and a hemiaminal ether group are particularly preferable.

The molecular weight of the compound (F) that has a nitrogen atom and that has a group left due to an action of an acid is preferably in the range of 100 to 1,000, more preferably in the range of 100 to 700, and particularly preferably in the range of 100 to 500.

As the compound (F), an amine derivative having a group that is left due to an action of an acid on a nitrogen atom is preferable.

The compound (F) may have a carbamate group that has a protective group on a nitrogen atom. The protective group that forms a carbamate group can be represented by General Formula (d-1) described below.

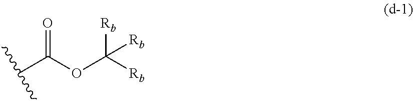

In General Formula (d-1),
R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be linked to each other to form a ring.

The alkyl group, the cycloalkyl group, the aryl group, and the aralkyl group represented by R_{b} may be substituted with a functional group such as a hydroxyl group, a cyano group, an amino group, a pyrrolidino group, a piperidino group, a morpholino group, or an oxo group, an alkoxy group, or a halogen atom. The alkoxyalkyl group represented by R_{b} is the same.

R_{b} is preferably a straight chain or branched alkyl group, a cycloalkyl group, or an aryl group. More preferably, R_{b} is a straight chain or branched alkyl group or a cycloalkyl group.

As the ring formed by linking two R_{b}'s to each other, an alicyclic hydrocarbon group, an aromatic hydrocarbon group, a heterocyclic hydrocarbon group, or derivatives thereof are included.

As the specific structure represented by General Formula (d-1), structures disclosed in Paragraph “0466” of US2012/0135348A can be included, but the invention is not limited thereto.

The compound (F) is particularly a compound having a structure represented by General Formula (6) below.

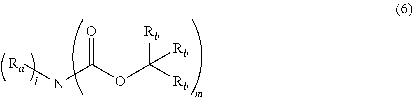

In General Formula (6), Rₐ represents a hydrogen atom, an alkyl group, a cycloalkyl group, an aryl group, or an aralkyl group. If 1 is 2, two Rₐ's may be identical to or different from each other, and the two Rₐ's may be linked to each other and may form a heterocyclic ring together with the nitrogen atom in the formula. The heterocyclic ring may include a heteroatom in addition to the nitrogen atom in the formula.

R_{b} has the same meaning as R_{b} in General Formula (d-1) described above, and preferred examples are also the same.

l represents an integer of 0 to 2, m represents an integer of 1 to 3, and 1+m=3 is satisfied.

In General Formula (6), the alkyl group, the cycloalkyl group, the aryl group, and the aralkyl group as Rₐ may be substituted with groups which are the same as the groups described as groups with which the alkyl group, the cycloalkyl group, the aryl group, and the aralkyl group as R_{b} may be substituted.

As preferred examples of the alkyl group, the cycloalkyl group, the aryl group, and the aralkyl group (the alkyl group, the cycloalkyl group, the aryl group, and the aralkyl group may be substituted with the groups described above) of Rₐ, groups which are the same as the preferred examples described above with respect to R_{b} are included.

In addition, as the heterocyclic ring that is formed by linking Rₐ's to each other, a group having 20 or less carbon atoms is preferable. For example, a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline, and 1,5,9-triazacyclododecane, and a group obtained by substituting a group derived from these heterocyclic compounds with one or more types of groups or one or more group selected from groups derived from a straight chain or branched alkane, a group derived from a cycloalkane, a group derived from an aromatic compound, a group derived from a heterocyclic compound, or a functional group such as a hydroxyl group, a cyano group, an amino group, a pyrrolidino group, a piperidino group, a morpholino group, or an oxo group is included.

As specific examples of the preferred compound (F), compounds disclosed in Paragraph “0475” of US2012/0135348A can be included, but the invention is not limited thereto.

The compounds represented by General Formula (6) can be synthesized based on JP2007-298569A and JP2009-199021A.

According to the invention, one type of the low-molecular-weight compound (F) may be used singly, or two or more types thereof may be used in a mixture.

The content of the compound (F) in the actinic ray-sensitive or radiation-sensitive resin composition is preferably in the range of 0.001% by mass to 20% by mass, more preferably in the range of 0.001% by mass to 10% by mass, and still more preferably in the range of 0.01% by mass to 5% by mass with respect to the total solid content of the composition.

(4) Onium Salt

In addition, as the basic compound, an onium salt represented by General Formula (6A) or (6B) described below may be included. It is expected that the onium salt controls the proliferation of the generated acid in a resist system, in relation to the acid strength of a photoacid generator generally used in the resist composition.

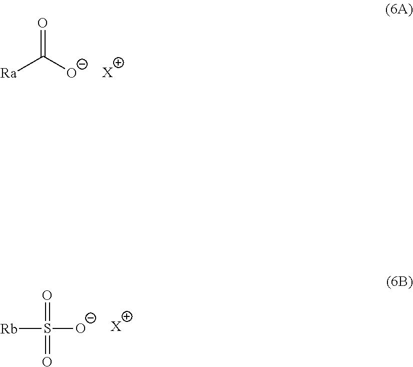

In General Formula (6A),
Ra represents an organic group. However, an organic group in which a fluorine atom is added to a carbon atom which is directly bonded to a carboxylic acid group in the formula is excluded. X⁺ represents an onium cation.

In General Formula (6B), Rb represents an organic group. However, an organic group in which a fluorine atom is added to a carbon atom which is directly bonded to a sulfonic acid group in the formula is excluded. X⁺ represents an onium cation.

In the organic groups represented by Ra and Rb, atoms directly bonded to the carboxylic acid group or the sulfonic acid group in the formulae are preferably carbon atoms. In this case, in order to cause the acid to be comparatively weaker than the acid generated from the photoacid generator described above, the carbon atom directly bonded to the sulfonic acid group or the carboxylic acid group is not substituted with a fluorine atom.

As the organic groups represented by Ra and Rb, for example, an alkyl group having 1 to 20 carbon atoms, a cycloalkyl group having 3 to 20 carbon atoms, an aryl group having 6 to 30 carbon atoms, an aralkyl group having 7 to 30 carbon atoms, and a heterocyclic group having 3 to 30 carbon atoms are included. In these groups, a portion or all of the hydrogen atoms may be substituted.

As the substituent in which the alkyl group, the cycloalkyl group, the aryl group, the aralkyl group, and the heterocyclic group may be included, and for example, a hydroxyl group, a halogen atom, an alkoxy group, a lactone group, and an alkylcarbonyl group are included.

As the onium cation represented by X⁺ in General Formula (6A) and (6B), a sulfonium cation, an ammonium cation, an iodonium cation, a phosphonium cation, a diazonium cation, and the like are included, and among them, the sulfonium cation is more preferable.

As the sulfonium cation, for example, an arylsulfonium cation that has at least one aryl group is preferable and a triarylsulfonium cation is more preferable. The aryl group may have a substituent, and as the aryl group, a phenyl group is preferable.

As examples of the sulfonium cation and the iodonium cation, a sulfonium cation structure of General Formula (ZI) in the compound (B) described above and the iodonium structure in General Formula (ZII) can be preferably included.

Specific structures of an onium salt represented by General Formula (6A) or (6B) are described below.

In addition, one type of the onium salt may be used singly, or two or more types thereof may be used in combination.

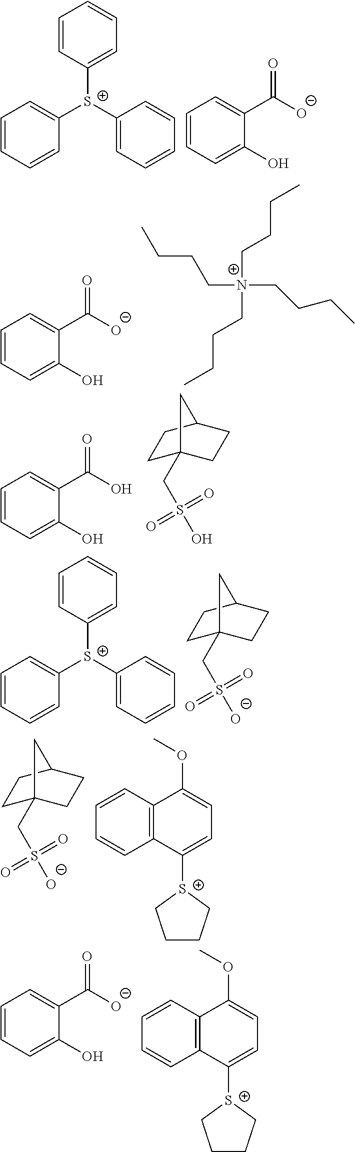

(5) Betaine Compound

Further, the composition can also preferably use a compound having both of an onium salt structure and an acid anion structure in one molecule (hereinafter, referred to as a “betaine compound”), such as a compound included in Formula (I) of JP2012-189977A, a compound represented by Formula (I) of JP2013-6827A, a compound represented by Formula (I) of JP2013-8020A, and a compound represented by Formula (I) of JP2012-252124A. As the onium salt structure, sulfonium, iodonium, and ammonium structures are included, and a sulfonium or iodonium salt structure is preferable. In addition, as the acid anion structure, a sulfonate anion or a carboxylate anion is preferable. As examples of the compound, for example, the following is included.

In addition, one type of the betaine compound may be used, and two or more types thereof may be used in combination.

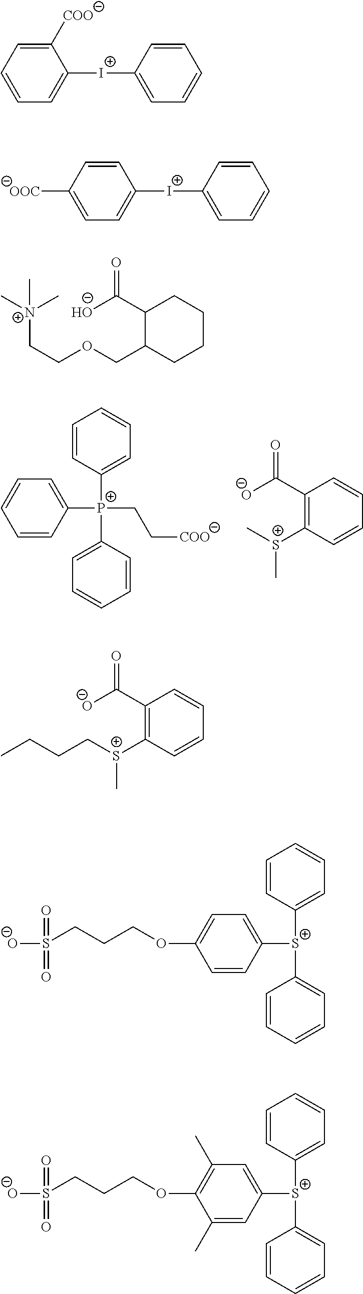

[6] Surfactant (H)

The actinic ray-sensitive or radiation-sensitive resin composition used in the invention may further include a surfactant. If the surfactant is contained, any one of fluorine and/or silicon-based surfactants (fluorine-based surfactant, silicon-based surfactant, or surfactant having both of fluorine atom and silicon atom) or two or more types thereof are preferably included.

If the actinic ray-sensitive or radiation-sensitive resin composition contains a surfactant, when an exposure light source of 250 nm or lower, particularly 220 nm or lower is used, a resist pattern having a small number of defects in adhesiveness and development can be formed with preferable sensitivity and resolution.

As the fluorine-based and/or silicon-based surfactants, surfactants disclosed in Paragraph “0276” of US2008/0248425A are included, and for example, EFTOP EF301 and EF303 (manufactured by Shin-Akita Kasei K.K.), FLUORAD FC430, 431, and 4430 (manufactured by Sumitomo 3M Limited), MEGAFAC F171, F173, F176, F189, F113, F110, F177, F120, and R08 (manufactured by DIC Corporation), SURFLON S-382, SC101, 102, 103, 104, 105, 106, and KH-20 (manufactured by Asahi Glass Co., Ltd.), TROYSOL S-366 (manufactured by TROY Chemical Corporation), GF-300 and GF-150 (manufactured by Toagosei Co., Ltd.), SURFLON S-393 (manufactured by AGC Seimi Chemical Co., Ltd.), EFTOP EF121, EF122A, EF122B, RF122C, EF125M, EF135M, EF351, EF352, EF801, EF802, and EF601 (manufactured by JEMCO Inc.), PF636, PF656, PF6320, and PF6520 (manufactured by OMNOVA Solutions Inc.), and FTX-204G, 208G, 218G, 230G, 204D, 208D, 212D, 218D, and 222D (manufactured by NEOS Corporation) are included. In addition, polysiloxane polymer KP-341 (produced by Shin-Etsu Chemical Co., Ltd.) may also be used as the silicon-based surfactant.

Further, as the surfactants, in addition to well-known surfactants described above, a surfactant using a polymer having a fluoro-aliphatic group derived from a fluoro-aliphatic compound that is manufactured by a telomerization process (also referred to as a telomer process) or an oligomerization process (also referred to as an oligomer process) may be used. The fluoro-aliphatic compound can be synthesized by the method disclosed in JP2002-90991A.

As a surfactant corresponding to the above, MEGAFAC F178, F-470, F-473, F-475, F-476, and F-472 (manufactured by DIC Corporation), a copolymer of a C₆F₁₃ group-containing acrylate (or methacrylate) and a (poly(oxyalkylene)) acrylate (or methacrylate), a copolymer of a C₃F₇ group-containing acrylate (or methacrylate), a (poly(oxyethylene)) acrylate (or methacrylate) and a (poly(oxypropylene)) acrylate (or methacrylate), and the like can be included.

In addition, according to the invention, other surfactants in addition to the fluorine-based and/or silicon-based surfactants disclosed in Paragraph “0280” of US2008/0248425A can be used.

These surfactants may be used singly, or some types thereof may be used in combination.

If the actinic ray-sensitive or radiation-sensitive resin composition contains a surfactant, the used amount of the surfactant is preferably in the range of 0.0001% by mass to 2% by mass and more preferably in the range of 0.0005% by mass to 1% by mass with respect to the total amount of the actinic ray-sensitive or radiation-sensitive resin composition (excluding the solvent).

Meanwhile, if the addition amount of the surfactant is 10 ppm or lower with respect to the total amount of the actinic ray-sensitive or radiation-sensitive resin composition (except for solvent), the uneven distribution properties of the surface of the hydrophobic resin increase, such that the resist film surface can be caused to be hydrophobic and the water conformity at the time of liquid immersion exposure can be enhanced.

[7] Other Additives (G)

The actinic ray-sensitive or radiation-sensitive resin composition may contain an acid proliferating agent, a dye, a plasticizer, a photosensitizer, a light absorbing agent, an alkali soluble resin, a dissolution inhibitor, a compound that promotes solubility with respect to a developer (for example, a phenol compound having a molecular weight of 1,000 or less or alicyclic or aliphatic compound having carboxyl group), and the like.

The phenol compound having a molecular weight of 1,000 or less can be easily synthesized by a person having ordinary skill in the art with reference to, for example, methods disclosed in JP1992-122938A (JP-H4-122938A), JP1990-28531A (JP-H2-28531A), U.S. Pat. No. 4,916,210B, and EP219294B.

As specific examples of the alicyclic or aliphatic compound having a carboxyl group, a carboxylic acid derivative, an adamantanecarboxylic acid derivative, an adamantane dicarboxylic acid, a cyclohexane carboxylic acid, a cyclohexane dicarboxylic acid, and the like which have a steroid structure such as a cholic acid, a deoxycholic acid, and a lithocholic acid are included, but the invention is not limited thereto.

In view of enhancement of the resolving power, the actinic ray-sensitive or radiation-sensitive resin composition is preferably used in a film thickness of 30 nm to 250 nm and more preferably used in a film thickness of 30 nm to 200 nm. The solid content concentration in the composition is set to a proper range such that the composition can have proper viscosity, the coating properties and film forming properties are increased, and thus such a film thickness can be achieved.

The solid content concentration of the actinic ray-sensitive or radiation-sensitive resin composition is generally in the range of 1.0% by mass to 10% by mass, preferably in the range of 2.0% by mass to 5.7% by mass, and more preferably in the range of 2.0% by mass to 5.3% by mass. If the solid content concentration is in the range described above, the resist solution can be evenly coated on the substrate, and it is possible to form a resist pattern of which line width roughness is excellent. The reason for this is not clear, but probably, if the solid content concentration is 10% by mass or less or preferably 5.7% by mass or less, it is thought that the aggregation of materials, particularly, the acid generator, in the resist solution is suppressed, and as a result, an even resist film can be formed.

The solid content concentration is a proportion by weight of the weight of other resist components except for the solvent with respect to the total weight of the actinic ray-sensitive or radiation-sensitive resin composition.

The actinic ray-sensitive or radiation-sensitive resin composition is preferably prepared by dissolving the components in a predetermined organic solvent, preferably, the mixed solvents described above.

In addition, at the time of preparation, a step of reducing metal impurities in the composition to a ppb level by using an ion exchange membrane, a step of filtrating impurities such as various particles by using a proper filter, a deaeration step, and the like may be performed. Details of the steps are disclosed in JP2012-88574A, JP2010-189563A, JP2001-12529A, JP2001-350266A, JP2002-99076A, JP1993-307263 A (JP-H5-307263 A), JP2010-164980A, WO2006/121162A, JP2010-243866A, JP2010-020297A, and the like.

Specifically, regarding proper filters used in the filtration step, polytetrafluoroethylene, polyethylene, nylon filters of which a pore size is 0.1 μm or less, more preferably 0.05 μm or less, and still more preferably 0.03 μm or less are preferable.

In addition, in the actinic ray-sensitive or radiation-sensitive resin composition, the water content is preferably low. Specifically, the water content is preferably 2.5% by mass or less, more preferable 1.0% by mass or less, and still more preferable 0.3% by mass or less with respect to the total weight of the composition.

(Sequence of Step (1))

The method of forming a film on a substrate by using the actinic ray-sensitive or radiation-sensitive resin composition is not particularly limited, and well-known methods can be employed. Among them, in order to make the adjustment of the film thickness easier, a method of forming the film by coating the actinic ray-sensitive or radiation-sensitive resin composition on the substrate may be provided.

In addition, the coating method is not particularly limited, but well-known method is employed. In the semiconductor production field, spin coating is preferably used.

In addition, after the actinic ray-sensitive or radiation-sensitive resin composition is coated, if necessary, a drying treatment may be performed. The method of the drying treatment is not particularly limited, and a baking treatment, an air drying treatment, and the like are included.

<Film>

The receding contact angle of the film (resist film) formed by using the actinic ray-sensitive or radiation-sensitive resin composition according to the invention is preferably 70° or greater at a temperature of 23±3° C., a humidity of 45±5%, which is preferable in the case where exposure is performed through the immersion medium, more preferably 75° or greater, and still more preferably in the range of 75° to 85°.

If the receding contact angle is too small, the film may not be preferably used in the case where exposure is performed through an immersion medium, and the effect of reducing defects in a water mark may not be sufficiently exhibited. In order to realize a preferable receding contact angle, the hydrophobic resin preferably includes the actinic ray-sensitive or radiation-sensitive composition. Otherwise, a receding contact angle may be increased by forming a coating layer (so-called “top coat”) with the hydrophobic resin composition on the resist film.

The thickness of the resist film is not particularly limited, but in order to form a highly accurate fine pattern, the thickness is preferably in the range of 1 nm to 500 nm and more preferably in the range of 1 nm to 100 nm.

[Step (2): Exposure Step]

Step (2) is a step of exposing the film formed in Step (1). More specifically, Step (2) is a step of selectively exposing the film such that a desired pattern is formed. Accordingly, the film is exposed in a pattern shape, and the solubility of the film is changed only in an exposed portion.

In addition, the “exposure” means the irradiation of actinic rays or radiation.

The light used in the exposure is not particularly limited, but, for example, infrared light, visible light, ultraviolet light, far ultraviolet light, extreme ultraviolet light, X-rays, and electron beams can be included. Far-ultraviolet light having a wavelength preferably 250 nm or shorter, more preferably 220 nm or shorter, still more preferably in the range of 1 nm to 200 nm is included.

More specifically, a KrF excimer laser (248 nm), an ArF excimer laser (193 nm), a F₂ excimer laser (157 nm), X rays, EUV (13 nm), electron beams, and the like are included. Among them, a KrF excimer laser, an ArF excimer laser, EUV, or electron beams are preferable, and an ArF excimer laser is more preferable.

The method of selectively exposing the film is not particularly limited, and well-known methods can be used. For example, a binary mask in which the transmittance of a light shielding portion is 0% or a halftone-type phase shift mask (HT-Mask) in which the transmissivity of the light shielding portion is 6% can be used.

As the binary mask, a product in which a chromium film, a chromium oxide film, or the like is formed on the quartz glass substrate as the light shielding portion is generally used.

As the halftone-type phase shift mask, a product in which a molybdenum silicide (MoSi) film, a chromium film, a chromium oxide film, a silicon oxynitride film, and the like is formed on the quartz glass substrate as the light shielding portion is generally used.

In addition, the invention is not limited to the exposure performed through a photomask, and exposure without a photomask, for example, selective exposure (pattern exposure) by drawing by electron beams and the like may be performed.

This step may include exposure plural times.

(Baking Treatment)

A baking treatment (PB: Prebake) may be performed on the film before this step. The baking treatment (PB) may be performed plural times.

In addition, a baking treatment (PEB: Post Exposure Bake) may be performed on the resist film after this step. The baking treatment (PEB) may be performed plural times.

The reaction of the exposure portion is promoted by the baking treatment, and thus the sensitivity or the pattern profile are further improved.

In both of PB and PEB, the temperature of the baking treatment is preferably in the range of 70° C. to 130° C. and more preferably in the range of 80° C. to 120° C.

In both of PB and PEB, the time of the baking treatment is preferably in the range of 30 seconds to 300 seconds, more preferably in the range of 30 seconds to 180 seconds, and still more preferably in the range of 30 seconds to 90 seconds.

In both of PB and PEB, the baking treatment may be performed by means included in a general exposing and developing machine, and a hot plate or the like may be used.

### Preferred Embodiment Liquid Immersion Exposure

As a preferred embodiment of the exposure, for example, liquid immersion exposure is included. If the liquid immersion exposure is used, a finer pattern can be formed. In addition, the liquid immersion exposure may be combined with a super resolution technique such as a phase shift method or a modified illumination method.

As the immersion liquid used in the liquid immersion exposure, a liquid in which a temperature coefficient of the refractive index is minimized so as to be transparent at the exposure wavelength and limit the deform of an optical image projected on the resist film is preferable. Particularly, if the exposure light source is an ArF excimer laser (wavelength; 193 nm), in addition to the viewpoint described above, in view of the easy acquisition and easy handling, water is preferably used.

If water is used as the immersion liquid, a small proportion of additives (liquid) that decreases the surface tension of water and also increases the surface activity may be added. As the additive, a product that does not dissolve the resist film and of which an influence on an optical coat on a lower surface of the lens element is negligible is preferable.

As an additive like this, for example, an aliphatic alcohol which has a refractive index approximately equal to a refractive index of water is preferable, and specifically, a methyl alcohol, an ethyl alcohol, an isopropyl alcohol, and the like are included. If an alcohol having a refractive index approximately equal to a refractive index of water is added, it is possible to obtain an advantage of causing the variation in the refractive index in the entire liquid to be extremely small, even if alcohol components in water evaporate and the content concentration changes.

Meanwhile, if materials which are opaque to 193 nm light or impurities that have greatly different refractive indexes as that of water are mixed in, the optical image which is projected on the resist may be deformed. Therefore, as the water used, distilled water is preferable. Further, pure water which is filtered by an ion exchange filter may be used.

The electrical resistance of water used as the immersion liquid is preferably 18.3 MQcm or higher, the TOC (concentration of organic substance) is preferably 20 ppb or less, and a deaeration treatment is preferably performed.

If the refractive index of the immersion liquid is increased, it is possible to enhance the lithography performances. From this point of view, additives that increase the refractive index may be added to water, or heavy water (D₂O) may be used instead of water.

With respect to the liquid immersion exposure, before the exposure and/or after the exposure (before baking treatment), the surface of the resist film may be washed with aqueous chemical liquid.

In addition, according to this specification, the general exposure (exposure that does not use immersion liquid) except for the liquid immersion exposure is referred to as dry exposure.

[Step (3): Development Step]

Step (3) is a step of developing the film exposed in Step (2) above, by using the developer including the organic solvent. Accordingly, the desired negative tone pattern is formed.

In addition, a negative tone refers to an image form in which an area with a relatively small degree of exposure is removed and an area with a relatively large degree of exposure remains, in the exposure of Step (2).

As described above, predetermined compounds A are included in the developer.

Hereinafter, first, those compounds A (onium salt, polymer having onium salt, nitrogen-containing compound including three or more nitrogen atoms, basic polymer, and phosphorus-based compound) and the developer are described, and the sequence of this step is described.

(Onium Salt)

The onium salt refers to a salt generated by a coordinate bond formed by an organic substance component and a Lewis base.

The types of the onium salt used are not particularly limited, for example, an ammonium salt, a phosphonium salt, an oxonium salt, a sulfonium salt, a selenonium salt, a carbonium salt, a diazonium salt, and an iodonium salt, which have cation structures described below are included.

In addition, as the cation in the onium salt structure, a product having a positive charge on a heteroatom of a heteroaromatic ring is included. As the onium salt, for example, a pyridinium salt and an imidazolium salt are included.

In addition, in this specification, as one form of the ammonium salt, the pyridinium salt and the imidazolium salt are included.

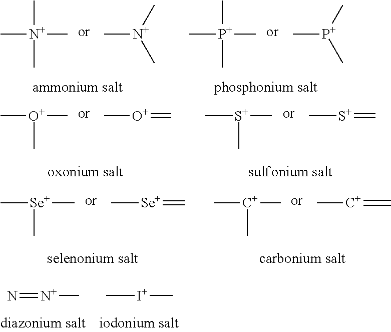

The onium salt may be a polyvalent onium salt having 2 or more onium ion atoms in a molecule. As the polyvalent onium salt, a compound in which 2 or more cation portions are linked by a covalent bond is preferable.

As the polyvalent onium salt, for example, a diazonium salt, an iodonium salt, a sulfonium salt, an ammonium salt, and a phosphonium salt are included. In view of sensitivity, a diazonium salt, an iodonium salt, and a sulfonium salt are preferable, and in view of stability, an iodonium salt and a sulfonium salt are more preferable.

In addition, the anion (negative ion) included in an onium salt is not particularly limited, and any anions can be used, but the anion may be a monovalent ion or a polyvalent ion.

For example, as the monovalent anion, a sulfonate anion, a formate anion, a carboxylate anion, a sulfinate anion, a boron anion, a halide ion, a phenol anion, an alkoxy anion, and a hydroxide ion are included. In addition, as the divalent anion, for example, an oxalate ion, phthalate ion, a maleate ion, a fumarate ion, a tartrate ion, a malate ion, a lactate ion, a sulfate ion, a diglycolate ion, and an ion of a 2,5-furandicarboxylic acid are included.

More specifically, as an monovalent anion, Cl⁻, Br⁻, I⁻, AlCl₄⁻, Al₂Cl₇⁻, BF₄⁻, PF₆⁻, ClO₄⁻, NO₃⁻, CH₃COO⁻, CF₃COO⁻, CH₃SO₃⁻, CF₃SO₃⁻, (CF₃SO₂)₂N⁻, (CF₃SO₂)₃C⁻, AsF₆⁻, SbF₆⁻, NbF₆⁻, TaF₆⁻, F(HF)ₙ⁻, (CN)₂N⁻, C₄F₉SO₃⁻, (C₂F₅SO₂)₂N⁻, C₃F₇COO⁻, (CF₃SO₂)(CF₃CO)N⁻, C₉H₁₉COO⁻, (CH₃)₂PO₄⁻, (C₂H₅)₂PO₄⁻, C₂H₅OSO₃⁻, C₆H₁₃OSO₃⁻, C₈H₁₇OSO₃⁻, CH₃ (OC₂H₄)₂OSO₃⁻, C₆H₄(CH₃)SO₃⁻, (C₂F₅)₃PF₃⁻, CH₃CH(OH)COO⁻, B(C₆F₅)₄⁻, FSO₃⁻, C₆H₅O⁻, (CF₃)₂CHO⁻, (CF₃)₃CHO⁻, C₆H₃(CH₃)₂O⁻, C₂H₅OC₆H₄COO⁻, and the like are included.

Hereinafter, specific examples of the cations included in the onium salt are described.

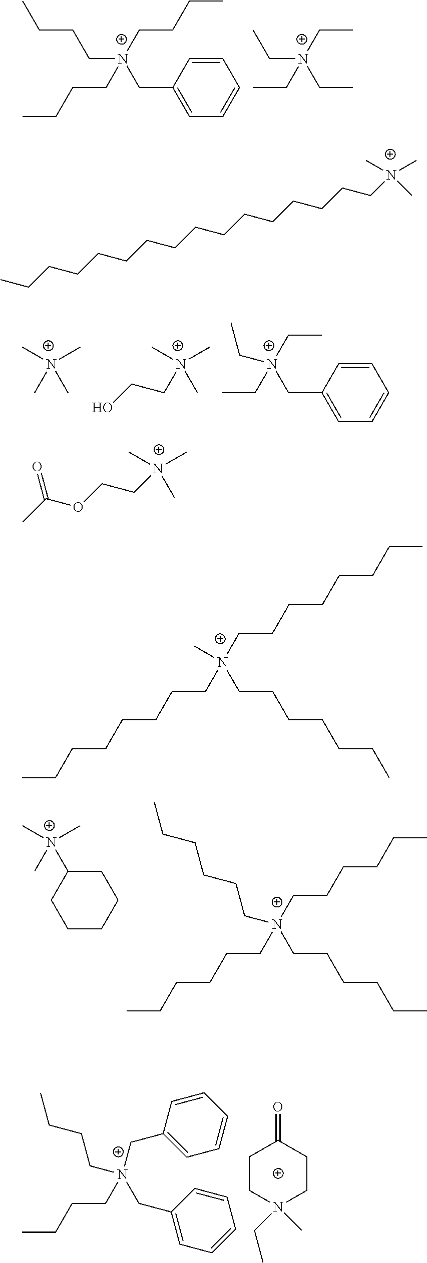

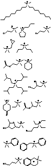

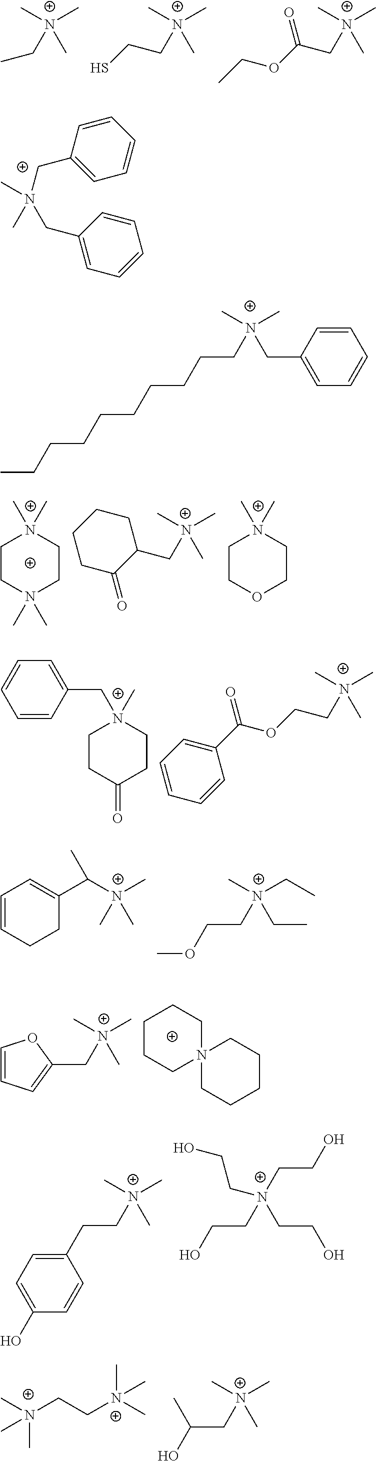

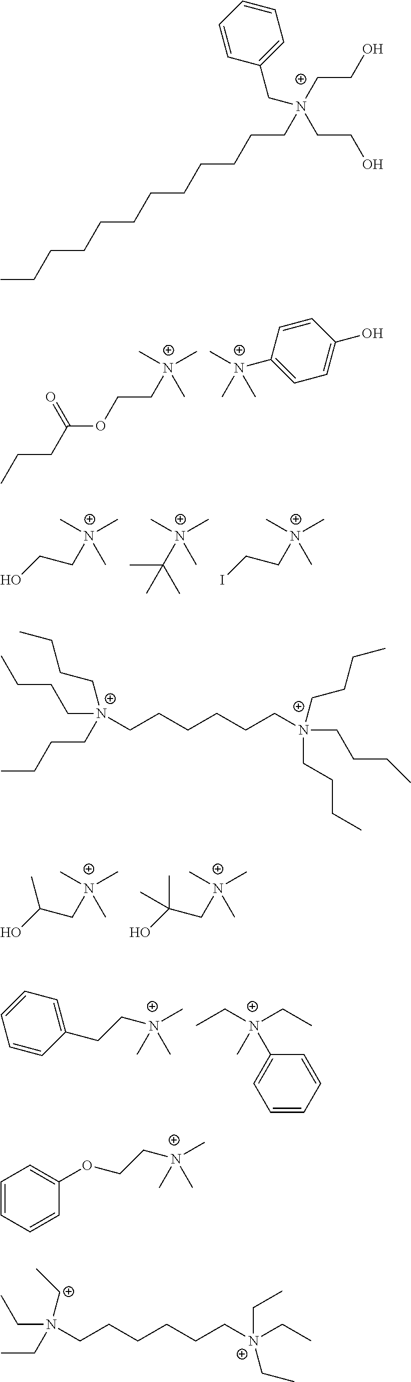

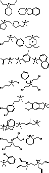

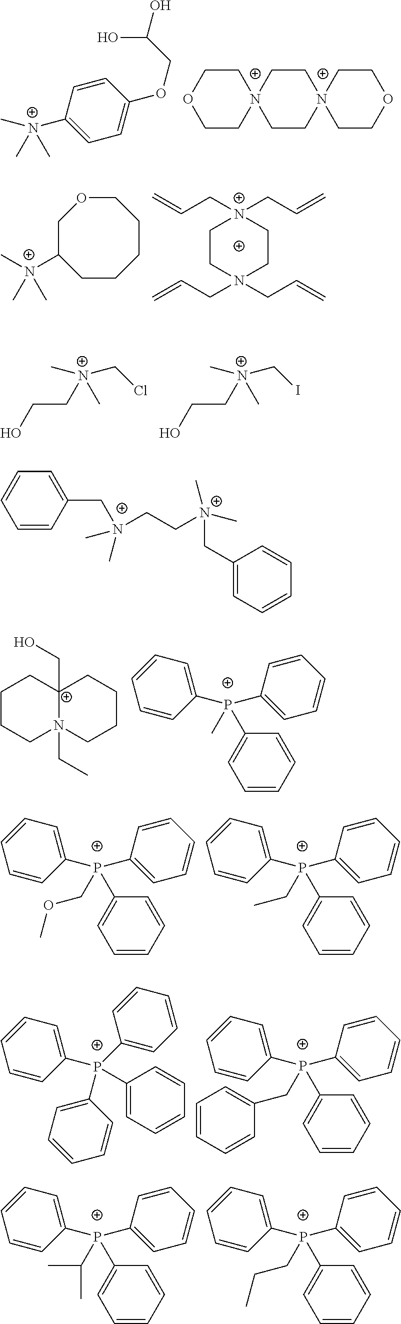

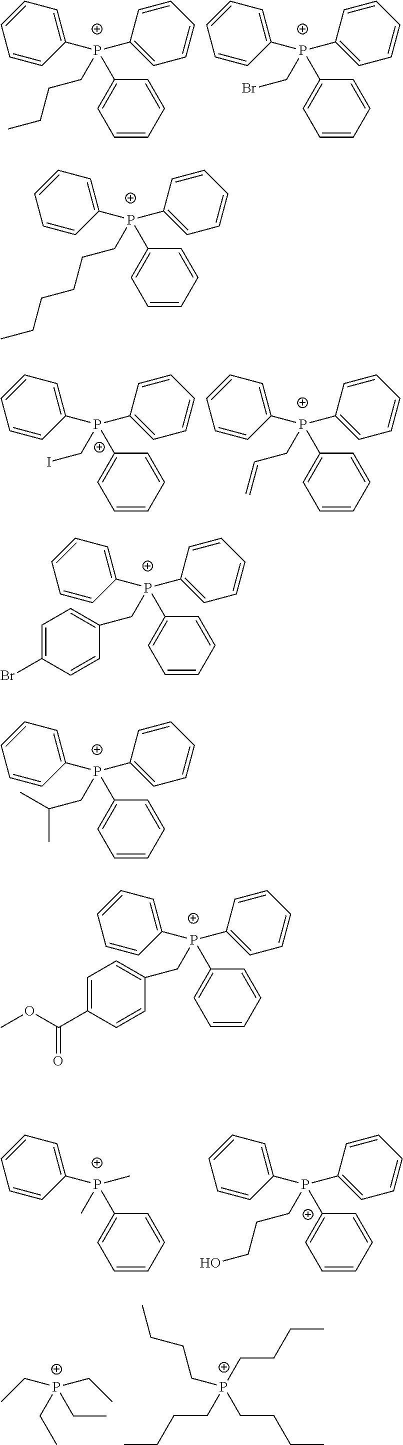

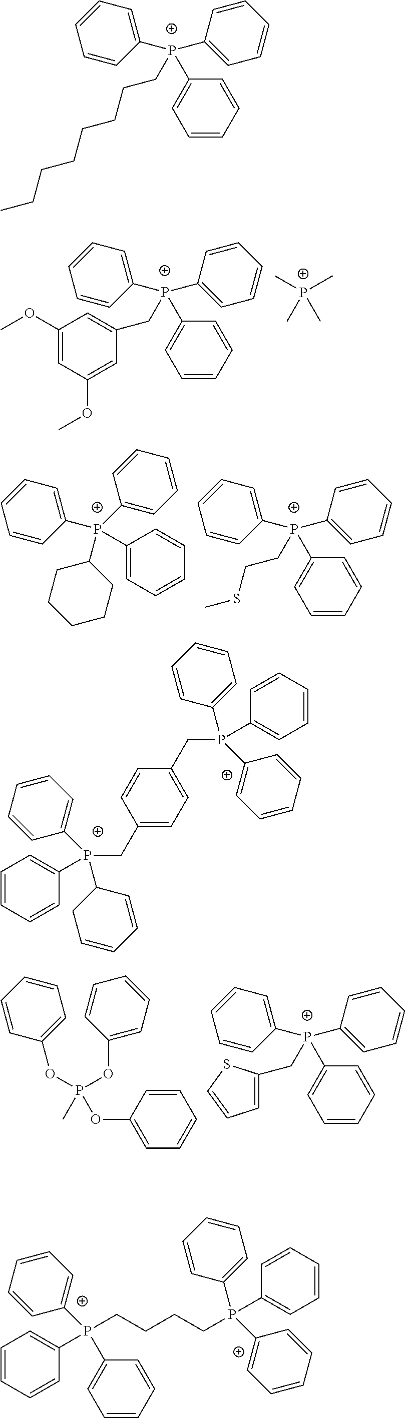

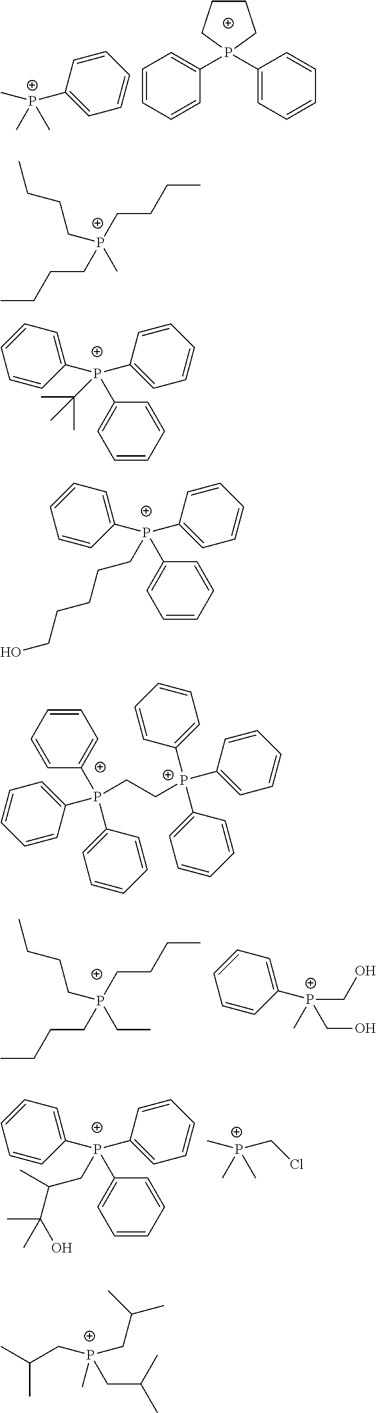

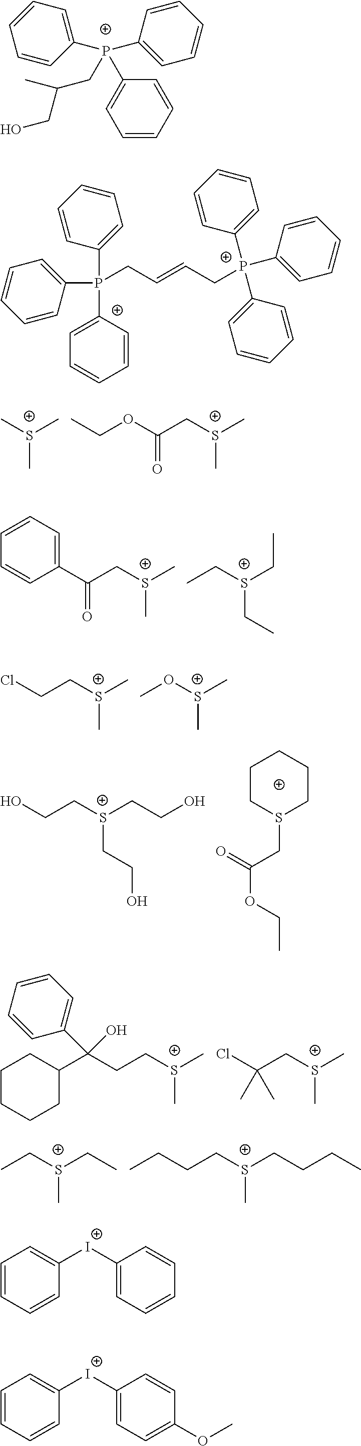

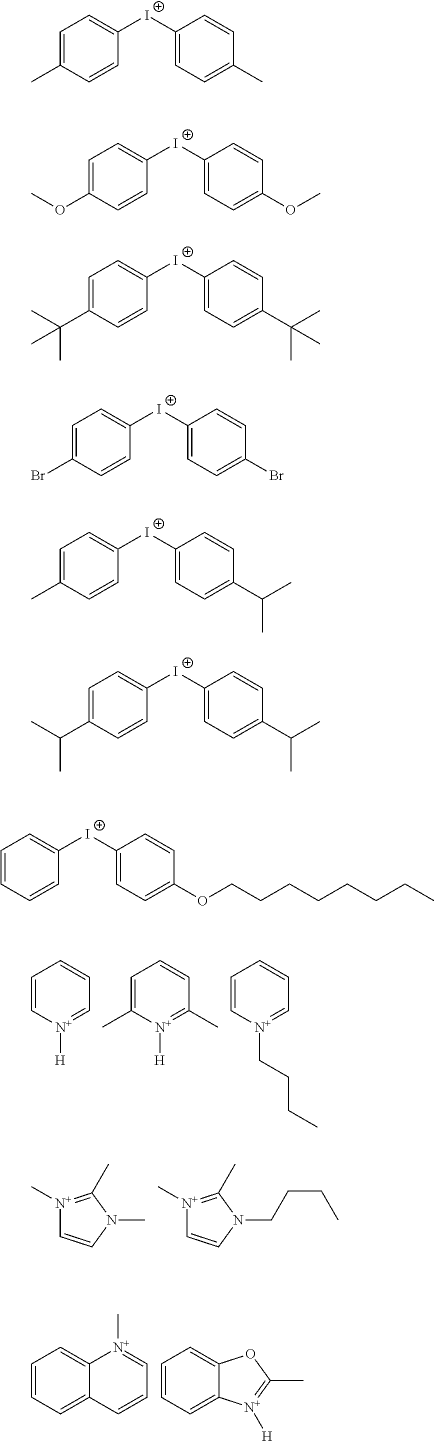

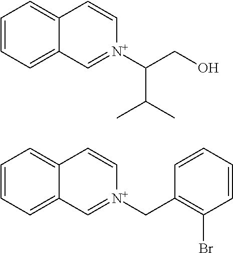 [SMILES: CC(C)C(CO)[n+]1ccc2ccccc2c1 ; Brc1ccccc1C[n+]1ccc2ccccc2c1]

Hereinafter, specific examples of the anion included in the onium salt are described.

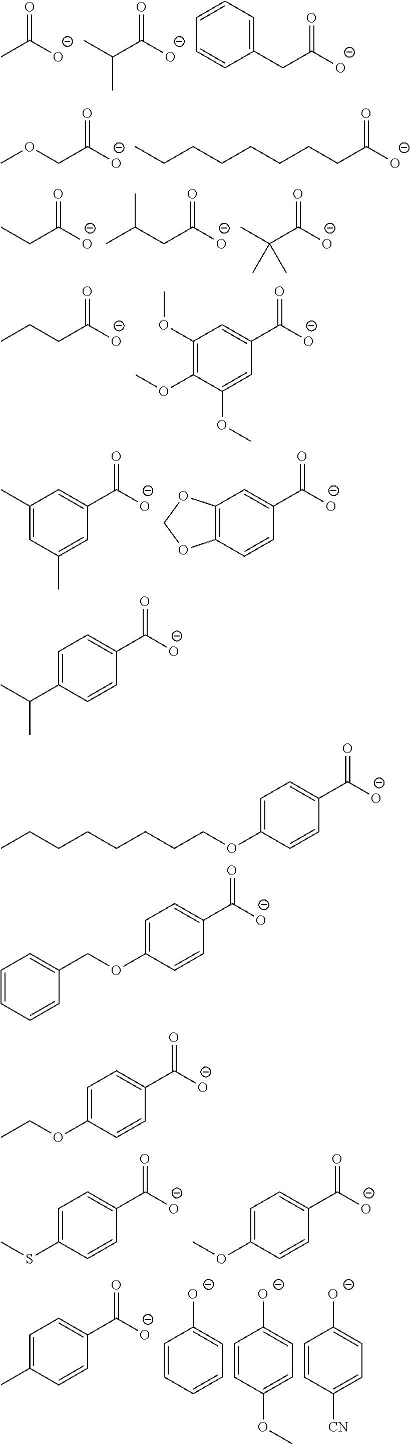

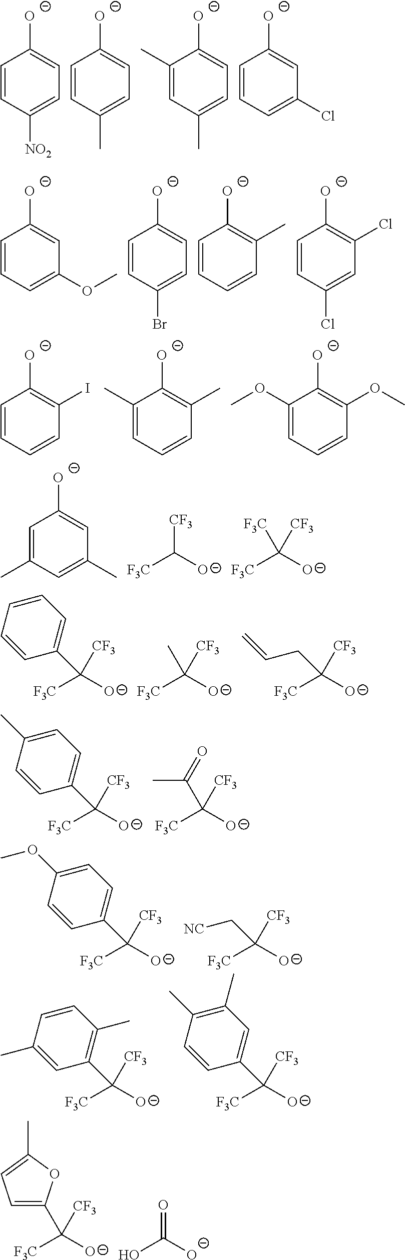

Hereinafter, specific examples of the onium salt are described.

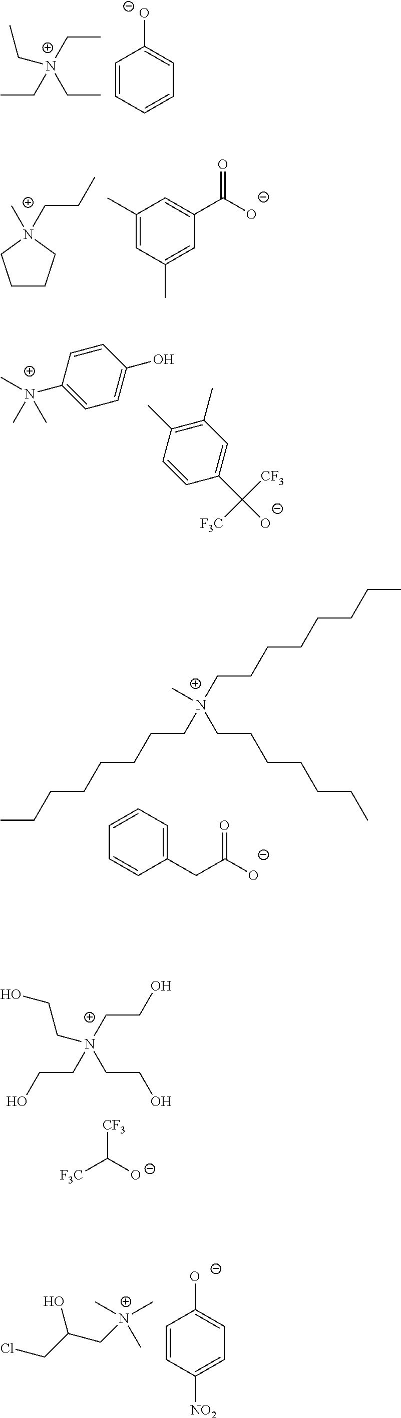

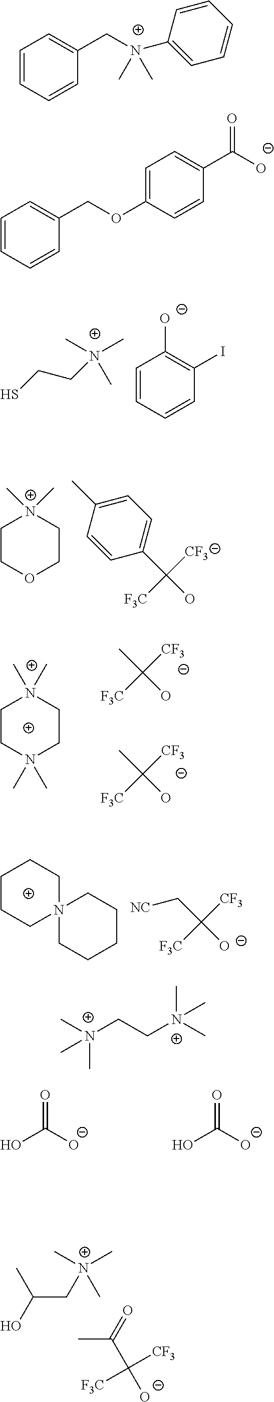

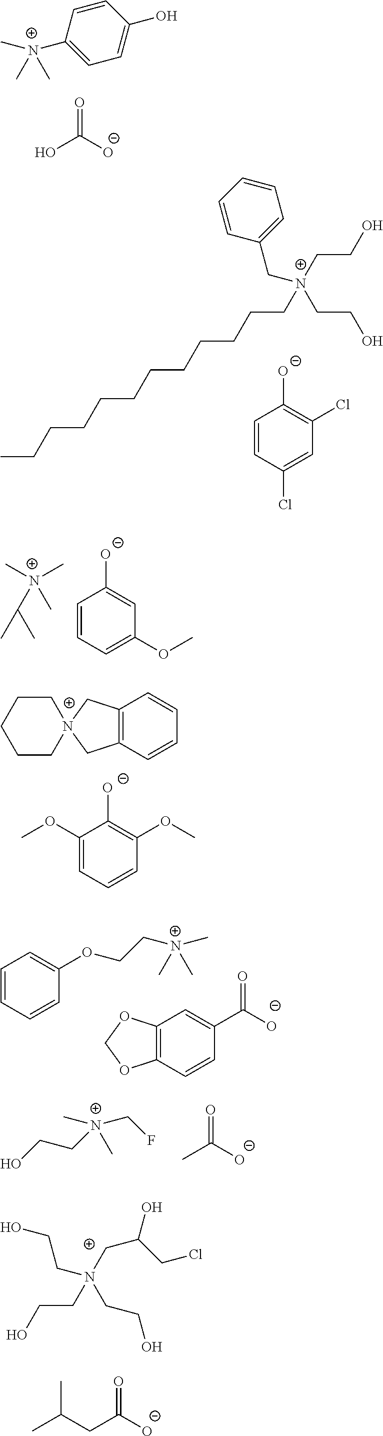

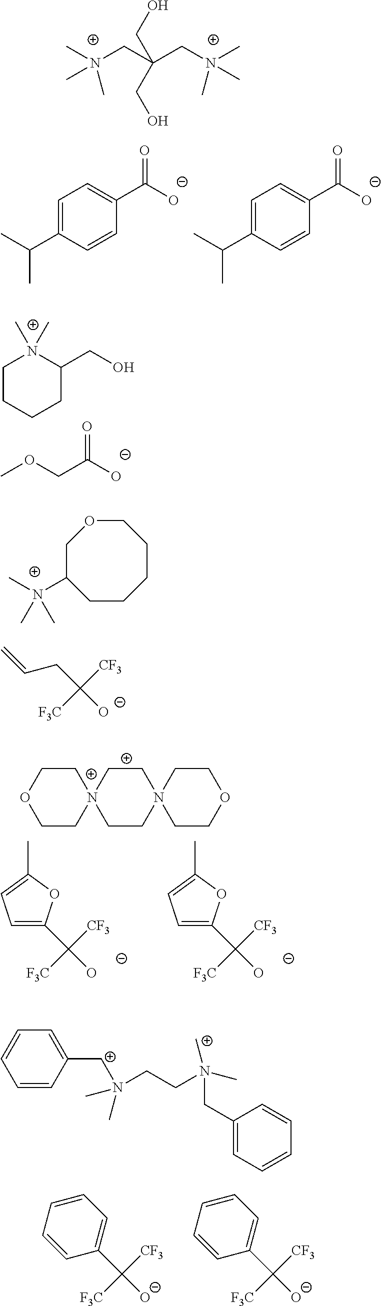

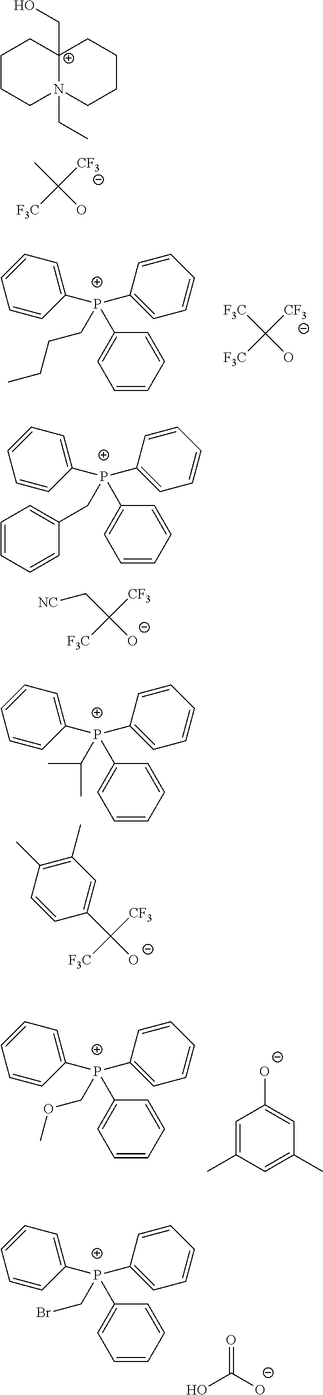

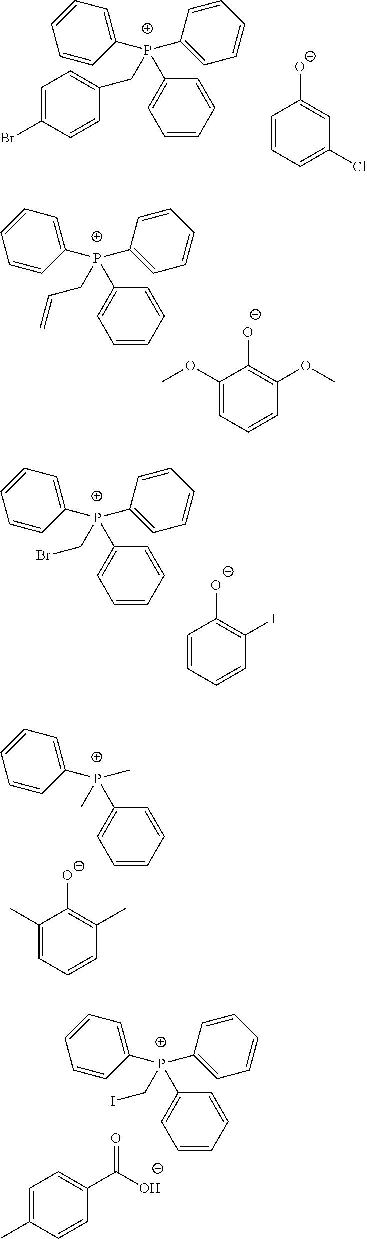

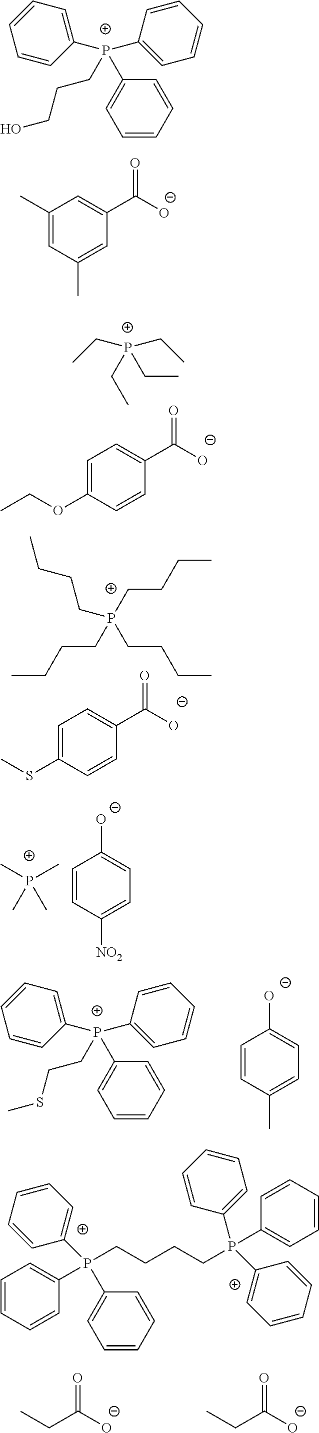

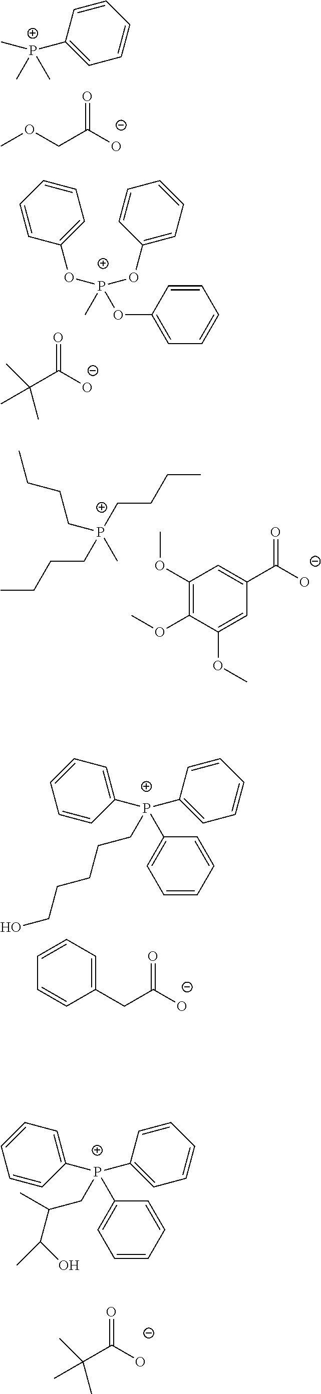

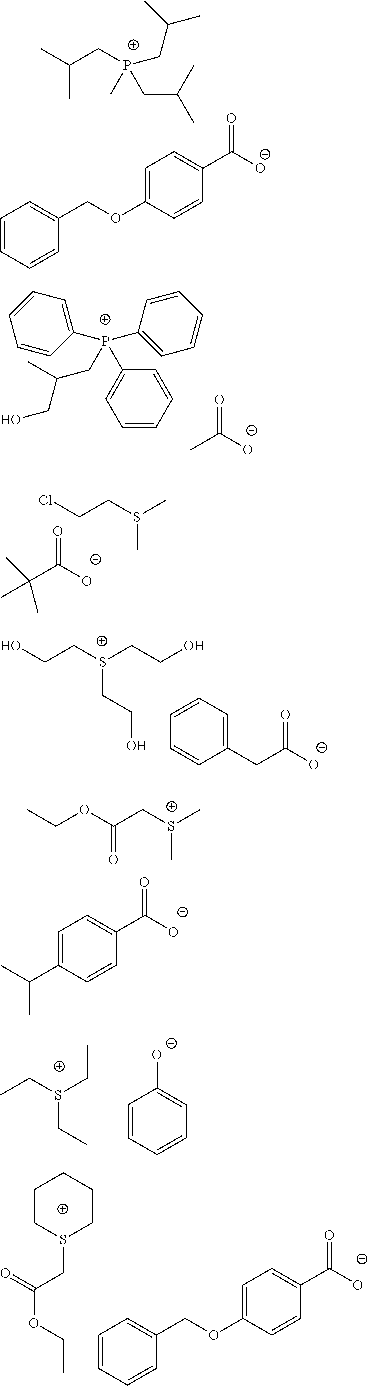

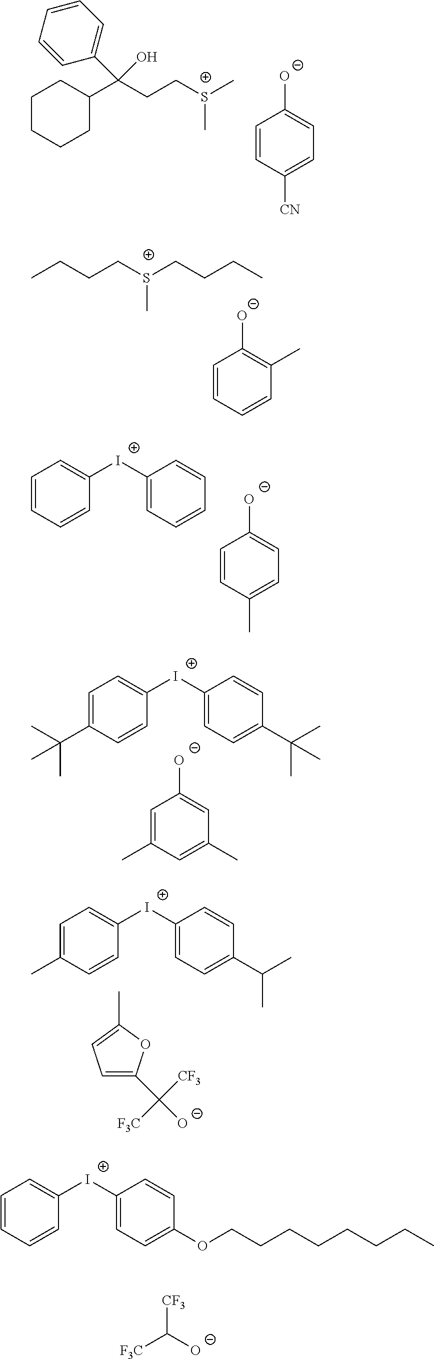

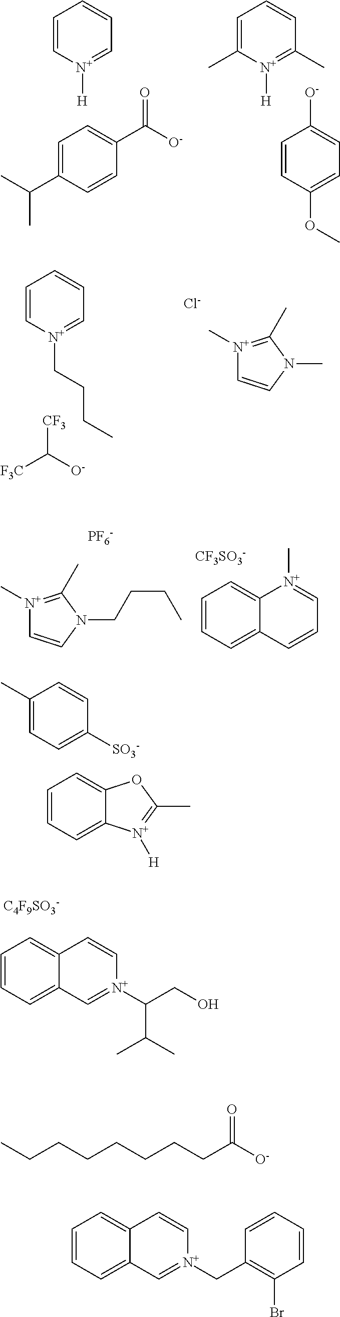

In order to make the effect of the invention more excellent, pKa thereof of the conjugate acid of the anion is preferably higher than 4.0, and more preferably 5.0 or higher. The upper limit is not particularly limited, but pKa is 11.0 or lower in many cases, and in order to make the pattern collapse to be more suppressed (hereinafter, referred to as “in order to make the effect of the invention more excellent”), pKa thereof is preferably 10.5 or lower.

In addition, in this specification, pKa is a calculated value obtained from ACD/ChemSketch (ACD/Labs 8.00 Release Product Version: 8.08).

In addition, hereinafter, specific examples of pKa of the conjugate acid of the anion are described.

Respective numbers below in the structural formulae represent pKa of the conjugate acids of the anions, respectively.

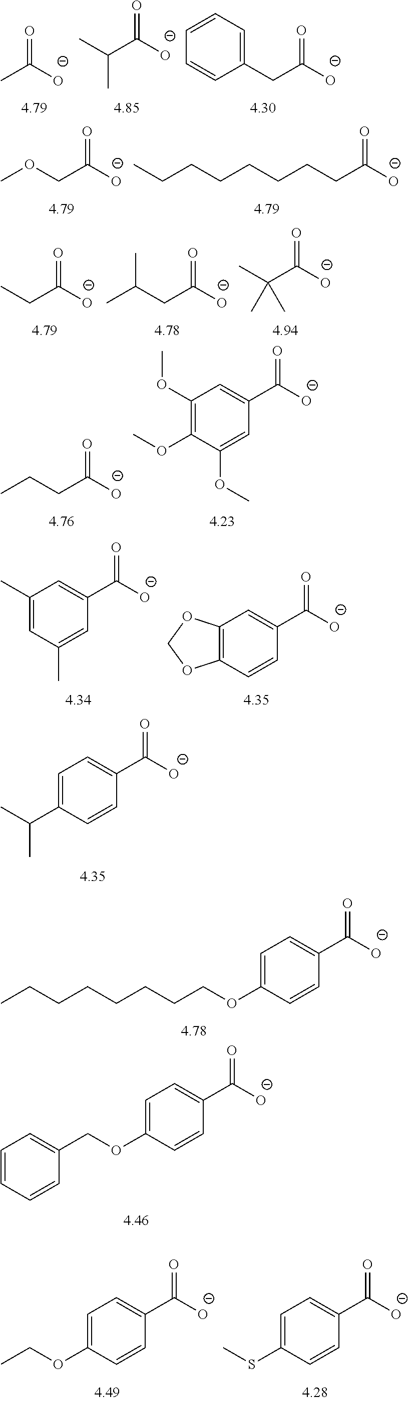

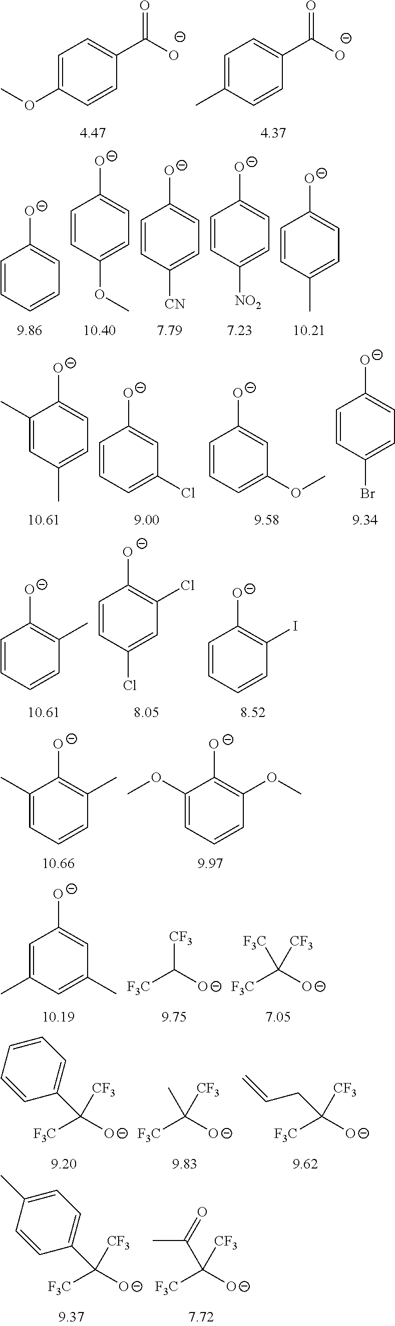

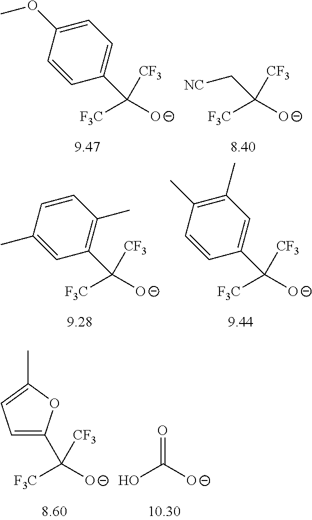

In addition, the proportion of the molecular weight occupied by carbon atoms in the cation of the onium salt and the total molecular weight of the cation (molecular weight occupied by carbon atom/total molecular weight of cation) is not particularly limited, but in order to make the effect of the invention more excellent, the proportion is preferably 0.75 or lower and more preferably in the range of 0.4 to 0.65.

In addition, the molecular weight occupied by the carbon atom in the cation of the onium salt refers to the total molecular weight of carbon atoms in the cation included in the onium salt. For example, if 10 carbon atoms are included in the cation of the onium salt, the molecular weight occupied by carbon atoms is 120.

As a preferred embodiment of the onium salt, in order to make the effect of the invention more excellent, at least one selected from the group consisting of an onium salt represented by Formula (1-1) and onium salt represented by Formula (1-2) is included.

In addition, only one type of the onium salt represented by Formula (1-1) may be used, or two or more types thereof may be used in combination. In addition, only one type of the onium salt represented by Formula (1-2) may be used, or two or more types thereof may be used in combination. In addition, the onium salt represented by Formula (1-1) and the onium salt represented by Formula (1-2) may be used in combination.

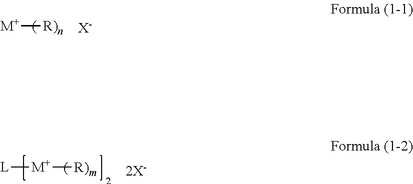

In Formula (1-1), M represents a nitrogen atom, a phosphorus atom, a sulfur atom, or an iodine atom. Among them, in order to make the effect of the invention more excellent, a nitrogen atom is preferable.

R's each independently represent a hydrogen atom, an aliphatic hydrocarbon group that may include a heteroatom, an aromatic hydrocarbon group that may include a heteroatom, or a group obtained by combining two or more types thereof.

The aliphatic hydrocarbon group may have any one of a straight chain shape, a branched chain shape, or a cyclic shape. In addition, the number of carbon atoms included in the aliphatic hydrocarbon group is not particularly limited, but in order to make the effect of the invention more excellent, the number of carbon atoms is preferably in the range of 1 to 15 and more preferably in the range of 1 to 5.

As the aliphatic hydrocarbon group, for example, an alkyl group, a cycloalkyl group, an alkene group, or an alkyne group, or a group obtained by combining two or more types thereof is included.

In the aliphatic hydrocarbon group, a heteroatom may be included. That is, the aliphatic hydrocarbon group may be a heteroatom-containing hydrocarbon group. The type of the contained heteroatom is not particularly limited, but a halogen atom, an oxygen atom, a nitrogen atom, a sulfur atom, a selenium atom, a tellurium atom, and the like are included. For example, —Y₁—, —N(Rₐ)—, —C(═Y₂)—, —CON(R_{b})—, —C(═Y₃)Y₄—, —SOₜ—, —SO₂N(R_{c})—, a halogen atom, or a form of a group obtained by combining two or more types thereof are included.

Y₁ to Y₄ are each independently selected from the group consisting of an oxygen atom, a sulfur atom, a selenium atom, and a tellurium atom. Among them, in view of easiy handling, an oxygen atom and a sulfur atom are preferable.

Rₐ, R_{b}, and R_{c} described above are each independently selected from a hydrogen atom or a hydrocarbon group having 1 to 20 carbon atoms.

t represents an integer of 1 to 3.

The number of carbon atoms included in the aromatic hydrocarbon group is not particularly limited, but in order to make the effect of the invention more excellent, the number of carbon atoms is preferably in the range of 6 to 20 and more preferably in the range of 6 to 10.

As the aromatic hydrocarbon group, for example, a phenyl group and a naphthyl group are included.

In the aromatic hydrocarbon group, a heteroatom may be included. The form of including the heteroatom is as described above. In addition, if a heteroatom is included in the aromatic hydrocarbon group, an aromatic heterocyclic group may be formed.

As the preferred embodiment of R, in order to make the effect of the invention more excellent, an alkyl group that may include a heteroatom, an alkene group that may include a heteroatom, a cycloalkyl group that may include a heteroatom, and an aryl group that may include a heteroatom are included.

In Formula (1-1), n represents an integer of 2 to 4. In addition, plural R's may be bonded to each other to form a ring. The types of the formed ring are not particularly limited, but, for example, 5-membered and 6-membered ring structures can be included.

In addition, the formed ring may have aromaticity, and, for example, the cation of the onium salt represented by Formula (1-1) may be a pyridinium ring represented by Formula (10) described below. Further, a heteroatom may be included in a portion of the formed ring, for example, the cation of the onium salt represented by Formula (1-1) may be an imidazolium ring represented by Formula (11) described below.

In addition, the definition of R in Formulae (10) and (11) is the same as the definition of R in Formula (1-1).

In Formulae (10) and (11), Rv's each independently represent a hydrogen atom or an alkyl group. Plural Rv's may be bonded to each other to form a ring.

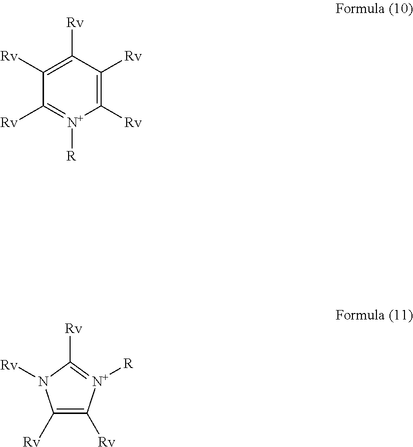

X⁻ represents an monovalent anion. The definition of monovalent anion is as described above.

In Formula (1-1), if M is a nitrogen atom or a phosphorus atom, n represents 4. If M is a sulfur atom, n represents 3. If M is an iodine atom, n represents 2.

The definitions of R and X⁻ in Formula (1-2) are the same as the definitions of R and X⁻ in Formula (1-1). In addition, in Formula (1-2), two X⁻'s are included.

L represents a divalent linking group. As the divalent linking group, a substituted or unsubstituted divalent aliphatic hydrocarbon group (preferably having 1 to 8 carbon atoms. For example, alkylene group such as methylene group, ethylene group, and propylene group), a substituted or unsubstituted divalent aromatic hydrocarbon group (preferably having 6 to 12 carbon atoms. For example, phenylene group), —O—, —S—, —SO₂—, —N(R)— (R: alkyl group), —CO—, —NH—, —COO—, —CONH—, and a group obtained by combining two or more types thereof (for example, alkyleneoxy group, alkyleneoxycarbonyl group, and alkylenecarbonyloxy group) are included.

Among them, in order to make the effect of the invention more excellent, a divalent aliphatic hydrocarbon group or a divalent aromatic hydrocarbon group are preferable.

In Formula (1-2), m's each independently represent an integer of 1 to 3. In addition, if M is a nitrogen atom or a phosphorus atom, m represents 3. If M is a sulfur atom, m represents 2. If M is an iodine atom, m represents 1.

(Polymer Having Onium Salt)

The polymer having an onium salt means a polymer having an onium salt structure in a side chain or a main chain. In other words, the polymer having an onium salt is a polymer having a repeating unit having an onium salt structure.

The definition of the onium salt is the same as the definition of the onium salt described above, and the definitions of the cation and the anion are the same.

As the preferred embodiment of the polymer having an onium salt, in order to make the effect of the invention more excellent, the polymer having the repeating unit represented by Formula (5-1) is included.

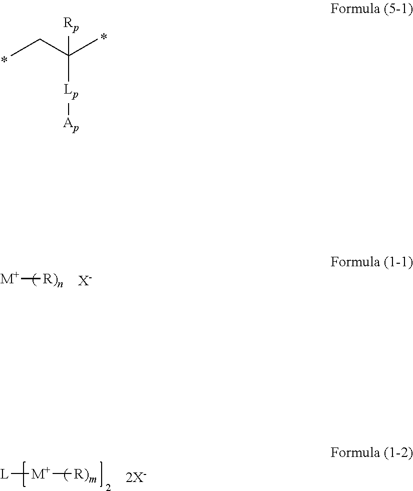

In Formula (5-1), Rₚ represents a hydrogen atom or an alkyl group. The number of carbon atoms included in the alkyl group is not particularly limited, but in order to make the effect of the invention more excellent, the number of carbon atoms is preferably in the range of 1 to 20 and more preferably in the range of 1 to 10.

Lₚ represents a divalent linking group. The definition of the divalent linking group represented by Lₚ is the same as the definition of L represented by Formula (1-2) described above.

Among them, in order to make the effect of the invention more excellent, as Lₚ, an alkylene group, an arylene group, —COO—, and a group obtained by combining two or more types thereof (-arylene group-alkylene group-, —COO-alkylene group-, and the like) are preferable, and an alkylene group is more preferable.

Aₚ represents a residue obtained by excluding one hydrogen atom from onium salts represented by any one of Formulae (1-1) and (1-2). In addition, the residue refers to a group from which one hydrogen atom is extracted from an arbitrary position in a structural formula representing an onium salt so as to have a structure for being bonded to Lₚ above. Generally, one of the hydrogen atoms in R is extracted so as to be a group having a structure for being bonded to Lₚ.

The definitions of the respective groups in Formulae (1-1) and (1-2) are as described above.

Contents of the repeating units represented by Formula (5-1) in the polymer are not particularly limited, but in order to make the effect of the invention more excellent, the content is preferably in the range of 30% by mol to 100% by mol and more preferably in the range of 50% by mol to 100% by mol with respect to the entire repeating units in the polymer.

The weight average molecular weight of the polymer is not particularly limited, but in order to make the effect of the invention more excellent, the weight average molecular weight is preferably in the range of 1,000 to 30,000 and more preferably in the range of 1,000 to 10,000.

As the preferred embodiment of the repeating unit represented by Formula (5-1), the repeating unit represented by Formula (5-2) is included.

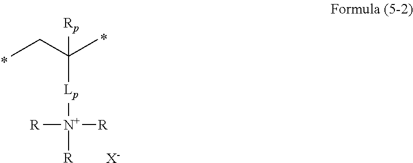

In Formula (5-2), the definitions of Rₚ, Lₚ, and X⁻ are the same as those of Rₚ, Lₚ, and X⁻ in Formula (5-1), and the definition of R is the same as that of R in Formula (1-1).

Further, as the preferred embodiment of the repeating unit represented by Formula (5-2), the repeating units represented by Formulae (5-3) to (5-5) are included.

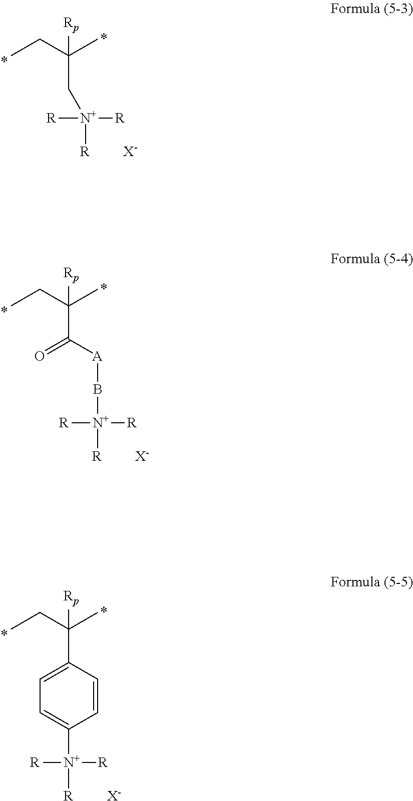

In Formulae (5-3), (5-4), and (5-5), the definition of R is the same as that of R in Formula (1-1), and the definitions of Rₚ and X⁻ are the same as those of Rₚ and X⁻ in Formula (5-2).

In Formula (5-4), A represents —O—, —NH—, or —NR—, and B represents an alkylene group.

(Nitrogen-Containing Compound Including 3 or More Nitrogen Atoms)

In the nitrogen-containing compound, 3 or more nitrogen atoms are included. In order to make the effect of the invention more excellent, the number of nitrogen atoms is preferably 3 or more and more preferably 4 or more.

The molecular weight of the nitrogen-containing compound is not particularly limited, but in order to make the effect of the invention more excellent, the molecular weight is preferably in the range of 50 to 900 and more preferably in the range of 50 to 700.

As the nitrogen-containing compound, in order to make the effect of the invention more excellent, compounds represented by Formula (3) are included.

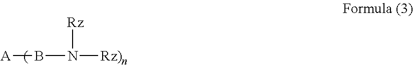

In Formula (3), A represents a single bond, or an n-valent organic group.

As A, specifically, a single bond, a group represented by Formula (1A) below, a group represented by Formula (1B) below,

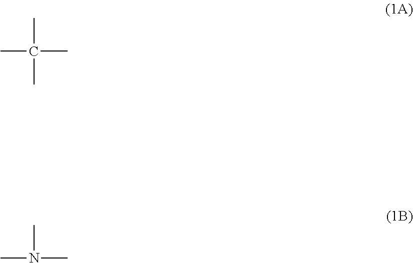

—NH—, —NR—, —O—, —S—, a carbonyl group, an alkylene group, an alkenylene group, an alkynylene group, a cycloalkylene group, an aromatic group, and a heterocyclic group, and an n-valent organic group formed by combining two or more types thereof can be included as preferred examples. Here, R represents an organic group, and is preferably an alkyl group, an alkylcarbonyl group, and an alkylsulfonyl group. In addition, with respect to the combination above, heteroatoms are not linked to each other.

Among them, an alkyl group, a group represented by Formula (1B) described above, —NH— and —NR— are preferable.

Here, as an alkylene group, an alkenylene group, and an alkynylene group, groups having 1 to 40 carbon atoms are preferable, groups having 1 to 20 carbon atoms are more preferable, and groups having 2 to 12 carbon atoms are still more preferable. Here, the alkylene group may be a straight chain group or a branched group, and may have a substituent. Here, as the cycloalkylene group, a group having 3 to 40 carbon atoms is preferable, a group having 3 to 20 carbon atoms is more preferable, and a group having 5 to 12 carbon atoms is still more preferable. The cycloalkylene group may be monocyclic or polycyclic, and may have a substituent on the ring.

The aromatic group may be monocyclic or polycyclic, and a non-benzenoid aromatic group is also included. As the monocyclic aromatic group, a benzene residue, a pyrrole residue, a furan residue, a thiophene residue, an indole residue, and the like can be included, and as the polycyclic aromatic group, a naphthalene residue, an anthracene residue, a tetracene residue, a benzofuran residue, a benzothiophene residue, and the like can be included. The aromatic group may have a substituent.

The n-valent organic group may have a substituent, and the types thereof are not particularly limited, but an alkyl group, an alkoxy group, an alkylcarbonyl group, an alkylcarbonyloxy group, an alkyloxycarbonyl group, an alkenyl group, an alkenyloxy group, an alkenylcarbonyl group, an alkenylcarbonyloxy group, an alkenyloxycarbonyl group, an alkynyl group, an alkynyleneoxy group, an alkynylenecarbonyl group, an alkynylenecarbonyloxy group, an alkynyleneoxycarbonyl group, an aralkyl group, an aralkyloxy group, an aralkylcarbonyl group, an aralkylcarbonyloxy group, an aralkyloxycarbonyl group, a hydroxyl group, an amide group, a carboxyl group, a cyano group, a fluorine atom, and the like can be included as examples.

B represents a single bond, an alkylene group, a cycloalkylene group, or an aromatic group, and the alkylene group, the cycloalkylene group, and the aromatic group may have substituents. Here, descriptions of the alkylene group, the cycloalkylene group, and the aromatic group are as described above.

However, both of A and B are not single bonds.

R_{z}'s each independently represent a hydrogen atom or an alkyl group.

n represents an integer of 2 to 8 and preferably represents an integer of 3 to 8.

In addition, if n is 2, at least one nitrogen atom is included in A. If a nitrogen atom is included in A, for example, at least one selected from the group consisting of a group represented by Formula (1B) described above, —NH—, and NR— is included in A.

Hereinafter, a nitrogen-containing compound is exemplified.

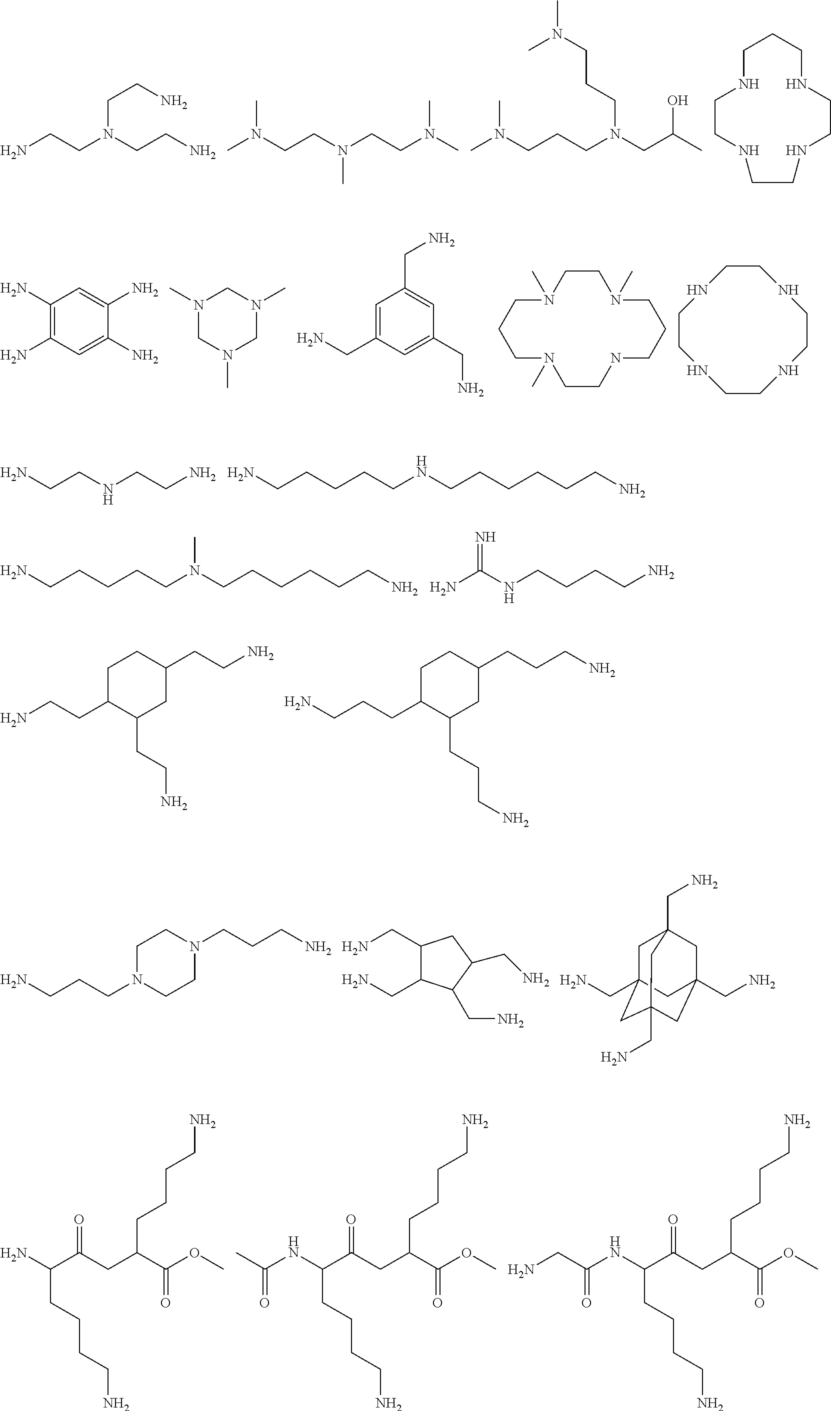

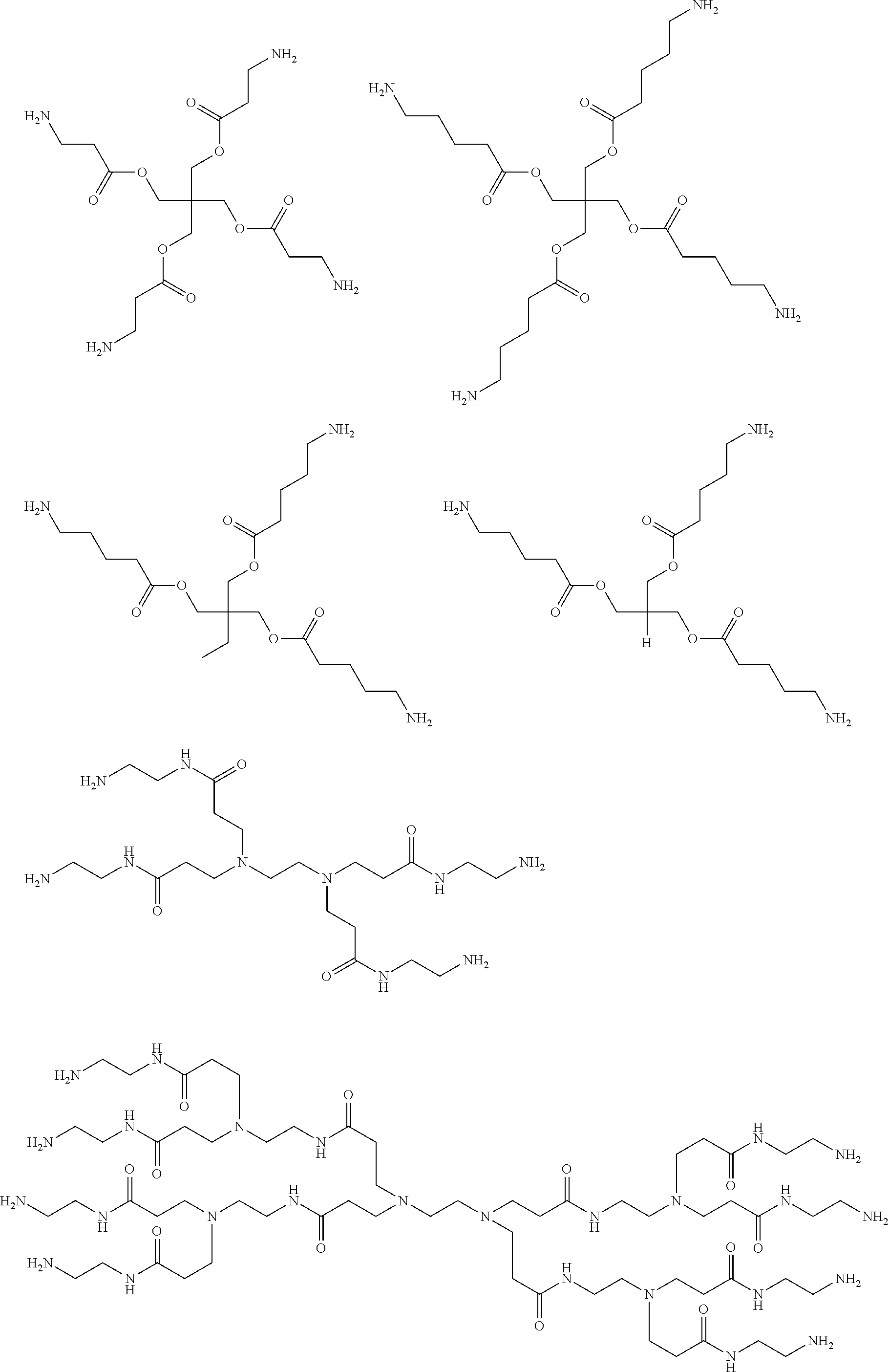 [SMILES: NCCC(=O)OCC(COC(=O)CCN)(COC(=O)CCN)COC(=O)CCN ; NCCCCC(=O)OCC(COC(=O)CCCCN)(COC(=O)CCCCN)COC(=O)CCCCN ; CCC(COC(=O)CCCCN)(COC(=O)CCCCN)COC(=O)CCCCN ; NCCCCC(=O)OCC(COC(=O)CCCCN)COC(=O)CCCCN ; NCCNC(=O)CCN(CCC(=O)NCCN)CCN(CCC(=O)NCCN)CCC(=O)NCCN ; NCCNC(=O)CCN(CCNC(=O)CCN(CCC(=O)NCCN(CCC(=O)NCCN)CCC(=O)NCCN)CCN(CCC(=O)NCCN(CCC(=O)NCCN)CCC(=O)NCCN)CCC(=O)NCCN(CCC(=O)NCCN)CCC(=O)NCCN)CCC(=O)NCCN]

(Basic Polymer)

The basic polymer refers to a polymer having a proton-accepting group and a polymer that interacts with the polar group generated in the resin (A).

In the basic polymer, generally, a repeating unit having a basic region is included, but another repeating unit not having a basic region may be included. In addition, the repeating unit having a basic region is not limited to one type, and plural types thereof may be included.

In addition, as the repeating unit having the basic region, for example, a repeating unit represented by Formula (2) described below, and the like can be included.

As the basic polymer, a polymer having an amino group is preferably included. In addition, in this specification, the “amino group” is a concept including a primary amino group, a secondary amino group, and a tertiary amino group. In addition, in the secondary amino group, a cyclic secondary amino group such as a pyrrolidino group, a piperidino group, a piperazino group, a hexahydrotriazino group, or the like are included.

The amino group may be included in any one of a main chain and a side chain of the polymer.

Specific examples of the side chain in the case where the amino group is included in a portion of the side chain are described below. In addition, “*” represents a linking portion to the polymer.

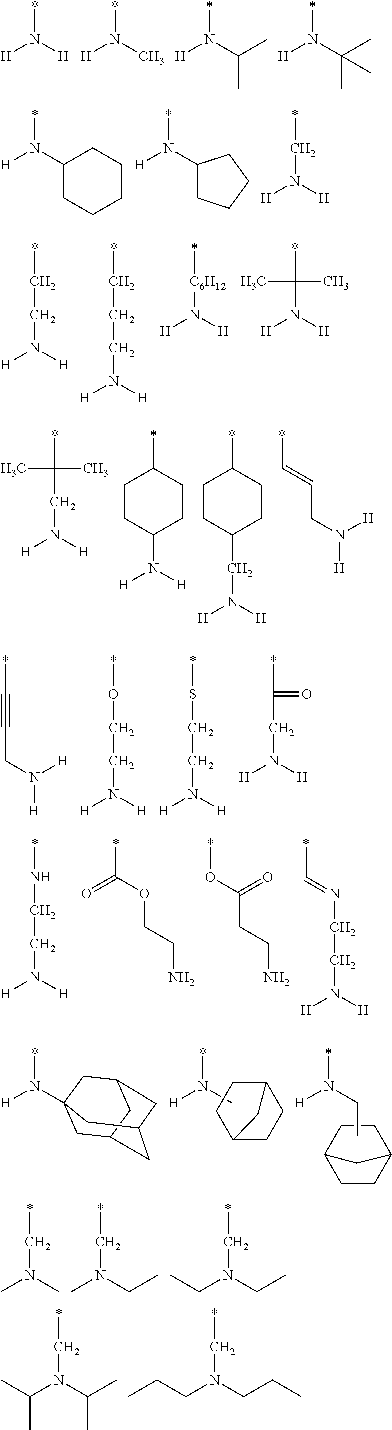

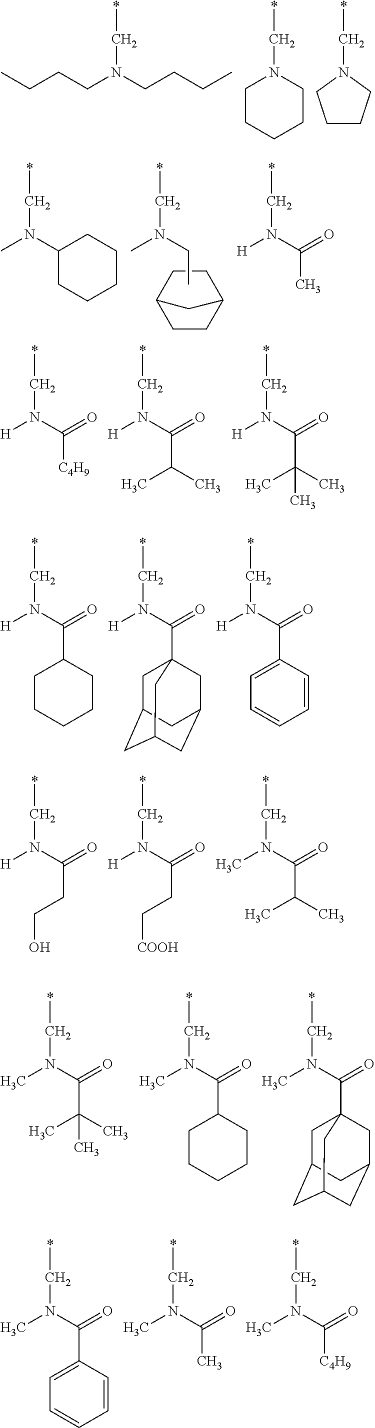

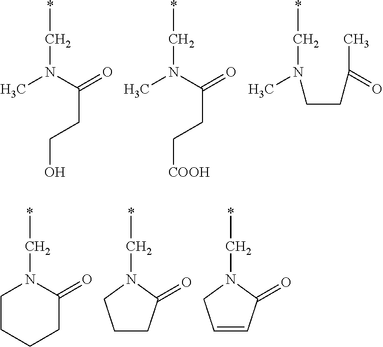

As the polymer having the amino group, for example, polyallylamine, polyethyleneimine, polyvinyl pyridine, polyvinyl imidazole, polypyrimidine, polytriazole, polyquinoline, polyindole, polypurine, polyvinyl pyrrolidone, and polybenzimidazole are included.

As the preferred embodiment of the basic polymer, polymers having the repeating unit represented by Formula (2) are included.

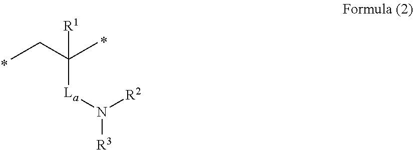

In Formula (2), R¹ represents a hydrogen atom or an alkyl group. The number of carbon atoms included in the alkyl group is not particularly limited, but, in order to make the effect of the invention more excellent, the number of carbon atoms is preferably in the range of 1 to 4 and more preferably in the range of 1 to 2.

R² and R³ each independently represent a hydrogen atom, an alkyl group that may contain a heteroatom, a cycloalkyl group that may contain a heteroatom, or an aromatic group that may contain a heteroatom.

The numbers of carbon atoms included in the alkyl group and the cycloalkyl group are not particularly limited, but the number of carbon atoms is preferably in the range of 1 to 20 and more preferably in the range of 1 to 10.

As the aromatic group, an aromatic hydrocarbon, an aromatic heterocyclic group, or the like is included.

In the alkyl group, the cycloalkyl group, or the aromatic group, a heteroatom may be included. The definition and the preferred embodiment of an heteroatom are the same as those of the heteroatom described in Formula (1-1) above.

In addition, in the alkyl group, the cycloalkyl group, and the aromatic group, substituents (for example, functional group such as hydroxyl group, cyano group, amino group, pyrrolidino group, piperidino group, morpholino group, or oxo group, alkoxy group, or halogen atom) may be included.

Lₐ represents a divalent linking group. The definition of the divalent linking group represented by Lₐ is the same as that of L represented by in Formula (1-2) described above.

Among them, in order to make the effect of the invention more excellent, as Lₐ, an alkylene group, an arylene group, and —COO—, and a group obtained by combining two or more types thereof (-arylene group-alkylene group-, —COO-alkylene group-, and the like) are preferable, and an alkylene group is more preferable.

In addition, a substituent (for example, hydroxyl group) may be further substituted with the groups represented by R¹ to R³ described above and the divalent linking group represented by Lₐ.

Hereinafter, the repeating unit represented by Formula (2) is exemplified.

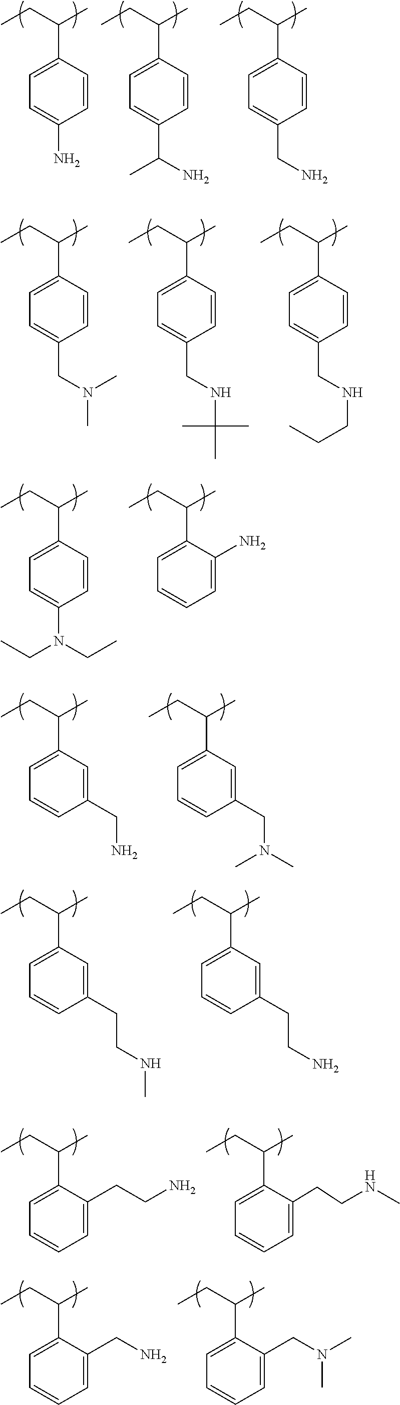

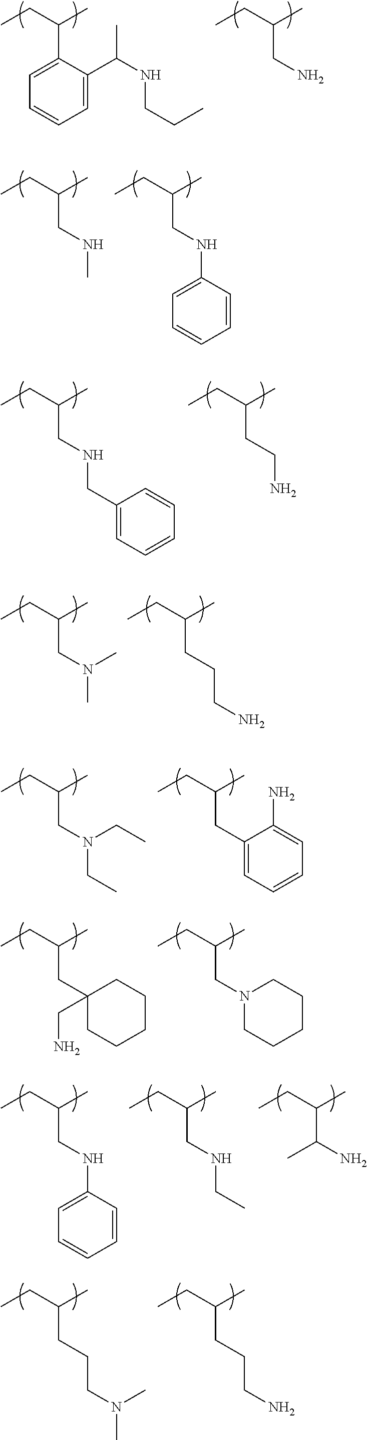

The content of the repeating unit represented by Formula (2) described above in the polymer is not particularly limited, but, in order to make the effect of the invention more excellent, the content is preferably in the range of 40% by mol to 100% by mol and more preferably in the range of 70% by mol to 100% by mol with respect to the entire repeating units in the polymer.

In addition, another repeating unit in addition to the repeating unit represented by Formula (2) may be included in the polymer.

The weight average molecular weight of the basic polymer is not particularly limited, but, in order to make the effect of the invention more excellent, the weight average molecular weight is preferably in the range of 1,000 to 30,000 and more preferably in the range of 1,000 to 10,000.

(Phosphorus-Based Compound)

The phosphorus-based compound is a compound including —P<(phosphorus atom).

At least one phosphorus atom is included in the phosphorus-based compound, and plural (2 or more) phosphorus atoms may be included.

The molecular weight of the phosphorus-based compound is not particularly limited, but, in order to make the effect of the invention more excellent, the molecular weight is preferably in the range of 70 to 500 and more preferably in the range of 70 to 300.

As the preferred embodiment of the phosphorus-based compound, in order to make the effect of the invention more excellent, a phosphorus-based compound selected from the group consisting of the compound represented by Formula (4-1) below and the compound represented by Formula (4-2) is preferable.

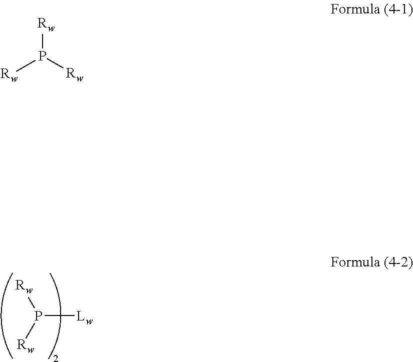

In Formulae (4-1) and (4-2), R_{W}'s each independently represent an aliphatic hydrocarbon group that may include a heteroatom, an aromatic hydrocarbon group that may include a heteroatom, or a group obtained by combining two or more types thereof.

The aliphatic hydrocarbon group may have any one of a straight chain shape, a branched chain shape, or a cyclic shape. In addition, the number of carbon atoms included in the aliphatic hydrocarbon group is not particularly limited, but, in order to make the effect of the invention more excellent, the number of carbon atoms is preferably in the range of 1 to 15 and more preferably in the range of 1 to 5.

As the aliphatic hydrocarbon group, for example, an alkyl group, a cycloalkyl group, an alkene group, an alkyne group, or a group obtained by combining two or more types thereof is included.

The number of carbon atoms included in the aromatic hydrocarbon group is not particularly limited, but, in order to make the effect of the invention more excellent, the number of carbon atoms is preferably in the range of 6 to 20 and more preferably in the range of 6 to 10.

As the aromatic hydrocarbon group, for example, a phenyl group and a naphthyl group are included.

In the aliphatic hydrocarbon group and the aromatic hydrocarbon group, heteroatoms may be included. The definition and the preferred embodiment of an heteroatom are the same as those of the heteroatom described in Formula (1-1). In addition, as the heteroatom, an oxygen atom is preferably included, and an atom included in the form of —O— is more preferable.

L_{W} represents a divalent linking group. As the divalent linking group, a substituted or unsubstituted divalent aliphatic hydrocarbon group (preferably having 1 to 8 carbon atoms. For example, alkylene group such as methylene group, ethylene group, or propylene group), a substituted or unsubstituted divalent aromatic hydrocarbon group (preferably having 6 to 12 carbon atoms. For example, arylene group), —O—, —S—, —SO₂—, —N(R)— (R: alkyl group), —CO—, —NH—, —COO—, —CONH—, or a group obtained by combining two or more types thereof (for example, alkyleneoxy group, alkyleneoxycarbonyl group, or alkylenecarbonyloxy group) is included.

Among them, in order to make the effect of the invention more excellent, a divalent aliphatic hydrocarbon group or a divalent aromatic hydrocarbon group is preferable.

Hereinafter, specific examples of the phosphorus-based compound are exemplified.

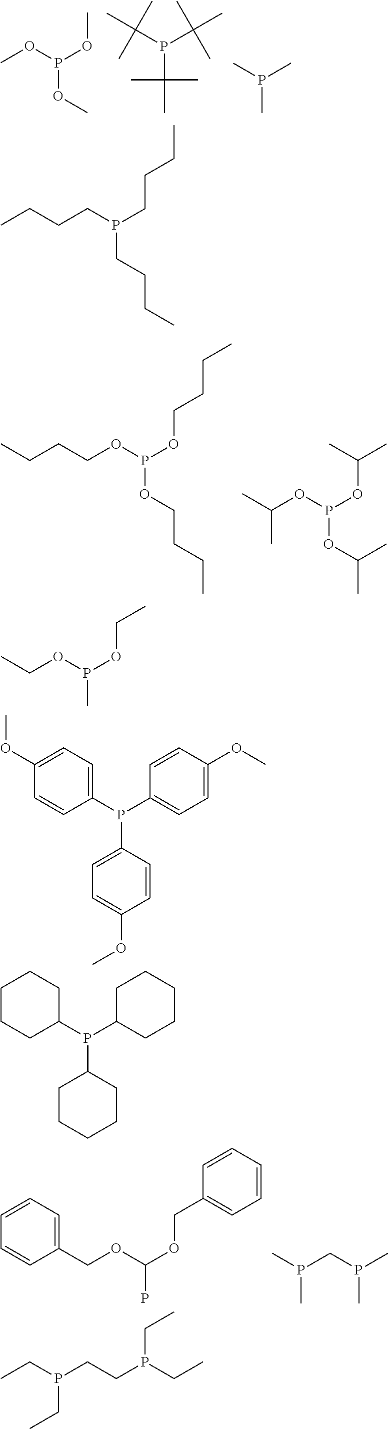

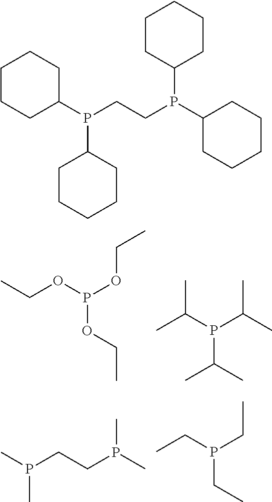

In the developer, a total mass of at least one of the compounds A selected from the group consisting of the onium salt described above, a polymer having an onium salt, a nitrogen-containing compound including three or more nitrogen atoms, and the phosphorus-based compounds is not particularly limited, but, in order to make the effect of the invention more excellent, the total mass is preferably 10% by mass or lower and more preferably in the range of 0.5% by mass to 5% by mass with respect to the total amount of the developer.

In addition, according to the invention, in the compounds A described above, only one type of the compounds A may be used, and two or more types of the compounds A having different chemical structures may be used in combination.

The organic solvent contained in the developer is not particularly limited, but, for example, polar solvents such as a ketone-based solvent, an ester-based solvent, an alcohol-based solvent, an amide-based solvent, and an ether-based solvent, and a hydrocarbon-based solvent are included. In addition, a solvent obtained by mixing these may be used.

As the ketone-based solvent, for example, 1-octanone, 2-octanone, 1-nonanone, 2-nonanone, acetone, 2-heptanone (methyl amyl ketone), 4-heptanone, 1-hexanone, 2-hexanone, diisobutylketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, and propylene carbonate can be included.

As the ester-based solvent, for example, methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, and propyl lactate can be included.

As an alcohol-based solvent, for example, an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol, a glycol solvent such as ethyleneglycol, diethyleneglycol, and triethyleneglycol, a glycol ether solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol can be included.

As the ether-based solvent, for example, in addition to the glycol ether solvents described above, dioxane and tetrahydrofuran are included.

As the amide-based solvent, for example, N-methyl-2-pyrrolidone, N,N-dimethylacetamide, N,N-dimethylformamide, hexamethylphosphoric triamide, and 1,3-dimethyl-2-imidazolidinone can be used.

As the hydrocarbon-based solvent, for example, an aromatic hydrocarbon-based solvent such as toluene and xylene, and an aliphatic hydrocarbon-based solvent such as pentane, hexane, octane, and decane are included.

Particularly, the developer is preferably a developer that contains at least one type of organic solvent selected from the group consisting of a ketone-based solvent and an ester-based solvent, and particularly, a developer including butyl acetate as an ester-based solvent or methyl amyl ketone (2-heptanone) as a ketone-based solvent is preferable.

Plural types of the organic solvents may be used in a mixture, or the organic solvents may be used in a mixture with an organic solvent except for the organic solvents described above or water. However, in order to sufficiently exhibit the effect of the invention, it is preferable that the water content ratio in the total developer is preferably less than 10% by mass and it is more preferable that moisture is not substantially contained.

That is, the used amount of the organic solvent to the developer is preferably in the range of 90% by mass or greater and less than 100% by mass and more preferably in the range of 95% by mass or greater and less than 100% by mass with respect to the total amount of the developer.

The vapor pressure of the developer is preferably 5 kPa or lower, more preferably 3 kPa or lower, and particularly preferably 2 kPa or lower at 20° C. If the vapor pressure of the developer is 5 kPa or lower, evaporation on the substrate of the developer or in the developing cup is suppressed, the evenness in temperature on the wafer surface is enhanced, and resultantly the evenness in dimension on the wafer surface is enhanced.

A proper amount of the surfactant can be added to the developer, if necessary.

The surfactant is not particularly limited, but, for example, ionic or nonionic fluorine-based and/or silicon-based surfactants and the like can be used. As these fluorine and/or silicon-based surfactants, for example, surfactants disclosed in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A), U.S. Pat. No. 5,405,720B, U.S. Pat. No. 5,360,692B, U.S. Pat. No. 5,529,881B, U.S. Pat. No. 5,296,330B, U.S. Pat. No. 5,436,098B, U.S. Pat. No. 5,576,143B, U.S. Pat. No. 5,294,511B, and U.S. Pat. No. 5,824,451B can be included, and preferably a nonionic surfactant is included. The nonionic surfactant is not particularly limited, but it is more preferable to use the fluorine-based surfactant or the silicon-based surfactant.

The used amount of the surfactant is generally in the range of 0.001% by mass to 5% by mass, more preferably in the range of 0.005% by mass to 2% by mass, and still more preferably in the range of 0.01% by mass to 0.5% by mass with respect to the total amount of the developer.

(Developing Method)

As the developing method, for example, a method of immersing a substrate for a certain period of time in a tank filled with the developer (dipping method), a method of performing development by raising the developer onto the substrate surface by the surface tension and resting the developer for a certain period of time (paddle method), and a method of spraying the developer on the substrate surface (spraying method), and a method of continuously discharging a developer while scanning a developer ejecting nozzle at a certain speed on a substrate rotating at a certain speed (dynamic dispensing method), and the like can be applied.

If the various developing methods above include a step of discharging the developer from a development nozzle of a developing apparatus to a resist film, the ejection pressure of the ejected developer (flow velocity per unit area of the ejected developer) is, for example, preferably 2 mL/sec/mm² or slower, more preferably 1.5 mL/sec/mm² or slower, and still more preferably 1 mL/sec/mm² or slower. The lower limit of the flow velocity is not particularly limited, but, considering the throughput, the preferable flow velocity is preferably 0.2 mL/sec/mm² or faster.

Details thereof are disclosed in JP2010-232550A, particularly in Paragraphs “0022” to “0029”.

In addition, after the step of performing development by using the developer including the organic solvent, a step of stopping the development while substituting a developer to another solvent may be performed.

(Rinsing Treatment)

After the organic solvent development, it is preferable to perform washing by using the rinse liquid.

The rinse liquid is not particularly limited as long as the rinse liquid does not dissolve the resist film, and liquid including a general organic solvent can be used.

The rinse liquid is preferably a rinse liquid containing at least one type of organic solvents selected from the group consisting of a hydrocarbon-based solvent, a ketone-based solvent, an ester-based solvent, an alcohol-based solvent, an amide-based solvent, and an ether-based solvent, more preferably a rinse liquid containing at least one type of organic solvents selected from the group consisting of a ketone-based solvent, an ester-based solvent, an alcohol-based solvent, and an amide-based solvent, still more preferably a rinse liquid containing an alcohol-based solvent or an ester-based solvent, particularly preferably a rinse liquid containing an monovalent alcohol, and most preferably a rinse liquid containing an monovalent alcohol having 5 or more carbon atoms.

Specific examples of the hydrocarbon solvent, the ketone-based solvent, the ester-based solvent, the alcohol-based solvent, the amide-based solvent, and the ether-based solvent are the same as those of the organic-based developer described above.

As the monovalent alcohol, for example, straight chain, branched, or cyclic monovalent alcohols and the like are included, and specifically, 1-hexanol, 2-hexanol, 4-methyl-2-pentanol, 1-pentanol, 3-methyl-1-butanol, and the like are included.

The rinse liquid may be rinse liquid containing plural solvents. In addition, the rinse liquid may contain organic solvents other than those above.

The water content of the rinse liquid is preferably 10% by mass or less, more preferably 5% by mass or less, and particularly preferably 3% by mass or less. If the water content ratio is 10% by mass or less, more preferable developing characteristics can be obtained.

The vapor pressure of the rinse liquid is preferably in the range of 0.05 kPa to 5 kPa or lower, more preferably in the range of 0.1 kPa to 5 kPa, and most preferably in the range of 0.12 kPa to 3 kPa at 20° C. If the vapor pressure of the rinse liquid is in the range of 0.05 kPa to 5 kPa, the evenness in temperature on the wafer surface is enhanced, and further the swelling caused by the penetration of the rinse liquid is suppressed such that the evenness in dimension on the wafer surface is enhanced.

A proper amount of the surfactant may be added to the rinse liquid, to be used. Specific examples and the used amount of the surfactant are the same as those in the organic-based developer described above.

In the rinse treatment, the washing treatment is performed on the wafer subjected to the organic solvent development by using the rinse liquid. The method of the washing treatment is not particularly limited, but, for example, a method of continuously discharging the rinse liquid to the substrate rotating at a certain speed (spin coating method), a method of immersing a substrate for a certain period of time in a tank filled with the rinse liquid (dipping method), and a method of spraying a rinse liquid to a substrate surface (spraying method) can be applied. Among them, a method of performing a washing treatment by the spin coating method, rotating the substrate at the rotation speed of 2,000 rpm to 4,000 rpm after the washing, and removing the rinse liquid from the substrate is preferable. In addition, a method of performing a baking treatment (Post Bake) after a rinse treatment is preferable. By the baking treatment, the developer and the rinse liquid remaining between patterns and in a pattern are removed. The baking treatment after the rinse treatment is generally in the range of 40° C. to 160° C., preferably in the range of 70° C. to 95° C., generally for 10 seconds to 3 minutes, and preferably for 30 seconds to 90 seconds.

[Arbitrary Step]

Before Step (1) described above, if necessary, a step of forming an antireflection film on a substrate (antireflection film forming step) may be performed. If the antireflection film is provided, the accuracy of the pattern is enhanced.

After the antireflection film forming step is performed, the film in Step (1) described above is formed on the antireflection film.

As the antireflection film, both of inorganic film types such as titanium, titanium dioxide, titanium nitride, chromium oxide, carbon, and amorphous silicon, and organic film types formed of a light absorbing agent and a polymer material can be used. The former requires equipment such as a vacuum coating apparatus, a CVD apparatus, and a sputtering apparatus, in the film form. As the organic antireflection film, for example, a product formed of a condensation product of a diphenylamine derivative, and a formaldehyde-modified melamine resin, an alkali soluble resin, and a light absorbing agent, disclosed in JP1995-69611A (JP-H7-69611A), a reaction product of a maleic anhydride copolymer and a diamine light absorbing agent disclosed in U.S. Pat. No. 5,294,680B, a product containing a resin binder and a methylol melamine-based heat crosslinking agent disclosed in JP1994-118631A (JP-H6-118631A), an acrylic resin-type antireflection film having a carboxylic acid group, an epoxy group, and a light absorbing group disclosed in JP1994-118656A (JP-H6-118656A), a product formed of methylol melamine and a benzophenone-based light absorbing agent disclosed in JP1996-87115A (JP-H8-87115A), and a product obtained by adding a low molecular light absorbing agent to a polyvinyl alcohol resin disclosed in JP1996-179509A (JP-H8-179509A) can be included.

In addition, as the organic antireflection film, a commercially available organic antireflection film such as DUV30 series or DUV-40 series manufactured by Brewer Science Inc., AR-2, AR-3, or AR-5 manufactured by Shipley Japan can be used.

As the antireflection film, for example, AQUATAR-II, AQUATAR-III, AQUATAR-VII, and AQUATAR-VIII manufactured by AZ Electronic Materials are included.

The thickness of the antireflection film is not particularly limited, but in view of the antireflective function, the thickness is preferably in the range of 1 μm to 500 μm and more preferably in the range of 1 μm to 200 μm.

The pattern-forming method according to the invention can include a step (alkaline development step) of forming a resist pattern by performing development using an alkaline aqueous solution. Accordingly, a finer pattern can be formed.

According to the invention, a portion having weak exposure strength is removed by the development step using the developer including the organic solvent described above, but a portion having strong exposure strength is also removed by performing an alkaline development step. By a multiple development process in which development is performed plural times in this manner, pattern-forming is performed without dissolving only an area of the intermediate exposure strength. Therefore, it is possible to form a pattern finer than a general pattern (the same mechanism as in “0077” of JP2008-292975).

The alkaline development can be performed at any time of before or after the step of performing development by using the developer including the organic solvent, but the alkaline development is preferably performed before the step of performing development by using the developer including the organic solvent.

As the alkaline developer, for example, alkaline aqueous solutions of inorganic alkalis such as sodium hydroxide, potassium hydroxide, sodium carbonate, sodium silicate, sodium metasilicate, aqueous ammonia, primary amines such as ethylamine and n-propylamine, secondary amines such as diethylamine and di-n-butylamine, tertiary amines such as triethylamine and methyldiethylamine, alkanolamines such as dimethylethanolamine and triethanolamine, quaternary ammonium salts such as tetramethylammonium hydroxide and tetraethylammonium hydroxide, and cyclic amines such as pyrrole and piperidine can be used.

Further, proper amounts of alcohols and surfactants may be added to the alkaline aqueous solution to be used.

The alkali concentration of the alkaline developer is generally in the range of 0.1% by mass to 20% by mass.

The pH of the alkaline developer is generally in the range of 10.0 to 15.0.

Particularly, a 2.38% by mass tetramethylammonium hydroxide aqueous solution is preferable.

The invention also relates to an electronic device producing method including the pattern-forming method according to the invention described above and an electronic device produced by the producing method.

It is preferable that the electronic device according to the invention is mounted on electric and electronic apparatuses (household electrical appliances, OA and media related devices, optical apparatuses, and communication equipment, and the like). In addition, it is preferable that the pattern obtained with the pattern-forming method according to the invention is used generally as etching masks of semiconductor devices and the like, but may be used for other uses. As the other uses, for example, a form of a guide pattern (for example, see ACS Nano Vol. 4 No. 8 Pages 4815-4823) in Directed Self-Assembly (DSA), the use as a core of a so-called spacer process (for example, see JP1991-270227 (JP-H3-270227) and JP2013-164509), is included.

### EXAMPLES

Hereinafter examples are provided, but the invention is not limited thereto.

<Preparation of Composition (Composition for Forming Resist Film)>

Components presented in Table 4 below were dissolved in a solvent presented in the same table, so as to prepare a composition for forming a resist film (actinic ray-sensitive or radiation-sensitive resin composition). In addition, the solid content concentration in the composition for forming the resist film was 3.5% by mass. The solid content concentration means the total concentration of the components except for the solvent.

In addition, if two types are used in the sections of “resin (10 g)” and “hydrophobic resin (0.05 g)” in Table 4, the mass ratio between of the both is 1:1.

TABLE 4

| | Composition | | | | | | | | Developer | | |
|---|---|---|---|---|---|---|---|---|---|---|---|
| | | | | | Hydro- | | | | additive | Rinse | PEB |
| | | Acid | | Basic | phobic | | | | (2% by | liquid | tem- |
| | | generator | | compound | resin | Solvent (mass | Surfactant | | mass to | (mass | pera- |
| | Type | (g) | Resin (10 g) | (g) | (0.05 g) | ratio) | (0.03 g) | Developer | developer) | ratio) | ture |
| Example 1 | A1 | PAG-1 (0.7) | Polymer (3) | N-1 (0.1) | 1b | SL-1/SL-4 | W-1 | SG-1 | A-2 | SR-1 | 100 |
| | | | | | | (80/20) | | | | | |
| Example 2 | A2 | PAG-9 (1.0) | Polymer (12) | N-5 (0.12) | 1b/3b | SL-1/SL-2/SL-3 | | SG-4 | A-5 | SR-1 | 105 |
| | | | | | | (90/5/5) | | | | | |
| Example 3 | A3 | PAG-2 (0.7) | Polymer (7)/ | N-6 (0.08) | 2b | SL-1/SL-3(70/30) | | SG-1 | A-4 | SR-1/SR-4 | 110 |
| | | | Polymer (8) | | | | | | | (90/10) | |
| Example 4 | A4 | PAG-7 (1.0) | Polymer (15) | N-5 (0.14) | 4b | SL-1/SL-4(80/23) | W-2 | SG-1 | A-1 | SR-1 | 100 |
| Example 5 | A5 | PAG-12 | Polymer (1) | N-2/N-7 | 3b | SL-1/SL-3(90/10) | | SG-3 | A-3 | SR-1 | 100 |
| | | (1.0) | | (0.08/0.05) | | | | | | | |
| Example 6 | A6 | PAG-11 | Polymer (10) | N-2/N-11 | 2b/3b | SL-1/SL-3 | | SG-3 | A-9 | SR-1 | 100 |
| | | (1.0) | | (0.06/0.07) | | (70/30) | | | | | |
| Example 7 | A7 | PAG-16 | Polymer (4)/ | N-11 (0.12) | 2b | SL-1/SL-4 | W-2 | SG-1 | A-10 | SR-1/SR-3 | 100 |
| | | (1.0) | Polymer (6) | | | (65/35) | | | | (90/10) | |
| Example 8 | A8 | PAG-4 (0.7) | Polymer (14) | N-8 (0.08) | 4b | SL-1/SL-4 | | SG-1 | A-6 | SR-1 | 100 |
| | | | | | | (70/30) | | | | | |
| Example 9 | A9 | PAG-14 | Polymer (2)/ | N-9 (0.08) | 3b | SL-1/SL-3 | W-1 | SG-1 | A-8 | SR-1 | 100 |
| | | (0.7) | Polymer (13) | | | (65/35) | | | | | |
| Example 10 | A10 | PAG-3 (0.7) | Polymer (8) | N-4 (0.1) | 1b/2b | SL-1/SL-4 | | SG-1 | A-7 | SR-1 | 100 |
| | | | | | | (70/30) | | | | | |
| Example 11 | A11 | PAG-9 (1.0) | Polymer (5) | N-5 (0.12) | 1b | SL-1/SL-3 | | SG-4 | A-6 | | 105 |
| | | | | | | (90/10) | | | | | |
| Example 12 | A12 | PAG-5 (0.7) | Polymer (1)/ | N-8 (0.08) | 4b | SL-1/SL-4 | | SG-3 | A-1 | SR-1 | 100 |
| | | | Polymer (3) | | | (70/30) | | | | | |
| Example 13 | A13 | PAG-10 | Polymer (11)/ | N-10 (0.1) | 2b | SL-1/SL-3 | W-2 | SG-1 | A-3 | SR-1/SR-4 | 100 |
| | | (1.0) | Polymer (15) | | | (90/10) | | | | (90/10) | |
| Example 14 | A14 | PAG-13 | Polymer (5) | N-3 (0.1) | 1b | SL-1/SL-2/SL-3 | | SG-1 | A-11 | SR-1 | 105 |
| | | (1.5)/ | | | | (90/5/5) | | | | | |
| | | PAG-7 (0.5) | | | | | | | | | |
| Example 15 | A15 | PAG-6 (1.0) | Polymer (13) | N-2/N-7 | 3b/4b | SL-1/SL-4 | | SG-4 | A-10 | SR-1/SR-4 | 100 |
| | | | | (0.08/0.05) | | (65/35) | | | | (90/10) | |
| Example 16 | A16 | PAG-8 (0.7) | Polymer (9) | N-5 (0.12) | 1b | SL-1/SL-3 | | SG-1 | A-1 | SR-1 | 100 |
| | | | | | | (90/10) | | | | | |
| Example 17 | A17 | PAG-17 | Polymer (6) | N-11 (0.12) | 4b | SL-5 | | SG-1 | A-10 | SR-2 | 105 |
| | | (1.0) | | | | | | | | | |
| Example 18 | A18 | PAG-7 (1.0) | Polymer (15) | N-5 (0.14) | 4b | SL-1/SL-4 | W-2 | SG-1 | A-3 | SR-1 | 100 |
| | | | | | | (80/23) | | | | | |
| Example 19 | A19 | PAG-7 (1.0) | Polymer (15) | N-5 (0.14) | 4b | SL-1/SL-4 | W-2 | SG-1 | A-9 | SR-1 | 100 |
| | | | | | | (80/23) | | | | | |
| Comparative | C1 | PAG-2 (0.7) | Polymer (7) | N-5 (0.14) | 2b | SL-1/SL-3 | | SG-1 | A′-1 | SR-1 | 100 |
| Example 1 | | | | | | (70/30) | | | | | |
| Comparative | C2 | PAG-12 | Polymer (4)/ | N-2/N-7 | 1b/2b | SL-1/SL-3 | | SG-4 | A′-3 | SR-1 | 100 |
| Example 2 | | (0.7) | Polymer (6) | (0.08/0.05) | | (90/10) | | | | | |
| Comparative | C3 | PAG-1 (1.0) | Polymer (3) | N-8 (0.08) | 4b | SL-1/SL-4 | W-1 | SG-1 | A′-5 | SR-1 | 100 |
| Example 3 | | | | | | (80/20) | | | | | |
| Comparative | C4 | PAG-14 | Polymer (1)/ | N-9 (0.08) | 3b | SL-1/SL-3 | W-1 | SG-3 | A′-4 | SR-1 | 100 |
| Example 4 | | (1.0) | Polymer (3) | | | (65/35) | | | | | |
| Comparative | C5 | PAG-11 | Polymer (6) | N-1 (0.1) | 1b | SL-1/SL-3 | | SG-1 | A′-2 | SR-1 | 100 |
| Example 5 | | (1.0) | | | | (70/30) | | | | | |
| Comparative | C6 | PAG-16 | Polymer (8) | N-6 (0.08) | 1b | SL-1/SL-4 | W-2 | SG-2 | | SR-1 | 100 |
| Example 6 | | (1.0) | | | | (65/35) | | | | | |

Respective components used in Table 4 above are collectively presented below.

With respect to Polymers (1) to (15) described below, the composition ratio of the repeating unit is a molar ratio.

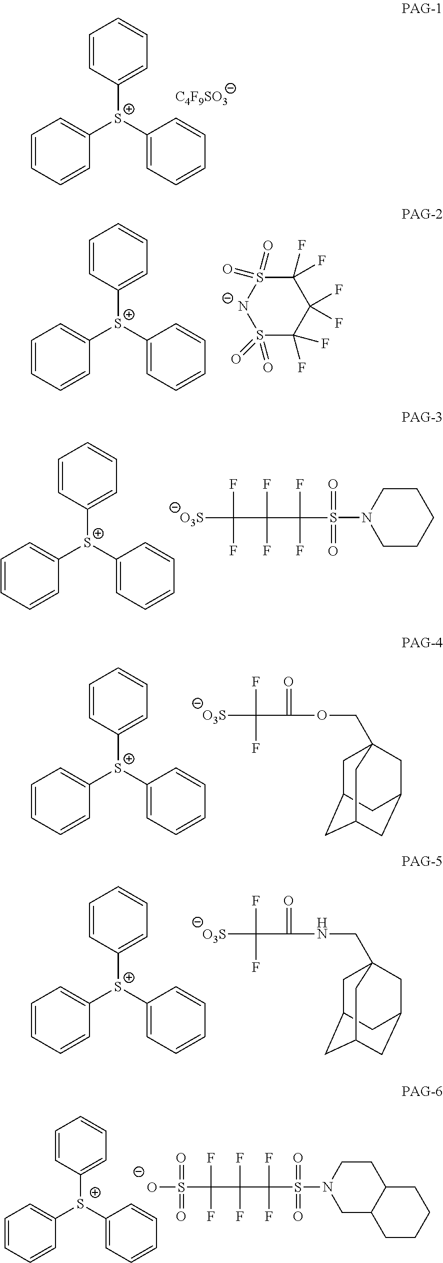

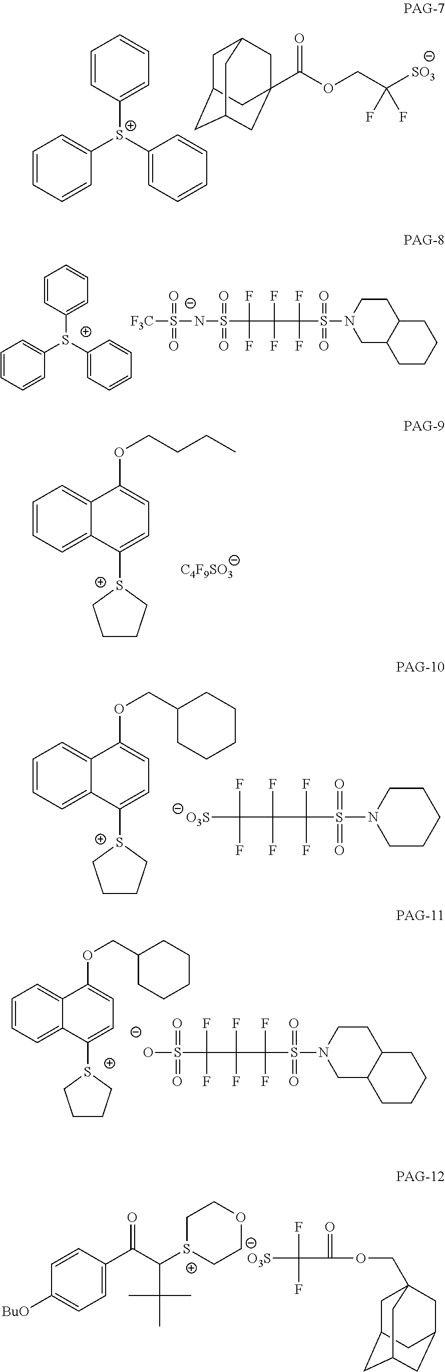

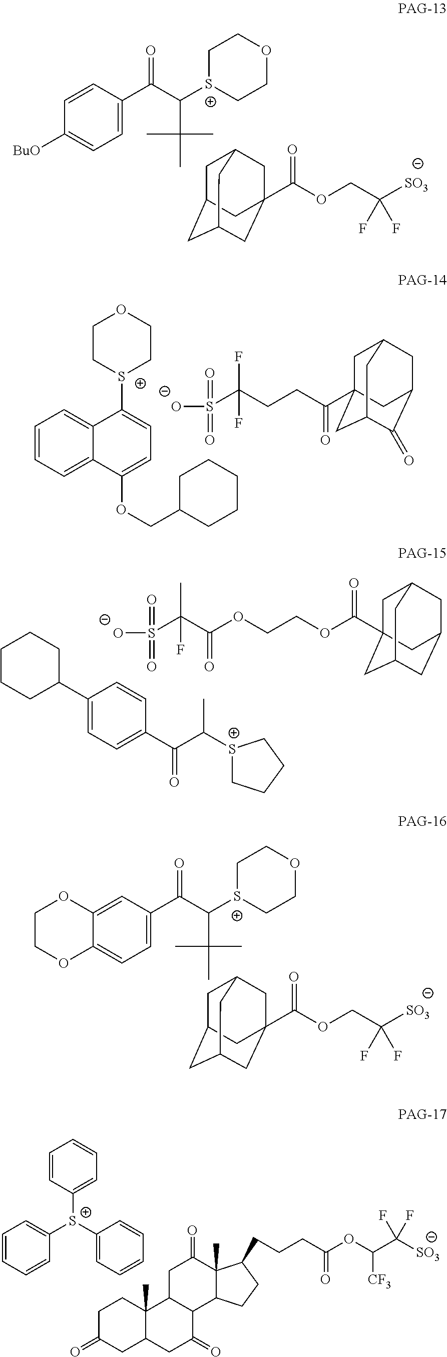

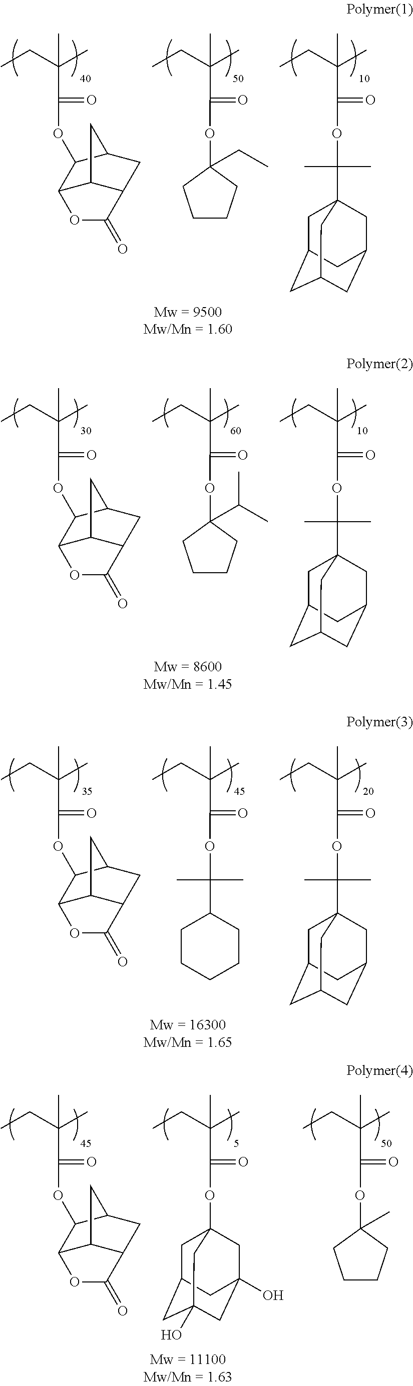

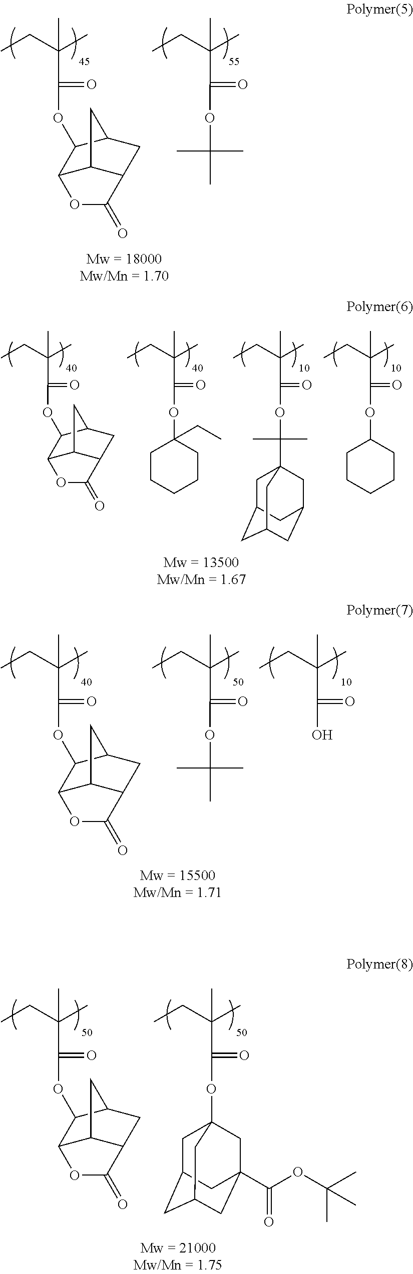

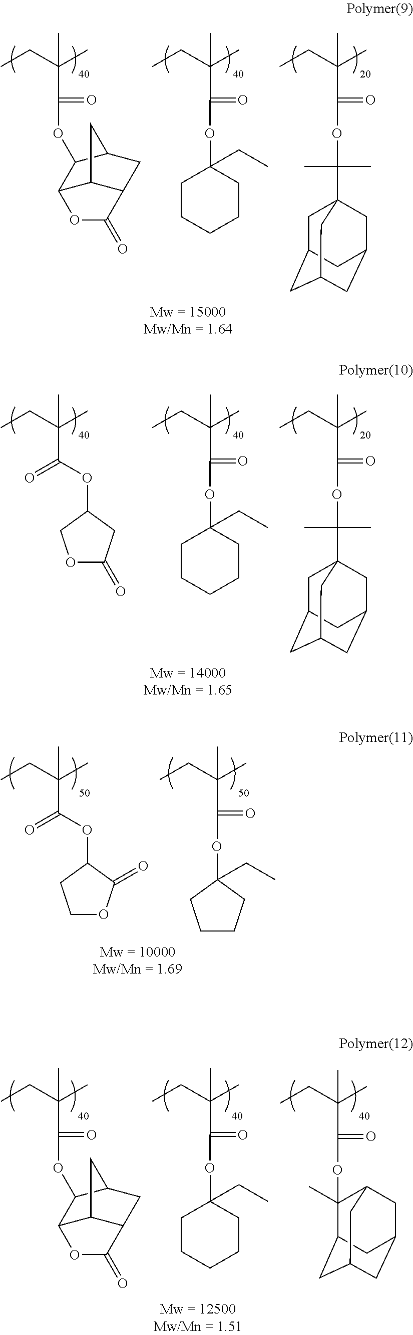

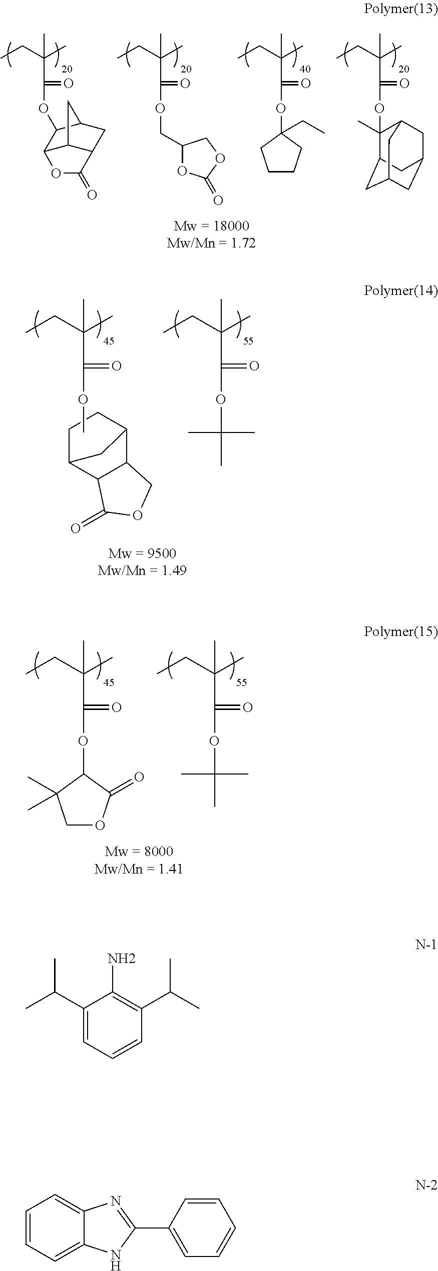

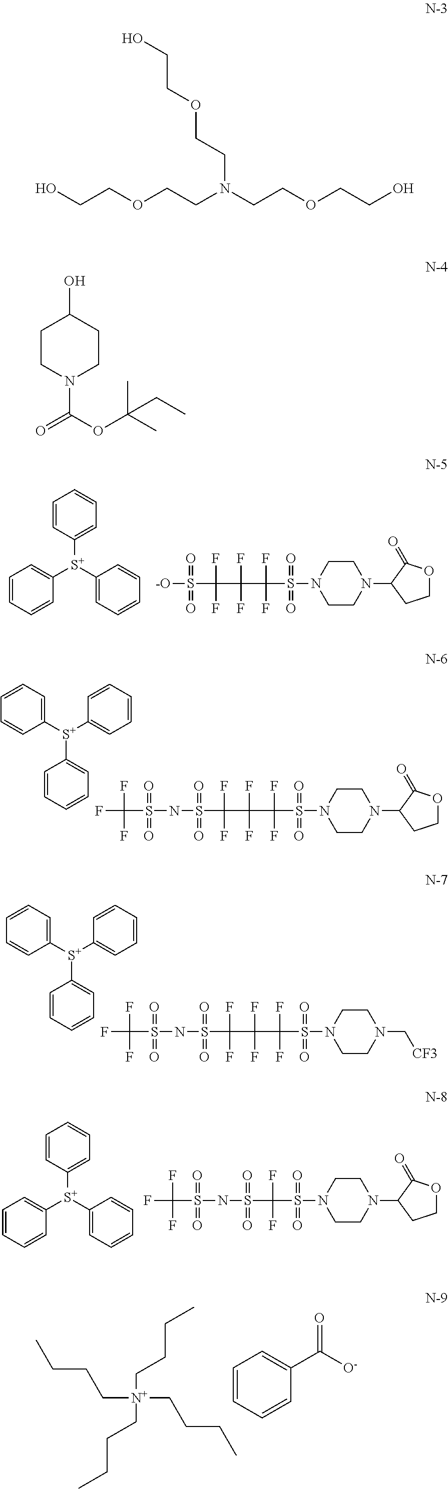

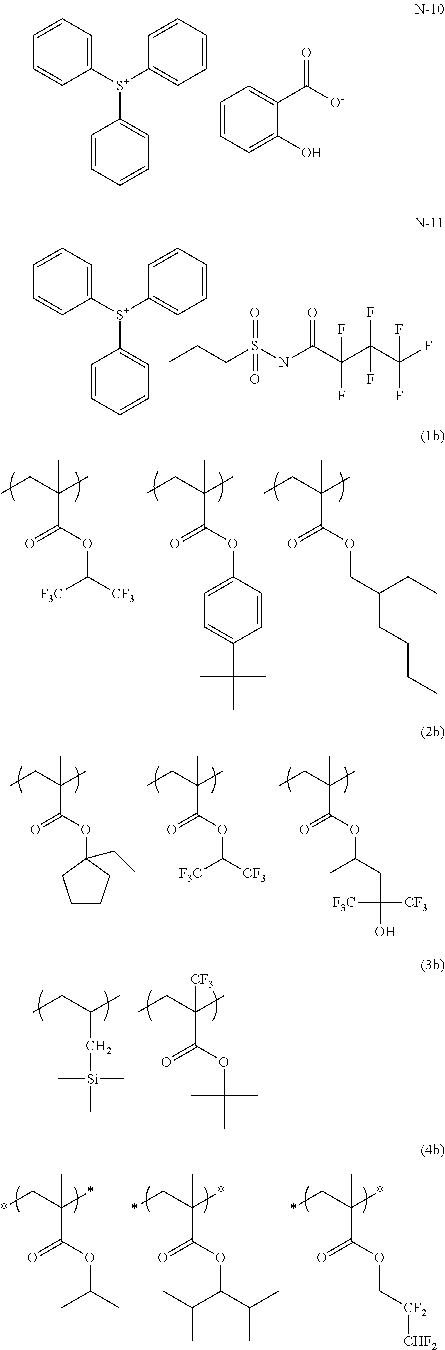

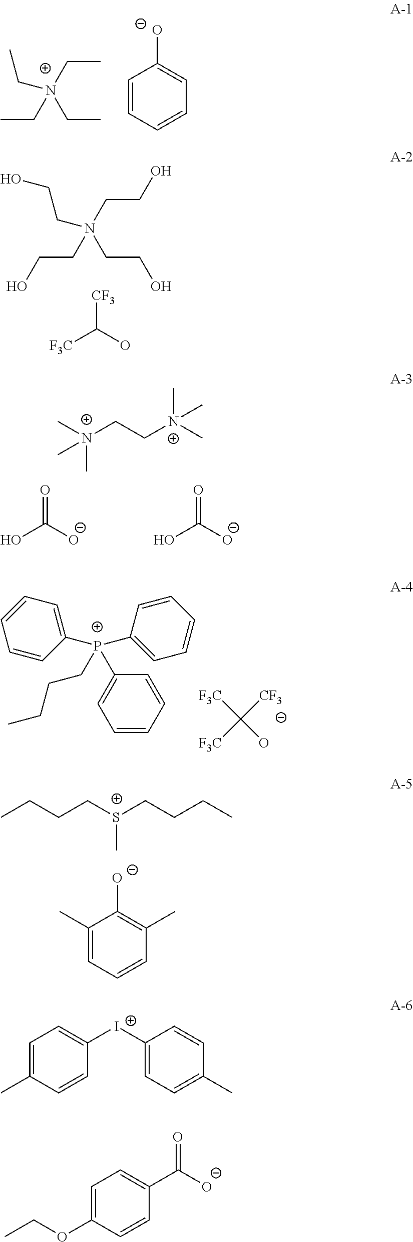

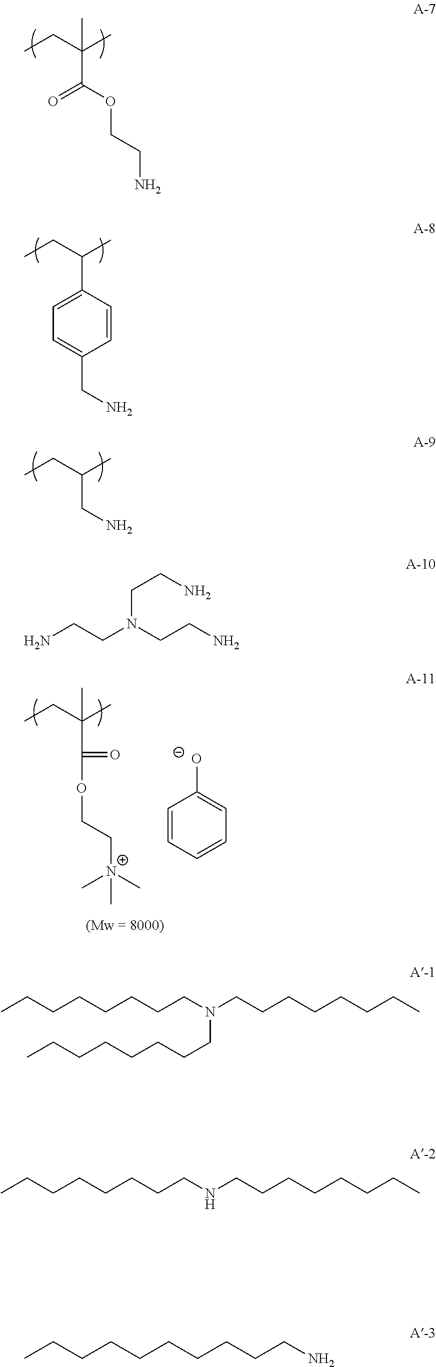

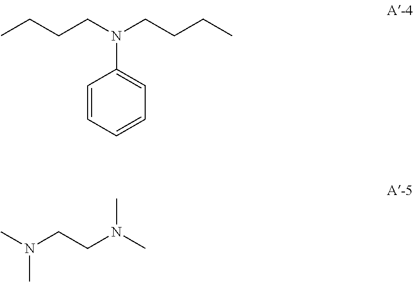

As the surfactant, the following surfactants were used.

W-1: Megaface F176 (manufactured by DIC Corporation; fluorine-based surfactant)

W-2: PolyFox PF-6320 (manufactured by OMNOVA Solutions Inc.; fluorine-based surfactant)

As the solvent, the following solvents were used.
SL-1: Propylene glycol monomethyl ether acetate (PGMEA)
SL-2: Butyl lactate
SL-3: Propylene glycol monomethyl ether (PGME)
SL-4: Cyclohexanone
SL-5: γ-Butyrolactone

As the developer, the following developers were used.
SG-1: Butyl acetate
SG-2: Methyl amyl ketone
SG-3: Pentyl acetate
SG-4: Isopentyl acetate

The following rinse liquids were used as the rinse liquid.
SR-1: 4-Methyl-2-pentanol
SR-2: 1-Hexanol
SR-3: Butyl acetate
SR-4: Methyl amyl ketone

### Example 1

A silicon wafer (diameter of 12 inches) was coated with a composition for forming an antireflection film ARC29SR (manufactured by Nissan Chemical Industries, Ltd.), baking was performed at 205° C. for 60 seconds, and an antireflection film having a film thickness of 86 nm was formed.

Further, the formed antireflection film was coated with a composition A1 for forming the resist film, baking was performed at 100° C. for 60 seconds, and a resist film having a film thickness of 85 nm was formed to obtain a wafer.

The obtained wafer was exposed through a 6% halftone mask having a 1:1 line-and-space pattern in a line width of 44 nm by using an ArF excimer laser liquid immersion scanner (manufactured by ASML HOLDING N.V, XT1700i, NA1.20, C-Quad, Outer sigma 0.750, Inner sigma 0.650, XY deflection). As the immersion liquid, hyperpure water was used. Thereafter, after the wafer was baked at 120° C. for 60 seconds, the wafer was developed by perform paddling for 30 seconds with a developer presented in Table 4, spin drying was performed by rotating the wafer for 30 seconds at the rotation speed of 4,000 rpm, and a 1:1 line and space pattern having a line width of 44 nm was obtained.

### Examples 2 to 19 and Comparative Examples 1 to 6

Instead of the composition A1 for forming the resist film, except for using the compositions A2 to A19 and C1 to C6 for forming the resist film presented in Table 4 and changing types of the developers and the rinse liquid according to Table 4, patterns were obtained in the same sequence as in Example 1.

In addition, the “PEB temperature” in Table 4 means the temperature at the time of baking the composition for forming the resist film.

<Evaluation>

(Pattern Collapse Properties)

When the exposure amount in which a mask pattern of the 1:1 line and space pattern having the line width of 44 nm was reproduced was set to the optimum exposure amount, and the exposure amount was decreased from the optimum exposure amount, pattern collapse properties were defined with a space width in which the pattern was resolved without collapse. When the value was high, the value indicated that a finer pattern had been resolved without collapse and indicated that it was difficult for the pattern collapse to be generated.

(Evaluation of Line Width Roughness (LWR))

The line patterns in the sizes described above in the respective examples and the respective comparative examples were observed using a length measurement scanning electron microscope (SEM manufactured by Hitachi, Ltd., S-9380II), the 50-point line width at the same interval of the range of 2 μm of the line pattern in the longitudinal direction was measured, and 3σ was calculated from the standard deviation, so as to measure the LWR. When a value was smaller, the value indicates that a performance are better.

(Focus Margin; DOF)

With respect to the exposure amount in which the line width of 44 nm can be obtained, the depth of focus in which a line width of 44 nm±10% was reproduced was observed. When a value is greater, a margin of a focus deviation is great and a value is preferable.

[Sensitivity (Eopt)]

The obtained pattern was observed by using a scanning electron microscope (SEM manufactured by Hitachi, Ltd., S-9380II), and an irradiation energy when the (1:1) line and space pattern in the line width of 44 nm was resolved was set to be sensitivity (Eopt). As the value becomes smaller, the sensitivity becomes higher.

(Development Defects Evaluation)

The prepared developer was left at 4° C. for 3 months. In the same manner as described above except for using the developer after having been left thus, a 1:1 line and space pattern having the line width of 44 nm was formed, a defect inspection device KLA2360 manufactured by KLA-Tencor Corporation was used, pixel sizes of the defect inspection device were set to 0.16 m, and the threshold value was set to 20, and the patterns were measured in a random mode. Development defects extracted from the difference caused by superposition of pixel units of a measured image and a comparative image were detected, and the number of defects per unit area (1 cm²) was calculated. When a value was smaller, the value indicated that a performance was better.

The evaluation results are collectively presented in Table 5.

In addition, in Table 5, “collapse” indicates “pattern collapse properties” and “number of defects” indicates “the number of development defects”.

TABLE 5

| | | | | | | Film |
|---|---|---|---|---|---|---|
| | | | | | | thick- |
| | | | | | | ness |
| | | | | | Number of | of |
| | Collapse | LWR | DOF | Sensitivity | defects | pattern |
| | (nm) | (nm) | (nm) | (mJ/cm²) | (unit/cm²) | (nm) |
| Example 1 | 49.2 | 2.9 | 139 | 34.8 | 0.18 | 69 |
| Example 2 | 49.6 | 3.1 | 140 | 36.1 | 0.16 | 67 |
| Example 3 | 49 | 3.1 | 138 | 34.2 | 0.18 | 66 |
| Example 4 | 49.4 | 3 | 142 | 35.1 | 0.19 | 67 |
| Example 5 | 52.1 | 2.9 | 151 | 34.7 | 0.17 | 69 |
| Example 6 | 50.3 | 3 | 146 | 36.1 | 0.5 | 70 |
| Example 7 | 50.1 | 3 | 143 | 35.5 | 0.8 | 69 |
| Example 8 | 48.7 | 3.1 | 139 | 34.5 | 0.2 | 67 |
| Example 9 | 50.5 | 3 | 145 | 35.9 | 0.63 | 71 |
| Example 10 | 50.7 | 3 | 143 | 36 | 0.68 | 74 |
| Example 11 | 50.5 | 3.1 | 143 | 35.8 | 0.69 | 72 |
| Example 12 | 49.6 | 3.1 | 143 | 35.3 | 0.18 | 68 |
| Example 13 | 52 | 2.9 | 150 | 35 | 0.18 | 69 |
| Example 14 | 52.2 | 3 | 151 | 35.5 | 0.16 | 70 |
| Example 15 | 50 | 3.1 | 144 | 35.1 | 0.71 | 69 |
| Example 16 | 50.6 | 3 | 144 | 35.8 | 0.66 | 73 |
| Example 17 | 50.1 | 3 | 143 | 35.4 | 0.72 | 68 |
| Example 18 | 52.2 | 3 | 152 | 35.1 | 0.17 | 70 |
| Example 19 | 50.5 | 2.9 | 146 | 35.3 | 0.55 | 69 |
| Comparative | 47.5 | 3.3 | 118 | 37.1 | 1.18 | 62 |
| Example 1 | | | | | | |
| Comparative | 46.8 | 3.5 | 116 | 36.9 | 1.2 | 61 |
| Example 2 | | | | | | |
| Comparative | 48 | 3.2 | 125 | 37.3 | 1.05 | 66 |
| Example 3 | | | | | | |
| Comparative | 47.6 | 3.3 | 116 | 36.8 | 1.27 | 63 |
| Example 4 | | | | | | |
| Comparative | 47.2 | 3.4 | 114 | 36.9 | 1.15 | 62 |
| Example 5 | | | | | | |
| Comparative | 46.3 | 3.9 | 102 | 40.8 | 0.17 | 58 |
| Example 6 | | | | | | |

As presented in Table 5, pattern collapse was more difficult in the pattern obtained by the pattern-forming method according to the invention, and the pattern collapse properties were excellent.

In addition, as understood by the comparison between Examples 18 and 19, if an onium salt was used as the compounds A, it was confirmed that it was more difficult for pattern collapse to occur.

In addition, as understood by comparison of Examples 5, 13, 14, and 18 with other examples, if a polyvalent onium salt and a polymer having an onium salt were used, it was confirmed that it was more difficult for pattern collapse to occur.

Meanwhile, in Comparative Examples 1 to 5 using the nitrogen-containing compound which is specifically used in the section of examples in JP5056974B, the pattern collapse properties were worse than in the examples. In addition, in Comparative Example 6 in which the predetermined compounds A were not used in the developer, a desired effect was not able to be obtained.

In addition, exposure evaluation by the ArF excimer laser was performed on the examples described above, but the same effects can be expected if the exposure were to be performed by EUV light.

What is claimed is:

1. A pattern-forming method comprising:
forming a film on a substrate by using an actinic ray-sensitive or radiation-sensitive resin composition containing at least a resin that exhibits, due to an action of an acid, increase in polarity and decrease in solubility with respect to a developer including an organic solvent;
exposing the film; and
forming a negative tone pattern by developing the exposed film with a developer including an organic solvent,
wherein the developer includes at least one compound A selected from the group consisting of an onium salt, a polymer having an onium salt, a nitrogen-containing compound including three or more nitrogen atoms, a basic polymer, and a phosphorus-based compound.

2. The pattern-forming method according to claim 1,
wherein the onium salt is at least one selected from the group consisting of an onium salt represented by Formula (1-1) and an onium salt represented by Formula (1-2), 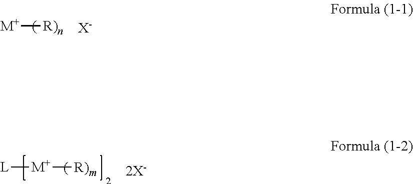
in Formula (1-1) and Formula (1-2), M represents, a nitrogen atom, a phosphorus atom, a sulfur atom, or an iodine atom, R's each are independently a hydrogen atom, an aliphatic hydrocarbon group that may include a heteroatom, an aromatic hydrocarbon group that may include a heteroatom, or a group obtained by combining two or more types thereof, and X⁻ represents a monovalent anion;
in Formula (1-2), L represents a divalent linking group;
in Formula (1-1), n represents an integer of 2 to 4, and n represents 4 if M is a nitrogen atom or a phosphorus atom, n represents 3 if M is a sulfur atom, and n represents 2 if M is an iodine atom;
in Formula (1-2), m's each independently represent an integer of 1 to 3; m represents 3 if M is a nitrogen atom or a phosphorus atom, m represents 2 if M is a sulfur atom, and m represents 1 if M represents an iodine atom; and
plural R's may be bonded to each other to form a ring.

3. The pattern-forming method according to claim 1,
wherein the basic polymer is a polymer having an amino group.

4. The pattern-forming method according to claim 1,
wherein the basic polymer is a polymer having a repeating unit represented by Formula (2), 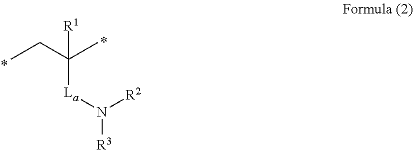
in Formula (2), R¹ represents a hydrogen atom or an alkyl group, R² and R³ each independently represent a hydrogen atom, an alkyl group that may include a heteroatom, a cycloalkyl group that may include a heteroatom, or an aromatic group that may include a heteroatom, Lₐ represents a divalent linking group, and R² and R³ may be bonded to each other to form a ring.

5. The pattern-forming method according to claim 1,
wherein a ratio of a molecular weight occupied by carbon atoms in cations of the onium salt with respect to a total molecular weight of cations in the onium salt is 0.75 or less.

6. The pattern-forming method according to claim 2,
wherein pKa of a conjugate acid of an anion is greater than 4.0.

7. The pattern-forming method according to claim 1,
wherein a total content of the compound A in the developer is 10% by mass or less with respect to a total amount of the developer.

8. The pattern-forming method according to claim 1,
wherein the exposing is exposure by an ArF excimer laser.

9. The pattern-forming method according to claim 1,
wherein the exposing is liquid immersion exposure.

10. The pattern-forming method according to claim 1,
wherein a content of the organic solvent in the developer including the organic solvent is 90% by mass or greater and less than 100% by mass with respect to a total amount of the developer.

11. An electronic device producing method comprising:
the pattern-forming method according to claim 1.

12. An electronic device produced by the electronic device producing method according to claim 11.

13. A developer used in the pattern-forming method according to claim 1, comprising:
at least one compound A selected from the group consisting of an onium salt, a polymer having an onium salt, a nitrogen-containing compound including three or more nitrogen atoms, a basic polymer, and a phosphorus-based compound.

14. The developer according to claim 13, further comprising:
an organic solvent,
wherein a content of the organic solvent is 90% by mass or greater and less than 100% by mass.
